(19) United States
(12) Patent Application Publication
(10) Pub. No.: US 2024/0164205 A1
(43) Pub. Date: May 16, 2024

(54) COMPOSITION FOR ORGANIC OPTOELECTRONIC DEVICE, ORGANIC OPTOELECTRONIC DEVICE, AND DISPLAY DEVICE

(71) Applicant: SAMSUNG SDI CO., LTD., Yongin-si, Gyeonggi-do (KR)

(72) Inventors: Hanill LEE, Suwon-si, Gyeonggi-do (KR); Hyung Sun KIM, Suwon-si, Gyeonggi-do (KR); Mijin LEE, Suwon-si, Gyeonggi-do (KR); Sung-Hyun JUNG, Suwon-si, Gyeonggi-do (KR); Ho Kuk JUNG, Suwon-si, Gyeonggi-do (KR); Seonyeong GWAK, Suwon-si, Gyeonggi-do (KR); Wook KIM, Suwon-si, Gyeonggi-do (KR); Jaehoon KIM, Suwon-si, Gyeonggi-do (KR); Seungjae LEE, Suwon-si, Gyeonggi-do (KR); Yoonman LEE, Suwon-si, Gyeonggi-do (KR); Suheon IM, Suwon-si, Gyeonggi-do (KR)

(21) Appl. No.: 18/285,683

(22) PCT Filed: Sep. 2, 2022
(86) PCT No.: PCT/KR2022/013153

§ 371 Date: Oct. 5, 2023

(30) Foreign Application Priority Data
Sep. 3, 2021 (KR) 10-2021-0117783
Sep. 1, 2022 (KR) 10-2022-0110892

(51) Int. Cl. H10K 85/60; H10K 50/12

(52) U.S. Cl. CPC H10K 85/654; H10K 50/12; H10K 85/622; H10K 85/626; H10K 85/6572; H10K 85/6574; H10K 85/6576

(57) ABSTRACT

Provided are a composition for an organic optoelectronic device, and an organic optoelectronic device including the same, and a display device, the composition for an organic optoelectronic device including a first compound, a second compound, and a third compound, wherein the first compound is represented by Chemical Formula I or Chemical Formula II, the second compound is represented by Chemical Formula III, and the third compound is represented by Chemical Formula IV.

Details of Chemical Formula I, Chemical Formula II, Chemical Formula III and Chemical Formula IV are as described in the specification.

### TECHNICAL FIELD

A composition for an organic optoelectronic device, an organic photoelectronic device, and a display device are disclosed.

### BACKGROUND ART

An organic optoelectronic device (organic optoelectronic diode) is a device capable of converting electrical energy and optical energy to each other.

Organic optoelectronic devices may be largely divided into two types according to a principle of operation. One is a photoelectric device that generates electrical energy by separating excitons formed by light energy into electrons and holes, and transferring the electrons and holes to different electrodes, respectively and the other is light emitting device that generates light energy from electrical energy by supplying voltage or current to the electrodes.

Examples of the organic optoelectronic device include an organic photoelectric device, an organic light emitting diode, an organic solar cell, and an organic photoconductor drum.

Among them, organic light emitting diodes (OLEDs) are attracting much attention in recent years due to increasing demands for flat panel display devices. The organic light emitting diode is a device that converts electrical energy into light, and the performance of the organic light emitting diode is greatly influenced by an organic material between electrodes.

### DISCLOSURE

### Technical Problem

An embodiment provides a composition for an organic optoelectronic device capable of implement an organic optoelectronic device having high efficiency and a long life-span.

Another embodiment provides an organic optoelectronic device including the composition for an organic optoelectronic device

Another embodiment provides a display device including the organic optoelectronic device.

### Technical Solution

According to an embodiment, a composition for an organic optoelectronic device includes a first compound, a second compound, and a third compound, wherein the first compound is represented by Chemical Formula I or Chemical Formula II, the second compound is represented by Chemical Formula III, and the third compound is represented by Chemical Formula IV.

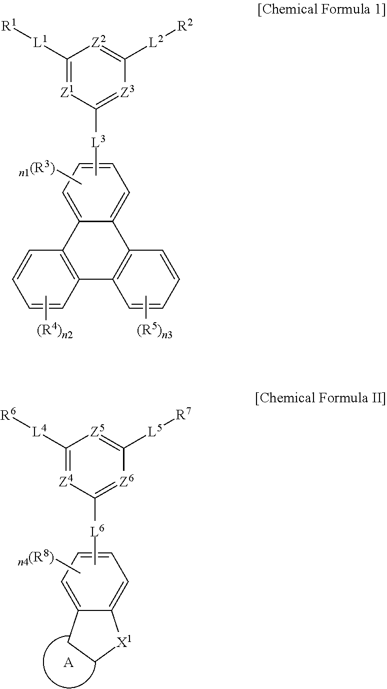

In Chemical Formula I and Chemical Formula II,
Z¹ to Z⁶ are N or C-L^{a}-R^{a},
at least two of Z¹ to Z³ are N,
at least two of Z⁴ to Z⁶ are N,
X¹ is O or S,
L^{a} and L¹ to L⁶ are each independently a single bond, a substituted or unsubstituted C6 to C20 arylene group, a substituted or unsubstituted C2 to C20 heterocyclic group, or a combination thereof,
R¹, R², R⁶, and R⁷ are each independently a substituted or unsubstituted C6 to C30 aryl group, a substituted or unsubstituted C2 to C30 heterocyclic group, or a combination thereof,
R^{a}, R³ to R⁵, and R⁸ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted thioaryl 50 group, a substituted or unsubstituted silyl group, a substituted or unsubstituted amine group, a halogen, a cyano group, or a combination thereof,
R^{a}s of Chemical Formula I are each independently present or linked to R¹ or R² to form a substituted or unsubstituted hetero aromatic polycyclic ring,
R³ to R⁵ of Chemical Formula I are each independently present or adjacent groups are linked to each other to form a substituted or unsubstituted hetero aromatic polycyclic ring, R^{a}s of Chemical Formula II are each independently present or linked to R⁶ or R⁷ to form a substituted or unsubstituted hetero aromatic polycyclic ring,
n1 and n4 are each independently one of integers of 1 to 3,
n2 and n3 are each independently one of integers of 1 to 4, and
ring A is represented by any one of Chemical Formulas II-1 to II-14,

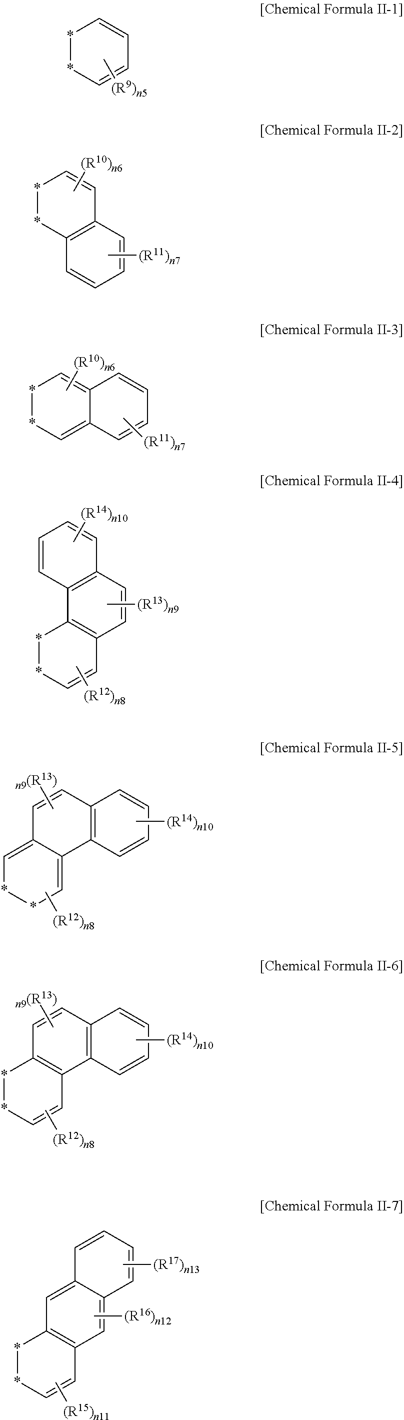

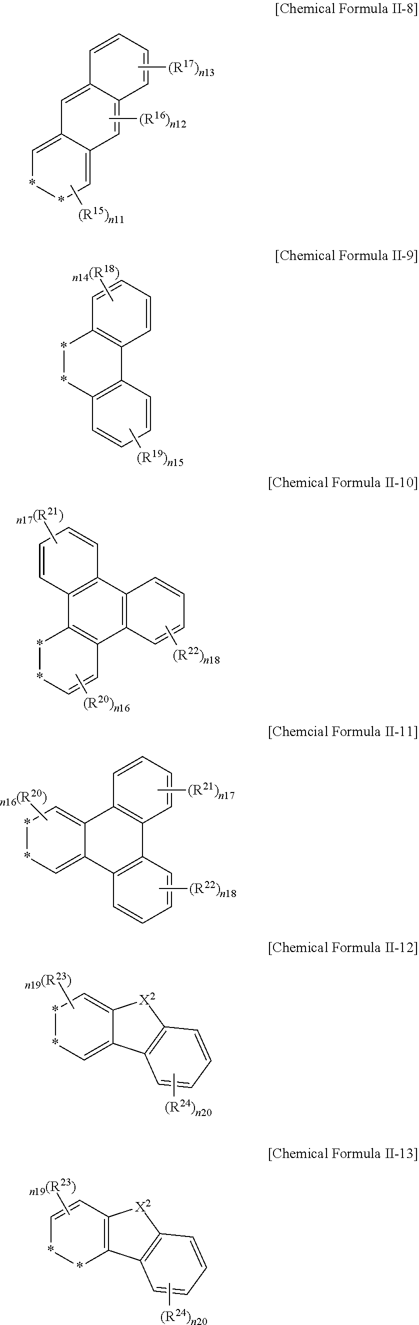

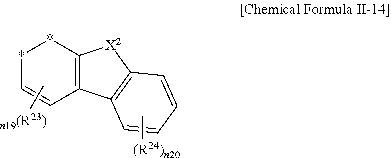

wherein, in Chemical Formula II-1 to Chemical Formula II-14,
X² is O or S,
R⁹ to R²⁴ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof,
n5, n7, n10, n13 to n15, n17, n18, and n20 are each independently one of integers of 1 to 4,
n6, n8, n9, n11, n12, n16, and n19 are each independently an integer of 1 or 2, and
* is a linking point;

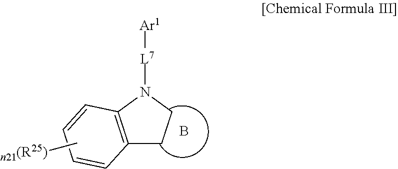

wherein, in Chemical Formula III,
L⁷ is a single bond, a substituted or unsubstituted C6 to C20 arylene group, a substituted or unsubstituted C2 to C20 heterocyclic group, or a combination thereof,
Ar¹ is a substituted or unsubstituted C6 to C30 aryl group, a substituted or unsubstituted dibenzofuranyl group, a substituted or unsubstituted dibenzothiophenyl group, or a combination thereof,
R²⁵ are each independently hydrogen, deuterium, a substituted or unsubstituted C1 to C30 90 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof,
n21 is an integer from 1 to 4, and
a ring B is represented by any one of Chemical Formulas III-1 to Chemical Formula III-4:

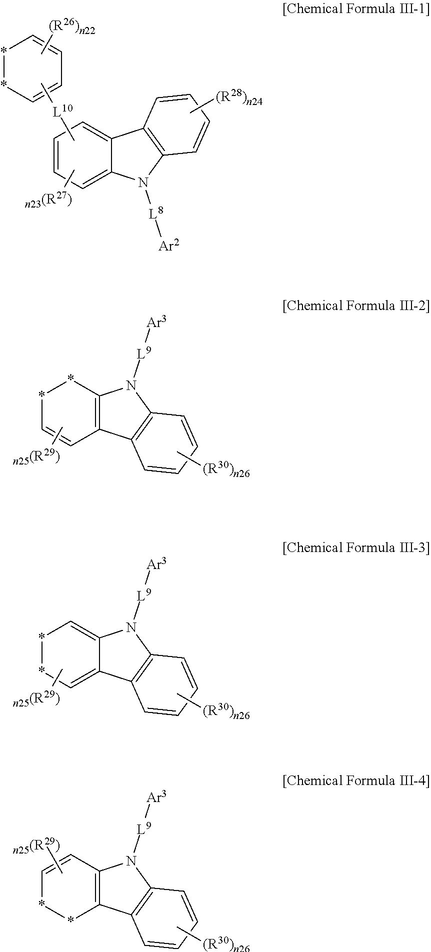

wherein, in Chemical Formula III-1 to Chemical Formula III-4,
L⁸ and L⁹ are each independently a single bond, a substituted or unsubstituted C6 to C20 arylene group, a substituted or unsubstituted C2 to C20 heterocyclic group, or a combination thereof,
L¹⁰ is a single bond or a substituted or unsubstituted C6 to C20 arylene group,
Ar² and Ar³ are a substituted or unsubstituted C6 to C30 aryl group, a substituted or unsubstituted dibenzofuranyl group, a substituted or unsubstituted dibenzothiophenyl group, or a combination thereof,
R²⁶ to R³⁰ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof,
n22 and n23 are each independently one of integers of 1 to 3,
n25 is an integer of 1 or 2,
n24 and n26 are each independently one of integers of 1 to 4, and
* is a linking point;

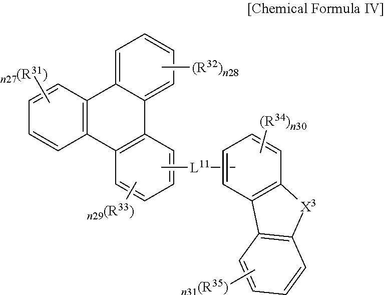

wherein, in Chemical Formula IV,
X³ is O or S,
L¹¹ is a single bond, a substituted or unsubstituted C6 to C20 arylene group, a substituted or unsubstituted C2 to C20 heterocyclic group, or a combination thereof,
R³¹ to R³⁵ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof,
n27, n28, and n31 are each independently an integer of 1 to 4, and
n29 and n30 are each independently an integer of 1 to 3.

According to another embodiment, an organic optoelectronic device includes an anode and a cathode facing each other, and at least one organic layer between the anode and the cathode, wherein the organic layer includes the composition for an organic optoelectronic device.

According to another embodiment, a display device including the organic optoelectronic device is provided.

### Advantageous Effects

High efficiency and long life-span organic optoelectronic devices may be implemented.

### DESCRIPTION OF THE DRAWINGS

FIG. 1 is a cross-sectional view illustrating an organic light emitting diode according to an embodiment.

### DESCRIPTION OF SYMBOLS

100: organic light emitting diode
105: organic layer
110: cathode
120: anode
130: light emitting layer
140: hole transport region
150: electron transport region

### MODE FOR INVENTION

Hereinafter, embodiments of the present invention are described in detail. However, these embodiments are exemplary, the present invention is not limited thereto and the present invention is defined by the scope of claims.

As used herein, when a definition is not otherwise provided, “substituted” refers to replacement of at least one hydrogen of a substituent or a compound by deuterium, a halogen, a hydroxyl group, an amino group, a substituted or unsubstituted C1 to C30 amine group, a nitro group, a substituted or unsubstituted C1 to C40 silyl group, a C1 to C30 alkyl group, a C1 to C10 alkylsilyl group, a C6 to C30 arylsilyl group, a C3 to C30 cycloalkyl group, a C3 to C30 heterocycloalkyl group, a C6 to C30 aryl group, a C2 to C30 heteroaryl group, a C1 to C20 alkoxy group, a C1 to C10 trifluoroalkyl group, a cyano group, or a combination thereof.

In one example of the present invention, the “substituted” refers to replacement of at least one hydrogen of a substituent or a compound by deuterium, a cyano group, a C1 to C30 alkyl group, a C1 to C10 alkylsilyl group, a C6 to C30 arylamine, a C6 to C30 arylsilyl group, a C3 to C30 cycloalkyl group, a C3 to C30 heterocycloalkyl group, a C6 to C30 aryl group, or a C2 to C30 heteroaryl group. In specific example of the present invention, the “substituted” refers to replacement of at least one hydrogen of a substituent or a compound by deuterium, a cyano group, a C1 to C20 alkyl group, a C6 to C30 arylamine, a C6 to C30 aryl group, or C2 to C30 heteroaryl group. In specific example of the present invention, the “substituted” refers to replacement of at least one hydrogen of a substituent or a compound by deuterium, a cyano group, a C1 to C5 alkyl group, a C6 to C20 arylamine group, a C6 to C18 aryl group, a dibenzofuranyl group, a dibenzothiophenyl group, carbazolyl group or pyridinyl group. In specific example of the present invention, the “substituted” refers to replacement of at least one hydrogen of a substituent or a compound by deuterium, a cyano group, a methyl group, an ethyl group, a propyl group, a butyl group, a C6 to C20 arylamine group, a phenyl group, a biphenyl group, a terphenyl group, a naphthyl group, a triphenylene group, a fluorenyl group, a dibenzofuranyl group, a dibenzothiophenyl group, a carbazolyl group or a pyridinyl group.

“Unsubstituted” refers to non-replacement of a hydrogen atom by another substituent and remaining of the hydrogen atom.

As used herein, “hydrogen substitution (—H)” may include deuterium substitution (-D) or “tritium substitution (-T).

As used herein, when a definition is not otherwise provided, “hetero” refers to one including one to three heteroatoms selected from N, O, S, P, and Si, and remaining carbons in one functional group.

As used herein, “an aryl group” refers to a group including at least one hydrocarbon aromatic moiety, and all elements of the hydrocarbon aromatic moiety have p-orbitals which form conjugation, for example a phenyl group, a naphthyl group, and the like, two or more hydrocarbon aromatic moieties may be linked by a sigma bond and may be, for example a biphenyl group, a terphenyl group, a quaterphenyl group, and the like, and two or more hydrocarbon aromatic moieties are fused directly or indirectly to provide a non-aromatic fused ring, for example a fluorenyl group.

The aryl group may include a monocyclic, polycyclic, or fused ring polycyclic (i.e., rings sharing adjacent pairs of carbon atoms) functional group.

As used herein, “a heterocyclic group” is a generic concept of a heteroaryl group, and may include at least one heteroatom selected from N, O, S, P, and Si instead of carbon (C) in a cyclic compound such as an aryl group, a cycloalkyl group, a fused ring thereof, or a combination thereof. When the heterocyclic group is a fused ring, the entire ring or each ring of the heterocyclic group may include one or more heteroatoms.

For example, “a heteroaryl group” may refer to an aryl group including at least one heteroatom selected from N, O, S, P, and Si. Two or more heteroaryl groups are linked by a sigma bond directly, or when the heteroaryl group includes two or more rings, the two or more rings may be fused. When the heteroaryl group is a fused ring, each ring may include one to three heteroatoms.

More specifically, the substituted or unsubstituted C6 to C30 aryl group may be a substituted or unsubstituted phenyl group, a substituted or unsubstituted naphthyl group, a substituted or unsubstituted anthracenyl group, a substituted or unsubstituted phenanthrenyl group, a substituted or unsubstituted naphthacenyl group, a substituted or unsubstituted pyrenyl group, a substituted or unsubstituted biphenyl group, a substituted or unsubstituted p-terphenyl group, a substituted or unsubstituted m-terphenyl group, a substituted or unsubstituted o-terphenyl group, a substituted or unsubstituted chrysenyl group, a substituted or unsubstituted triphenylene group, a substituted or unsubstituted perylenyl group, a substituted or unsubstituted fluorenyl group, a substituted or unsubstituted indenyl group, or a combination thereof, but is not limited thereto.

More specifically, the substituted or unsubstituted C2 to C30 heterocyclic group may be a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzothiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted carbazolyl group, a substituted or unsubstituted dibenzofuranyl group, a substituted or unsubstituted dibenzothiophenyl group, a substituted or unsubstituted benzofuranpyrimidinyl group, a substituted or unsubstituted benzothiophenepyrimidinyl group, or a combination thereof, but is not limited thereto.

As used herein, hole characteristics refer to an ability to donate an electron to form a hole when an electric field is applied and that a hole formed in the anode may be easily injected into the light emitting layer and transported in the light emitting layer due to conductive characteristics according to a highest occupied molecular orbital (HOMO) level.

In addition, electron characteristics refer to an ability to accept an electron when an electric field is applied and that electron formed in the cathode may be easily injected into the light emitting layer and transported in the light emitting layer due to conductive characteristics according to a lowest unoccupied molecular orbital (LUMO) level.

Hereinafter, a composition for an organic optoelectronic device according to an embodiment is described.

A composition for an organic optoelectronic device according to an embodiment is a mixture including three types of compounds, specifically, a first compound having electron characteristics, a second compound having hole characteristics, and a third compound having buffer characteristics.

The third compound is a compound having a wide range of HOMO-LUMO bandgaps including both the HOMO-LUMO bandgaps of the first compound and the second compound, and has a lower hole mobility than the hole mobility of the second compound having hole characteristics, thereby slowing down hole injection characteristics and thus reducing hole traps.

In addition, while having a lower electron mobility than the electron mobility of the first compound, as the light emitting layer region is relatively moved toward the hole transport auxiliary layer, it is possible to obtain an effect of reducing exciton quenching and deterioration caused by the exciton quenching at the interface of the electron transport auxiliary layer, so that the life-span can be increased.

An example of the first compound having the electron characteristics has a structure in which a triphenylene skeleton is substituted with a 6-membered nitrogen-containing ring and is represented by Chemical Formula I.

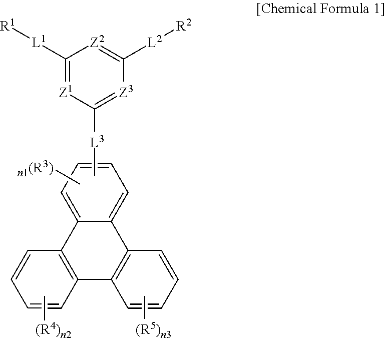

In Chemical Formula I,
Z¹ to Z³ are N or C-L^{a}-R^{a},
at least two of Z¹ to Z³ are N,
L^{a} and L¹ to L³ are each independently a single bond, a substituted or unsubstituted C6 to C20 arylene group, a substituted or unsubstituted C2 to C20 heterocyclic group, or a combination thereof,
R¹ and R² are each independently a substituted or unsubstituted C6 to C30 aryl group, a substituted or unsubstituted C2 to C30 heterocyclic group, or a combination thereof,
R^{a}, and R³ to R⁵ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted thioaryl group, a substituted or unsubstituted silyl group, a substituted or unsubstituted amine group, a halogen, a cyano group, or a combination thereof,
R^{a}s are each independently present or linked to R¹ or R² to form a substituted or unsubstituted heteroaromatic polycyclic ring,
n1 is an integer from 1 to 3, and
n2 and n3 are each independently an integer of 1 to 4.

For example, each of Z¹ to Z³ in Chemical Formula I may be N.

For example, Z¹ and Z² may be N, Z³ may be C-L^{a}-R^{a}, L^{a} is a single bond, and R^{a} may be linked to adjacent R² to form a substituted or unsubstituted heteroaromatic polycyclic ring, for example, a substituted or unsubstituted cyclic benzothiophenypyrimidine.

For example, Z¹ and Z³ may be N, Z² may be C-L^{a}-R^{a}, L^{a} may be a single bond, and R^{a} may be linked to adjacent R¹ to form a substituted or unsubstituted heteroaromatic polycyclic ring, for example, a substituted or unsubstituted benzothiophenypyrimidines.

For example, Chemical Formula I may be represented by any one of Chemical Formulas I-1 to I-3.

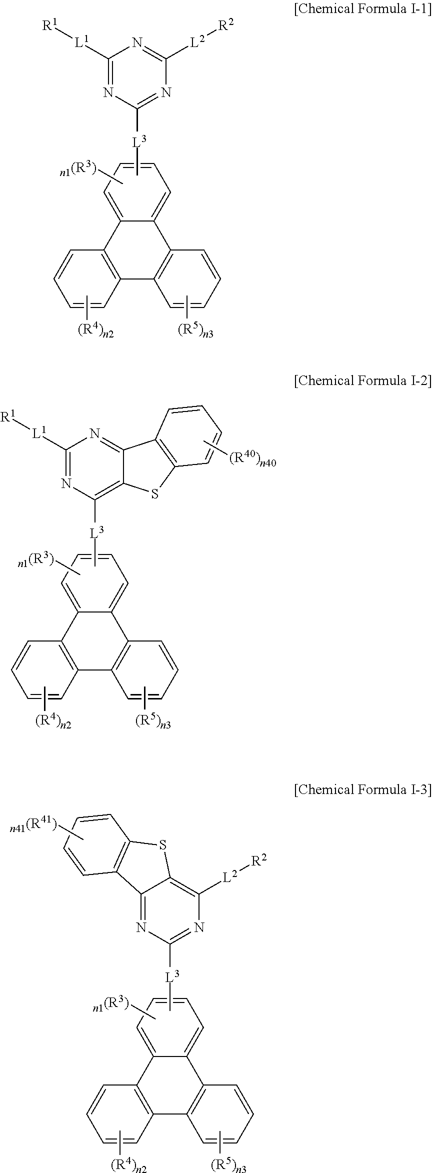

In Chemical Formula I-1 to Chemical Formula I-3, definitions of R¹ to R⁵, L¹ to L³ and n1 to n3 are the same as described above,
R⁴⁰ and R⁴¹ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and
n40 and n41 are each independently an integer of 1 to 4.

In an embodiment, R⁴⁰ and R⁴¹ may each independently be hydrogen, deuterium, a substituted or unsubstituted C1 to C10 alkyl group or a substituted or unsubstituted C6 to C12 aryl group, and n40 and n41 may each independently be an integer of 1 or 2.

Specifically, L¹ to L³ in Chemical Formula I may each independently be a single bond, a substituted or unsubstituted phenylene group, or a substituted or unsubstituted biphenylene group.

Specifically, R¹ and R² in Chemical Formula I may each independently be a substituted or unsubstituted phenyl group, a substituted or unsubstituted biphenyl group, a substituted or unsubstituted terphenyl group, a substituted or unsubstituted naphthyl group, a substituted or unsubstituted carbazolyl group, a substituted or unsubstituted indolocarbazolyl group, a substituted or unsubstituted dibenzofuranyl group, a substituted or unsubstituted dibenzothiophenyl group, a substituted or unsubstituted fused carbazolyl group, a substituted or unsubstituted fused dibenzofuranyl group, a substituted or unsubstituted fused dibenzothiophenyl group, a substituted or unsubstituted fused indolocarbazolyl group, a substituted or unsubstituted pyridinyl group, a substituted or unsubstituted pyrimidinyl group, a substituted or unsubstituted triazinyl group, a substituted or unsubstituted quinolinyl group, a substituted or unsubstituted isoquinolinyl group, a substituted or unsubstituted quinoxalinyl group, a substituted or unsubstituted quinazolinyl group, or a substituted or unsubstituted benzoquinazolinyl group.

For example, R¹ and R² in Chemical Formula I may each independently be a substituted or unsubstituted phenyl group, a substituted or unsubstituted biphenyl group, a substituted or unsubstituted terphenyl group, a substituted or unsubstituted fluorenyl group, a substituted or unsubstituted dibenzofuranyl group, or a substituted or unsubstituted dibenzothiophenyl group.

Specifically, R³ to R⁵ in Chemical Formula I may each independently be hydrogen, deuterium, a substituted or unsubstituted C1 to C10 alkyl group, or a substituted or unsubstituted C6 to C12 aryl group.

For example, R³ to R⁵ in Chemical Formula I may each independently be hydrogen, deuterium, a substituted or unsubstituted C1 to C5 alkyl group, a substituted or unsubstituted phenyl group, or a substituted or unsubstituted biphenyl group, and n1 to n3 may each independently be an integer of 1 or 2.

For example, adjacent groups of R³ to R⁵ may be linked to form a substituted or unsubstituted heteroaromatic polycyclic ring, for example, a substituted or unsubstituted benzofuranpyrimidine, or a substituted or unsubstituted benzothiophenypyrimidine.

For example, Chemical Formula I may be represented by any one of Chemical Formula I-4 to Chemical Formula I-6.

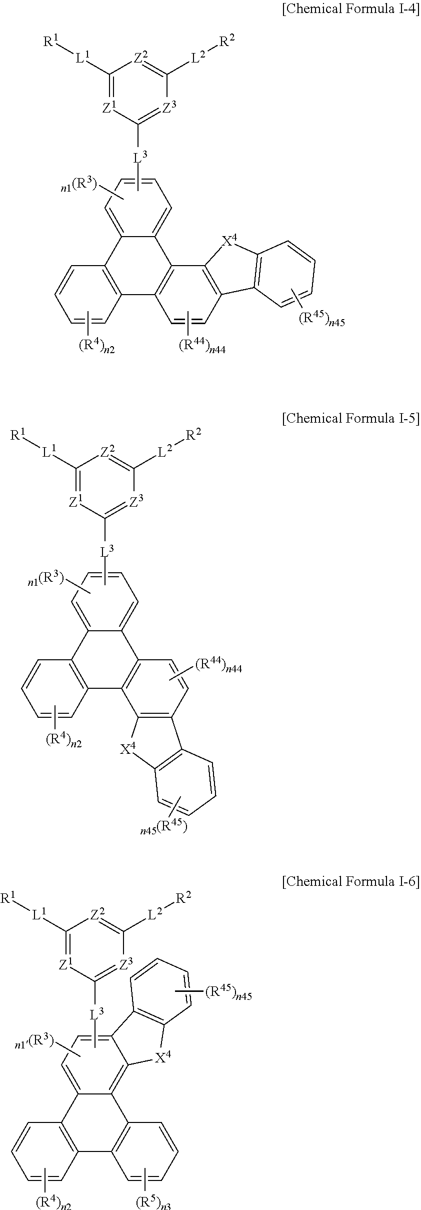

In Chemical Formula I-4 to Chemical Formula I-6, Z¹ to Z³, R¹ to R⁵, L¹ to L³, and n1 to n3 are the same as described above,
X⁴ is O or S,
R⁴⁴ and R⁴⁵ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof,
n44 is an integer of 1 or 2,
n45 is an integer of 1 to 4, and
n1′ is 1.

Chemical Formula I may be represented by, for example, Chemical Formula I-A or Chemical Formula I-B according to the substitution position of the 6-membered ring including Z¹ to Z³.

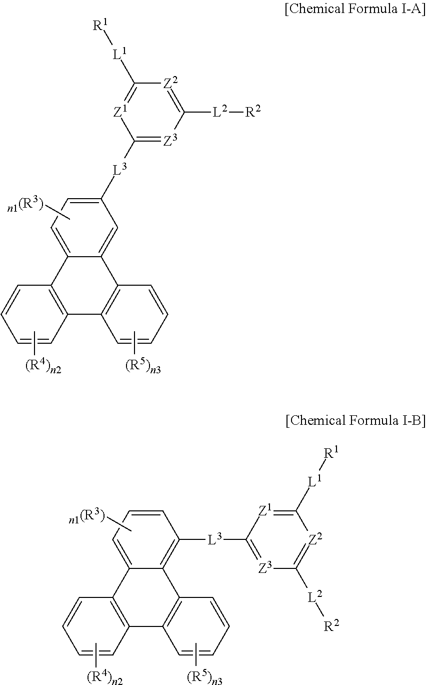

In Chemical Formula I-A and Chemical Formula I-B, Z¹ to Z³, L¹ to L¹, R¹ to R⁵ and n1 to n3 are the same as described above.

Another example of the first compound having the electron characteristics has a structure in which dibenzofuran (dibenzothiophene) and dibenzofuran (dibenzothiophene) derivatives are substituted with a 6-membered nitrogen-containing ring, and is represented by Chemical Formula II.

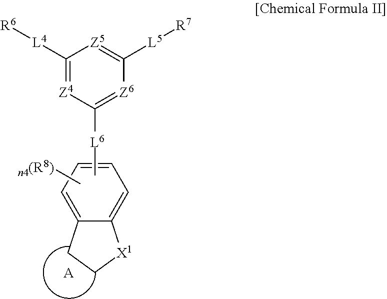

In Chemical Formula II,
Z⁴ to Z⁶ are N or C-L^{a}-R^{a},
at least two of Z⁴ to Z⁶ are N,
X¹ is O or S,
L^{a} and L⁴ to L⁶ are each independently a single bond, a substituted or unsubstituted C6 to C20 arylene group, a substituted or unsubstituted C2 to C20 heterocyclic group, or a combination thereof,
R⁶ and R⁷ are each independently a substituted or unsubstituted C6 to C30 aryl group, a substituted or unsubstituted C2 to C30 heterocyclic group, or a combination thereof,
R^{a} and R⁸ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted thioaryl group, a substituted or unsubstituted silyl group, a substituted or unsubstituted amine group, a halogen, a cyano group, or a combination thereof,
R^{a}s of Chemical Formula II are each independently present or linked to R⁶ or R⁷ to form a substituted or unsubstituted hetero aromatic polycyclic ring,
n4 is an integer of 1 to 3,
ring A is represented by any one of Chemical Formulas II-1 to II-14,

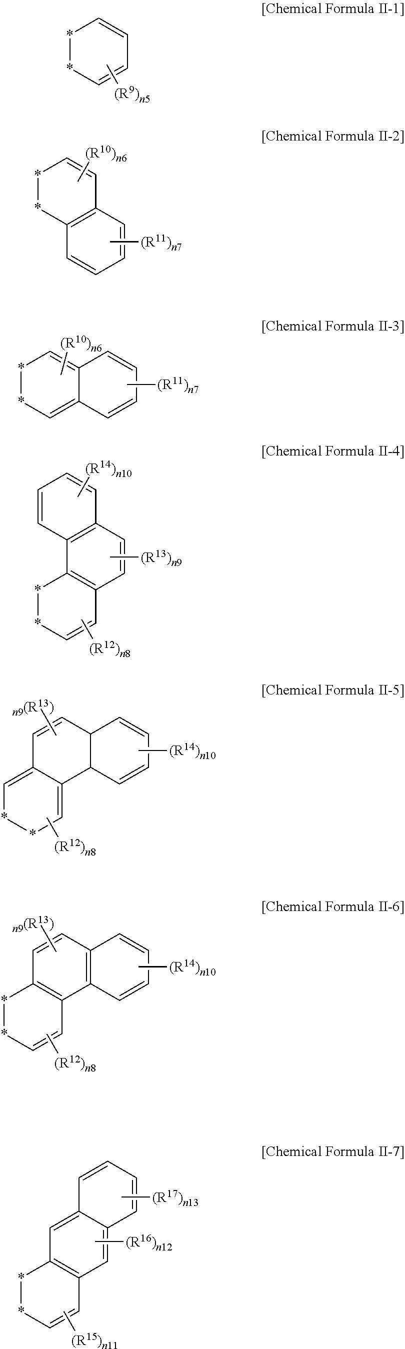

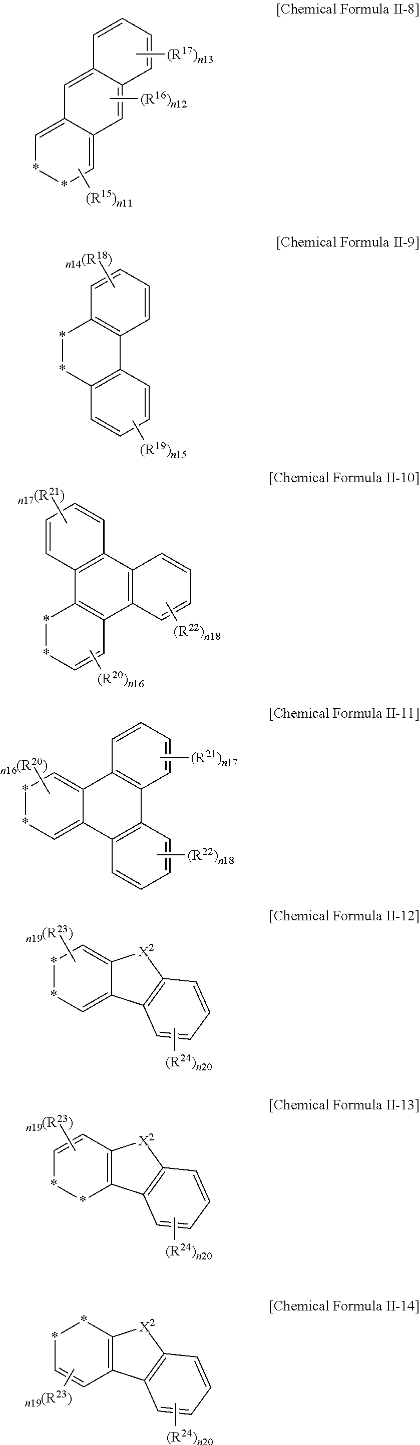

wherein, in Chemical Formula II-1 to Chemical Formula II-14,
X² is O or S,
R⁹ to R²⁴ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof,
n5, n7, n10, n13 to n15, n17, n18, and n20 are each independently one of integers of 1 to 4,
n6, n8, n9, n11, n12, n16, and n19 are each independently an integer of 1 or 2, and
* is a linking point.

For example, each of Z⁴ to Z⁶ in Chemical Formula II may be N.

For example, Z⁴ and Z⁵ may be N, Z⁶ is C-L^{a}-R^{a}, L^{a} may be a single bond, and R^{a} may be linked to adjacent R⁷ to form a substituted or unsubstituted heteroaromatic polycyclic ring, for example, a substituted or unsubstituted cyclic benzothiophenypyrimidine.

For example, Z⁴ and Z⁶ may be N, Z⁵ may be C-L^{a}-R^{a}, L^{a} may be a single bond, and R^{a} may be linked to adjacent R⁶ to form a substituted or unsubstituted heteroaromatic polycyclic ring, for example, a substituted or unsubstituted benzothiophenypyrimidine.

For example, Chemical Formula II may be represented by any one of Chemical Formula II-15 to Chemical Formula II-17.

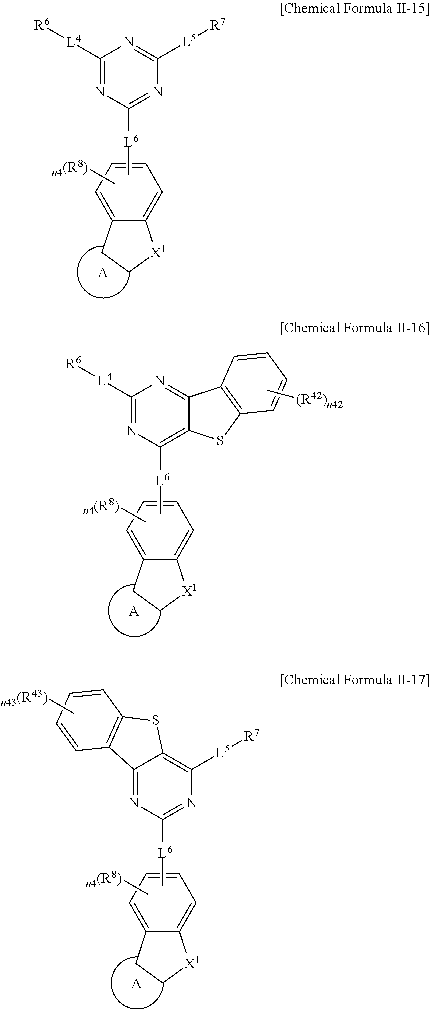

In Chemical Formula II-15 to Chemical Formula II-17, R⁶ to R⁸, L⁴ to L⁶ and n4 are the same as described above,

R⁴² and R⁴³ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and
n42 and n43 are each independently an integer of 1 to 4.

In an embodiment, R⁴² and R⁴³ may each independently be hydrogen, deuterium, a substituted or unsubstituted C1 to C10 alkyl group or a substituted or unsubstituted C6 to C12 aryl group, and n42 and n43 may each independently be an integer of 1 or 2.

L⁴ to L⁶ of Chemical Formula II may each independently be a single bond, a substituted or unsubstituted phenylene group, or a substituted or unsubstituted biphenylene group.

R⁶ and R⁷ in Chemical Formula II may each independently be a substituted or unsubstituted phenyl group, a substituted or unsubstituted biphenyl group, a substituted or unsubstituted terphenyl group, a substituted or unsubstituted naphthyl group, a substituted or unsubstituted carbazolyl group, a substituted or unsubstituted indolocarbazolyl group, a substituted or unsubstituted dibenzofuranyl group, a substituted or unsubstituted dibenzothiophenyl group, a substituted or unsubstituted fused carbazolyl group, a substituted or unsubstituted fused dibenzofuranyl group, a substituted or unsubstituted fused dibenzothiophenyl group, a substituted or unsubstituted fused indolocarbazolyl group, a substituted or unsubstituted pyridinyl group, a substituted or unsubstituted pyrimidinyl group, a substituted or unsubstituted triazinyl group, a substituted or unsubstituted quinolinyl group, a substituted or unsubstituted isoquinolinyl group, a substituted or unsubstituted quinoxalinyl group, a substituted or unsubstituted quinazolinyl group, or a substituted or unsubstituted benzoquinazolinyl group.

For example, R⁶ and R⁷ in Chemical Formula II may each independently be a substituted or unsubstituted phenyl group, a substituted or unsubstituted biphenyl group, a substituted or unsubstituted terphenyl group, a substituted or unsubstituted fluorenyl group, a substituted or unsubstituted dibenzofuranyl group, or a substituted or unsubstituted dibenzothiophenyl group.

Chemical Formula II may be represented by any one of Chemical Formula II-A to Chemical Formula II-W, depending on the specific structures of dibenzofuran (dibenzothiophene) and dibenzofuran (dibenzothiophene) derivatives.

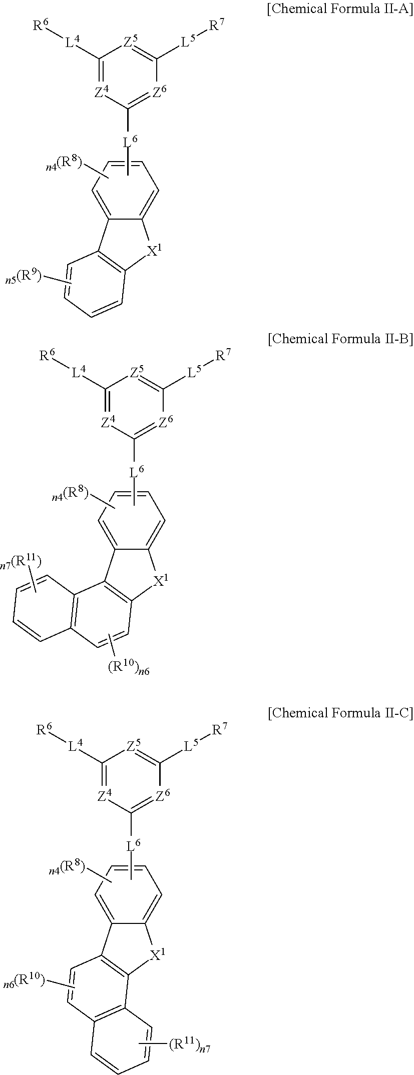

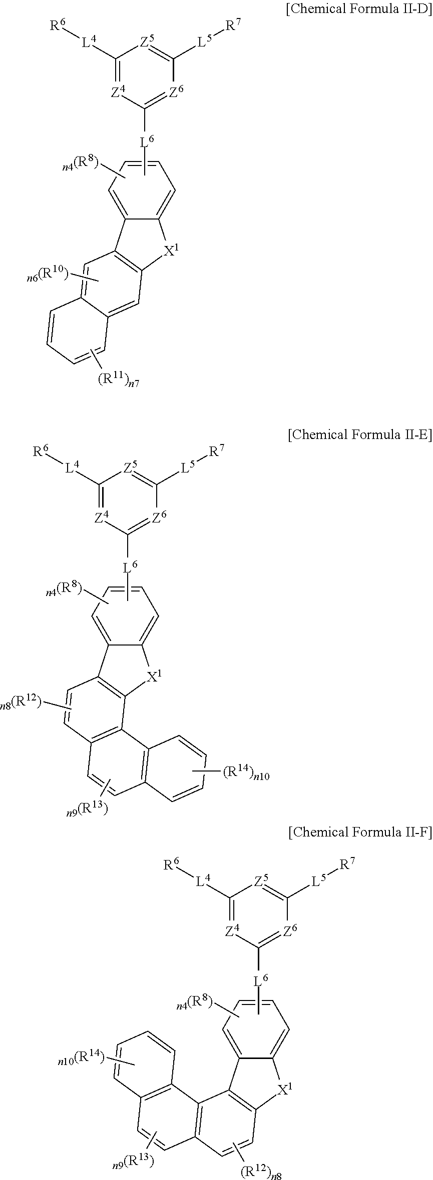

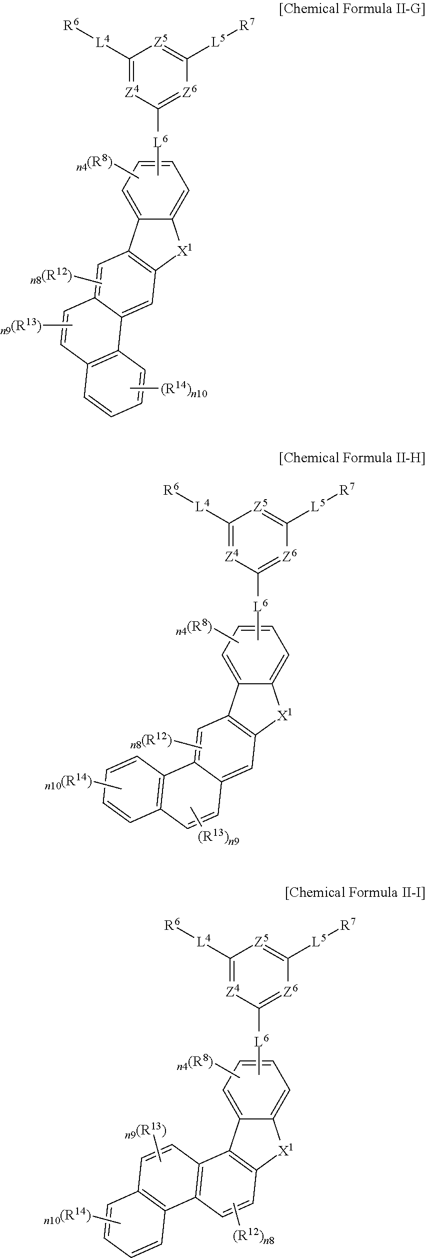

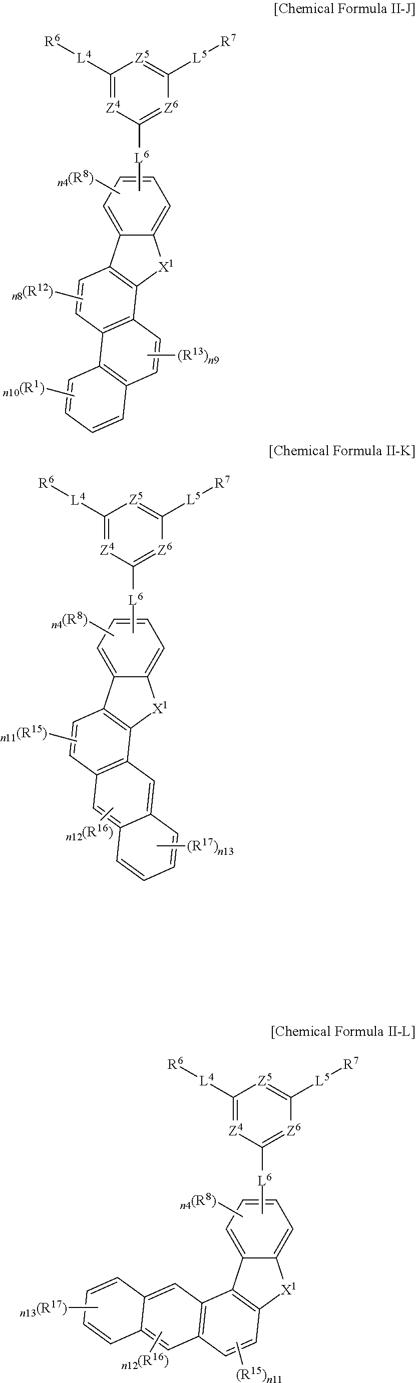

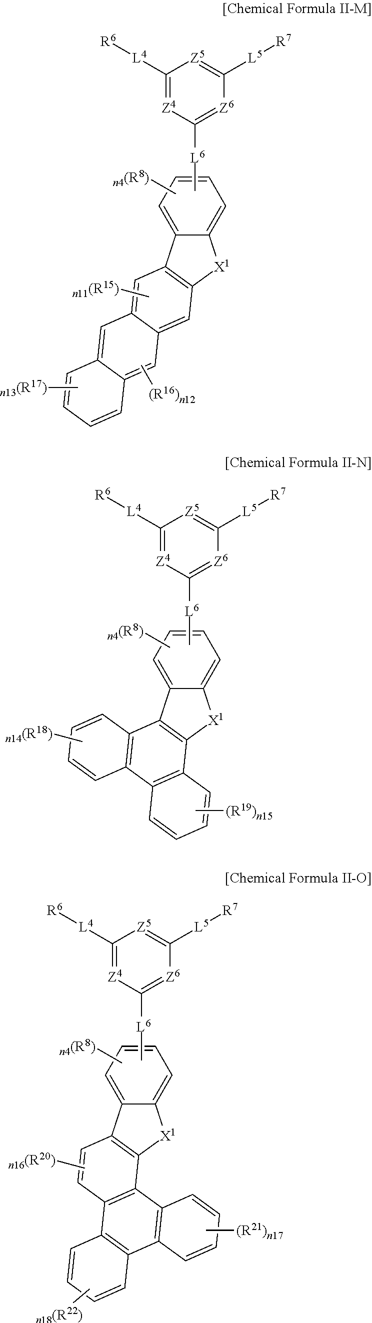

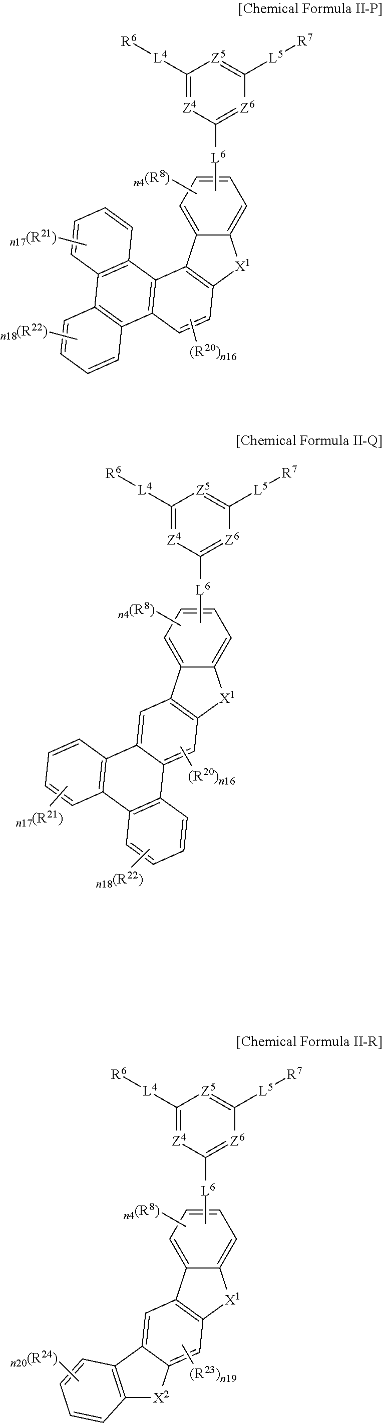

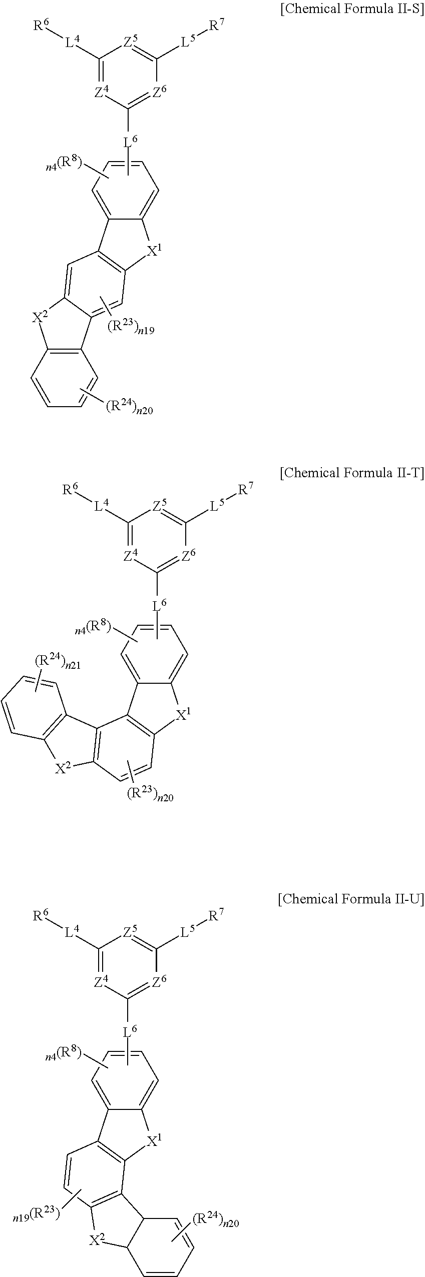

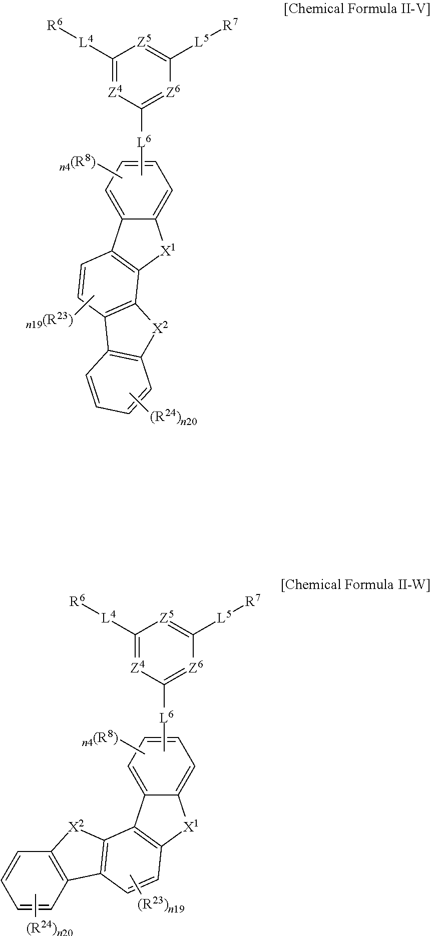

In Chemical Formula II-A to Chemical Formula II-W, Z⁴ to Z⁶, L⁴ to L⁶, R⁶ to R²⁴, X¹, X², and n4 to n20 are the same as described above.

For example, Chemical Formula II may be represented by any one of Chemical Formula II-A, Chemical Formula II-E, Chemical Formula II-O and Chemical Formula II-U.

For example, Chemical Formula II-A may be represented by any one of Chemical Formula II-A-1 to Chemical Formula II-A-4.

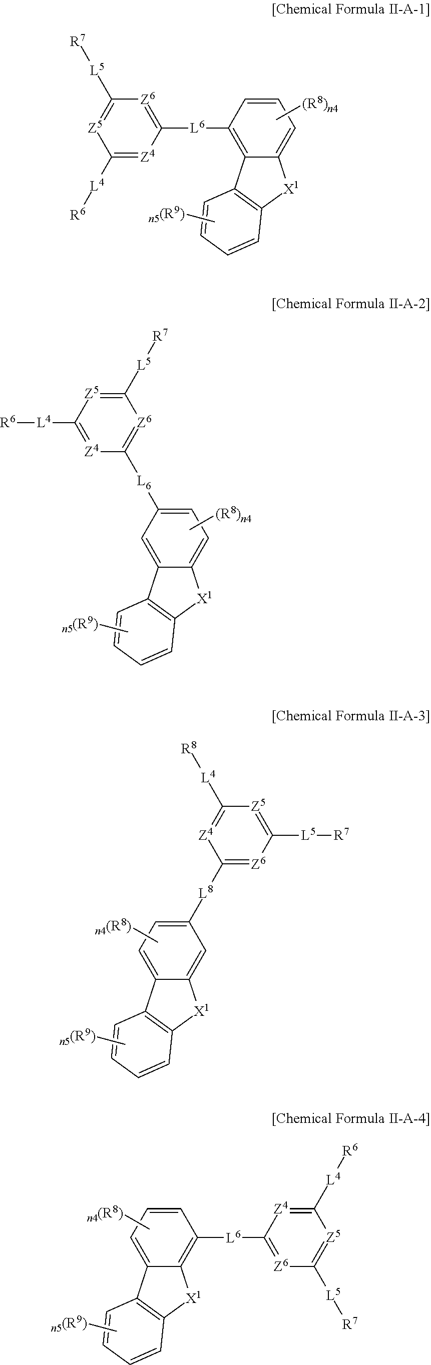

In Chemical Formula II-A-1 to Chemical Formula II-A-4, Z⁴ to Z⁶, L⁴ to L⁶, R⁶ to R⁹, X¹, n4, and n5 are the same as described above.

For example, Chemical Formula II-E may be represented by any one of Chemical Formulas II-E-1 to Chemical Formula II-E-4.

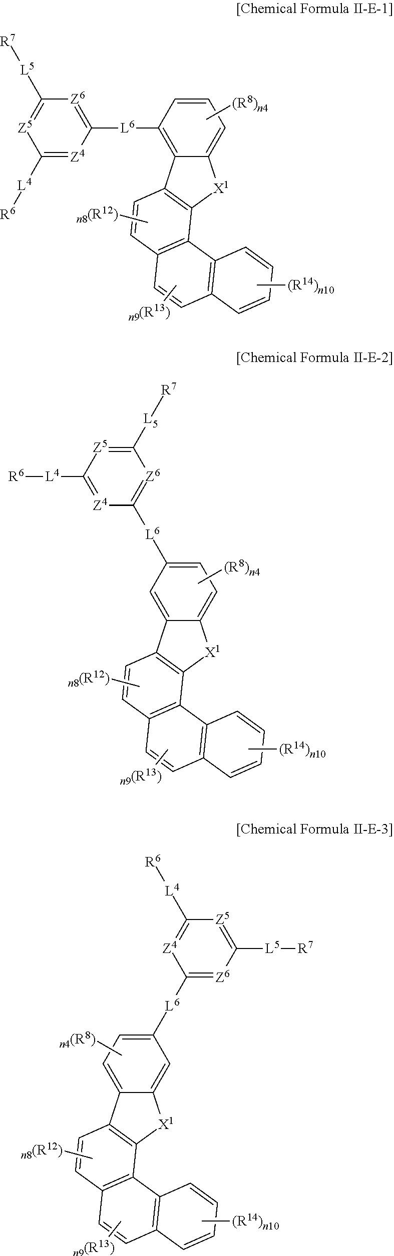

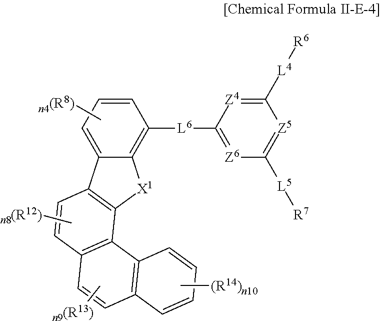

In Chemical Formula II-E-1 to Chemical Formula II-E-4 Z⁴ to Z⁶, L⁴ to L⁶, R⁶ to R⁸, R¹² to R¹⁴, X¹, n4, and n8 to n10 are the same as described above.

For example, Chemical Formula II-O may be represented by any one of Chemical Formula II-O-1 to Chemical Formula II-O-4.

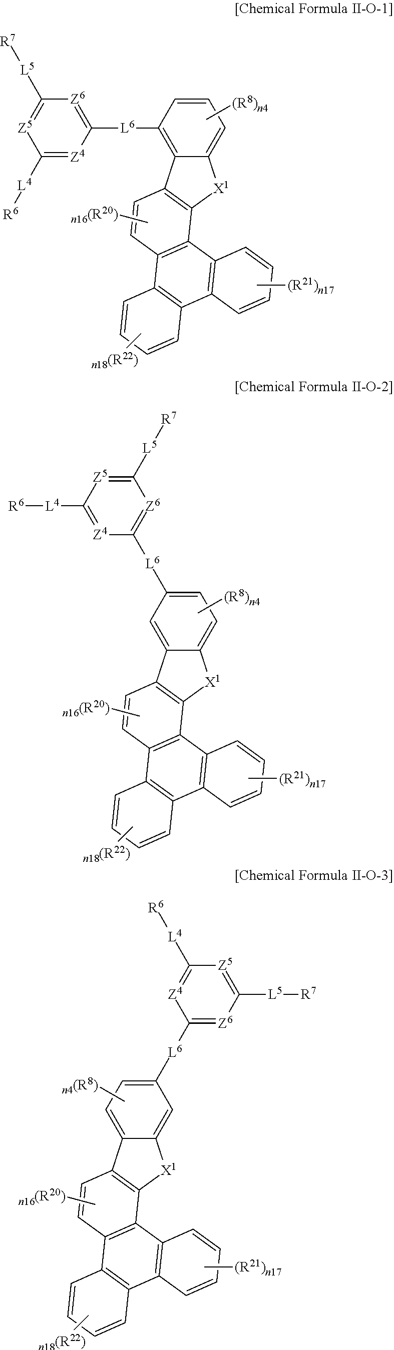

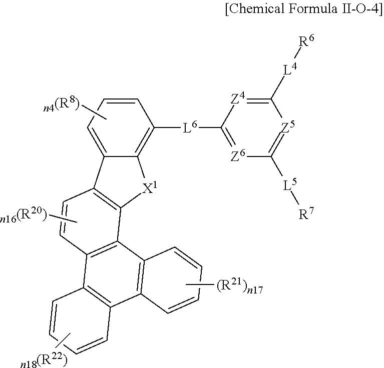

In Chemical Formula II-O-1 to Chemical Formula II-O-4, Z⁴ to Z⁶, L⁴ to L⁶, R⁶ to R⁸, R²⁰ to R²², X¹, n4, and n16 to n18 are the same as described above.

For example, Chemical Formula II-U may be represented by any one of Chemical Formula II-U-1 to Chemical Formula II-U-4.

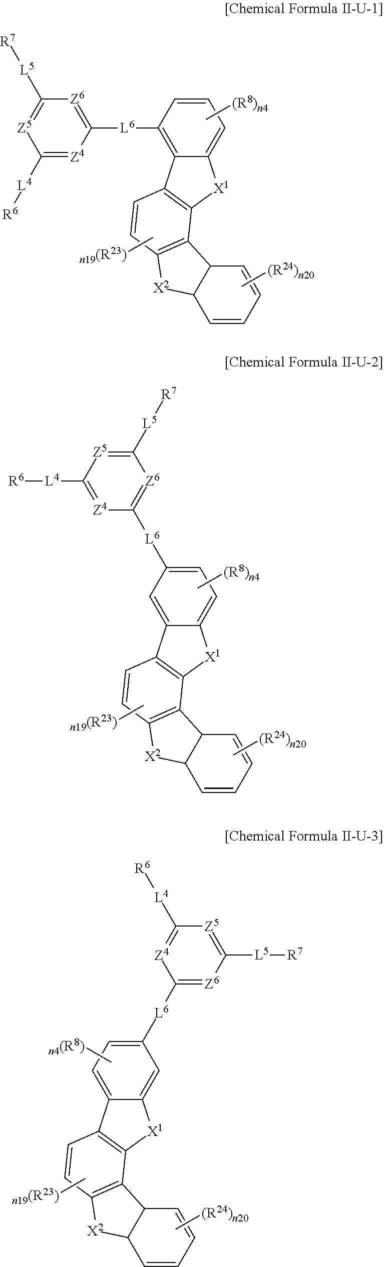

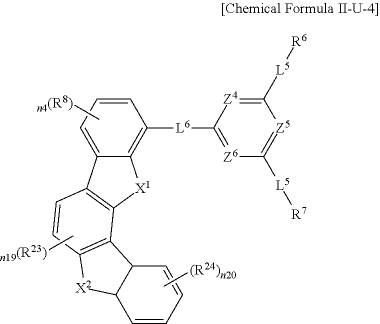

In Chemical Formula II-U-1 to Chemical Formula II-U-4, Z⁴ to Z⁶, L⁴ to L⁶, R⁶ to R⁸, R²³, R²⁴, X¹, X², n4, n19 and n20 are the same as described above.

In a specific embodiment of the present invention, the first compound may be represented by any one of Chemical Formula I-A, Chemical Formula II-A-3, Chemical Formula II-E-4, Chemical Formula II-O-4, and Chemical Formula II-U-3, and the definition of each substituent is the same as described above.

The first compound may be, for example, one selected from the compounds listed in Group 1.

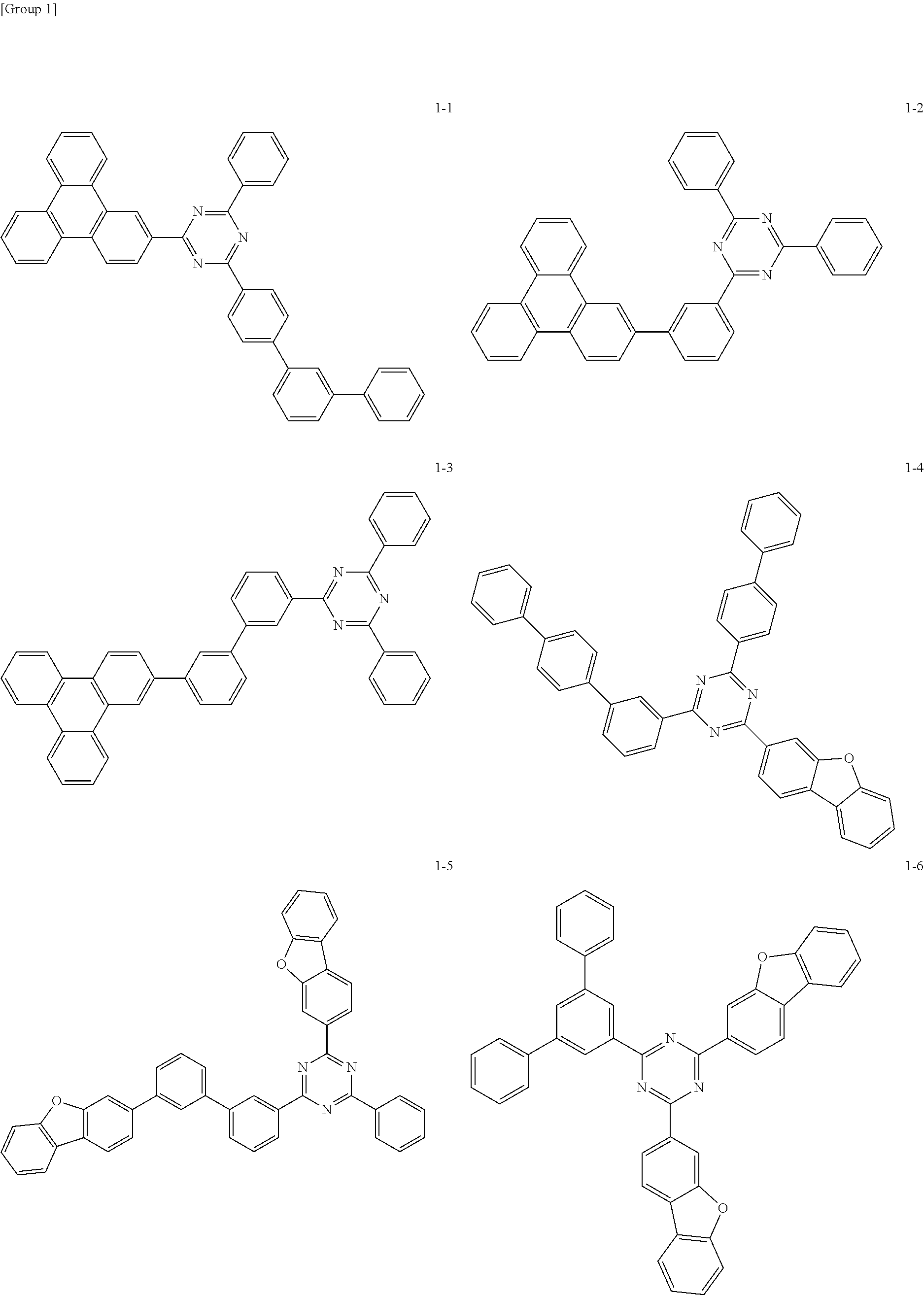

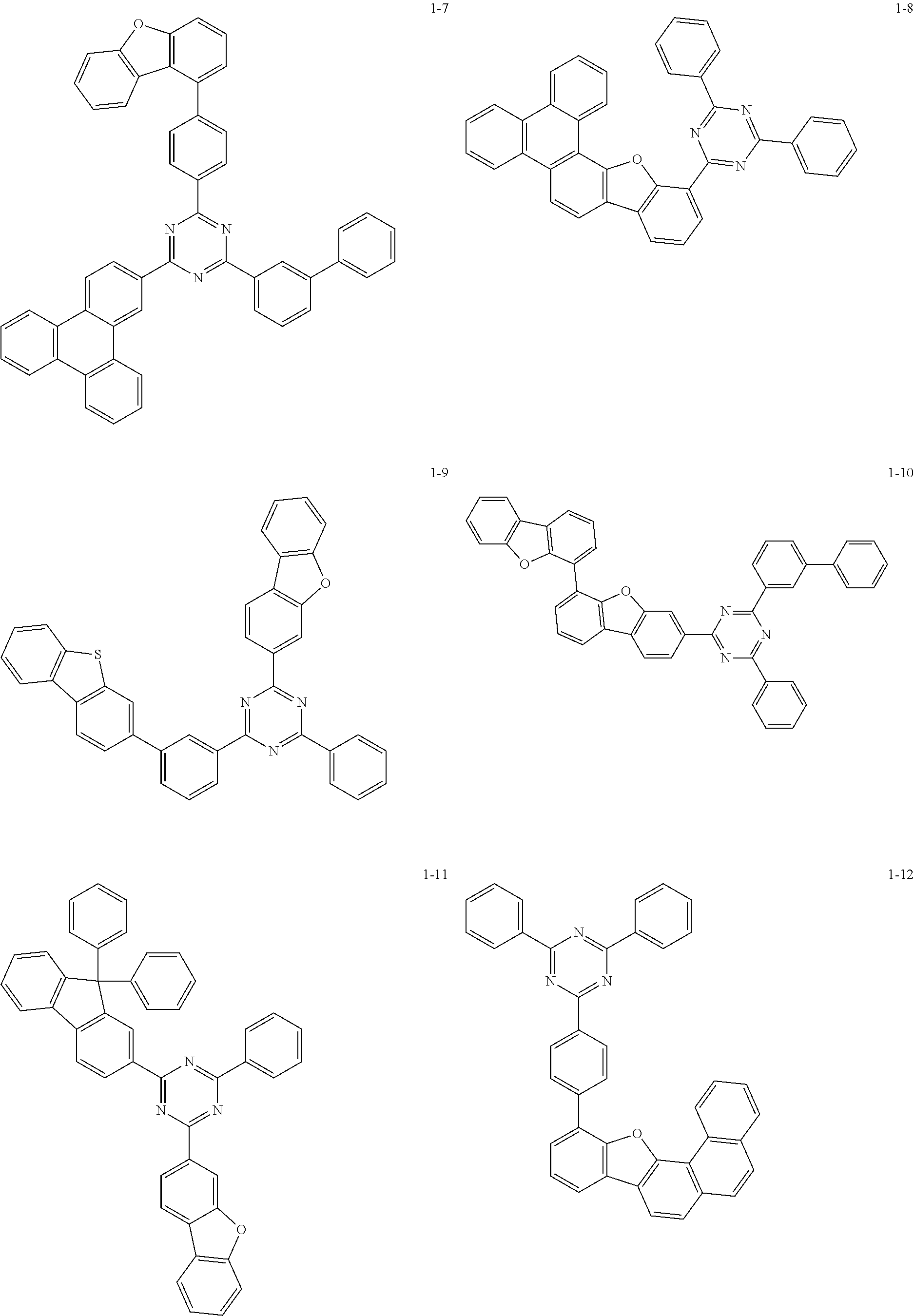

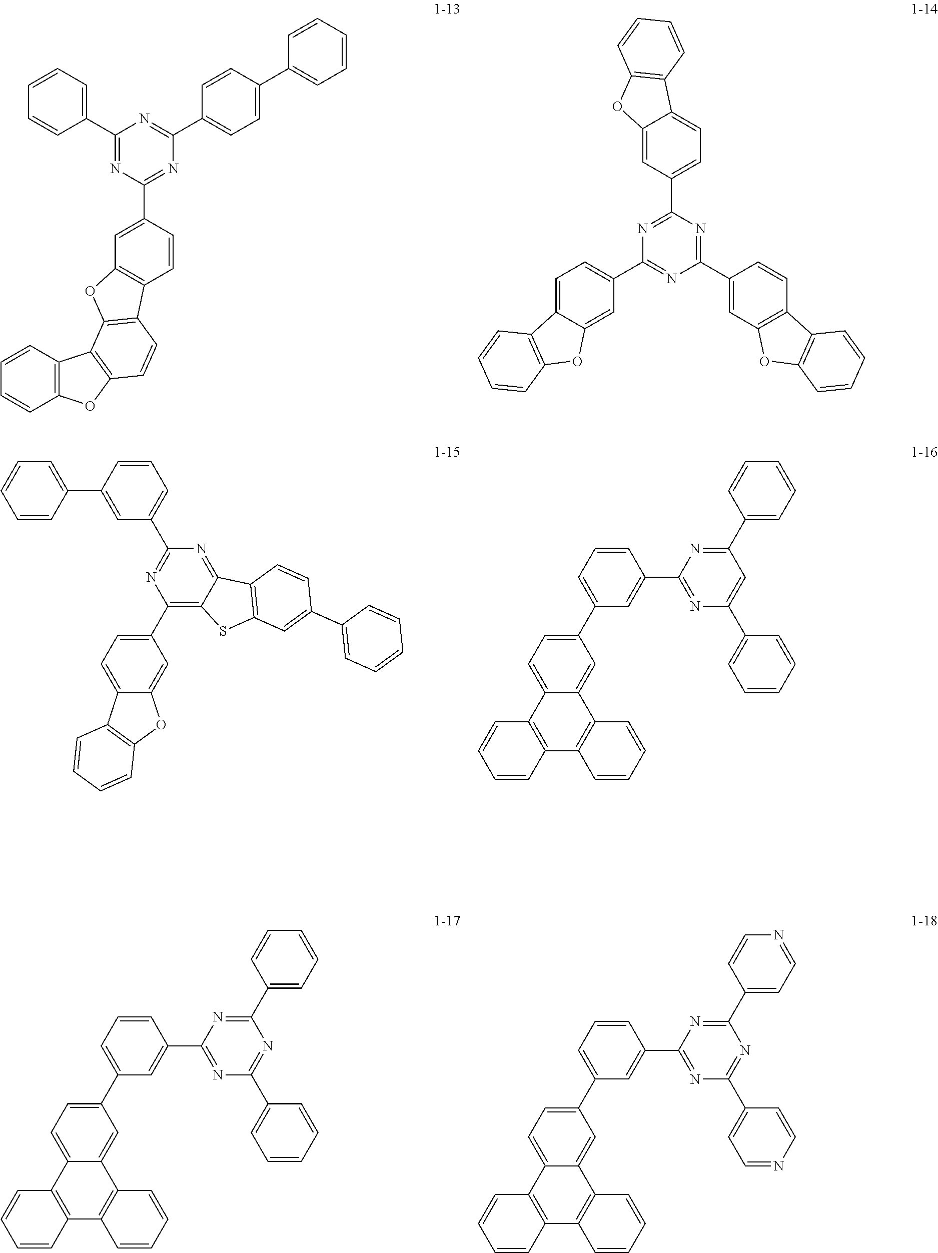 [SMILES: c1ccc(-c2ccc(-c3nc(-c4ccccc4)nc(-c4ccc5c(c4)oc4c5ccc5oc6ccccc6c54)n3)cc2)cc1 ; c1ccc2c(c1)oc1cc(-c3nc(-c4ccc5c(c4)oc4ccccc45)nc(-c4ccc5c(c4)oc4ccccc45)n3)ccc12 ; c1ccc(-c2cccc(-c3nc(-c4ccc5c(c4)oc4ccccc45)c4sc5cc(-c6ccccc6)ccc5c4n3)c2)cc1 ; c1ccc(-c2cc(-c3ccccc3)nc(-c3cccc(-c4ccc5c6ccccc6c6ccccc6c5c4)c3)n2)cc1 ; c1ccc(-c2nc(-c3ccccc3)nc(-c3cccc(-c4ccc5c6ccccc6c6ccccc6c5c4)c3)n2)cc1 ; c1cc(-c2ccc3c4ccccc4c4ccccc4c3c2)cc(-c2nc(-c3ccncc3)nc(-c3ccncc3)n2)c1]

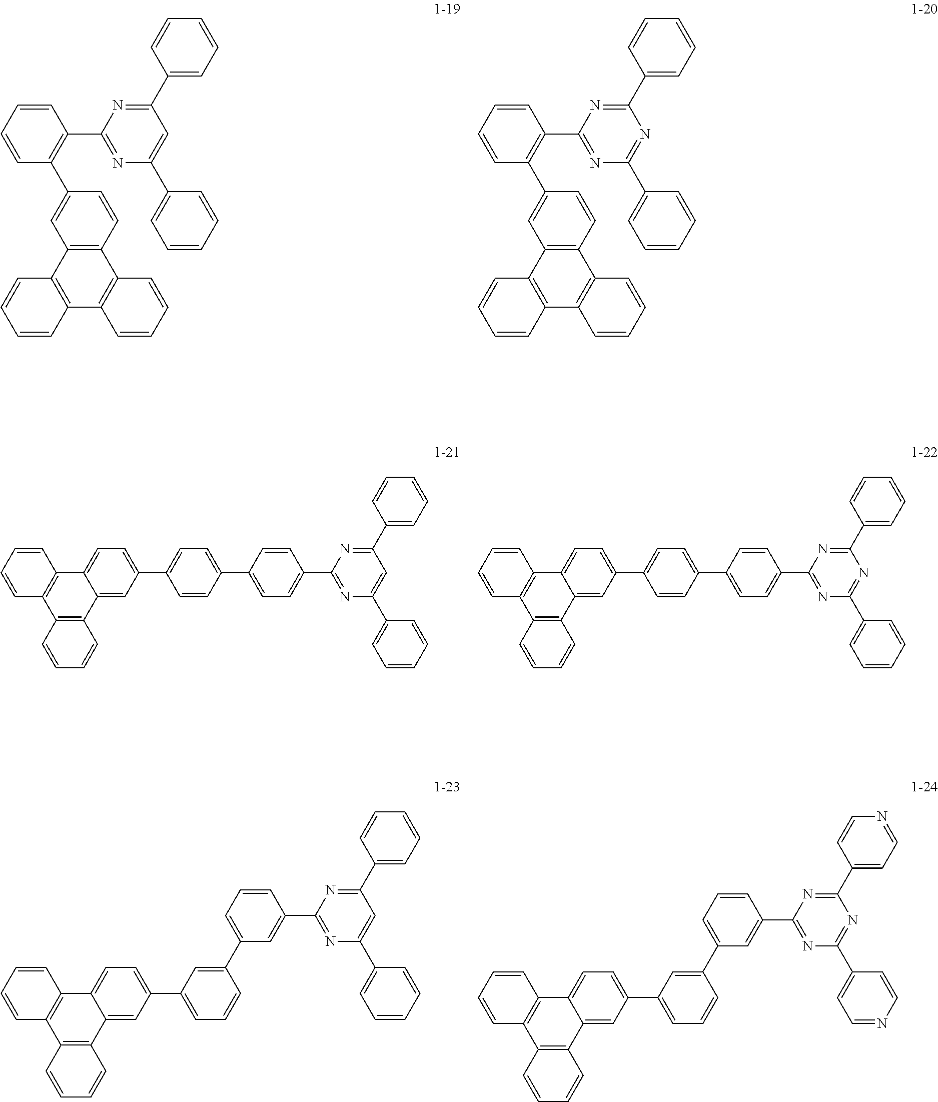 [SMILES: c1ccc(-c2cc(-c3ccccc3)nc(-c3ccccc3-c3ccc4c5ccccc5c5ccccc5c4c3)n2)cc1 ; c1ccc(-c2nc(-c3ccccc3)nc(-c3ccccc3-c3ccc4c5ccccc5c5ccccc5c4c3)n2)cc1 ; c1ccc(-c2cc(-c3ccccc3)nc(-c3ccc(-c4ccc(-c5ccc6c7ccccc7c7ccccc7c6c5)cc4)cc3)n2)cc1 ; c1ccc(-c2nc(-c3ccccc3)nc(-c3ccc(-c4ccc(-c5ccc6c7ccccc7c7ccccc7c6c5)cc4)cc3)n2)cc1 ; c1ccc(-c2cc(-c3ccccc3)nc(-c3cccc(-c4cccc(-c5ccc6c7ccccc7c7ccccc7c6c5)c4)c3)n2)cc1 ; c1cc(-c2cccc(-c3nc(-c4ccncc4)nc(-c4ccncc4)n3)c2)cc(-c2ccc3c4ccccc4c4ccccc4c3c2)c1]

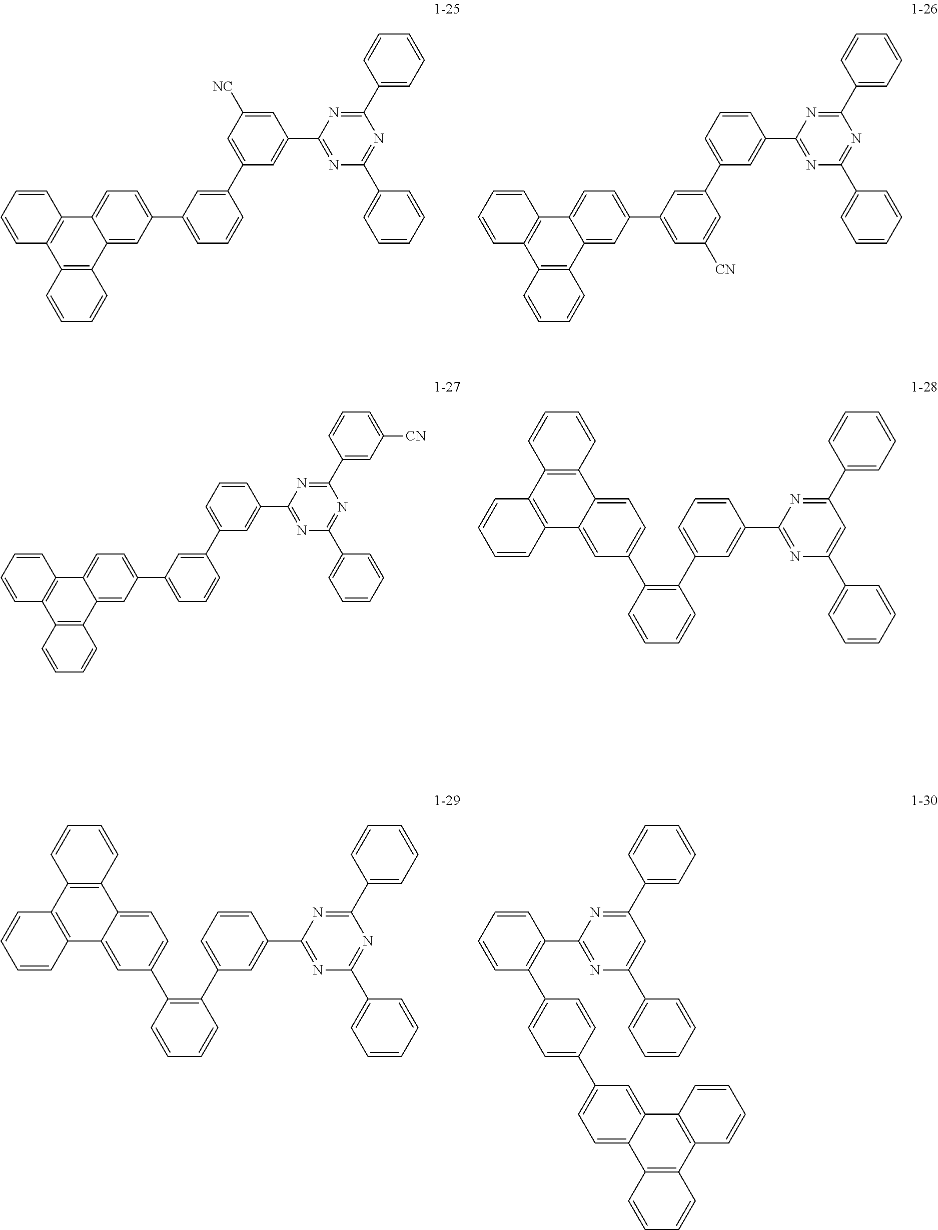

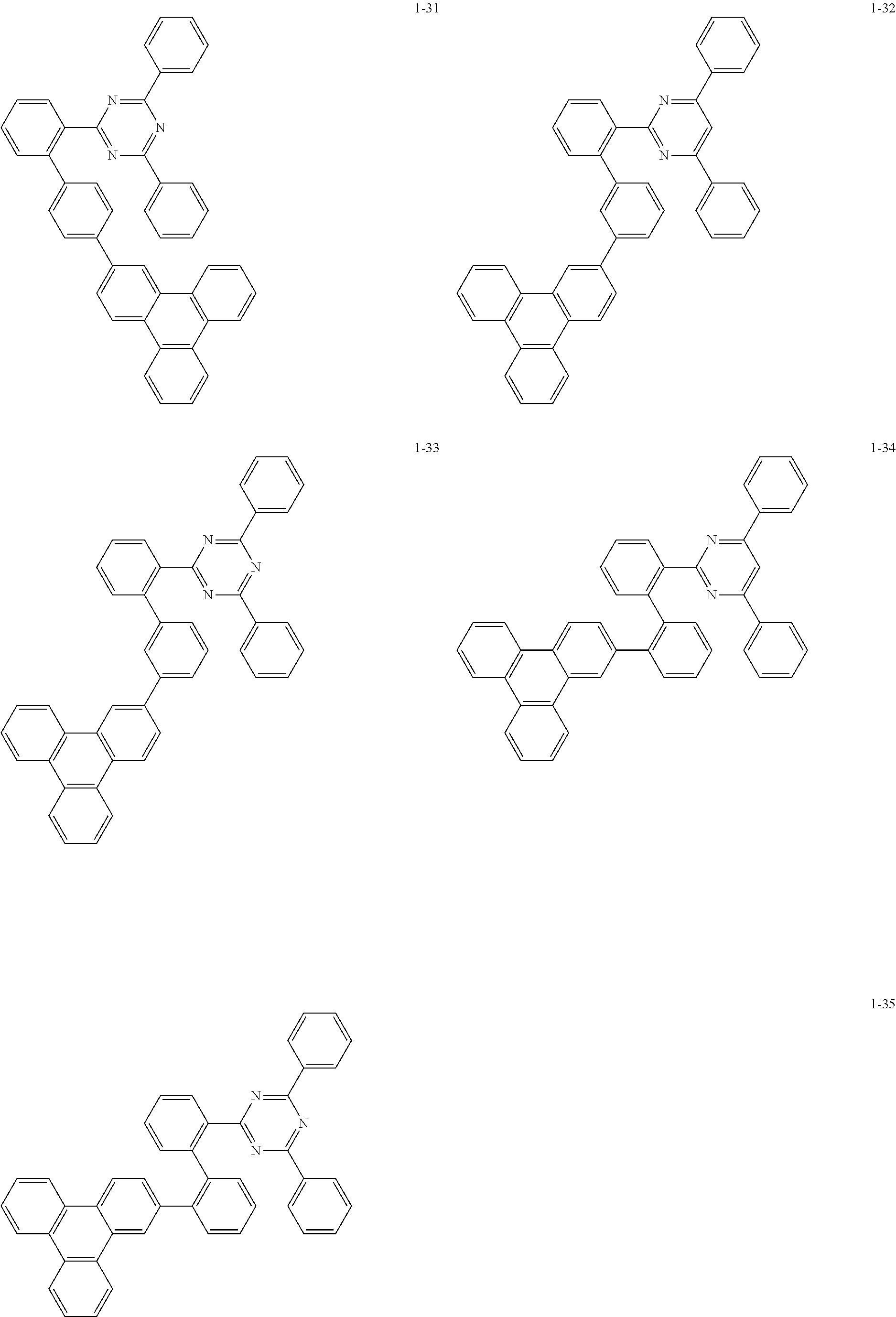 [SMILES: c1ccc(-c2nc(-c3ccccc3)nc(-c3ccccc3-c3ccc(-c4ccc5c6ccccc6c6ccccc6c5c4)cc3)n2)cc1 ; c1ccc(-c2cc(-c3ccccc3)nc(-c3ccccc3-c3cccc(-c4ccc5c6ccccc6c6ccccc6c5c4)c3)n2)cc1 ; c1ccc(-c2nc(-c3ccccc3)nc(-c3ccccc3-c3cccc(-c4ccc5c6ccccc6c6ccccc6c5c4)c3)n2)cc1 ; c1ccc(-c2cc(-c3ccccc3)nc(-c3ccccc3-c3ccccc3-c3ccc4c5ccccc5c5ccccc5c4c3)n2)cc1 ; c1ccc(-c2nc(-c3ccccc3)nc(-c3ccccc3-c3ccccc3-c3ccc4c5ccccc5c5ccccc5c4c3)n2)cc1]

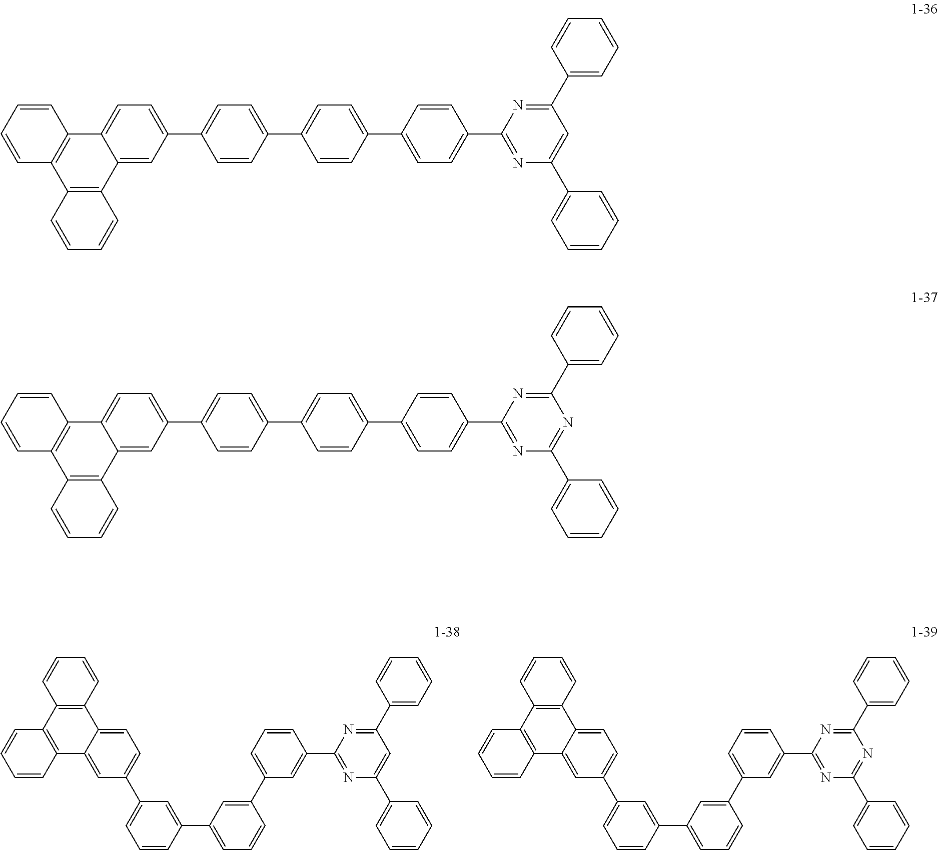 [SMILES: c1ccc(-c2cc(-c3ccccc3)nc(-c3ccc(-c4ccc(-c5ccc(-c6ccc7c8ccccc8c8ccccc8c7c6)cc5)cc4)cc3)n2)cc1 ; c1ccc(-c2nc(-c3ccccc3)nc(-c3ccc(-c4ccc(-c5ccc(-c6ccc7c8ccccc8c8ccccc8c7c6)cc5)cc4)cc3)n2)cc1 ; c1ccc(-c2cc(-c3ccccc3)nc(-c3cccc(-c4cccc(-c5cccc(-c6ccc7c8ccccc8c8ccccc8c7c6)c5)c4)c3)n2)cc1 ; c1ccc(-c2nc(-c3ccccc3)nc(-c3cccc(-c4cccc(-c5cccc(-c6ccc7c8ccccc8c8ccccc8c7c6)c5)c4)c3)n2)cc1]

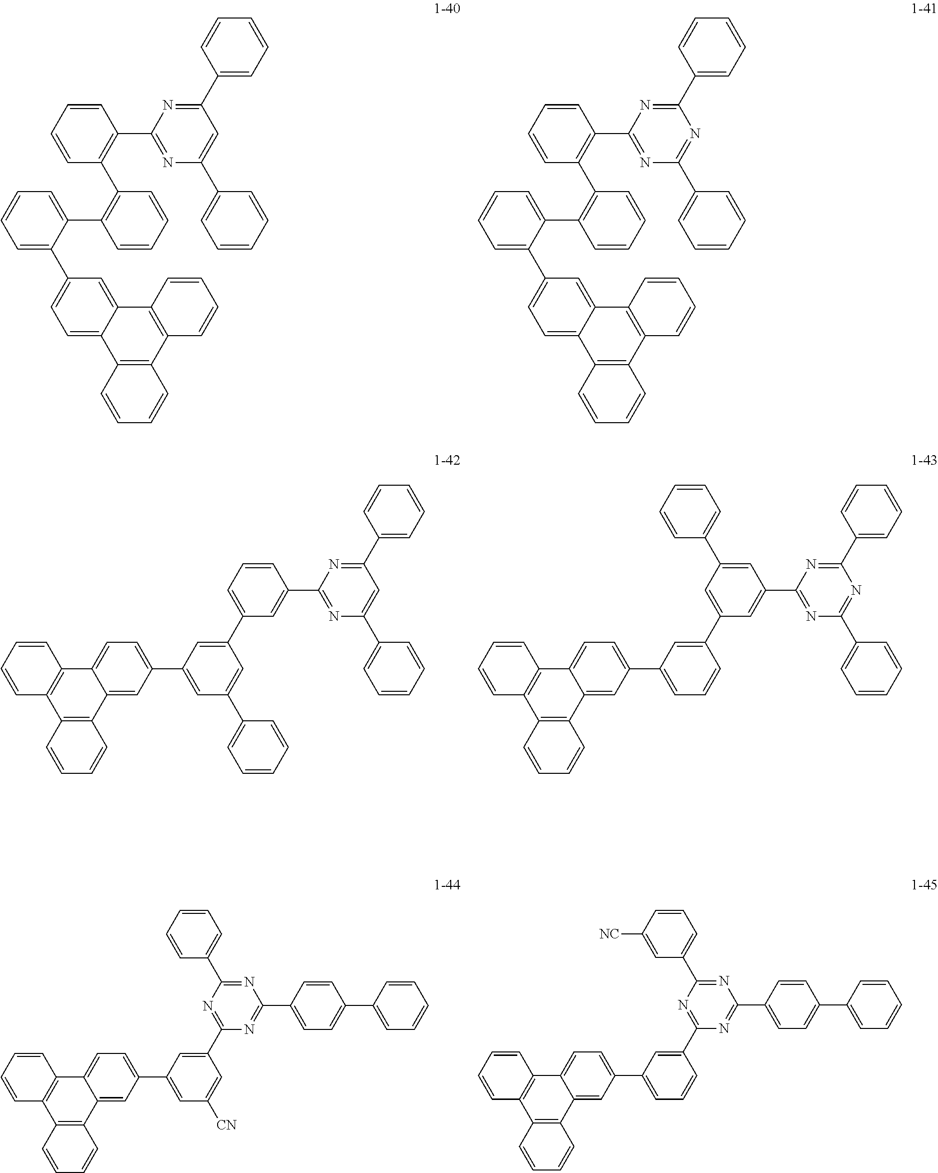

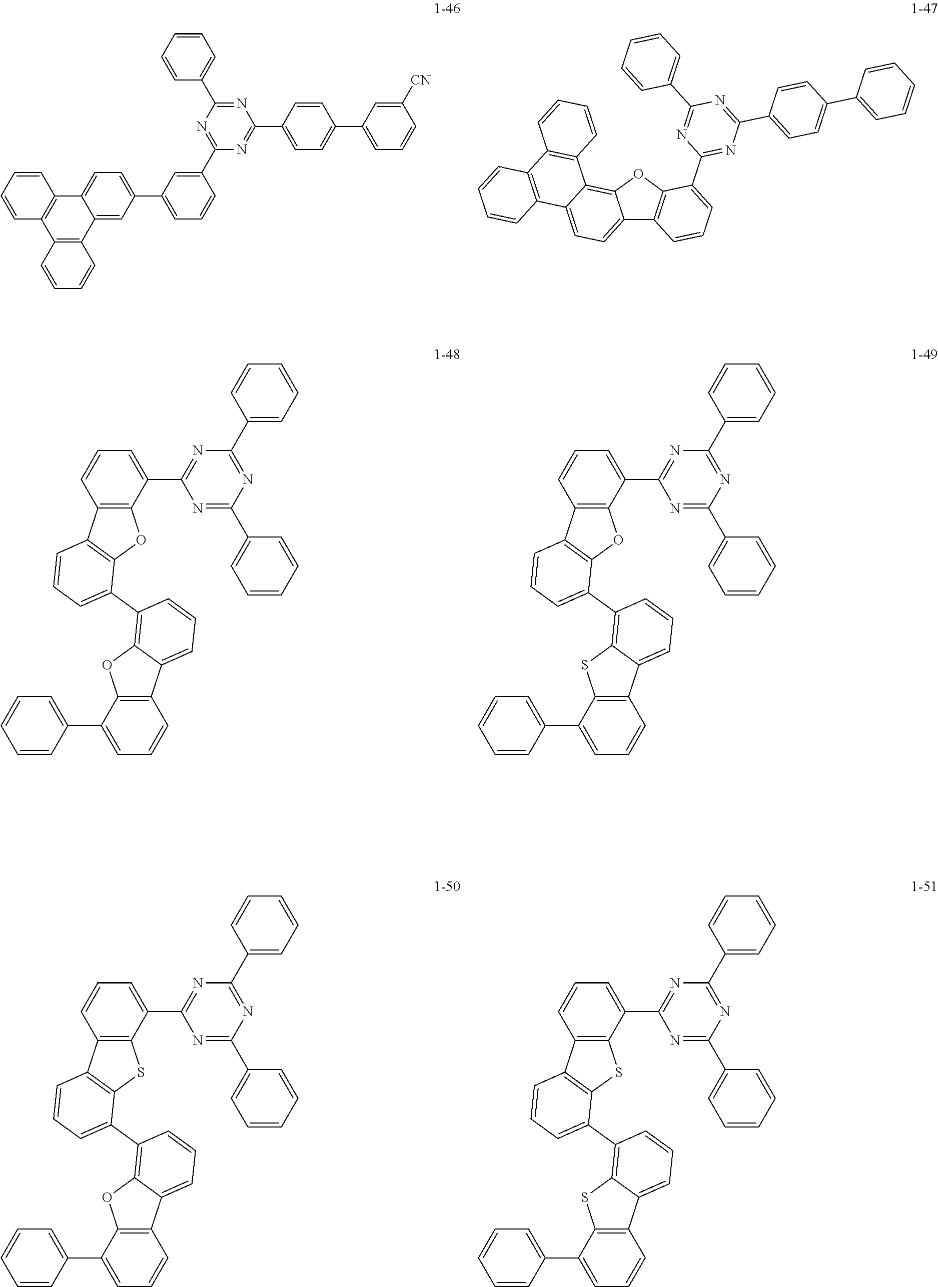

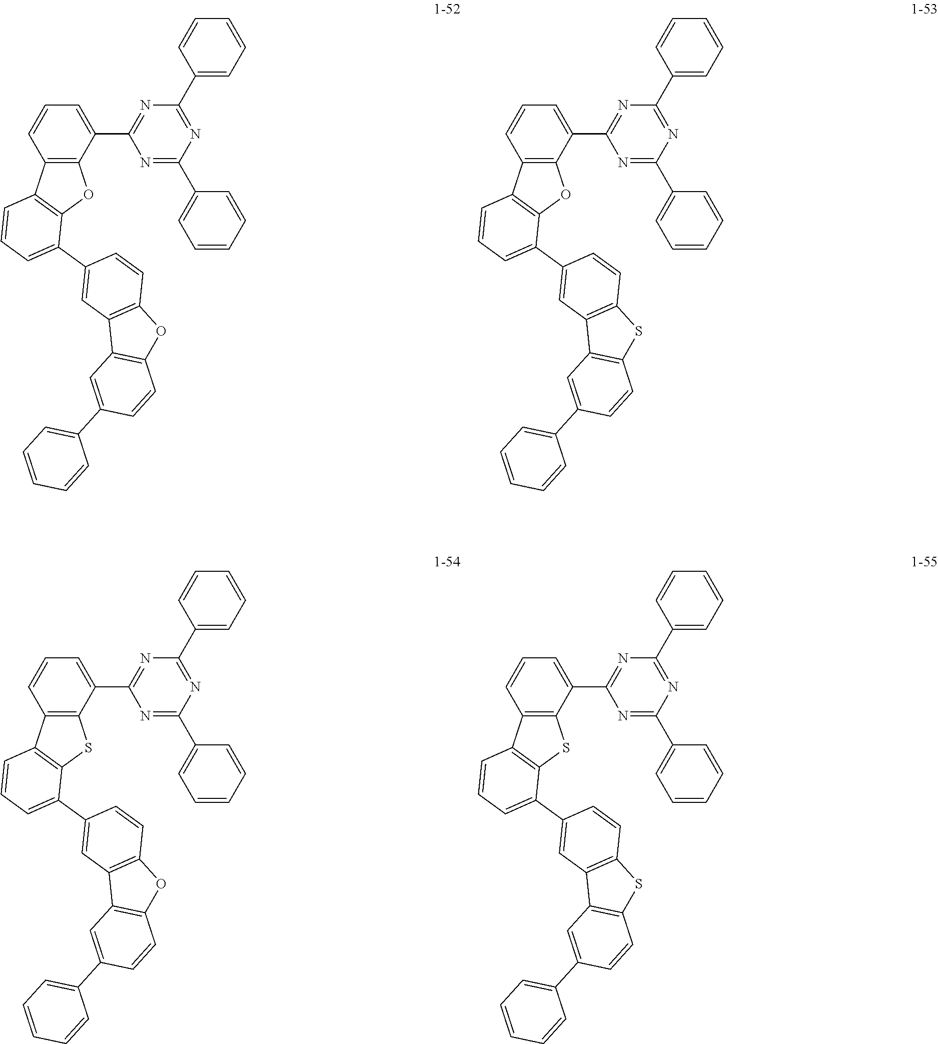 [SMILES: c1ccc(-c2ccc3oc4ccc(-c5cccc6c5oc5c(-c7nc(-c8ccccc8)nc(-c8ccccc8)n7)cccc56)cc4c3c2)cc1 ; c1ccc(-c2ccc3sc4ccc(-c5cccc6c5oc5c(-c7nc(-c8ccccc8)nc(-c8ccccc8)n7)cccc56)cc4c3c2)cc1 ; c1ccc(-c2ccc3oc4ccc(-c5cccc6c5sc5c(-c7nc(-c8ccccc8)nc(-c8ccccc8)n7)cccc56)cc4c3c2)cc1 ; c1ccc(-c2ccc3sc4ccc(-c5cccc6c5sc5c(-c7nc(-c8ccccc8)nc(-c8ccccc8)n7)cccc56)cc4c3c2)cc1]

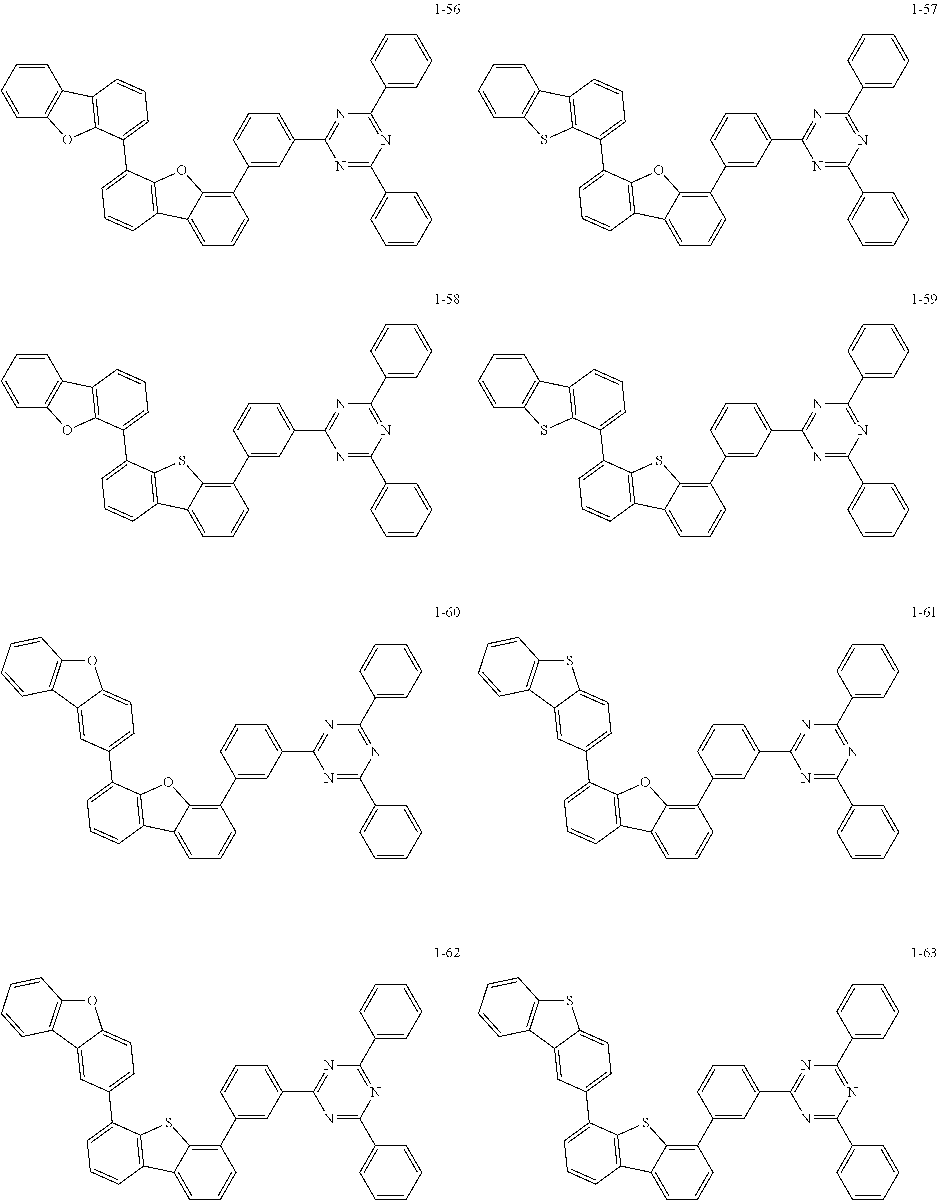

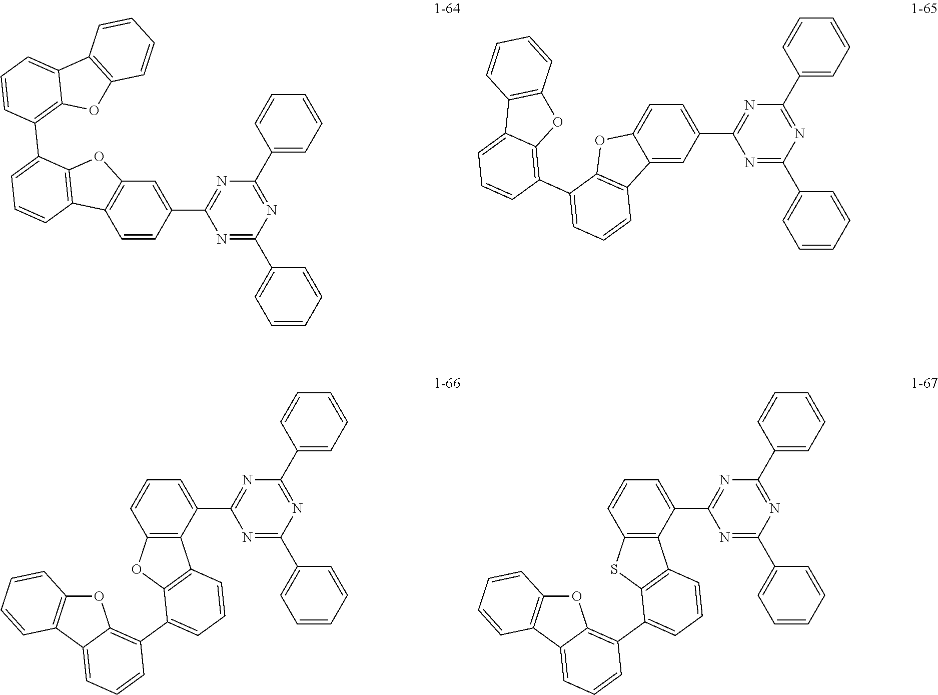 [SMILES: c1ccc(-c2nc(-c3ccccc3)nc(-c3ccc4c(c3)oc3c(-c5cccc6c5oc5ccccc56)cccc34)n2)cc1 ; c1ccc(-c2nc(-c3ccccc3)nc(-c3ccc4oc5c(-c6cccc7c6oc6ccccc67)cccc5c4c3)n2)cc1 ; c1ccc(-c2nc(-c3ccccc3)nc(-c3cccc4oc5c(-c6cccc7c6oc6ccccc67)cccc5c34)n2)cc1 ; c1ccc(-c2nc(-c3ccccc3)nc(-c3cccc4sc5c(-c6cccc7c6oc6ccccc67)cccc5c34)n2)cc1]

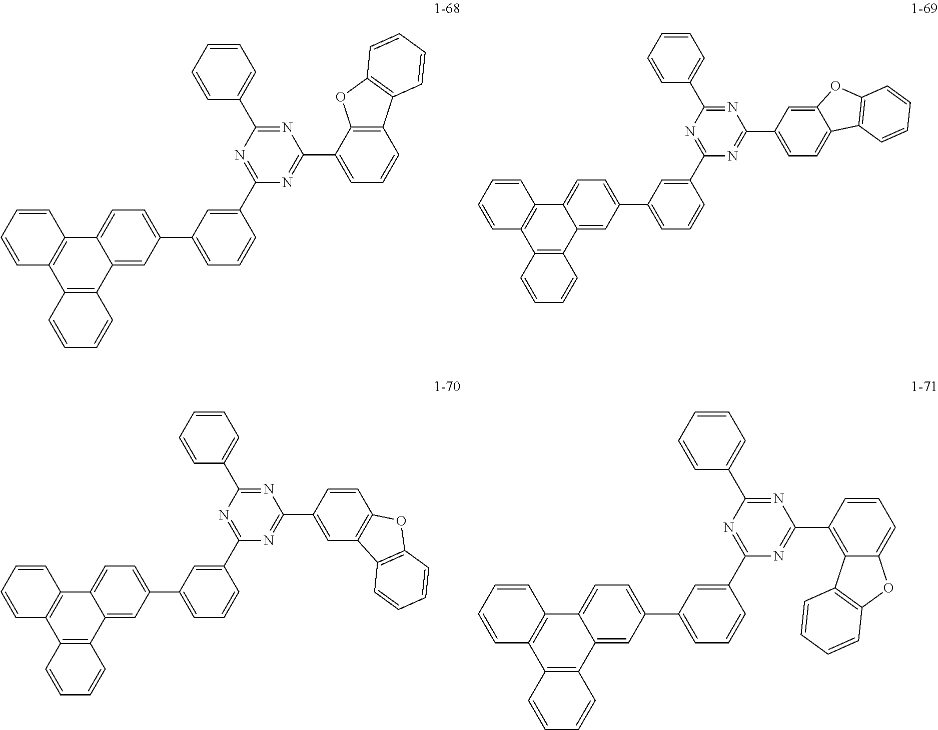 [SMILES: c1ccc(-c2nc(-c3cccc(-c4ccc5c6ccccc6c6ccccc6c5c4)c3)nc(-c3cccc4c3oc3ccccc34)n2)cc1 ; c1ccc(-c2nc(-c3cccc(-c4ccc5c6ccccc6c6ccccc6c5c4)c3)nc(-c3ccc4c(c3)oc3ccccc34)n2)cc1 ; c1ccc(-c2nc(-c3cccc(-c4ccc5c6ccccc6c6ccccc6c5c4)c3)nc(-c3ccc4oc5ccccc5c4c3)n2)cc1 ; c1ccc(-c2nc(-c3cccc(-c4ccc5c6ccccc6c6ccccc6c5c4)c3)nc(-c3cccc4oc5ccccc5c34)n2)cc1]

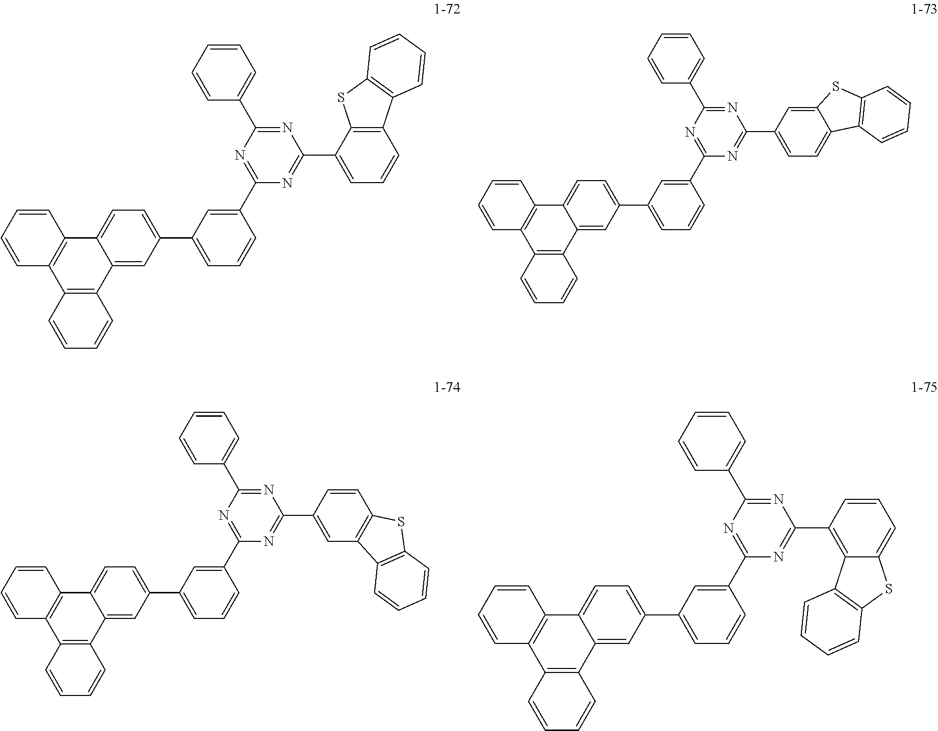 [SMILES: c1ccc(-c2nc(-c3cccc(-c4ccc5c6ccccc6c6ccccc6c5c4)c3)nc(-c3cccc4c3sc3ccccc34)n2)cc1 ; c1ccc(-c2nc(-c3cccc(-c4ccc5c6ccccc6c6ccccc6c5c4)c3)nc(-c3ccc4c(c3)sc3ccccc34)n2)cc1 ; c1ccc(-c2nc(-c3cccc(-c4ccc5c6ccccc6c6ccccc6c5c4)c3)nc(-c3ccc4sc5ccccc5c4c3)n2)cc1 ; c1ccc(-c2nc(-c3cccc(-c4ccc5c6ccccc6c6ccccc6c5c4)c3)nc(-c3cccc4sc5ccccc5c34)n2)cc1]

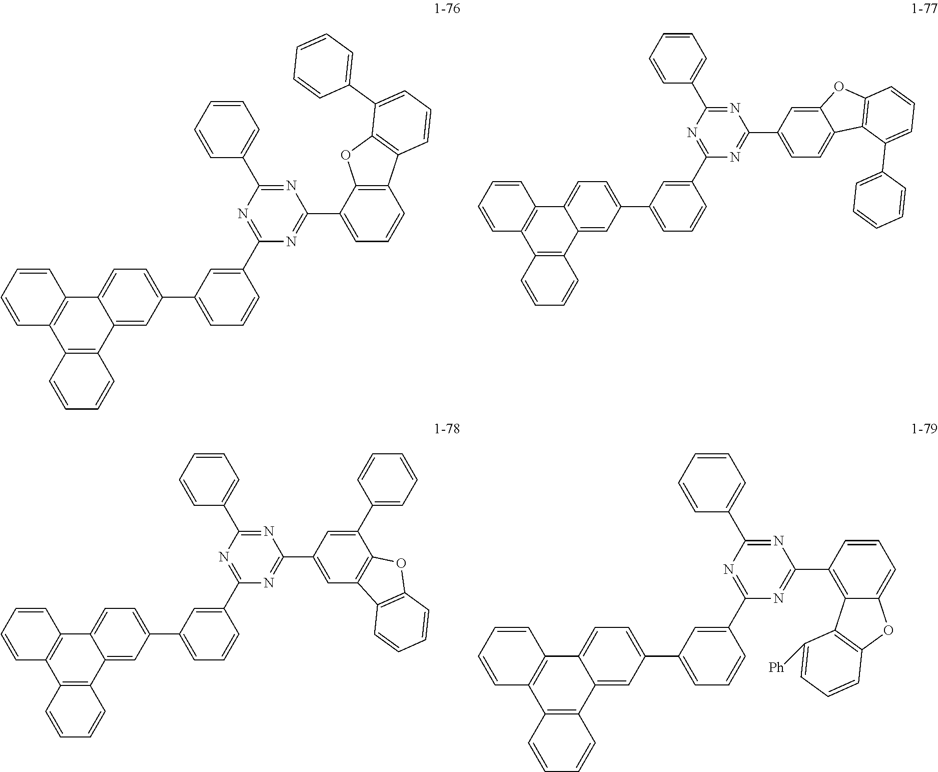 [SMILES: c1ccc(-c2nc(-c3cccc(-c4ccc5c6ccccc6c6ccccc6c5c4)c3)nc(-c3cccc4c3oc3c(-c5ccccc5)cccc34)n2)cc1 ; c1ccc(-c2nc(-c3cccc(-c4ccc5c6ccccc6c6ccccc6c5c4)c3)nc(-c3ccc4c(c3)oc3cccc(-c5ccccc5)c34)n2)cc1 ; c1ccc(-c2nc(-c3cccc(-c4ccc5c6ccccc6c6ccccc6c5c4)c3)nc(-c3cc(-c4ccccc4)c4oc5ccccc5c4c3)n2)cc1 ; c1ccc(-c2nc(-c3cccc(-c4ccc5c6ccccc6c6ccccc6c5c4)c3)nc(-c3cccc4oc5cccc(-c6ccccc6)c5c34)n2)cc1]

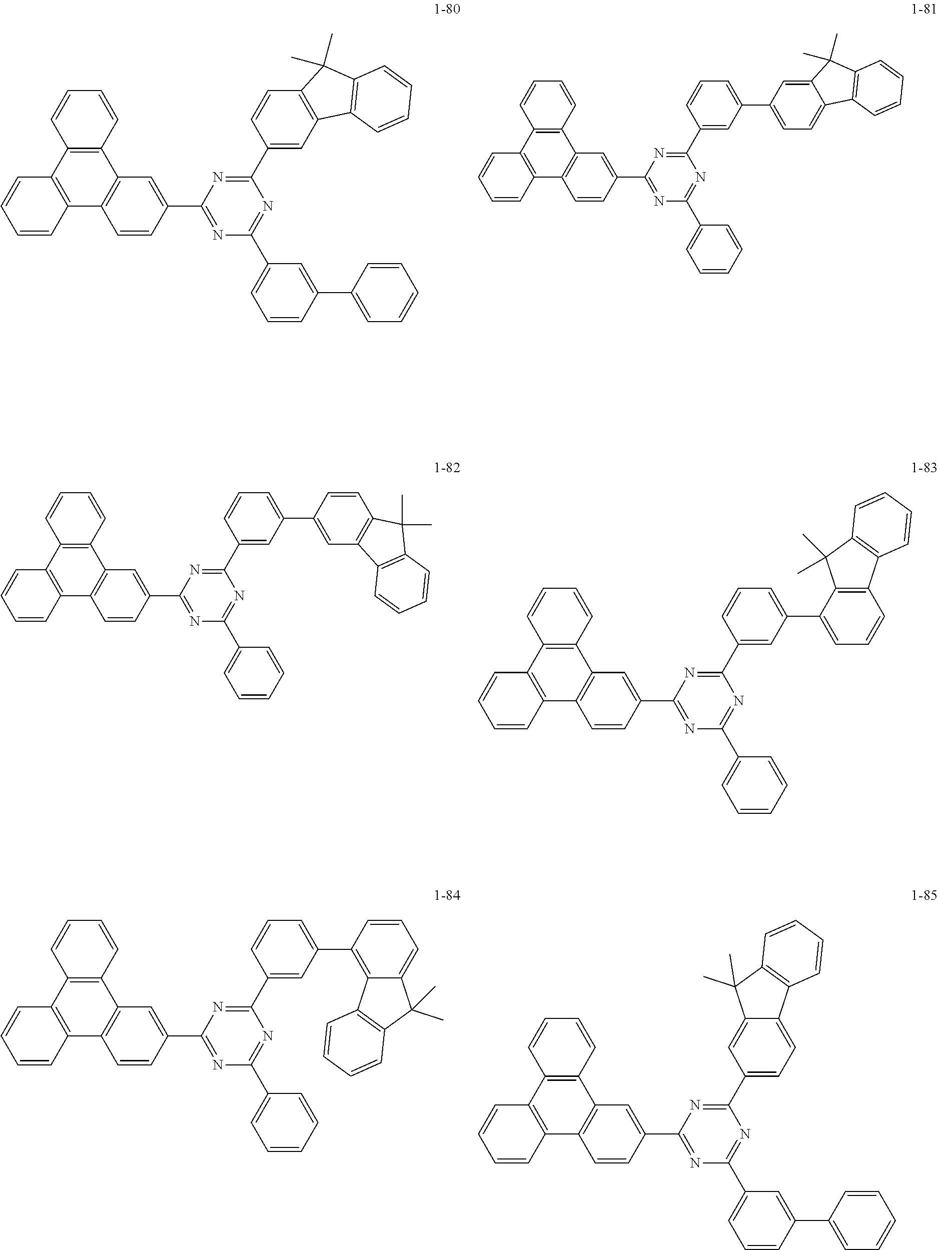

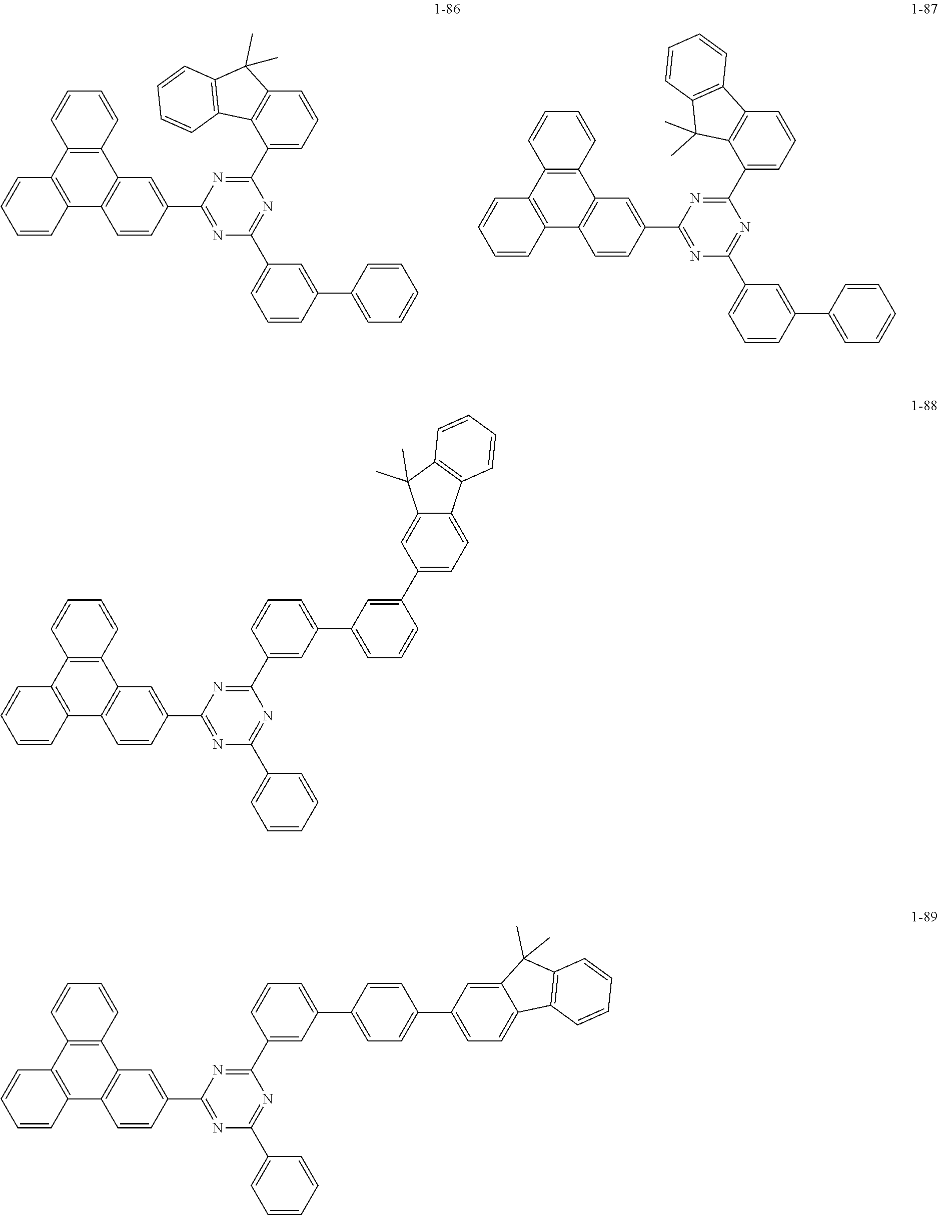 [SMILES: CC1(C)c2ccccc2-c2c(-c3nc(-c4cccc(-c5ccccc5)c4)nc(-c4ccc5c6ccccc6c6ccccc6c5c4)n3)cccc21 ; CC1(C)c2ccccc2-c2cccc(-c3nc(-c4cccc(-c5ccccc5)c4)nc(-c4ccc5c6ccccc6c6ccccc6c5c4)n3)c21 ; CC1(C)c2ccccc2-c2ccc(-c3cccc(-c4cccc(-c5nc(-c6ccccc6)nc(-c6ccc7c8ccccc8c8ccccc8c7c6)n5)c4)c3)cc21 ; CC1(C)c2ccccc2-c2ccc(-c3ccc(-c4cccc(-c5nc(-c6ccccc6)nc(-c6ccc7c8ccccc8c8ccccc8c7c6)n5)c4)cc3)cc21]

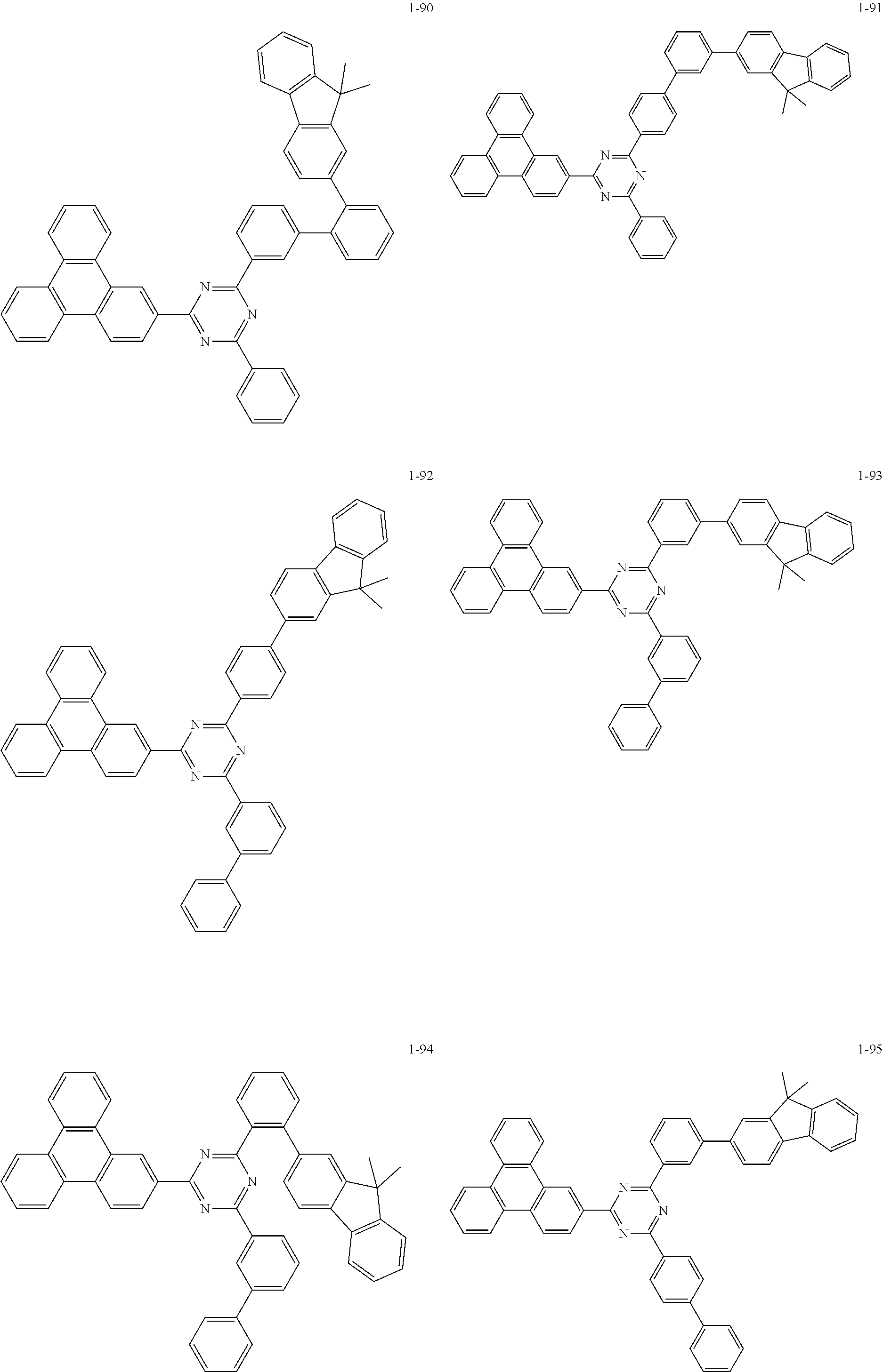

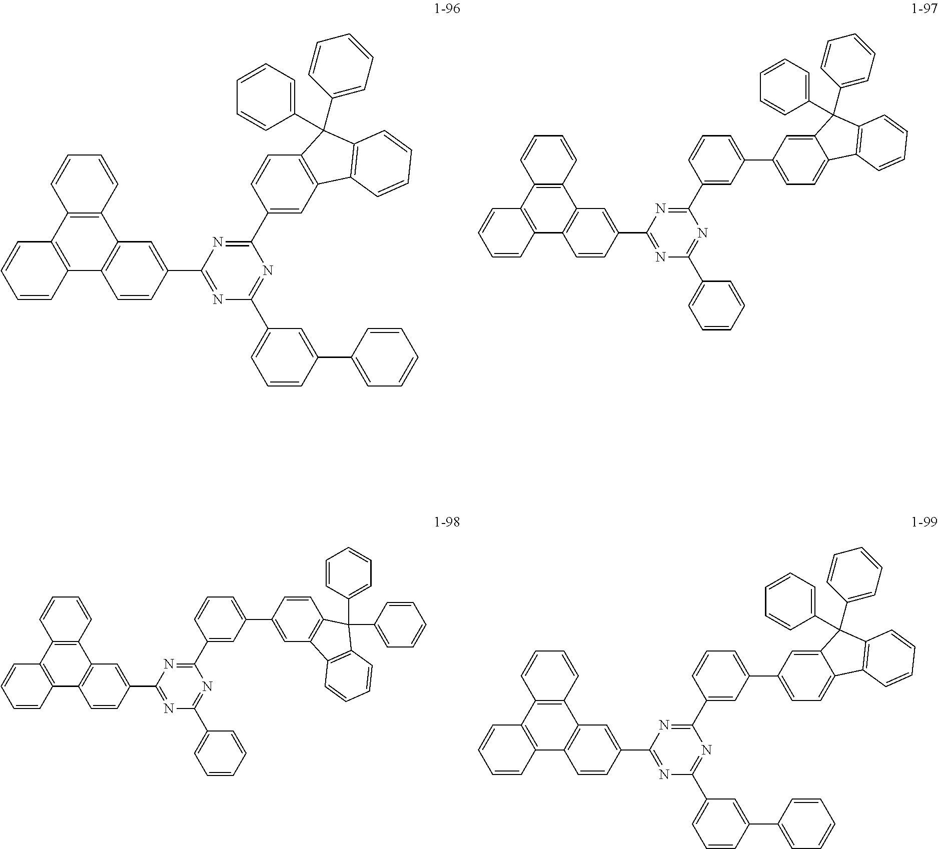 [SMILES: c1ccc(-c2cccc(-c3nc(-c4ccc5c(c4)-c4ccccc4C5(c4ccccc4)c4ccccc4)nc(-c4ccc5c6ccccc6c6ccccc6c5c4)n3)c2)cc1 ; c1ccc(-c2nc(-c3cccc(-c4ccc5c(c4)C(c4ccccc4)(c4ccccc4)c4ccccc4-5)c3)nc(-c3ccc4c5ccccc5c5ccccc5c4c3)n2)cc1 ; c1ccc(-c2nc(-c3cccc(-c4ccc5c(c4)-c4ccccc4C5(c4ccccc4)c4ccccc4)c3)nc(-c3ccc4c5ccccc5c5ccccc5c4c3)n2)cc1 ; c1ccc(-c2cccc(-c3nc(-c4cccc(-c5ccc6c(c5)C(c5ccccc5)(c5ccccc5)c5ccccc5-6)c4)nc(-c4ccc5c6ccccc6c6ccccc6c5c4)n3)c2)cc1]

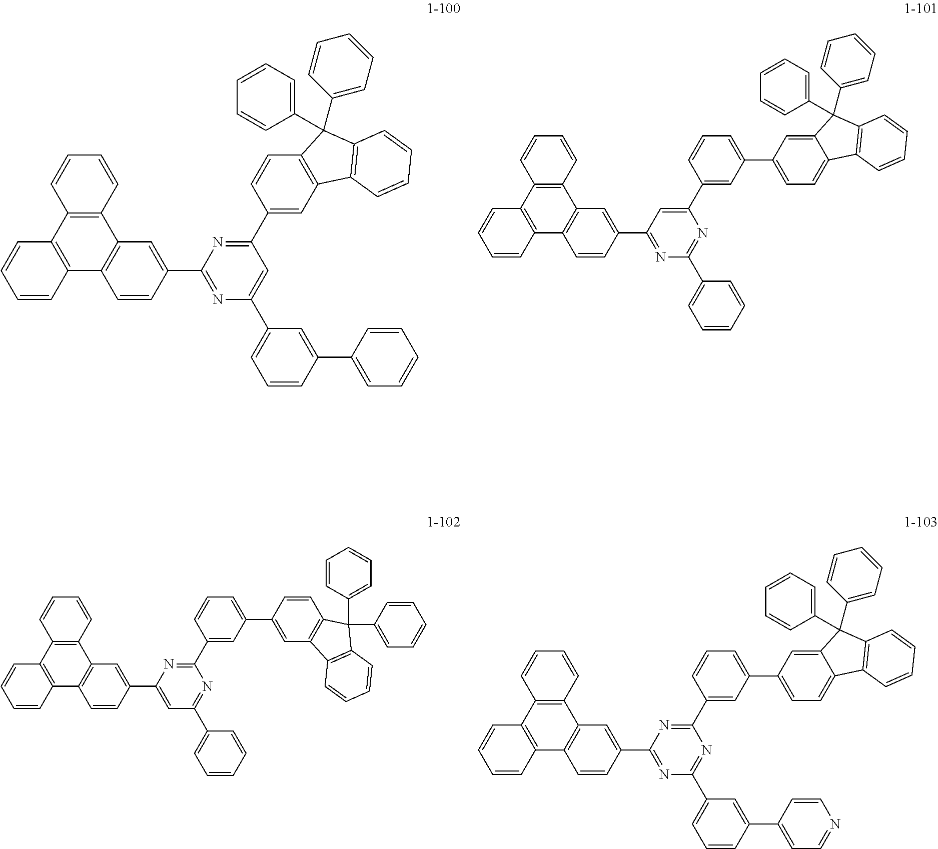 [SMILES: c1ccc(-c2cccc(-c3cc(-c4ccc5c(c4)-c4ccccc4C5(c4ccccc4)c4ccccc4)nc(-c4ccc5c6ccccc6c6ccccc6c5c4)n3)c2)cc1 ; c1ccc(-c2nc(-c3cccc(-c4ccc5c(c4)C(c4ccccc4)(c4ccccc4)c4ccccc4-5)c3)cc(-c3ccc4c5ccccc5c5ccccc5c4c3)n2)cc1 ; c1ccc(-c2cc(-c3ccc4c5ccccc5c5ccccc5c4c3)nc(-c3cccc(-c4ccc5c(c4)-c4ccccc4C5(c4ccccc4)c4ccccc4)c3)n2)cc1 ; c1ccc(C2(c3ccccc3)c3ccccc3-c3ccc(-c4cccc(-c5nc(-c6cccc(-c7ccncc7)c6)nc(-c6ccc7c8ccccc8c8ccccc8c7c6)n5)c4)cc32)cc1]

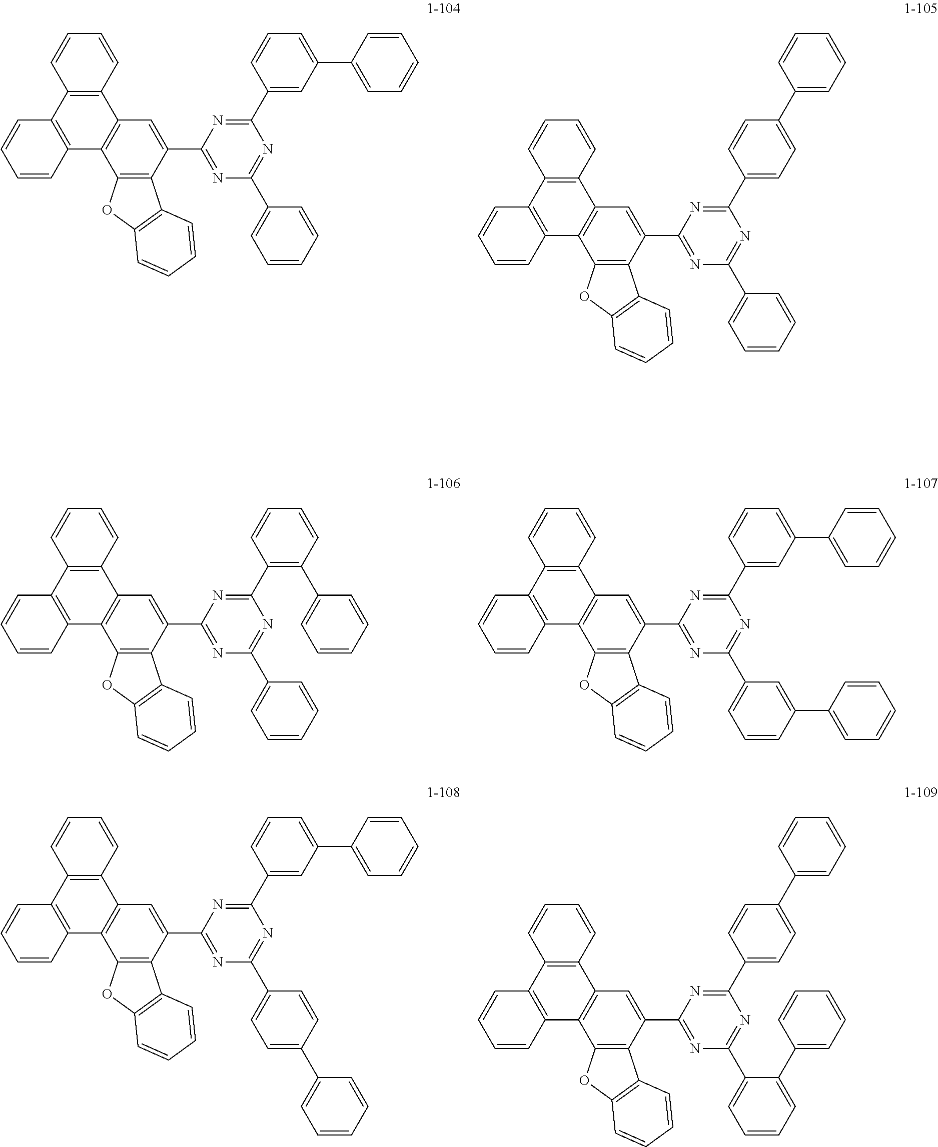

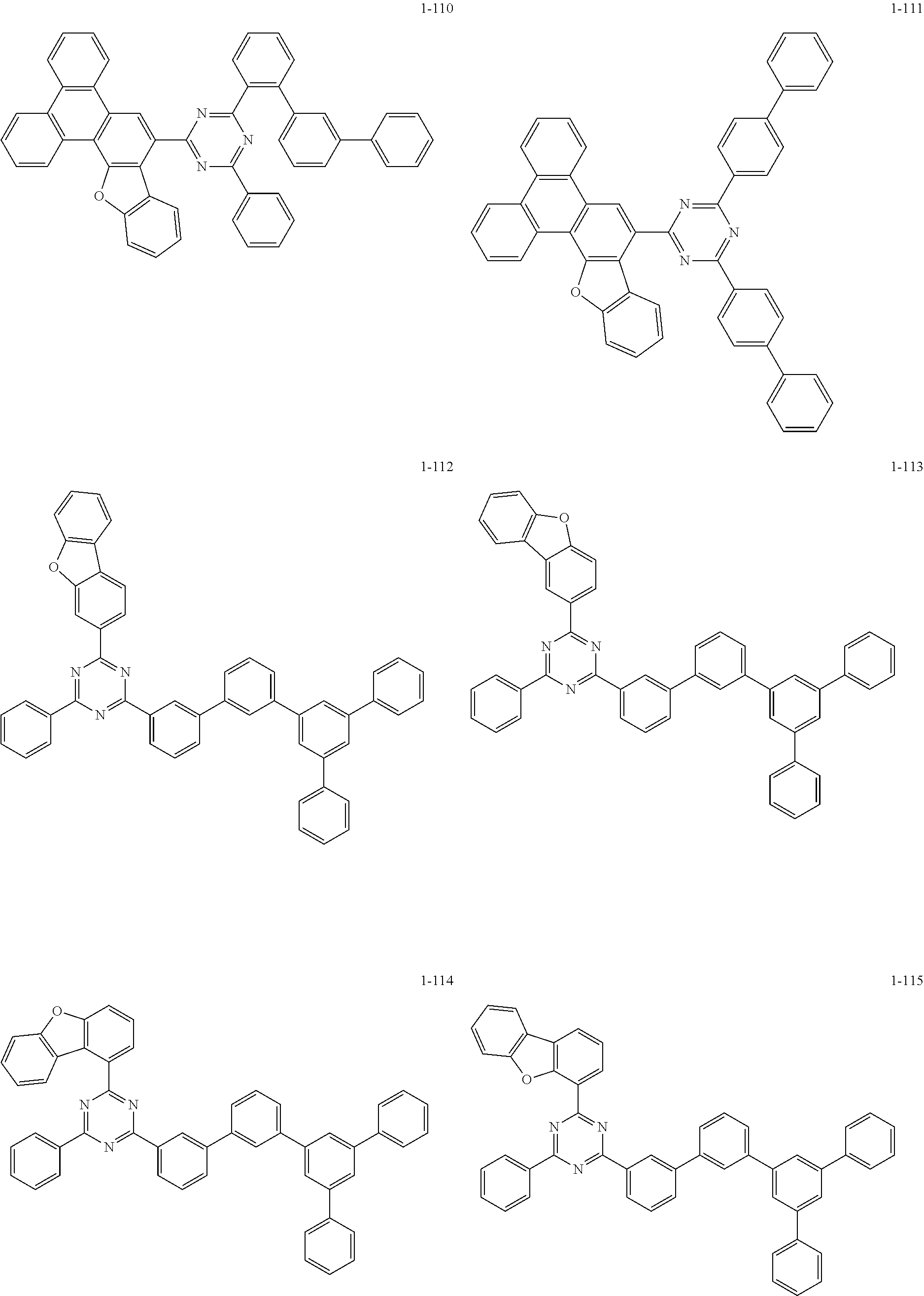

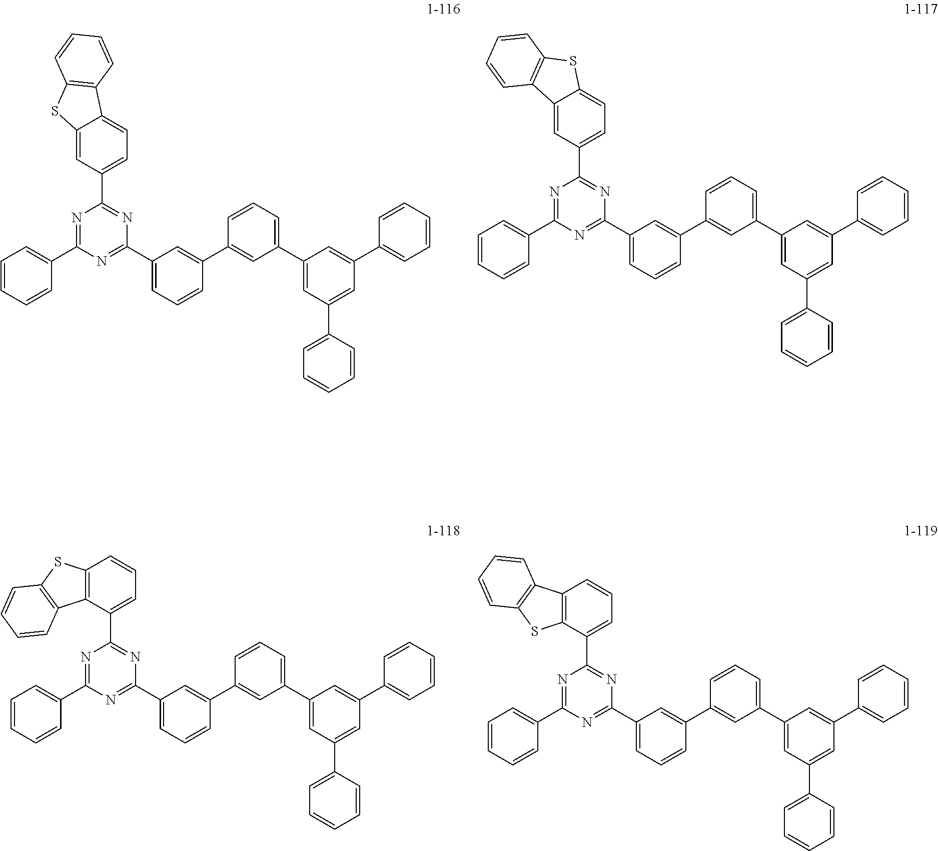 [SMILES: c1ccc(-c2cc(-c3ccccc3)cc(-c3cccc(-c4cccc(-c5nc(-c6ccccc6)nc(-c6ccc7c(c6)sc6ccccc67)n5)c4)c3)c2)cc1 ; c1ccc(-c2cc(-c3ccccc3)cc(-c3cccc(-c4cccc(-c5nc(-c6ccccc6)nc(-c6ccc7sc8ccccc8c7c6)n5)c4)c3)c2)cc1 ; c1ccc(-c2cc(-c3ccccc3)cc(-c3cccc(-c4cccc(-c5nc(-c6ccccc6)nc(-c6cccc7sc8ccccc8c67)n5)c4)c3)c2)cc1 ; c1ccc(-c2cc(-c3ccccc3)cc(-c3cccc(-c4cccc(-c5nc(-c6ccccc6)nc(-c6cccc7c6sc6ccccc67)n5)c4)c3)c2)cc1]

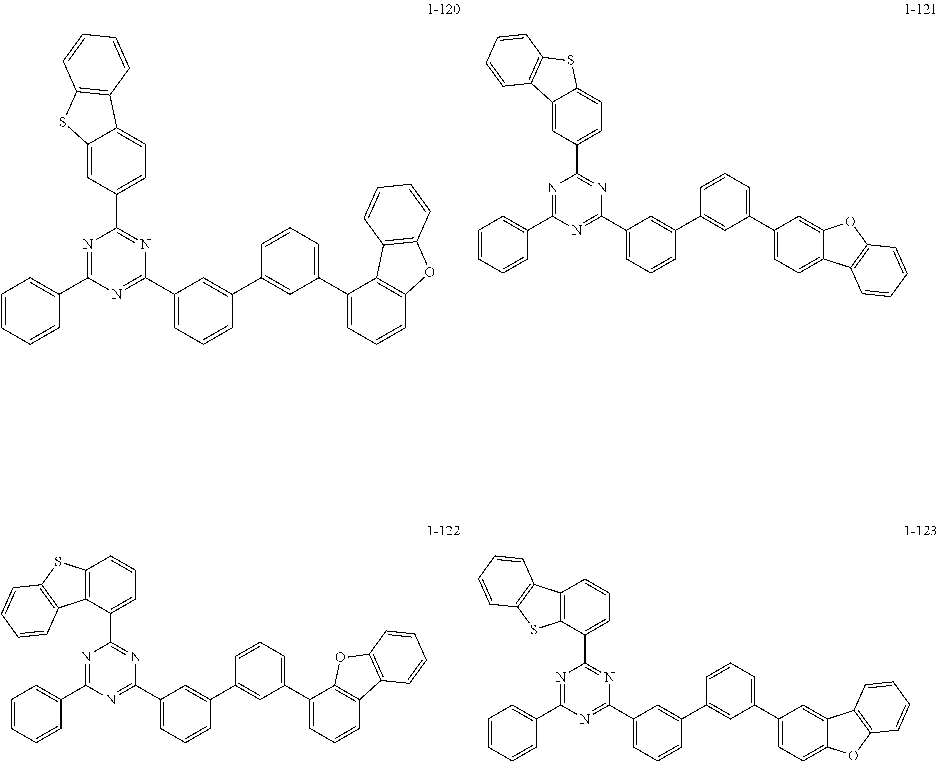 [SMILES: c1ccc(-c2nc(-c3cccc(-c4cccc(-c5cccc6oc7ccccc7c56)c4)c3)nc(-c3ccc4c(c3)sc3ccccc34)n2)cc1 ; c1ccc(-c2nc(-c3cccc(-c4cccc(-c5ccc6c(c5)oc5ccccc56)c4)c3)nc(-c3ccc4sc5ccccc5c4c3)n2)cc1 ; c1ccc(-c2nc(-c3cccc(-c4cccc(-c5cccc6c5oc5ccccc56)c4)c3)nc(-c3cccc4sc5ccccc5c34)n2)cc1 ; c1ccc(-c2nc(-c3cccc(-c4cccc(-c5ccc6oc7ccccc7c6c5)c4)c3)nc(-c3cccc4c3sc3ccccc34)n2)cc1]

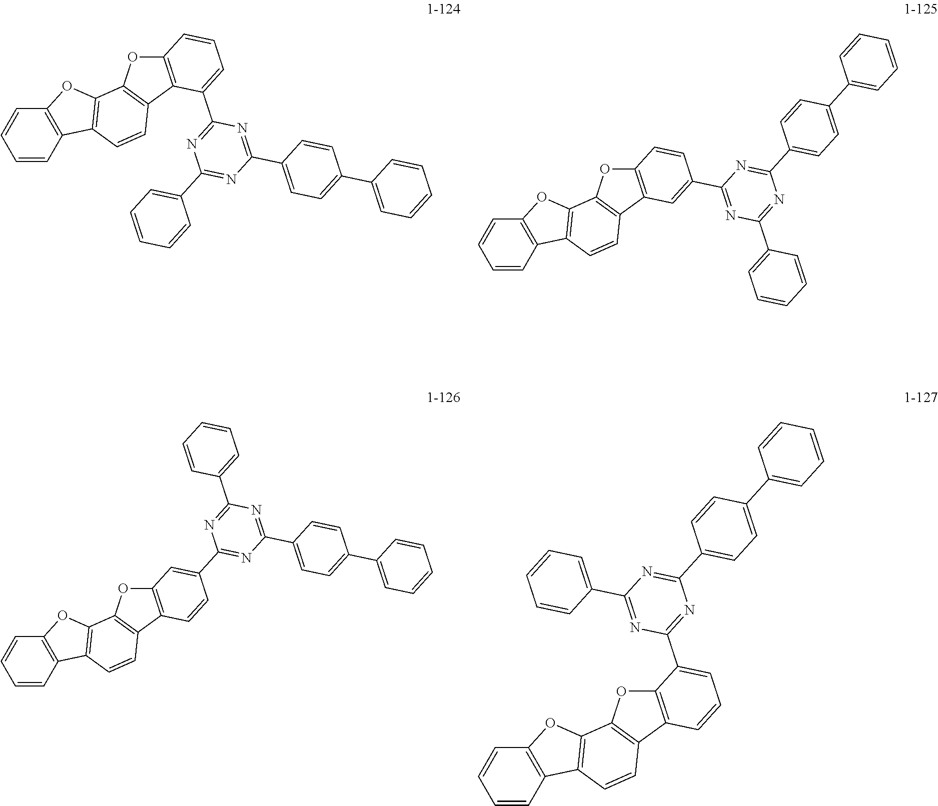 [SMILES: c1ccc(-c2ccc(-c3nc(-c4ccccc4)nc(-c4cccc5oc6c(ccc7c8ccccc8oc76)c45)n3)cc2)cc1 ; c1ccc(-c2ccc(-c3nc(-c4ccccc4)nc(-c4ccc5oc6c(ccc7c8ccccc8oc76)c5c4)n3)cc2)cc1 ; c1ccc(-c2ccc(-c3nc(-c4ccccc4)nc(-c4ccc5c(c4)oc4c5ccc5c6ccccc6oc54)n3)cc2)cc1 ; c1ccc(-c2ccc(-c3nc(-c4ccccc4)nc(-c4cccc5c4oc4c5ccc5c6ccccc6oc54)n3)cc2)cc1]

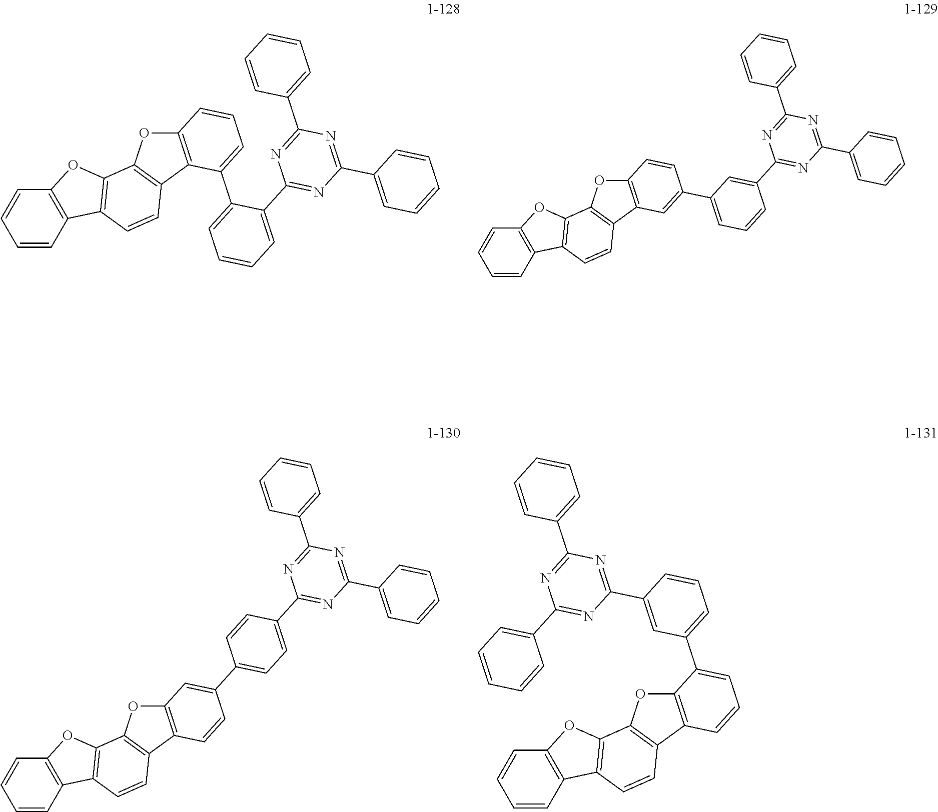 [SMILES: c1ccc(-c2nc(-c3ccccc3)nc(-c3ccccc3-c3cccc4oc5c(ccc6c7ccccc7oc65)c34)n2)cc1 ; c1ccc(-c2nc(-c3ccccc3)nc(-c3cccc(-c4ccc5oc6c(ccc7c8ccccc8oc76)c5c4)c3)n2)cc1 ; c1ccc(-c2nc(-c3ccccc3)nc(-c3ccc(-c4ccc5c(c4)oc4c5ccc5c6ccccc6oc54)cc3)n2)cc1 ; c1ccc(-c2nc(-c3ccccc3)nc(-c3cccc(-c4cccc5c4oc4c5ccc5c6ccccc6oc54)c3)n2)cc1]

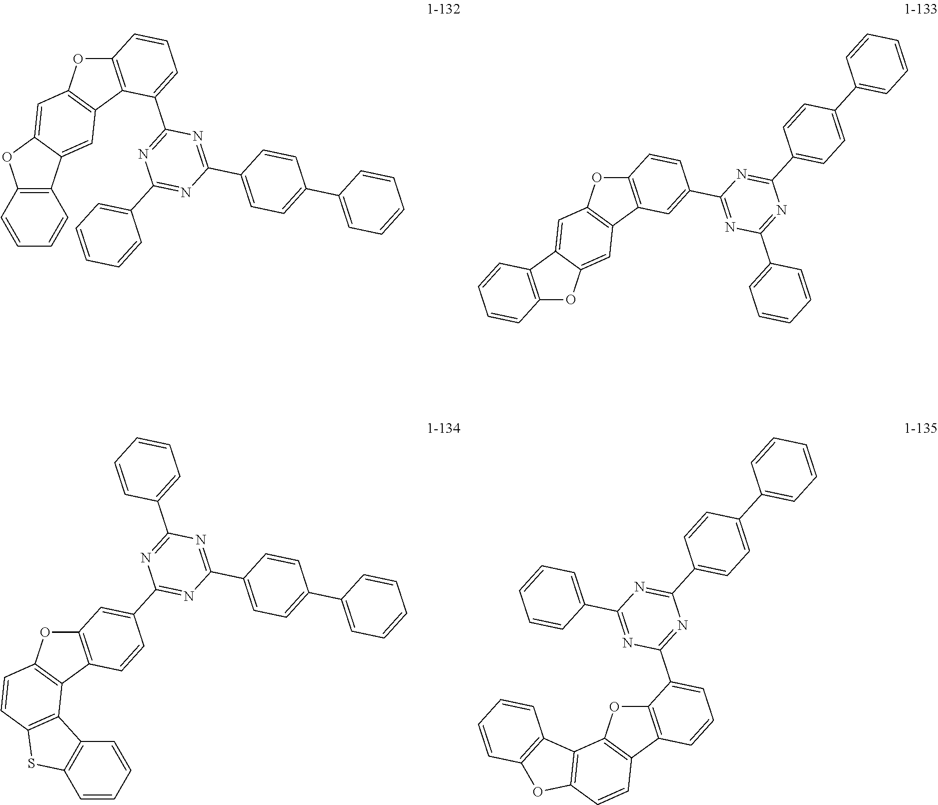 [SMILES: c1ccc(-c2ccc(-c3nc(-c4ccccc4)nc(-c4cccc5oc6cc7oc8ccccc8c7cc6c45)n3)cc2)cc1 ; c1ccc(-c2ccc(-c3nc(-c4ccccc4)nc(-c4ccc5oc6cc7c(cc6c5c4)oc4ccccc47)n3)cc2)cc1 ; c1ccc(-c2ccc(-c3nc(-c4ccccc4)nc(-c4ccc5c(c4)oc4ccc6sc7ccccc7c6c45)n3)cc2)cc1 ; c1ccc(-c2ccc(-c3nc(-c4ccccc4)nc(-c4cccc5c4oc4c5ccc5oc6ccccc6c54)n3)cc2)cc1]

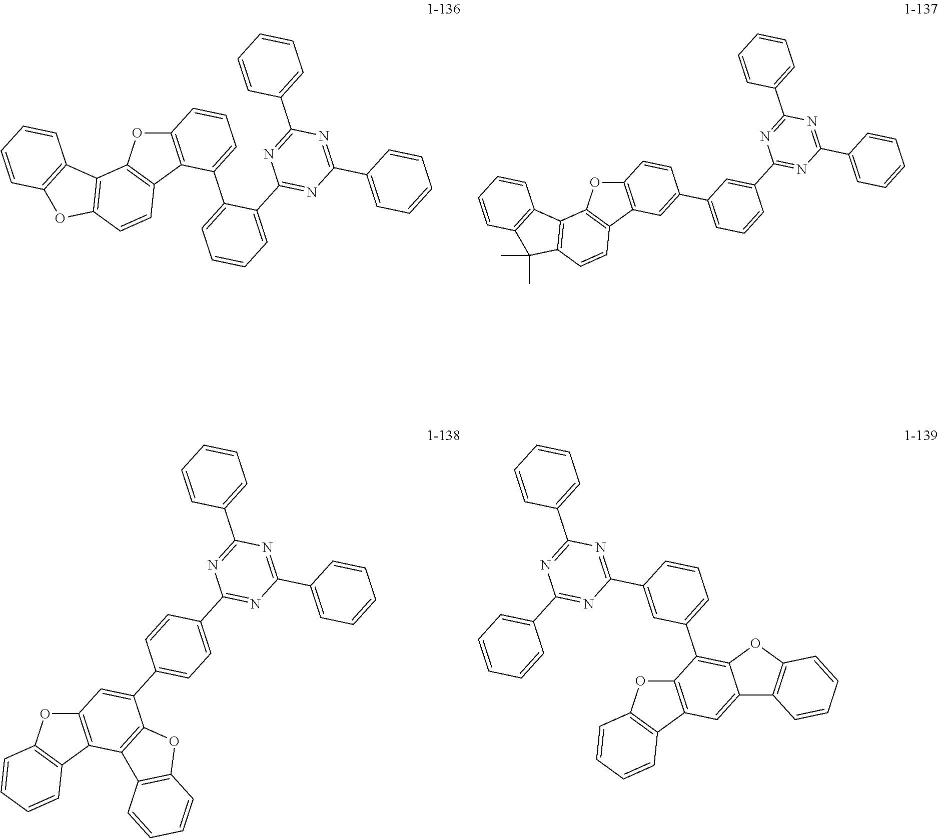 [SMILES: c1ccc(-c2nc(-c3ccccc3)nc(-c3ccccc3-c3cccc4oc5c(ccc6oc7ccccc7c65)c34)n2)cc1 ; CC1(C)c2ccccc2-c2c1ccc1c2oc2ccc(-c3cccc(-c4nc(-c5ccccc5)nc(-c5ccccc5)n4)c3)cc21 ; c1ccc(-c2nc(-c3ccccc3)nc(-c3ccc(-c4cc5oc6ccccc6c5c5c4oc4ccccc45)cc3)n2)cc1 ; c1ccc(-c2nc(-c3ccccc3)nc(-c3cccc(-c4c5oc6ccccc6c5cc5c4oc4ccccc45)c3)n2)cc1]

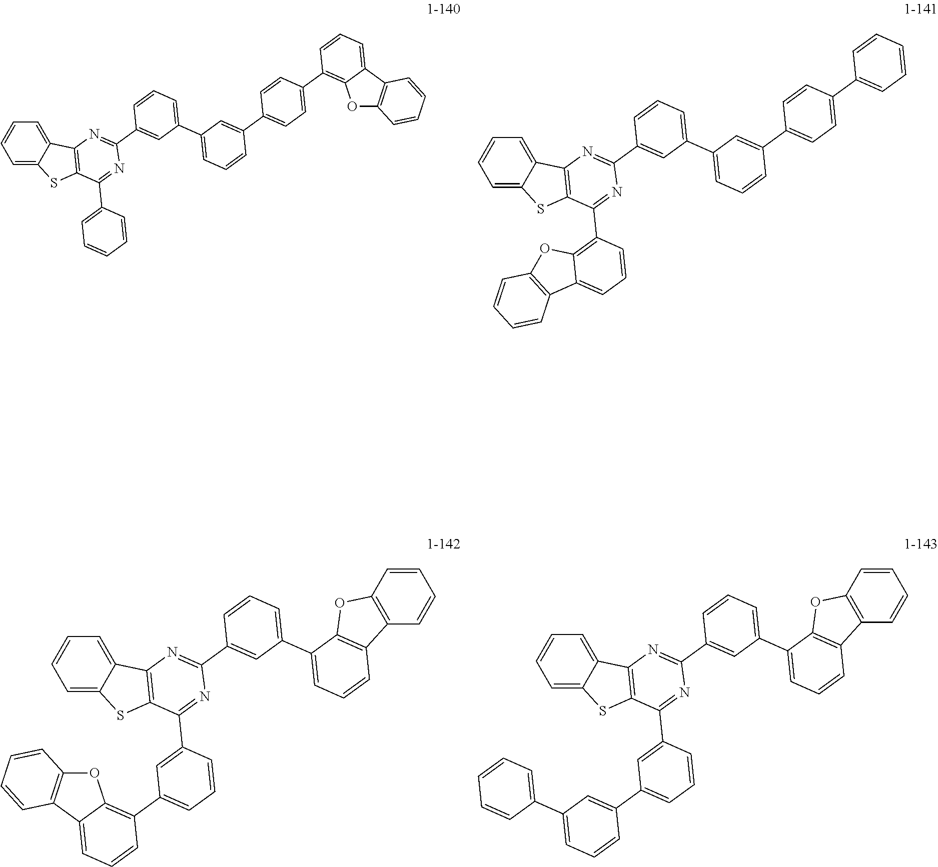 [SMILES: c1ccc(-c2nc(-c3cccc(-c4cccc(-c5ccc(-c6cccc7c6oc6ccccc67)cc5)c4)c3)nc3c2sc2ccccc23)cc1 ; c1ccc(-c2ccc(-c3cccc(-c4cccc(-c5nc(-c6cccc7c6oc6ccccc67)c6sc7ccccc7c6n5)c4)c3)cc2)cc1 ; c1cc(-c2nc(-c3cccc(-c4cccc5c4oc4ccccc45)c3)c3sc4ccccc4c3n2)cc(-c2cccc3c2oc2ccccc23)c1 ; c1ccc(-c2cccc(-c3cccc(-c4nc(-c5cccc(-c6cccc7c6oc6ccccc67)c5)nc5c4sc4ccccc45)c3)c2)cc1]

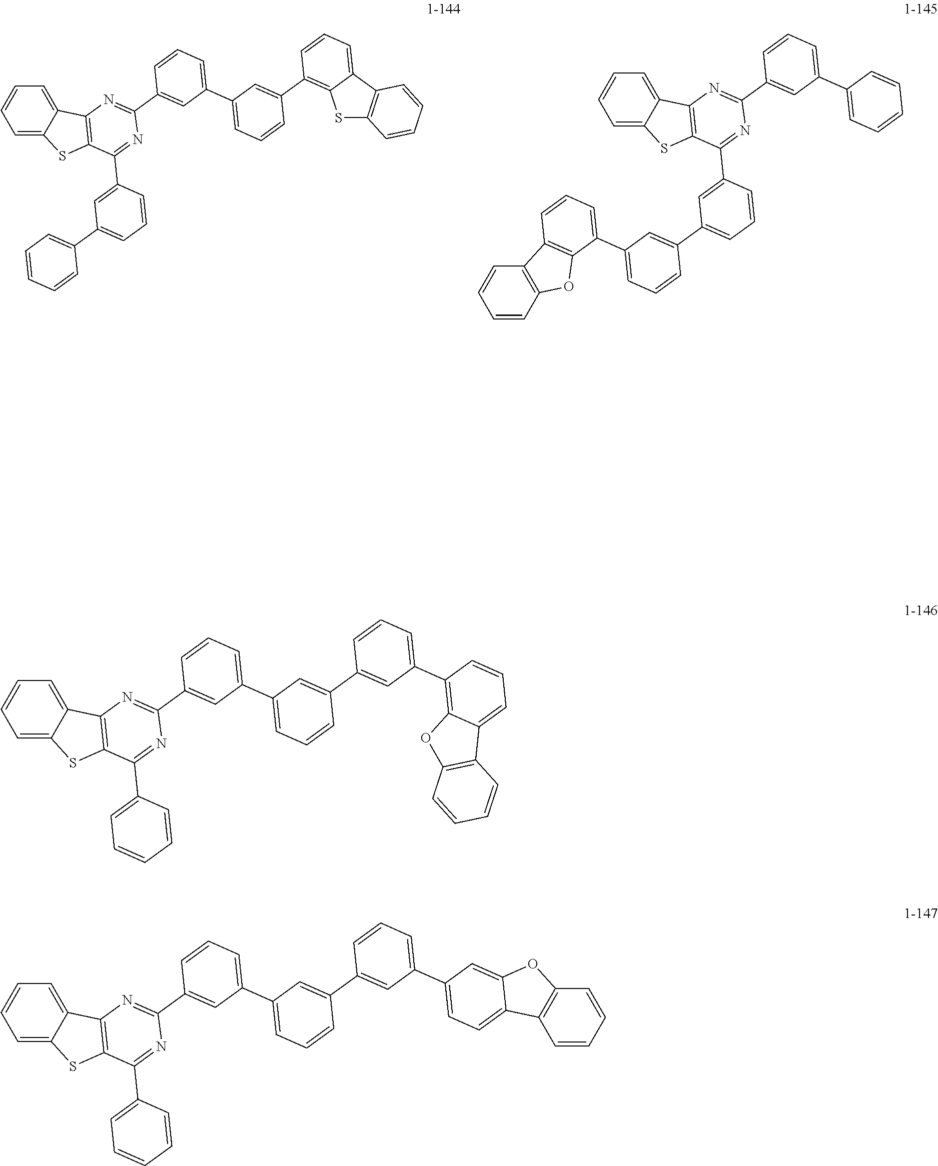 [SMILES: c1ccc(-c2cccc(-c3nc(-c4cccc(-c5cccc(-c6cccc7c6sc6ccccc67)c5)c4)nc4c3sc3ccccc34)c2)cc1 ; c1ccc(-c2cccc(-c3nc(-c4cccc(-c5cccc(-c6cccc7c6oc6ccccc67)c5)c4)c4sc5ccccc5c4n3)c2)cc1 ; c1ccc(-c2nc(-c3cccc(-c4cccc(-c5cccc(-c6cccc7c6oc6ccccc67)c5)c4)c3)nc3c2sc2ccccc23)cc1 ; c1ccc(-c2nc(-c3cccc(-c4cccc(-c5cccc(-c6ccc7c(c6)oc6ccccc67)c5)c4)c3)nc3c2sc2ccccc23)cc1]

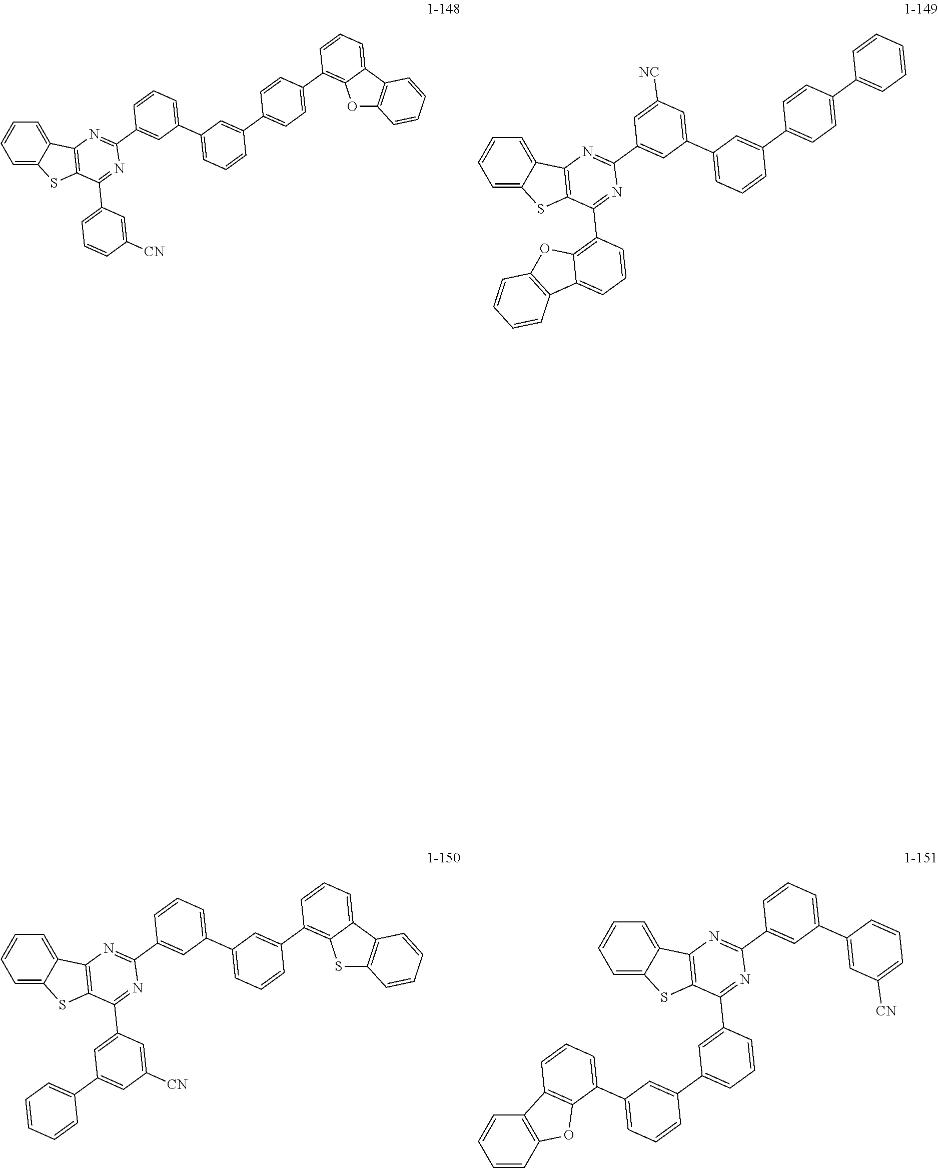 [SMILES: N#Cc1cccc(-c2nc(-c3cccc(-c4cccc(-c5ccc(-c6cccc7c6oc6ccccc67)cc5)c4)c3)nc3c2sc2ccccc23)c1 ; N#Cc1cc(-c2cccc(-c3ccc(-c4ccccc4)cc3)c2)cc(-c2nc(-c3cccc4c3oc3ccccc34)c3sc4ccccc4c3n2)c1 ; N#Cc1cc(-c2ccccc2)cc(-c2nc(-c3cccc(-c4cccc(-c5cccc6c5sc5ccccc56)c4)c3)nc3c2sc2ccccc23)c1 ; N#Cc1cccc(-c2cccc(-c3nc(-c4cccc(-c5cccc(-c6cccc7c6oc6ccccc67)c5)c4)c4sc5ccccc5c4n3)c2)c1]

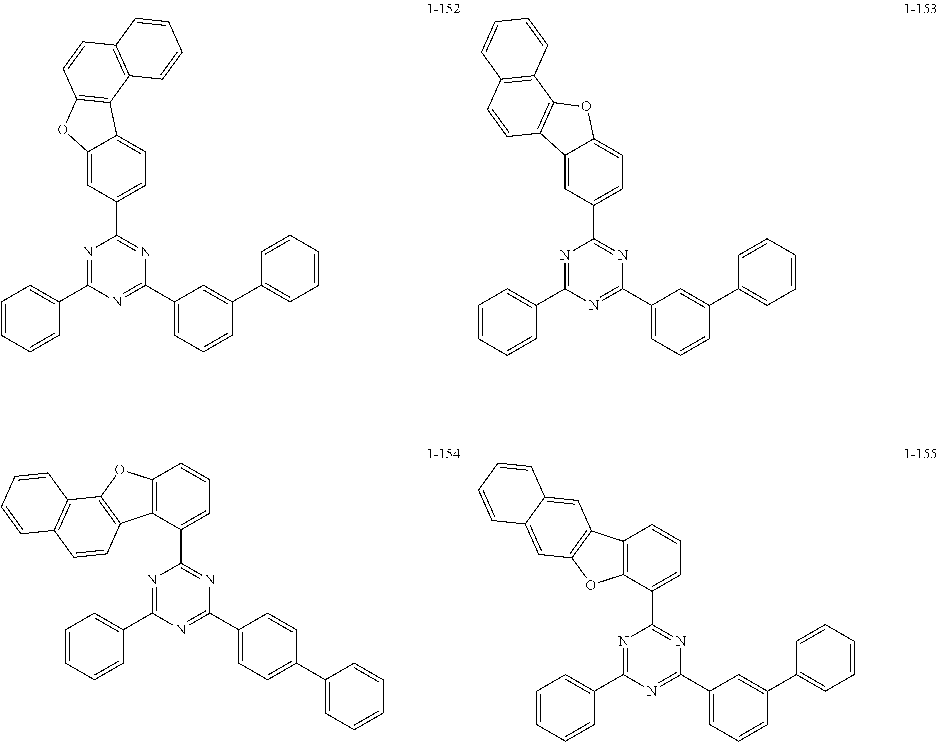 [SMILES: c1ccc(-c2cccc(-c3nc(-c4ccccc4)nc(-c4ccc5c(c4)oc4ccc6ccccc6c45)n3)c2)cc1 ; c1ccc(-c2cccc(-c3nc(-c4ccccc4)nc(-c4ccc5oc6c7ccccc7ccc6c5c4)n3)c2)cc1 ; c1ccc(-c2ccc(-c3nc(-c4ccccc4)nc(-c4cccc5oc6c7ccccc7ccc6c45)n3)cc2)cc1 ; c1ccc(-c2cccc(-c3nc(-c4ccccc4)nc(-c4cccc5c4oc4cc6ccccc6cc45)n3)c2)cc1]

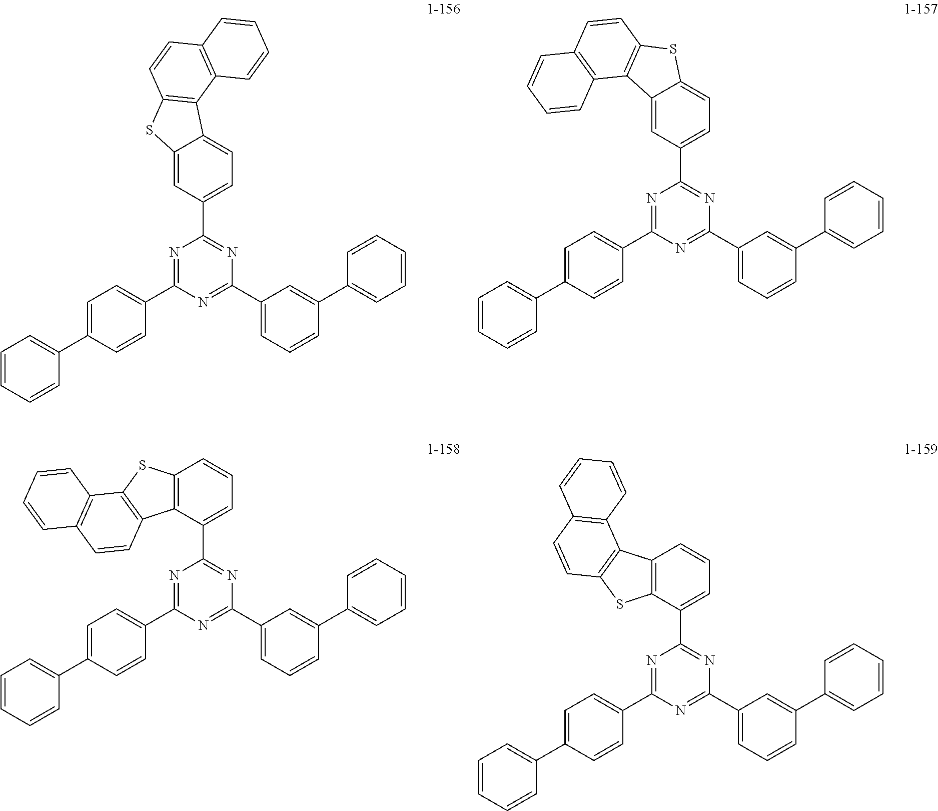 [SMILES: c1ccc(-c2ccc(-c3nc(-c4cccc(-c5ccccc5)c4)nc(-c4ccc5c(c4)sc4ccc6ccccc6c45)n3)cc2)cc1 ; c1ccc(-c2ccc(-c3nc(-c4cccc(-c5ccccc5)c4)nc(-c4ccc5sc6ccc7ccccc7c6c5c4)n3)cc2)cc1 ; c1ccc(-c2ccc(-c3nc(-c4cccc(-c5ccccc5)c4)nc(-c4cccc5sc6c7ccccc7ccc6c45)n3)cc2)cc1 ; c1ccc(-c2ccc(-c3nc(-c4cccc(-c5ccccc5)c4)nc(-c4cccc5c4sc4ccc6ccccc6c45)n3)cc2)cc1]

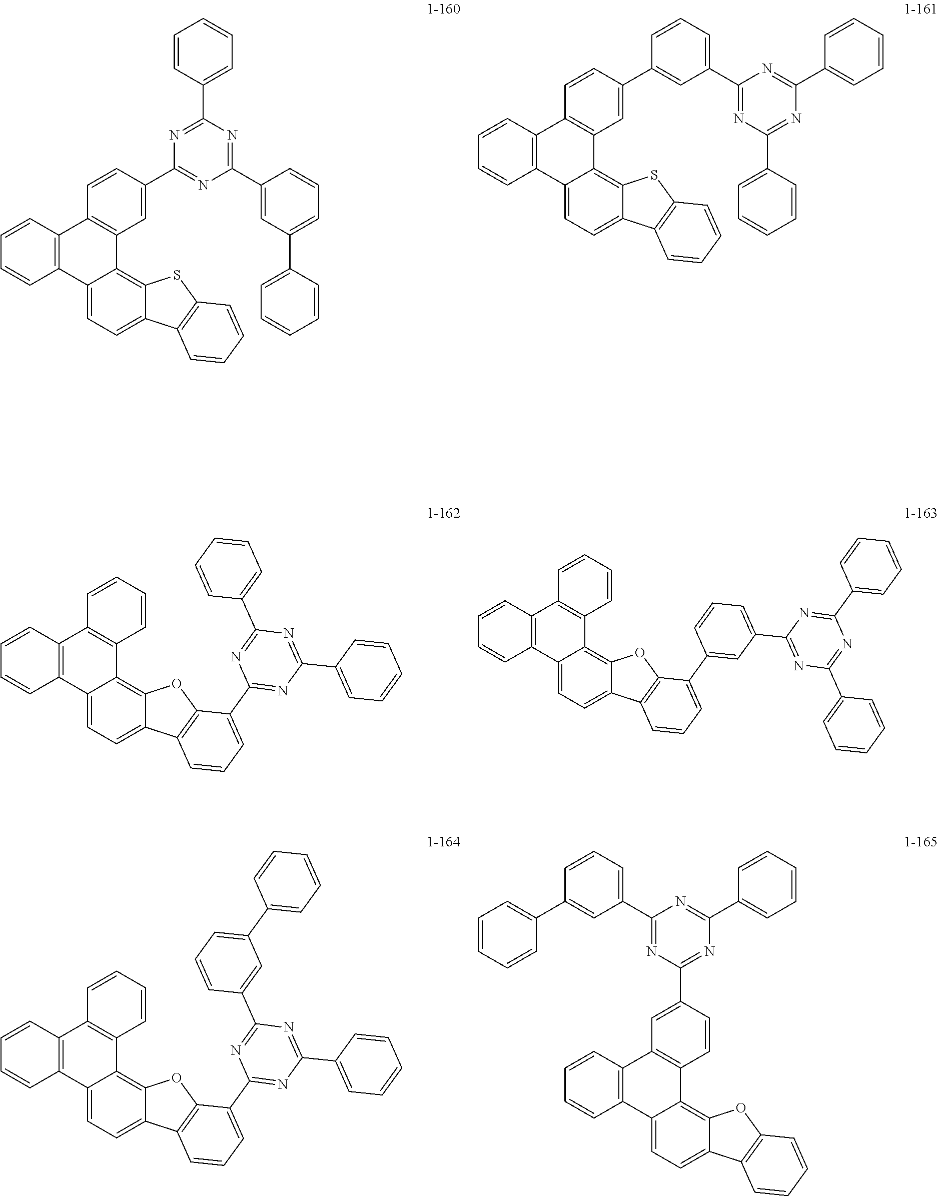 [SMILES: c1ccc(-c2cccc(-c3nc(-c4ccccc4)nc(-c4ccc5c6ccccc6c6ccc7c8ccccc8sc7c6c5c4)n3)c2)cc1 ; c1ccc(-c2nc(-c3ccccc3)nc(-c3cccc(-c4ccc5c6ccccc6c6ccc7c8ccccc8sc7c6c5c4)c3)n2)cc1 ; c1ccc(-c2nc(-c3ccccc3)nc(-c3cccc4c3oc3c4ccc4c5ccccc5c5ccccc5c43)n2)cc1 ; c1ccc(-c2nc(-c3ccccc3)nc(-c3cccc(-c4cccc5c4oc4c5ccc5c6ccccc6c6ccccc6c54)c3)n2)cc1 ; c1ccc(-c2cccc(-c3nc(-c4ccccc4)nc(-c4cccc5c4oc4c5ccc5c6ccccc6c6ccccc6c54)n3)c2)cc1 ; c1ccc(-c2cccc(-c3nc(-c4ccccc4)nc(-c4ccc5c(c4)c4ccccc4c4ccc6c7ccccc7oc6c45)n3)c2)cc1]

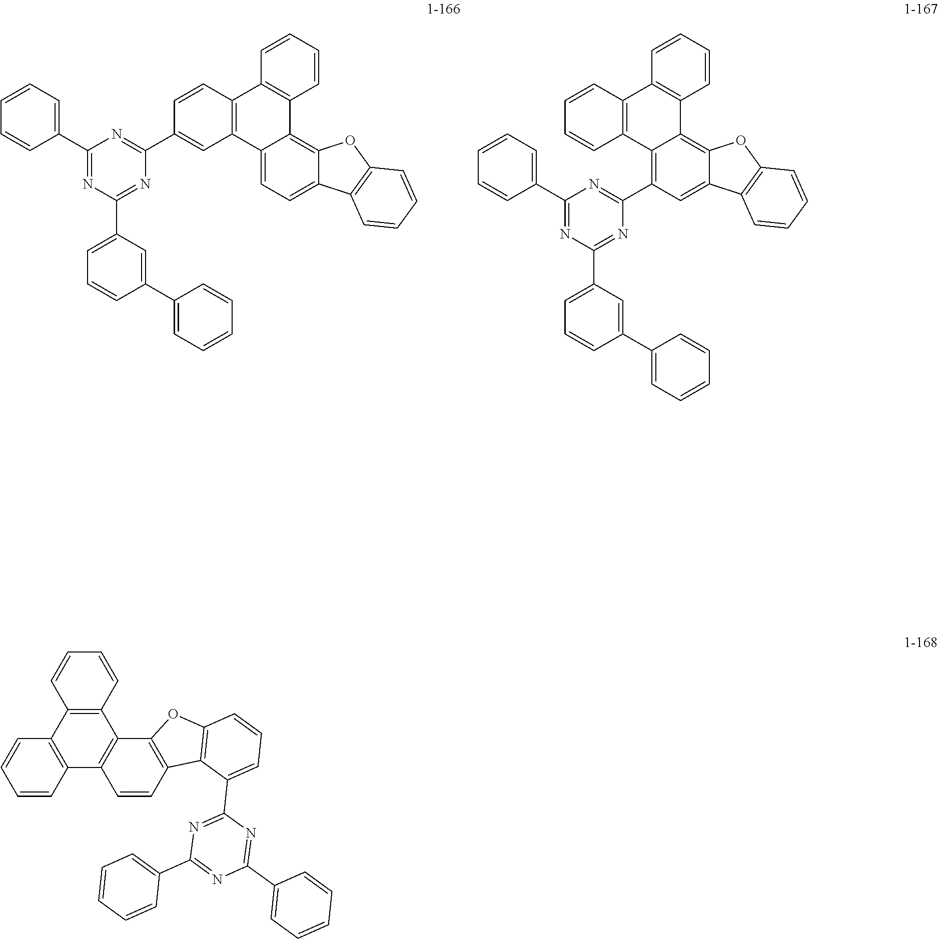 [SMILES: c1ccc(-c2cccc(-c3nc(-c4ccccc4)nc(-c4ccc5c6ccccc6c6c(ccc7c8ccccc8oc76)c5c4)n3)c2)cc1 ; c1ccc(-c2cccc(-c3nc(-c4ccccc4)nc(-c4cc5c6ccccc6oc5c5c6ccccc6c6ccccc6c45)n3)c2)cc1 ; c1ccc(-c2nc(-c3ccccc3)nc(-c3cccc4oc5c(ccc6c7ccccc7c7ccccc7c65)c34)n2)cc1]

The second compound having the hole characteristics has a structure in which carbazole or carbazole derivatives is substituted with a substituted or unsubstituted C6 to C30 aryl group, a substituted or unsubstituted dibenzofuranyl group, or a substituted or unsubstituted dibenzothiophenyl group and is represented by Chemical Formula III.

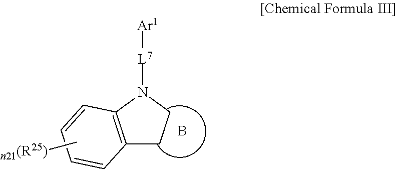

In Chemical Formula III,
L⁷ is a single bond, a substituted or unsubstituted C6 to C20 arylene group, a substituted or unsubstituted C2 to C20 heterocyclic group, or a combination thereof,
Ar¹ is a substituted or unsubstituted C6 to C30 aryl group, a substituted or unsubstituted dibenzofuranyl group, a substituted or unsubstituted dibenzothiophenyl group, or a combination thereof,
R²⁵s are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof,
n21 is an integer from 1 to 4, and
a ring B is represented by any one of Chemical Formulas III-1 to Chemical Formula III-4:

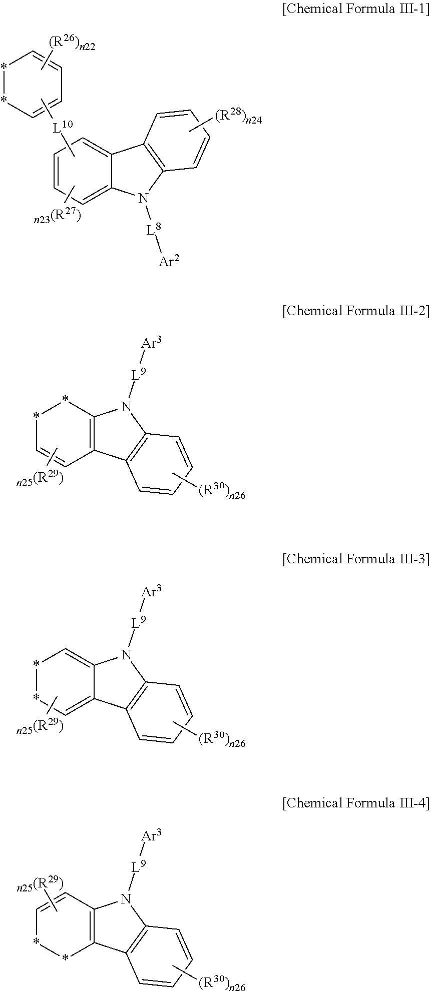

wherein, in Chemical Formula III-1 to Chemical Formula III-4,
L⁸ and L⁹ are each independently a single bond, a substituted or unsubstituted C6 to C20 arylene group, a substituted or unsubstituted C2 to C20 heterocyclic group, or a combination thereof,
L¹⁰ is a single bond or a substituted or unsubstituted C6 to C20 arylene group,
Ar² and Ar³ are a substituted or unsubstituted C6 to C30 aryl group, a substituted or unsubstituted dibenzofuranyl group, a substituted or unsubstituted dibenzothiophenyl group, or a combination thereof,
R²⁶ to R³⁰ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof,
n22 and n23 are each independently one of integers of 1 to 3,
n25 is an integer of 1 or 2,
n24 and n26 are each independently one of integers of 1 to 4, and
* is a linking point.

Specifically, L⁷ in Chemical Formula III may be a single bond or a C6 to C12 arylene group.

For example, L⁷ in Chemical Formula III may be a single bond or a substituted or unsubstituted phenyl group.

Ar¹ in Chemical Formula III may be a substituted or unsubstituted phenyl group, a substituted or unsubstituted biphenyl group, a substituted or unsubstituted terphenyl group, a substituted or unsubstituted naphthyl group, a substituted or unsubstituted phenanthrene group, or a substituted or unsubstituted terphenyl group, a substituted or unsubstituted triphenylene group, a substituted or unsubstituted fluorenyl group, a substituted or unsubstituted carbazolyl group, a substituted or unsubstituted dibenzofuranyl group, or a substituted or unsubstituted dibenzothiophenyl group.

For example, Ar¹ in Chemical Formula III may be a substituted or unsubstituted phenyl group or a substituted or unsubstituted biphenyl group.

According to specific structures of carbazole and carbazole derivatives, Chemical Formula III may be represented by any one of Chemical Formula III-A to Chemical Formula III-F.

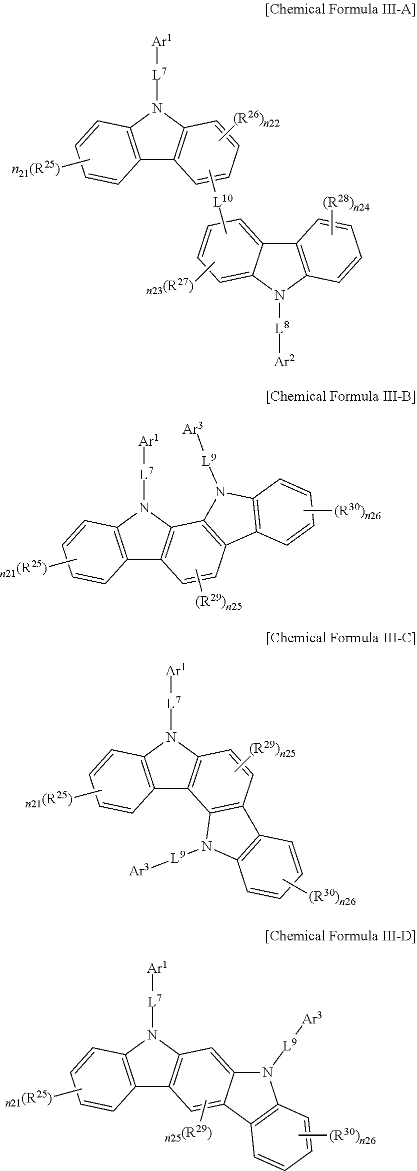

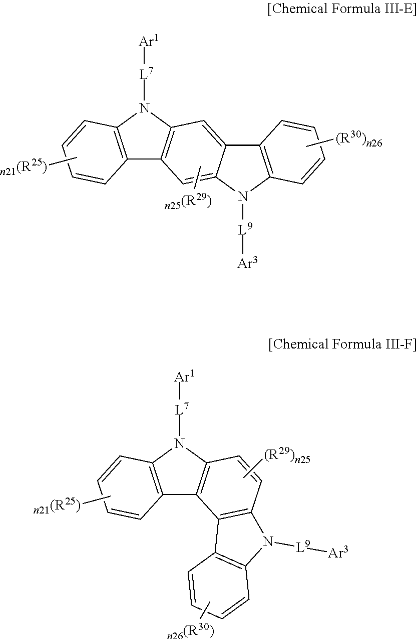

In Chemical Formula III-A to Chemical Formula III-F, L⁷ to L¹⁰, Ar¹ to Ar³, R²⁵ to R³⁰ and n21 to n26 are the same as described above.

Specifically, R²⁵ to R²⁸ in Chemical Formula III-A may each independently be hydrogen, heavy hydrogen, a substituted or unsubstituted phenyl group, a substituted or unsubstituted dibenzofuranyl group, a substituted or unsubstituted dibenzothiophenyl group, or a substituted or unsubstituted dibenzothiophenyl group, or a substituted or unsubstituted carbazolyl group, and n21 to n24 may each independently be an integer of 1 or 2.

Specifically, L⁷ and L⁸ in Chemical Formula III-A may each independently be a single bond or a substituted or unsubstituted C6 to C12 arylene group.

Specifically, L¹⁰ in Chemical Formula III-A may be a single bond or a substituted or unsubstituted C6 to C12 arylene group.

Specifically, Ar¹ and Ar² in Chemical Formula III-A may each independently be a substituted or unsubstituted phenyl group, a substituted or unsubstituted biphenyl group, a substituted or unsubstituted terphenyl group, a substituted or unsubstituted naphthyl group, a substituted or unsubstituted biphenyl group, or a substituted or unsubstituted naphthyl group, a substituted or unsubstituted anthracenyl group, a substituted or unsubstituted phenanthrenyl group, a substituted or unsubstituted triphenylene group, a substituted or unsubstituted fluorenyl group, a substituted or unsubstituted dibenzofuranyl group, or a substituted or unsubstituted dibenzothiophenyl group.

Specifically, R²⁵, R²⁹, and R³⁰ in Chemical Formula III-B to Chemical Formula III-F may each independently be hydrogen, heavy hydrogen, a substituted or unsubstituted phenyl group, a substituted or unsubstituted triphenylene group, or a substituted or unsubstituted carbazole group.

Specifically, L⁷ and L⁹ in Chemical Formula III-B to Chemical Formula III-F may each independently be a single bond or a substituted or unsubstituted phenylene group.

Specifically, Ar¹ and Ar³ in Chemical Formula III-B to Chemical Formula III-F may each independently be a substituted or unsubstituted phenyl group, a substituted or unsubstituted biphenyl group, a substituted or unsubstituted terphenyl group, a substituted or unsubstituted triphenylene group, a substituted or unsubstituted carbazolyl group, a substituted or unsubstituted dibenzofuranyl group, or a substituted or unsubstituted dibenzothiophenyl group.

For example, R²⁵ to R²⁸ in Chemical Formula III-A may each independently be hydrogen, deuterium, or a substituted or unsubstituted phenyl group.

For example, L⁷ and L⁸ in Chemical Formula III-A may be a single bond or a substituted or unsubstituted phenylene group.

For example, L¹⁰ in Chemical Formula IT-A may be a single bond or a substituted or unsubstituted phenylene group.

For example, Ar¹ and Ar² in Chemical Formula III-A may be a substituted or unsubstituted phenyl group or a substituted or unsubstituted biphenyl group.

For example, R²¹, R²⁹, and R³⁰ in Chemical Formula III-B to Chemical Formula III-F may each independently be hydrogen, deuterium, or a substituted or unsubstituted phenyl group.

For example, L⁷ and L⁹ in Chemical Formula III-B to Chemical Formula III-F may be a single bond or a substituted or unsubstituted phenylene group.

For example, Ar¹ and Ar³ in Chemical Formula III-B to Chemical Formula III-F may be a substituted or unsubstituted phenyl group or a substituted or unsubstituted biphenyl group.

For example, the second compound may be represented by Chemical Formula III-A or Chemical Formula III-F.

As a specific example, Chemical Formula III-A may be represented by any one of Chemical Formula III-A-1 to Chemical Formula III-A-3.

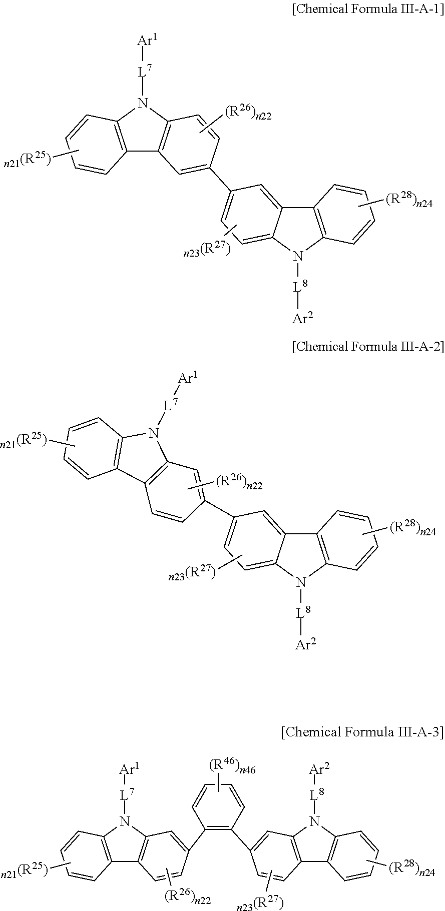

In Chemical Formula III-A-1 to Chemical Formula III-A-3, L⁷, L⁸, Ar¹, Ar², R²⁵ to R²⁸ and n21 to n24 are the same as described above,
R⁴⁶s are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and
n46 is an integer of 1 to 4.

For example, the second compound may be represented by any one of Chemical Formula III-A-1, Chemical Formula III-A-2, and Chemical Formula III-F.

According to a specific embodiment of the present invention, in Chemical Formula III-A-1 and Chemical Formula III-A-2, L⁷ and L⁸ are each independently a single bond or a substituted or unsubstituted phenylene group,
Ar¹ and Ar² are each independently a substituted or unsubstituted phenyl group or a substituted or unsubstituted biphenyl group, and
R²⁵ to R²⁸ may each independently be hydrogen, deuterium or a phenyl group.

For example, the second compound may be one selected from the compounds listed in Group 2.

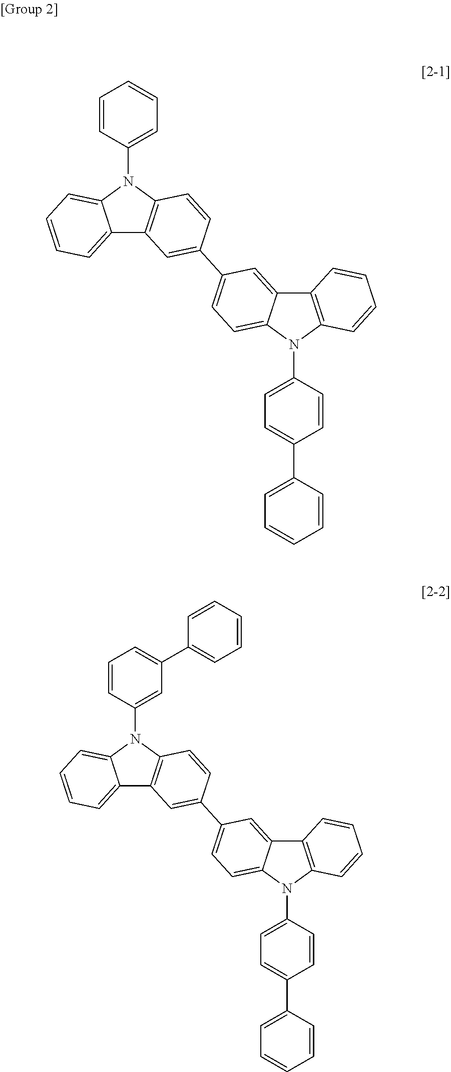 [SMILES: c1ccc(-c2ccc(-n3c4ccccc4c4cc(-c5ccc6c(c5)c5ccccc5n6-c5ccccc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

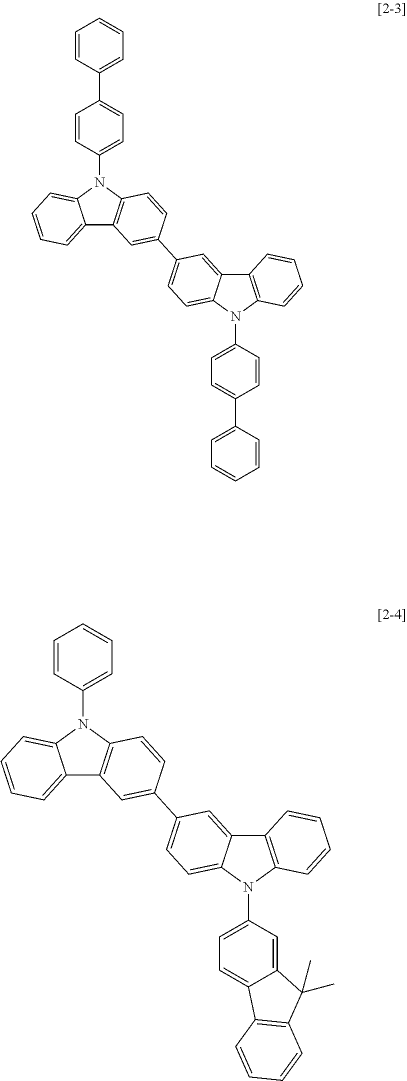 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; CC1(C)c2ccccc2-c2ccc(-n3c4ccccc4c4cc(-c5ccc6c(c5)c5ccccc5n6-c5ccccc5)ccc43)cc21]

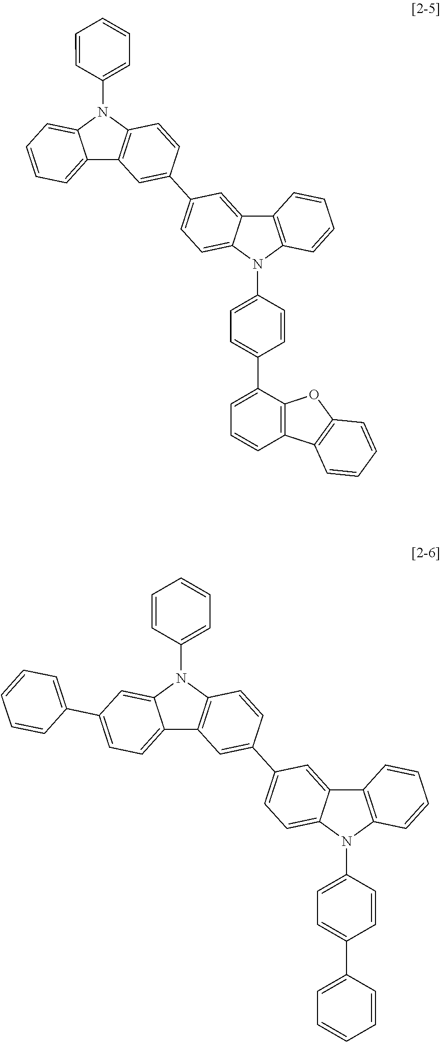 [SMILES: c1ccc(-n2c3ccccc3c3cc(-c4ccc5c(c4)c4ccccc4n5-c4ccc(-c5cccc6c5oc5ccccc56)cc4)ccc32)cc1 ; c1ccc(-c2ccc(-n3c4ccccc4c4cc(-c5ccc6c(c5)c5ccc(-c7ccccc7)cc5n6-c5ccccc5)ccc43)cc2)cc1]

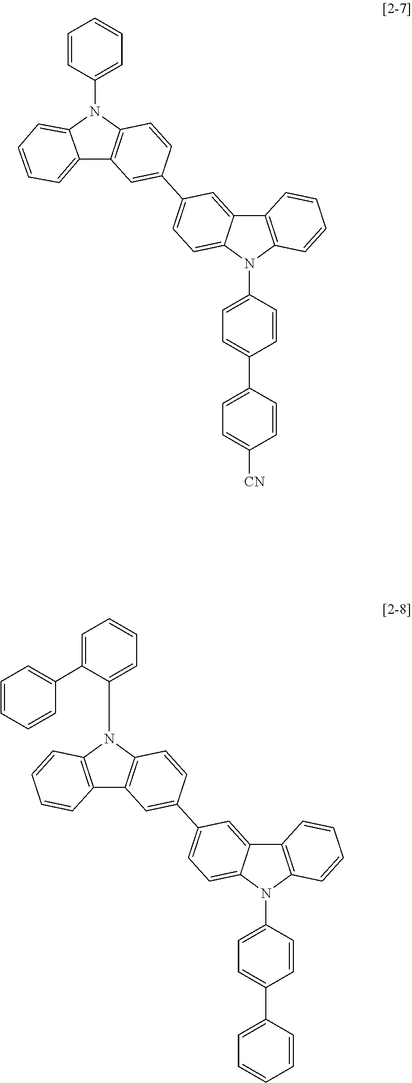

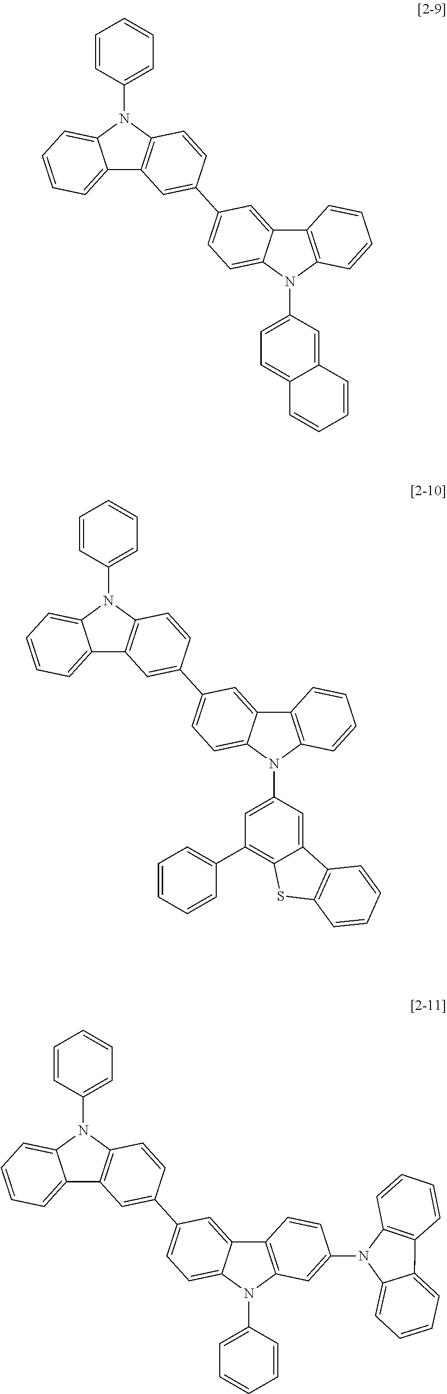 [SMILES: c1ccc(-n2c3ccccc3c3cc(-c4ccc5c(c4)c4ccccc4n5-c4ccc5ccccc5c4)ccc32)cc1 ; c1ccc(-c2cc(-n3c4ccccc4c4cc(-c5ccc6c(c5)c5ccccc5n6-c5ccccc5)ccc43)cc3c2sc2ccccc23)cc1 ; c1ccc(-n2c3ccccc3c3cc(-c4ccc5c(c4)c4ccc(-n6c7ccccc7c7ccccc76)cc4n5-c4ccccc4)ccc32)cc1]

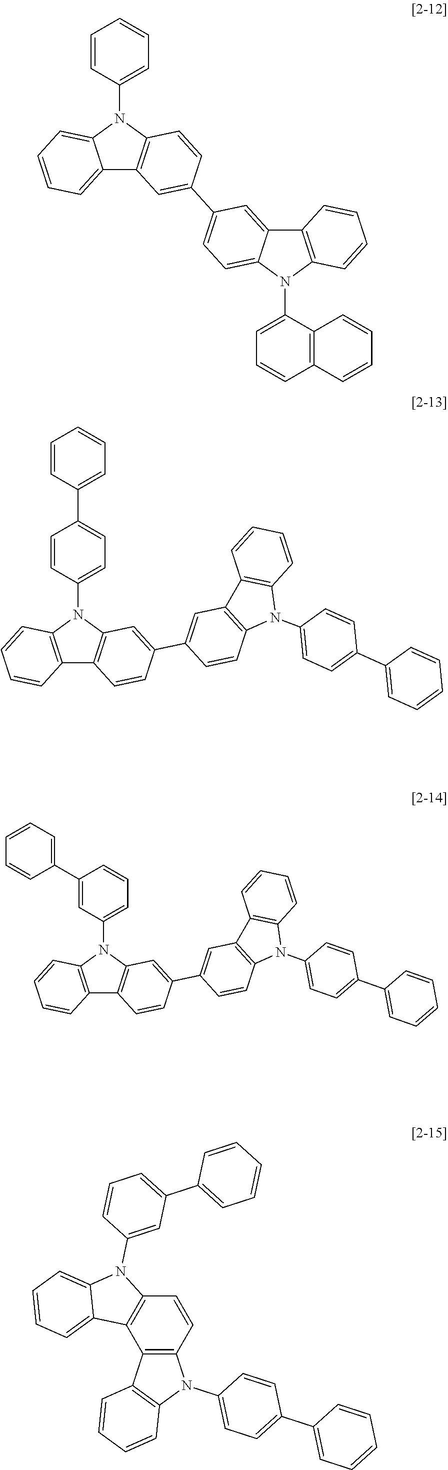 [SMILES: c1ccc(-n2c3ccccc3c3cc(-c4ccc5c(c4)c4ccccc4n5-c4cccc5ccccc45)ccc32)cc1 ; c1ccc(-c2ccc(-n3c4ccccc4c4cc(-c5ccc6c7ccccc7n(-c7ccc(-c8ccccc8)cc7)c6c5)ccc43)cc2)cc1 ; c1ccc(-c2ccc(-n3c4ccccc4c4cc(-c5ccc6c7ccccc7n(-c7cccc(-c8ccccc8)c7)c6c5)ccc43)cc2)cc1 ; c1ccc(-c2ccc(-n3c4ccccc4c4c5c6ccccc6n(-c6cccc(-c7ccccc7)c6)c5ccc43)cc2)cc1]

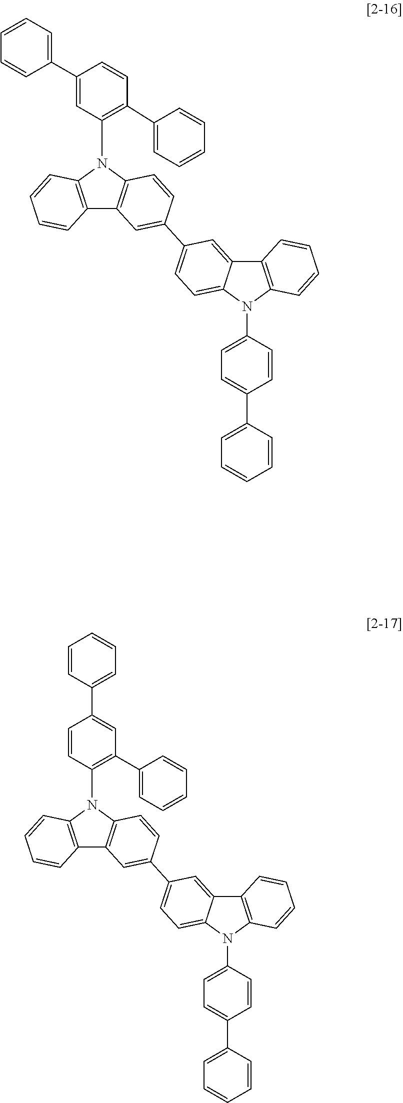 [SMILES: c1ccc(-c2ccc(-n3c4ccccc4c4cc(-c5ccc6c(c5)c5ccccc5n6-c5cc(-c6ccccc6)ccc5-c5ccccc5)ccc43)cc2)cc1 ; c1ccc(-c2ccc(-n3c4ccccc4c4cc(-c5ccc6c(c5)c5ccccc5n6-c5ccc(-c6ccccc6)cc5-c5ccccc5)ccc43)cc2)cc1]

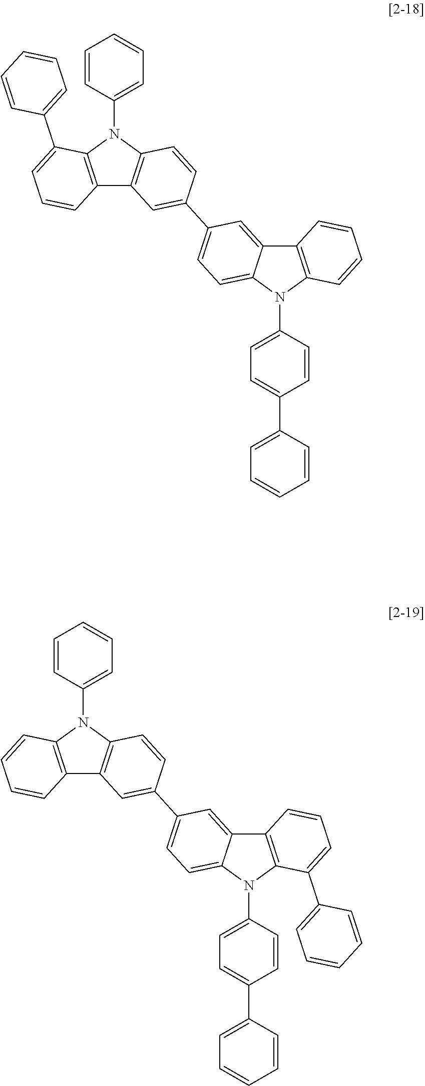 [SMILES: c1ccc(-c2ccc(-n3c4ccccc4c4cc(-c5ccc6c(c5)c5cccc(-c7ccccc7)c5n6-c5ccccc5)ccc43)cc2)cc1 ; c1ccc(-c2ccc(-n3c4ccc(-c5ccc6c(c5)c5ccccc5n6-c5ccccc5)cc4c4cccc(-c5ccccc5)c43)cc2)cc1]

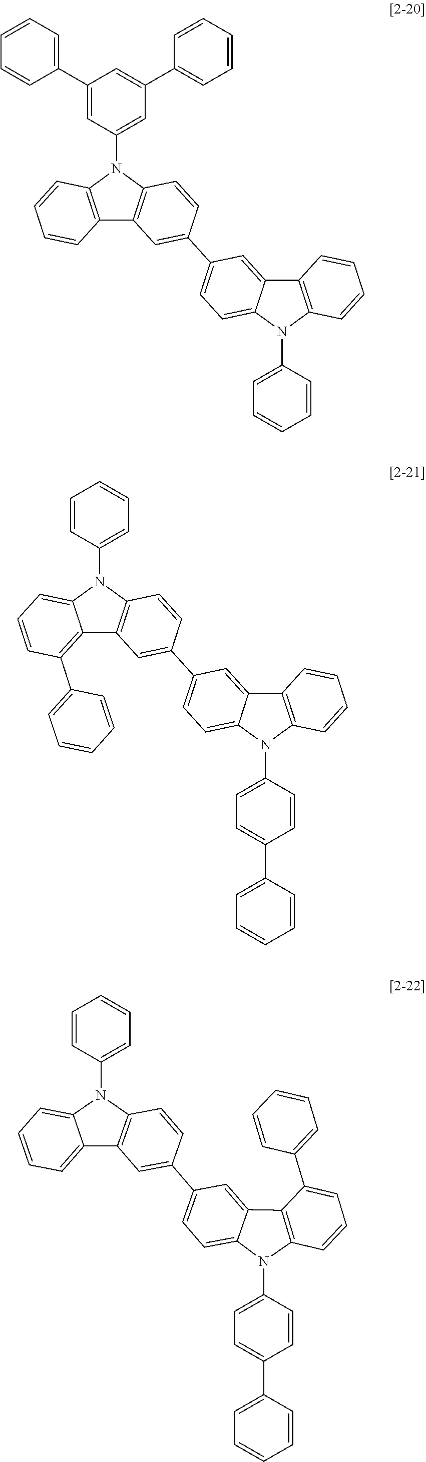

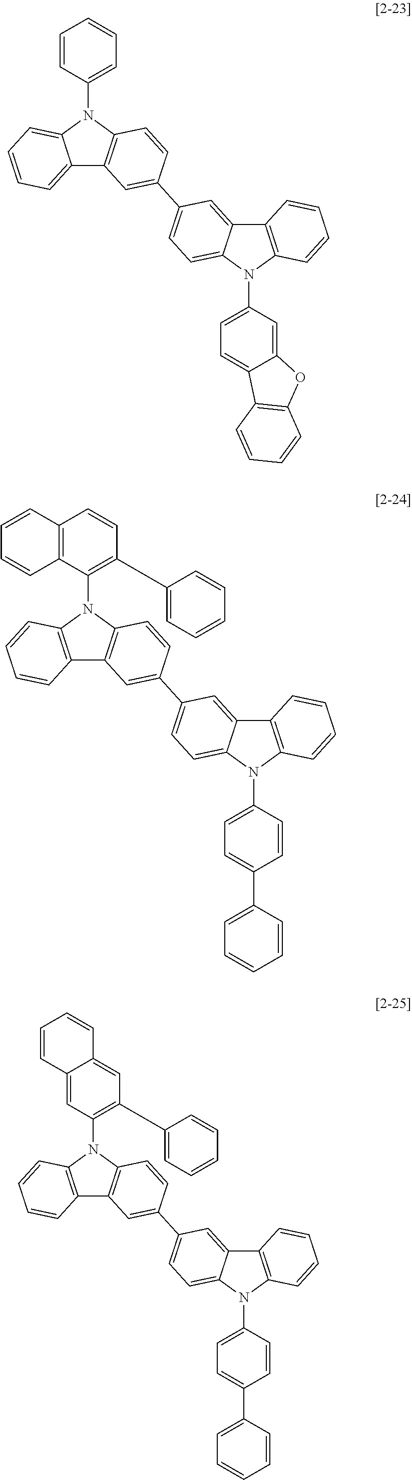 [SMILES: c1ccc(-n2c3ccccc3c3cc(-c4ccc5c(c4)c4ccccc4n5-c4ccc5c(c4)oc4ccccc45)ccc32)cc1 ; c1ccc(-c2ccc(-n3c4ccccc4c4cc(-c5ccc6c(c5)c5ccccc5n6-c5c(-c6ccccc6)ccc6ccccc56)ccc43)cc2)cc1 ; c1ccc(-c2ccc(-n3c4ccccc4c4cc(-c5ccc6c(c5)c5ccccc5n6-c5cc6ccccc6cc5-c5ccccc5)ccc43)cc2)cc1]

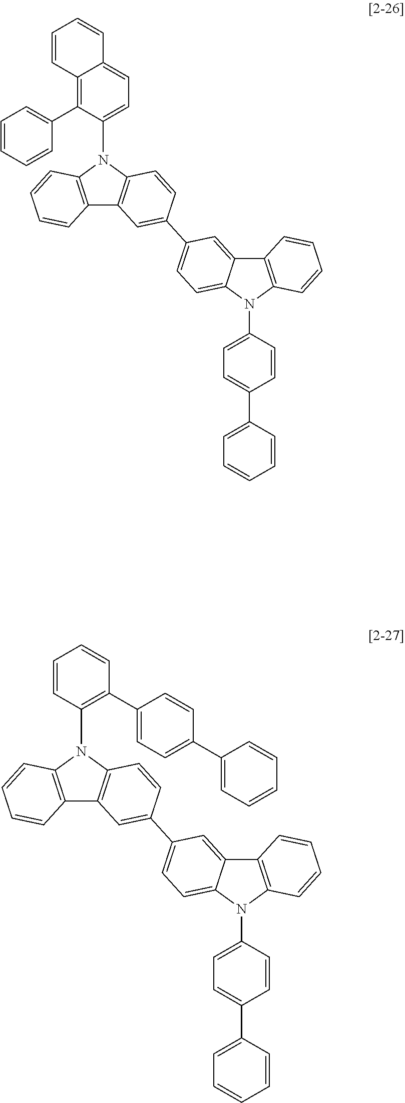 [SMILES: c1ccc(-c2ccc(-n3c4ccccc4c4cc(-c5ccc6c(c5)c5ccccc5n6-c5ccc6ccccc6c5-c5ccccc5)ccc43)cc2)cc1 ; c1ccc(-c2ccc(-c3ccccc3-n3c4ccccc4c4cc(-c5ccc6c(c5)c5ccccc5n6-c5ccc(-c6ccccc6)cc5)ccc43)cc2)cc1]

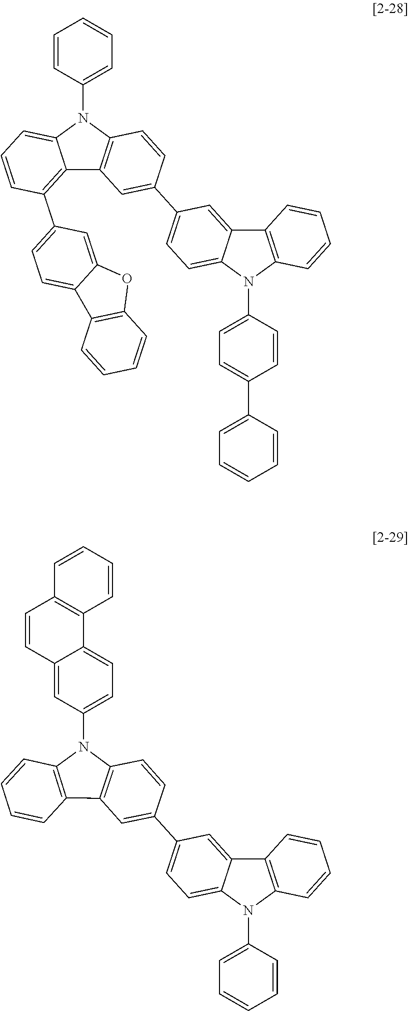 [SMILES: c1ccc(-c2ccc(-n3c4ccccc4c4cc(-c5ccc6c(c5)c5c(-c7ccc8c(c7)oc7ccccc78)cccc5n6-c5ccccc5)ccc43)cc2)cc1 ; c1ccc(-n2c3ccccc3c3cc(-c4ccc5c(c4)c4ccccc4n5-c4ccc5c(ccc6ccccc65)c4)ccc32)cc1]

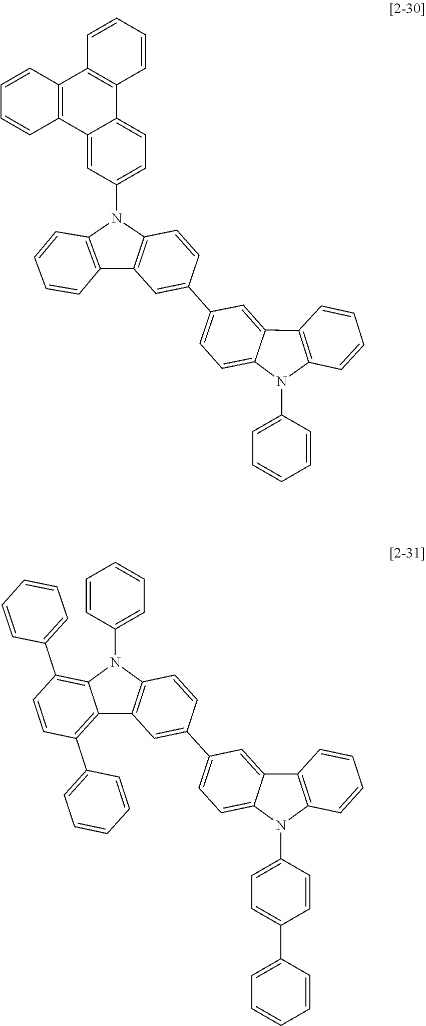

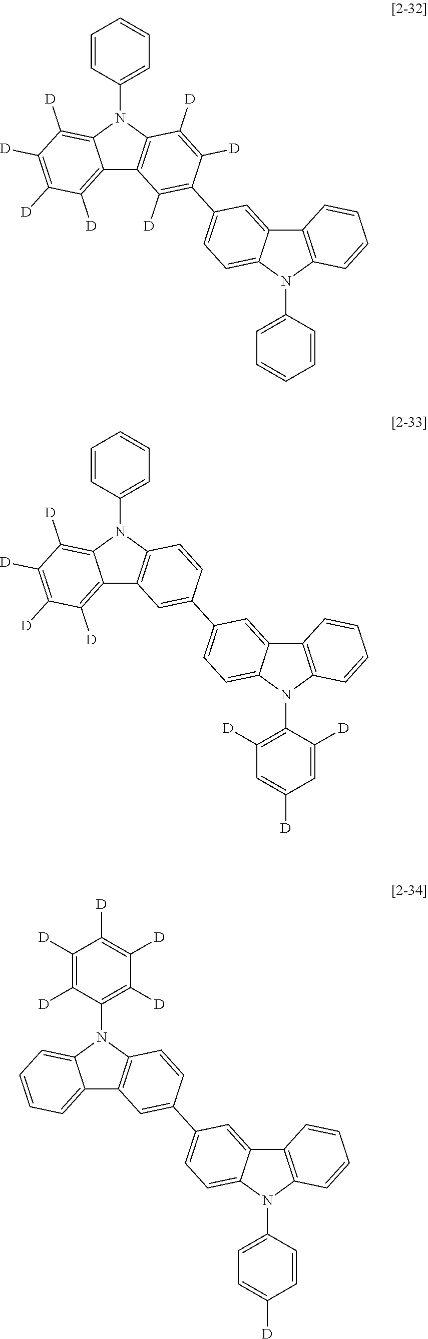 [SMILES: [2H]c1c([2H])c([2H])c2c(c1[2H])c1c([2H])c(-c3ccc4c(c3)c3ccccc3n4-c3ccccc3)c([2H])c([2H])c1n2-c1ccccc1 ; [2H]c1cc([2H])c(-n2c3ccccc3c3cc(-c4ccc5c(c4)c4c([2H])c([2H])c([2H])c([2H])c4n5-c4ccccc4)ccc32)c([2H])c1 ; [2H]c1ccc(-n2c3ccccc3c3cc(-c4ccc5c(c4)c4ccccc4n5-c4c([2H])c([2H])c([2H])c([2H])c4[2H])ccc32)cc1]

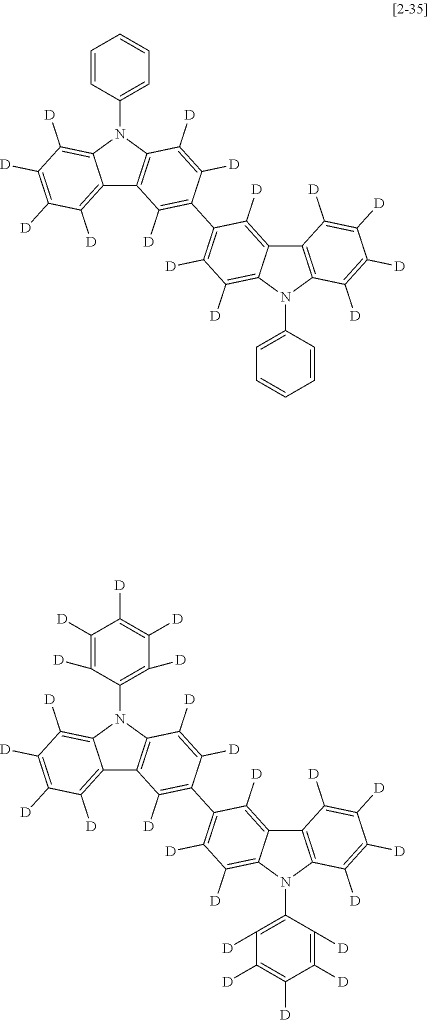 [SMILES: [2H]c1c([2H])c([2H])c2c(c1[2H])c1c([2H])c(-c3c([2H])c([2H])c4c(c3[2H])c3c([2H])c([2H])c([2H])c([2H])c3n4-c3ccccc3)c([2H])c([2H])c1n2-c1ccccc1 ; [2H]c1c([2H])c([2H])c(-n2c3c([2H])c([2H])c([2H])c([2H])c3c3c([2H])c(-c4c([2H])c([2H])c5c(c4[2H])c4c([2H])c([2H])c([2H])c([2H])c4n5-c4c([2H])c([2H])c([2H])c([2H])c4[2H])c([2H])c([2H])c32)c([2H])c1[2H]]

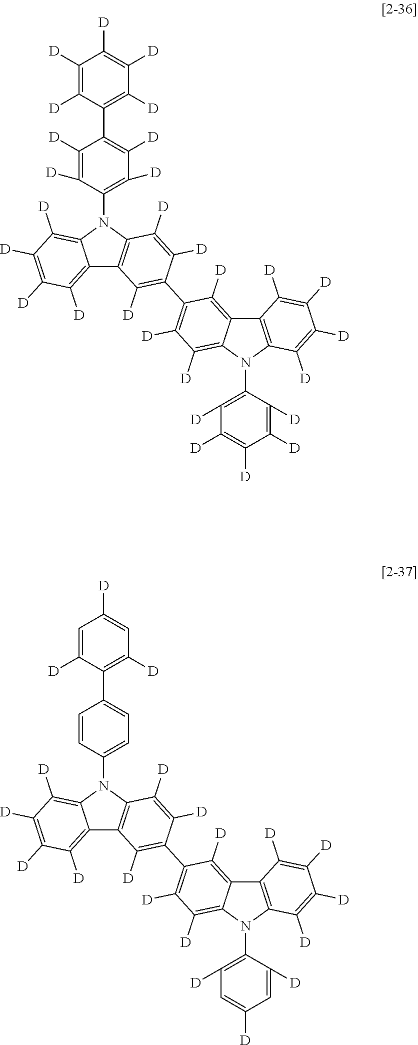 [SMILES: [2H]c1c([2H])c([2H])c(-c2c([2H])c([2H])c(-n3c4c([2H])c([2H])c([2H])c([2H])c4c4c([2H])c(-c5c([2H])c([2H])c6c(c5[2H])c5c([2H])c([2H])c([2H])c([2H])c5n6-c5c([2H])c([2H])c([2H])c([2H])c5[2H])c([2H])c([2H])c43)c([2H])c2[2H])c([2H])c1[2H] ; [2H]c1cc([2H])c(-c2ccc(-n3c4c([2H])c([2H])c([2H])c([2H])c4c4c([2H])c(-c5c([2H])c([2H])c6c(c5[2H])c5c([2H])c([2H])c([2H])c([2H])c5n6-c5c([2H])cc([2H])cc5[2H])c([2H])c([2H])c43)cc2)c([2H])c1]

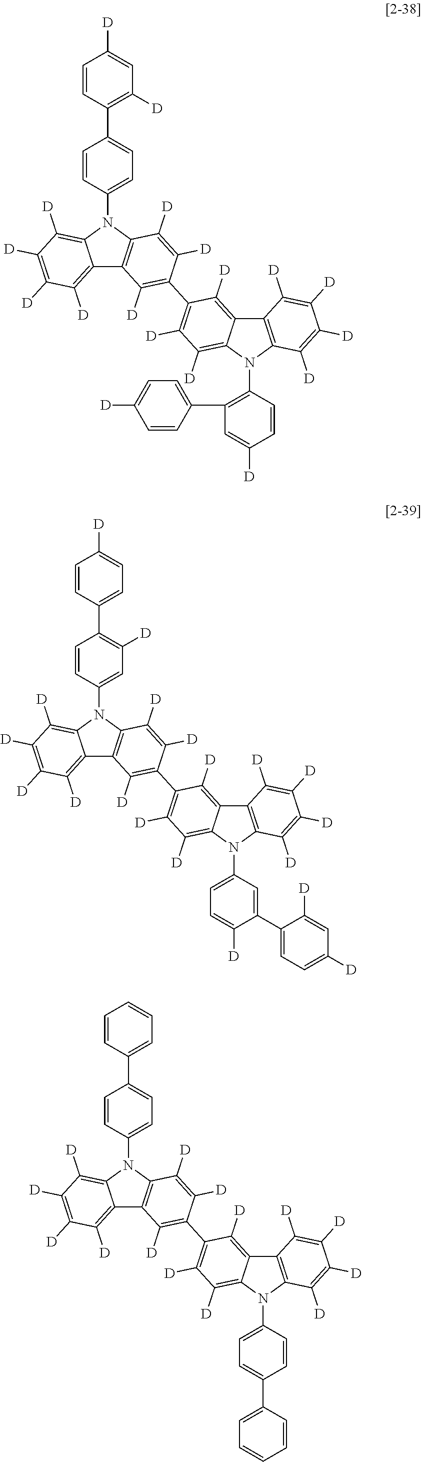

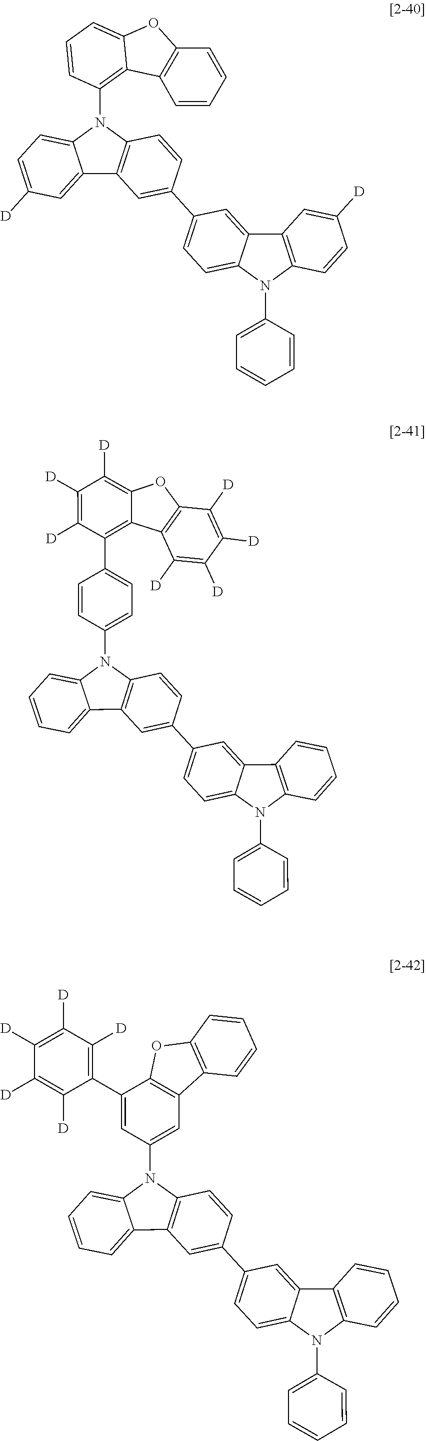 [SMILES: [2H]c1ccc2c(c1)c1cc(-c3ccc4c(c3)c3cc([2H])ccc3n4-c3cccc4oc5ccccc5c34)ccc1n2-c1ccccc1 ; [2H]c1c([2H])c([2H])c2c(oc3c([2H])c([2H])c([2H])c(-c4ccc(-n5c6ccccc6c6cc(-c7ccc8c(c7)c7ccccc7n8-c7ccccc7)ccc65)cc4)c32)c1[2H] ; [2H]c1c([2H])c([2H])c(-c2cc(-n3c4ccccc4c4cc(-c5ccc6c(c5)c5ccccc5n6-c5ccccc5)ccc43)cc3c2oc2ccccc23)c([2H])c1[2H]]

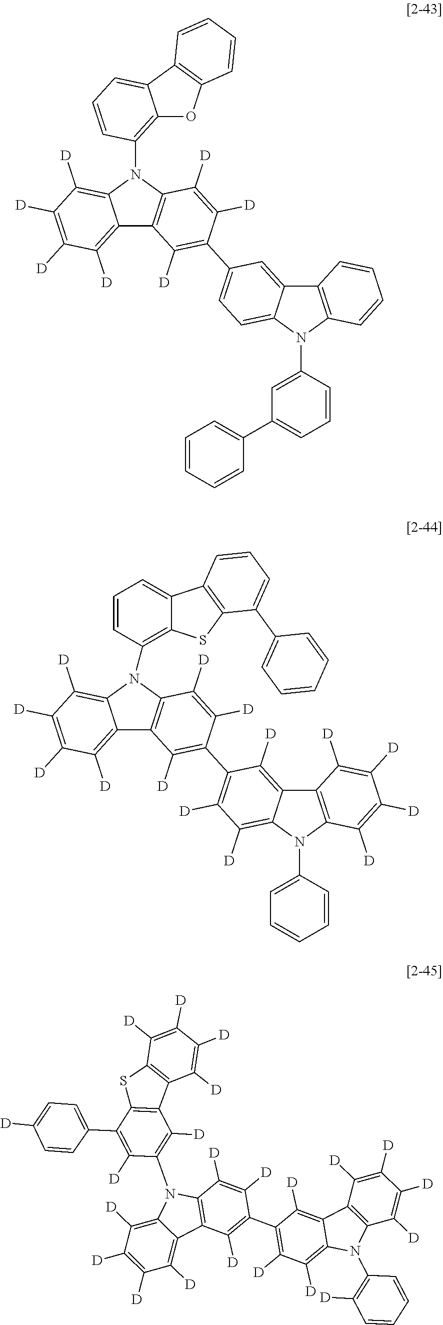

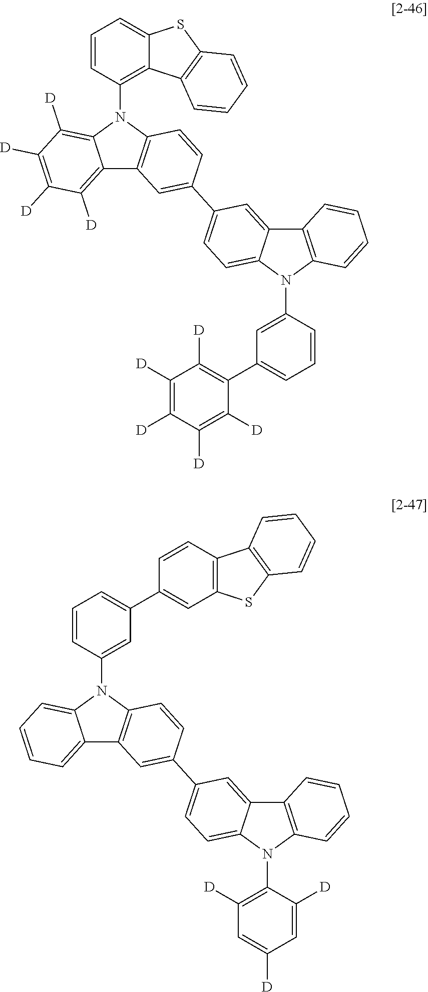 [SMILES: [2H]c1c([2H])c([2H])c(-c2cccc(-n3c4ccccc4c4cc(-c5ccc6c(c5)c5c([2H])c([2H])c([2H])c([2H])c5n6-c5cccc6sc7ccccc7c56)ccc43)c2)c([2H])c1[2H] ; [2H]c1cc([2H])c(-n2c3ccccc3c3cc(-c4ccc5c(c4)c4ccccc4n5-c4cccc(-c5ccc6c(c5)sc5ccccc56)c4)ccc32)c([2H])c1]

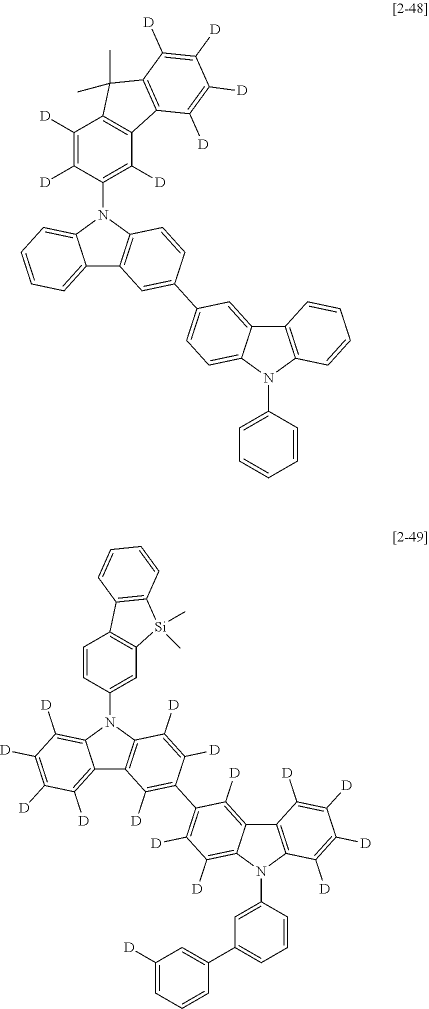 [SMILES: [2H]c1c([2H])c([2H])c2c(c1[2H])-c1c([2H])c(-n3c4ccccc4c4cc(-c5ccc6c(c5)c5ccccc5n6-c5ccccc5)ccc43)c([2H])c([2H])c1C2(C)C ; [2H]c1cccc(-c2cccc(-n3c4c([2H])c([2H])c([2H])c([2H])c4c4c([2H])c(-c5c([2H])c([2H])c6c(c5[2H])c5c([2H])c([2H])c([2H])c([2H])c5n6-c5ccc6c(c5)[Si](C)(C)c5ccccc5-6)c([2H])c([2H])c43)c2)c1]

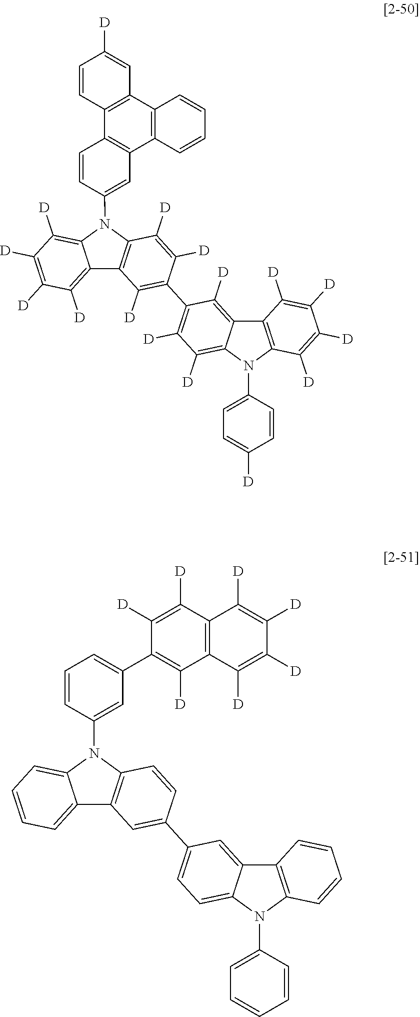 [SMILES: [2H]c1ccc(-n2c3c([2H])c([2H])c([2H])c([2H])c3c3c([2H])c(-c4c([2H])c([2H])c5c(c4[2H])c4c([2H])c([2H])c([2H])c([2H])c4n5-c4ccc5c6ccc([2H])cc6c6ccccc6c5c4)c([2H])c([2H])c32)cc1 ; [2H]c1c([2H])c([2H])c2c([2H])c(-c3cccc(-n4c5ccccc5c5cc(-c6ccc7c(c6)c6ccccc6n7-c6ccccc6)ccc54)c3)c([2H])c([2H])c2c1[2H]]

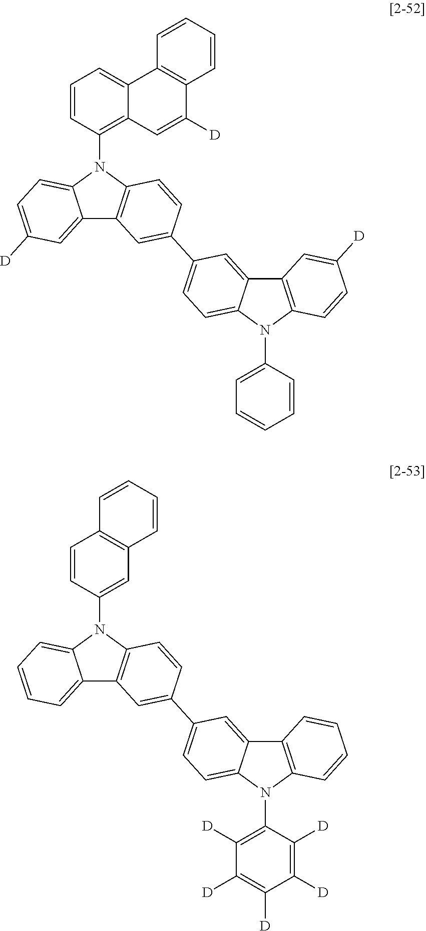 [SMILES: [2H]c1ccc2c(c1)c1cc(-c3ccc4c(c3)c3cc([2H])ccc3n4-c3cccc4c3cc([2H])c3ccccc34)ccc1n2-c1ccccc1 ; [2H]c1c([2H])c([2H])c(-n2c3ccccc3c3cc(-c4ccc5c(c4)c4ccccc4n5-c4ccc5ccccc5c4)ccc32)c([2H])c1[2H]]

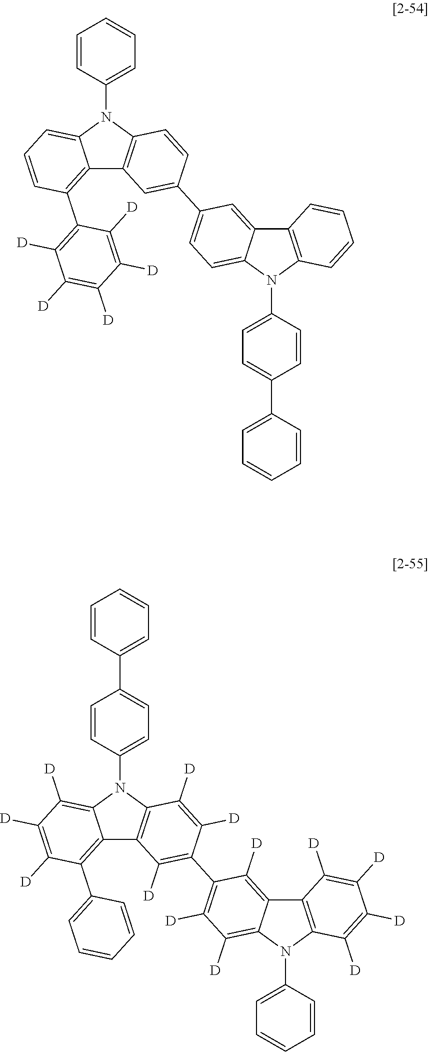 [SMILES: [2H]c1c([2H])c([2H])c(-c2cccc3c2c2cc(-c4ccc5c(c4)c4ccccc4n5-c4ccc(-c5ccccc5)cc4)ccc2n3-c2ccccc2)c([2H])c1[2H] ; [2H]c1c([2H])c([2H])c2c(c1[2H])c1c([2H])c(-c3c([2H])c([2H])c4c(c3[2H])c3c(-c5ccccc5)c([2H])c([2H])c([2H])c3n4-c3ccc(-c4ccccc4)cc3)c([2H])c([2H])c1n2-c1ccccc1]

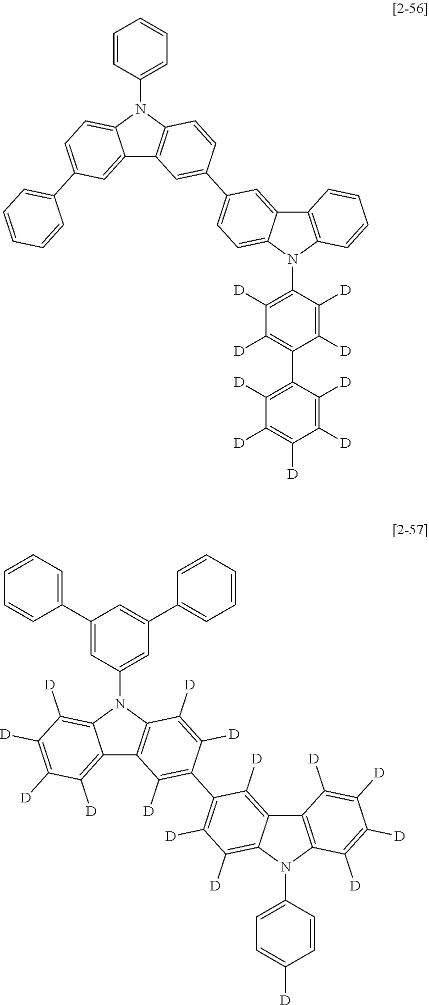 [SMILES: [2H]c1c([2H])c([2H])c(-c2c([2H])c([2H])c(-n3c4ccccc4c4cc(-c5ccc6c(c5)c5cc(-c7ccccc7)ccc5n6-c5ccccc5)ccc43)c([2H])c2[2H])c([2H])c1[2H] ; [2H]c1ccc(-n2c3c([2H])c([2H])c([2H])c([2H])c3c3c([2H])c(-c4c([2H])c([2H])c5c(c4[2H])c4c([2H])c([2H])c([2H])c([2H])c4n5-c4cc(-c5ccccc5)cc(-c5ccccc5)c4)c([2H])c([2H])c32)cc1]

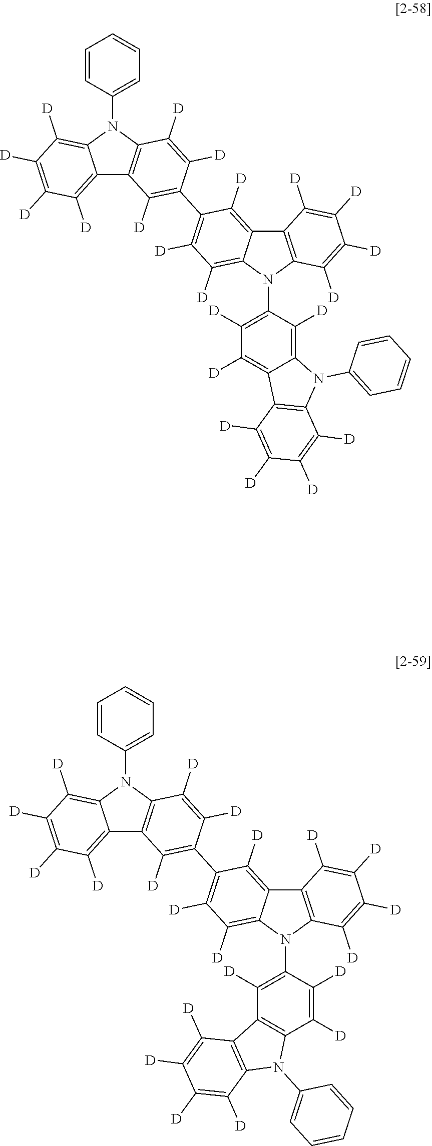 [SMILES: [2H]c1c([2H])c([2H])c2c(c1[2H])c1c([2H])c(-c3c([2H])c([2H])c4c(c3[2H])c3c([2H])c([2H])c([2H])c([2H])c3n4-c3c([2H])c([2H])c4c5c([2H])c([2H])c([2H])c([2H])c5n(-c5ccccc5)c4c3[2H])c([2H])c([2H])c1n2-c1ccccc1 ; [2H]c1c([2H])c([2H])c2c(c1[2H])c1c([2H])c(-c3c([2H])c([2H])c4c(c3[2H])c3c([2H])c([2H])c([2H])c([2H])c3n4-c3c([2H])c([2H])c4c(c3[2H])c3c([2H])c([2H])c([2H])c([2H])c3n4-c3ccccc3)c([2H])c([2H])c1n2-c1ccccc1]

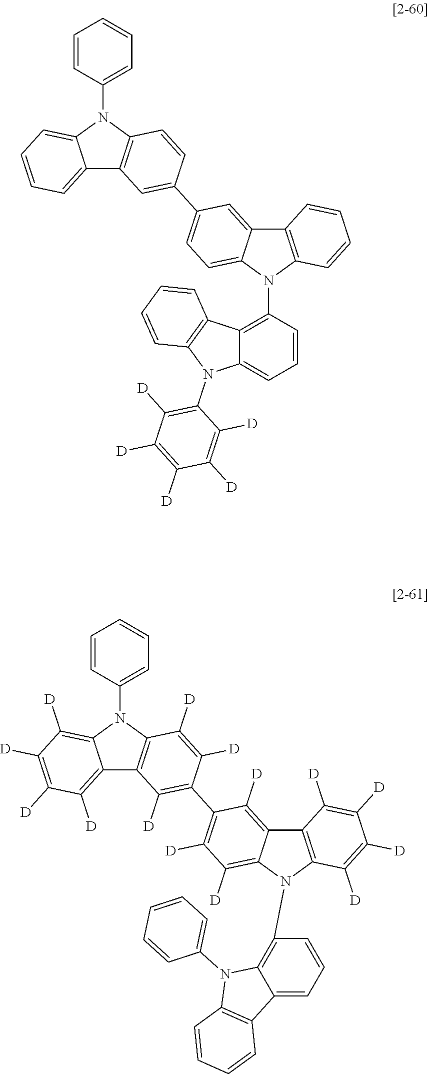 [SMILES: [2H]c1c([2H])c([2H])c(-n2c3ccccc3c3c(-n4c5ccccc5c5cc(-c6ccc7c(c6)c6ccccc6n7-c6ccccc6)ccc54)cccc32)c([2H])c1[2H] ; [2H]c1c([2H])c([2H])c2c(c1[2H])c1c([2H])c(-c3c([2H])c([2H])c4c(c3[2H])c3c([2H])c([2H])c([2H])c([2H])c3n4-c3cccc4c5ccccc5n(-c5ccccc5)c34)c([2H])c([2H])c1n2-c1ccccc1]

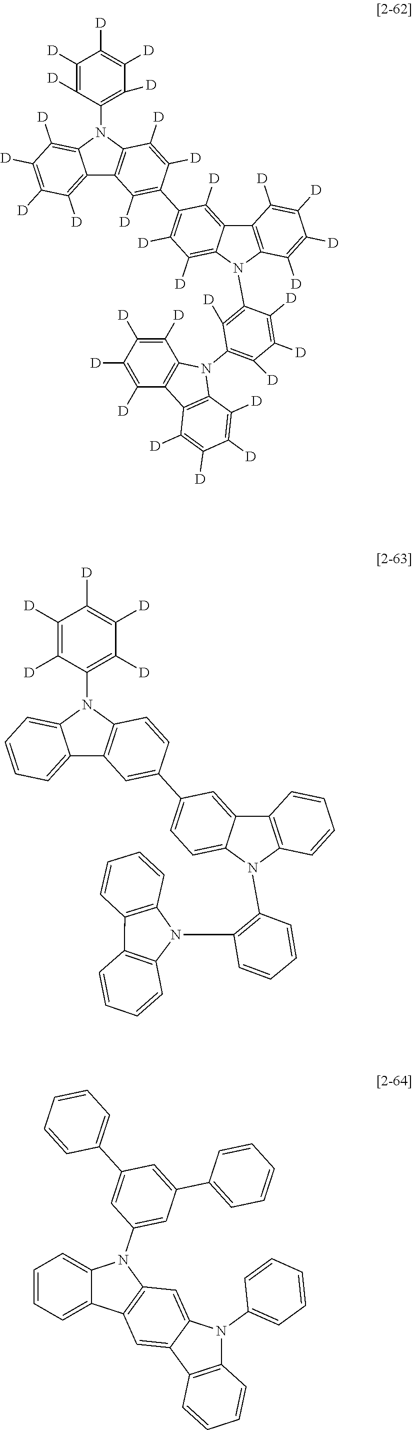 [SMILES: [2H]c1c([2H])c([2H])c(-n2c3c([2H])c([2H])c([2H])c([2H])c3c3c([2H])c(-c4c([2H])c([2H])c5c(c4[2H])c4c([2H])c([2H])c([2H])c([2H])c4n5-c4c([2H])c([2H])c([2H])c(-n5c6c([2H])c([2H])c([2H])c([2H])c6c6c([2H])c([2H])c([2H])c([2H])c65)c4[2H])c([2H])c([2H])c32)c([2H])c1[2H] ; [2H]c1c([2H])c([2H])c(-n2c3ccccc3c3cc(-c4ccc5c(c4)c4ccccc4n5-c4ccccc4-n4c5ccccc5c5ccccc54)ccc32)c([2H])c1[2H] ; c1ccc(-c2cc(-c3ccccc3)cc(-n3c4ccccc4c4cc5c6ccccc6n(-c6ccccc6)c5cc43)c2)cc1]

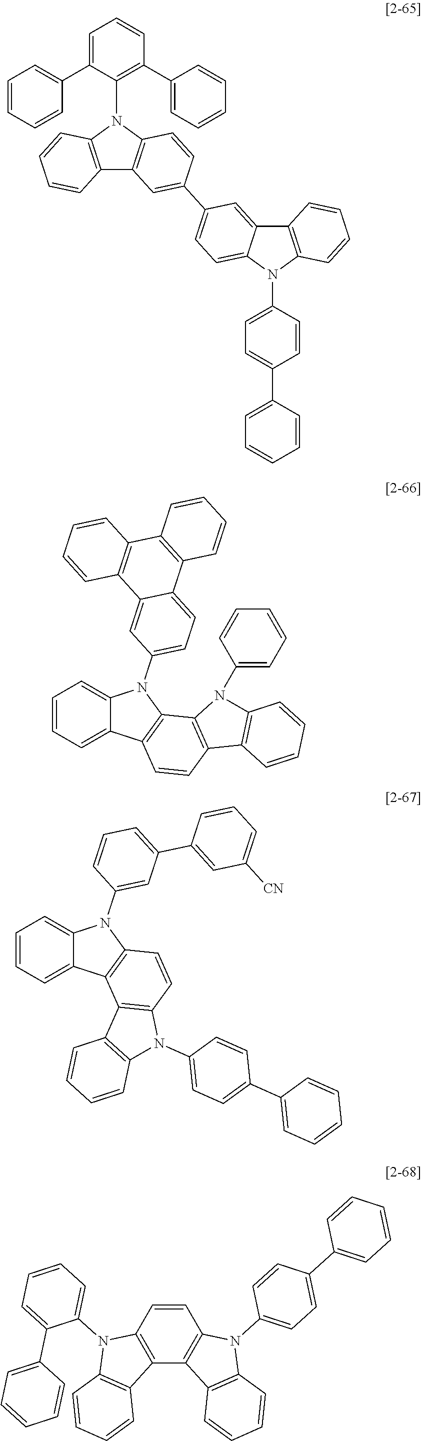

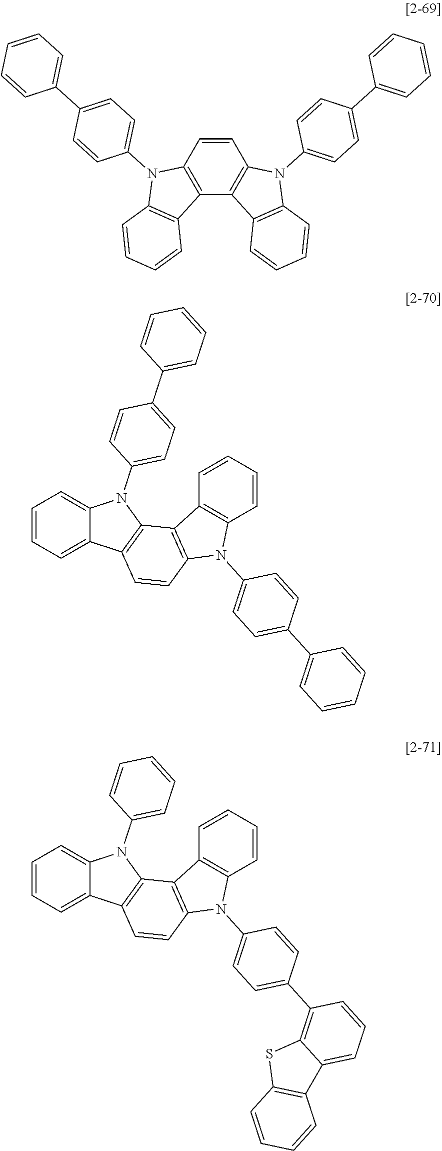

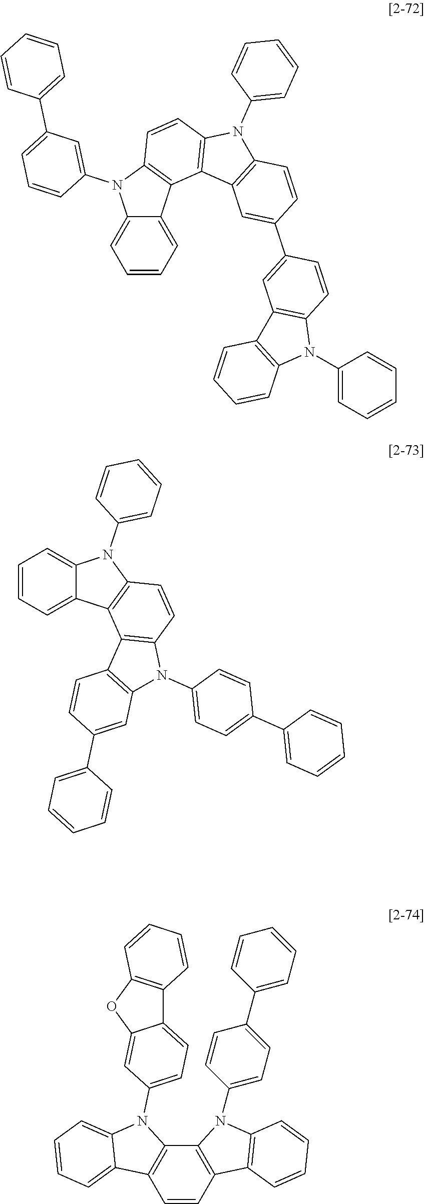 [SMILES: c1ccc(-c2cccc(-n3c4ccccc4c4c5c6cc(-c7ccc8c(c7)c7ccccc7n8-c7ccccc7)ccc6n(-c6ccccc6)c5ccc43)c2)cc1 ; c1ccc(-c2ccc(-n3c4cc(-c5ccccc5)ccc4c4c5c6ccccc6n(-c6ccccc6)c5ccc43)cc2)cc1 ; c1ccc(-c2ccc(-n3c4ccccc4c4ccc5c6ccccc6n(-c6ccc7c(c6)oc6ccccc67)c5c43)cc2)cc1]

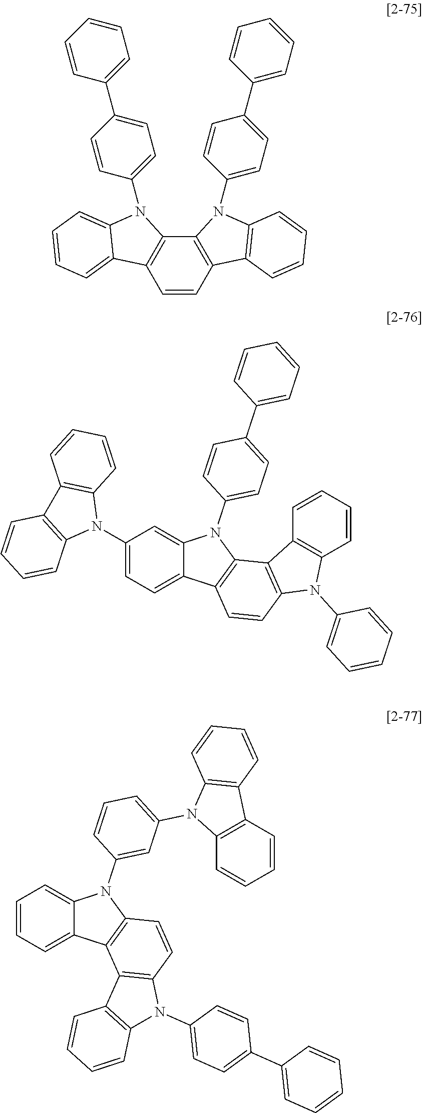 [SMILES: c1ccc(-c2ccc(-n3c4ccccc4c4ccc5c6ccccc6n(-c6ccc(-c7ccccc7)cc6)c5c43)cc2)cc1 ; c1ccc(-c2ccc(-n3c4cc(-n5c6ccccc6c6ccccc65)ccc4c4ccc5c(c6ccccc6n5-c5ccccc5)c43)cc2)cc1 ; c1ccc(-c2ccc(-n3c4ccccc4c4c5c6ccccc6n(-c6cccc(-n7c8ccccc8c8ccccc87)c6)c5ccc43)cc2)cc1]

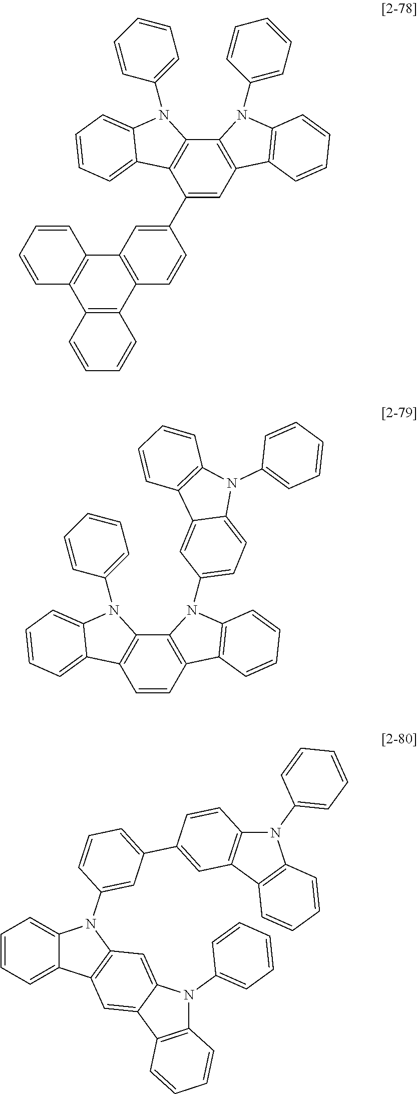 [SMILES: c1ccc(-n2c3ccccc3c3cc(-c4ccc5c6ccccc6c6ccccc6c5c4)c4c5ccccc5n(-c5ccccc5)c4c32)cc1 ; c1ccc(-n2c3ccccc3c3cc(-n4c5ccccc5c5ccc6c7ccccc7n(-c7ccccc7)c6c54)ccc32)cc1 ; c1ccc(-n2c3ccccc3c3cc(-c4cccc(-n5c6ccccc6c6cc7c8ccccc8n(-c8ccccc8)c7cc65)c4)ccc32)cc1]

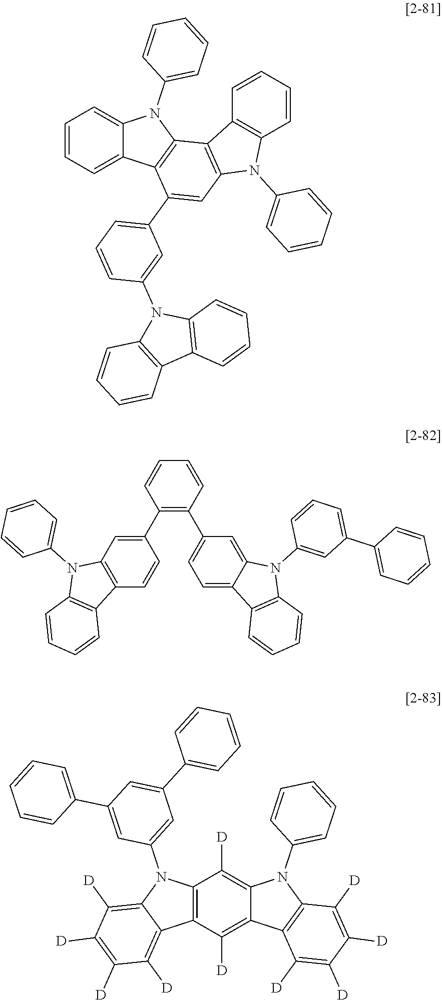 [SMILES: c1ccc(-n2c3ccccc3c3c2cc(-c2cccc(-n4c5ccccc5c5ccccc54)c2)c2c4ccccc4n(-c4ccccc4)c23)cc1 ; c1ccc(-c2cccc(-n3c4ccccc4c4ccc(-c5ccccc5-c5ccc6c7ccccc7n(-c7ccccc7)c6c5)cc43)c2)cc1 ; [2H]c1c([2H])c([2H])c2c(c1[2H])c1c([2H])c3c4c([2H])c([2H])c([2H])c([2H])c4n(-c4cc(-c5ccccc5)cc(-c5ccccc5)c4)c3c([2H])c1n2-c1ccccc1]

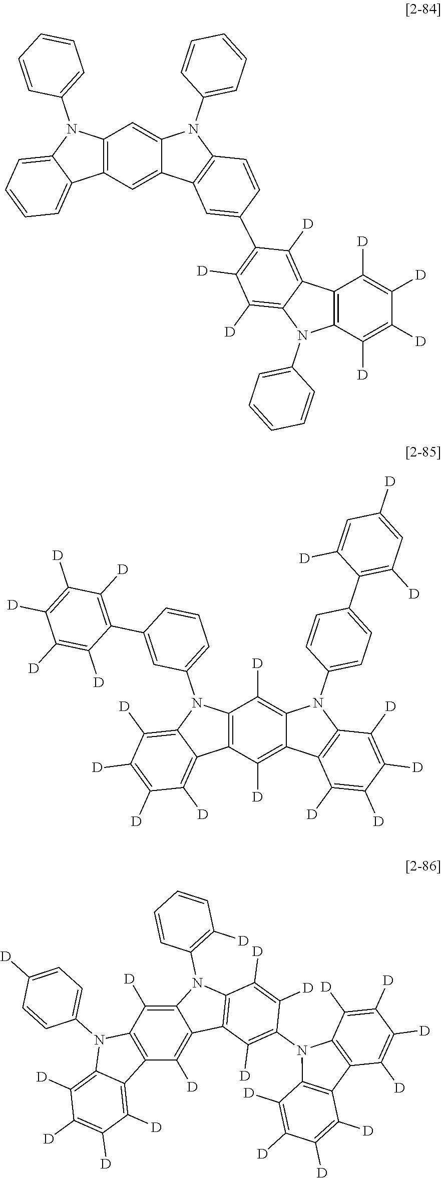 [SMILES: [2H]c1c([2H])c([2H])c2c(c1[2H])c1c([2H])c(-c3ccc4c(c3)c3cc5c6ccccc6n(-c6ccccc6)c5cc3n4-c3ccccc3)c([2H])c([2H])c1n2-c1ccccc1 ; [2H]c1cc([2H])c(-c2ccc(-n3c4c([2H])c([2H])c([2H])c([2H])c4c4c([2H])c5c6c([2H])c([2H])c([2H])c([2H])c6n(-c6cccc(-c7c([2H])c([2H])c([2H])c([2H])c7[2H])c6)c5c([2H])c43)cc2)c([2H])c1 ; [2H]c1ccc(-n2c3c([2H])c([2H])c([2H])c([2H])c3c3c([2H])c4c5c([2H])c(-n6c7c([2H])c([2H])c([2H])c([2H])c7c7c([2H])c([2H])c([2H])c([2H])c76)c([2H])c([2H])c5n(-c5ccccc5[2H])c4c([2H])c32)cc1]

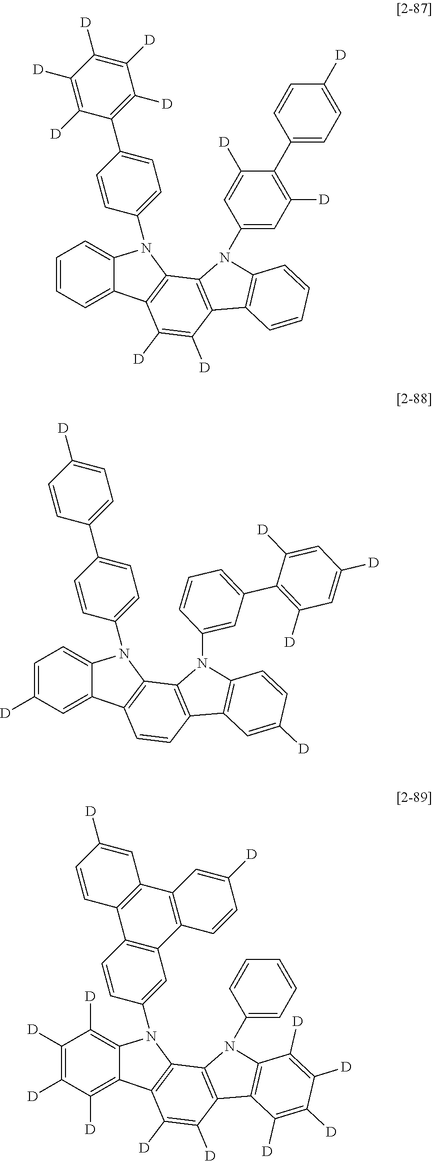 [SMILES: [2H]c1ccc(-c2c([2H])cc(-n3c4ccccc4c4c([2H])c([2H])c5c6ccccc6n(-c6ccc(-c7c([2H])c([2H])c([2H])c([2H])c7[2H])cc6)c5c43)cc2[2H])cc1 ; [2H]c1ccc(-c2ccc(-n3c4ccc([2H])cc4c4ccc5c6cc([2H])ccc6n(-c6cccc(-c7c([2H])cc([2H])cc7[2H])c6)c5c43)cc2)cc1 ; [2H]c1ccc2c3ccc(-n4c5c([2H])c([2H])c([2H])c([2H])c5c5c([2H])c([2H])c6c7c([2H])c([2H])c([2H])c([2H])c7n(-c7ccccc7)c6c54)cc3c3ccc([2H])cc3c2c1]

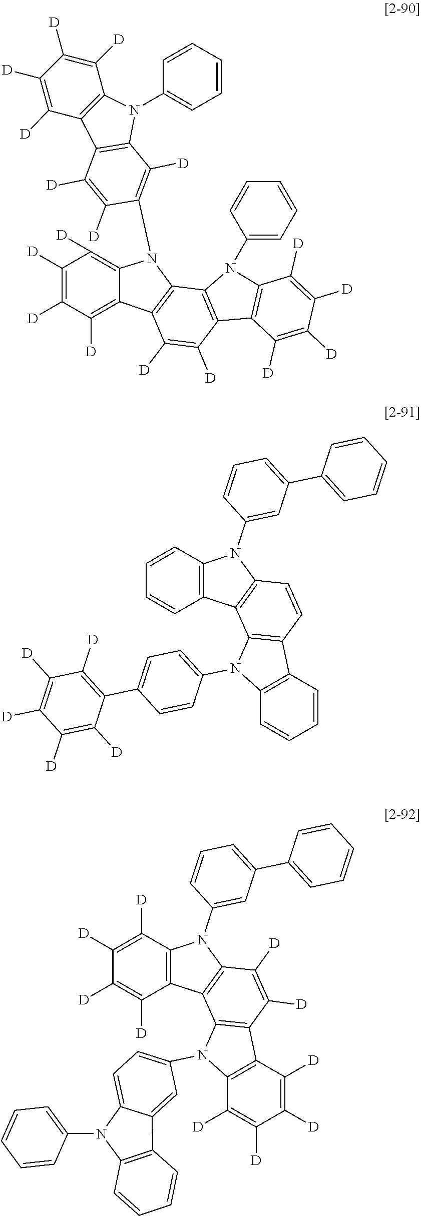 [SMILES: [2H]c1c([2H])c([2H])c2c(c1[2H])c1c([2H])c([2H])c(-n3c4c([2H])c([2H])c([2H])c([2H])c4c4c([2H])c([2H])c5c6c([2H])c([2H])c([2H])c([2H])c6n(-c6ccccc6)c5c43)c([2H])c1n2-c1ccccc1 ; [2H]c1c([2H])c([2H])c(-c2ccc(-n3c4ccccc4c4ccc5c(c6ccccc6n5-c5cccc(-c6ccccc6)c5)c43)cc2)c([2H])c1[2H] ; [2H]c1c([2H])c([2H])c2c(c1[2H])c1c(c([2H])c([2H])c3c4c([2H])c([2H])c([2H])c([2H])c4n(-c4ccc5c(c4)c4ccccc4n5-c4ccccc4)c31)n2-c1cccc(-c2ccccc2)c1]

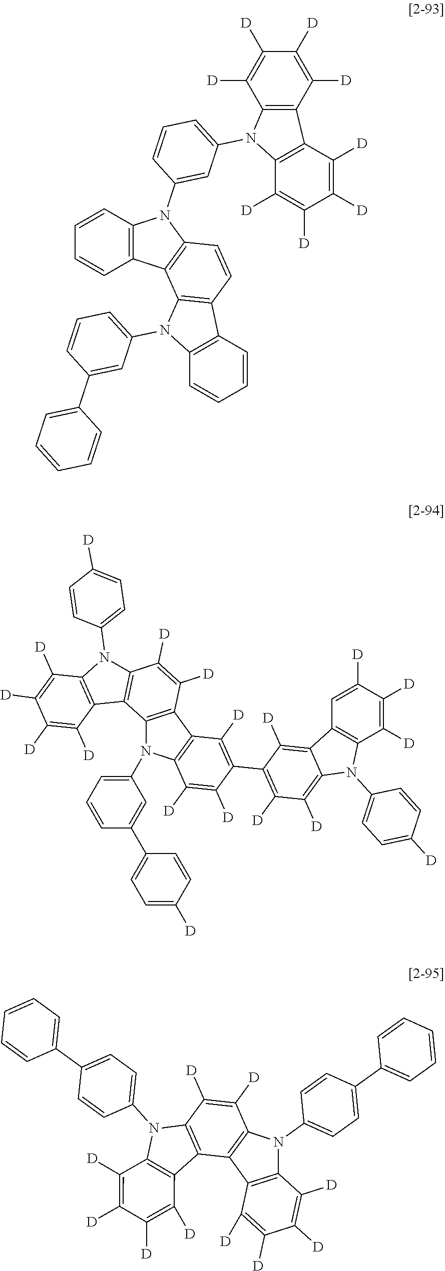 [SMILES: [2H]c1c([2H])c([2H])c2c(c1[2H])c1c([2H])c([2H])c([2H])c([2H])c1n2-c1cccc(-n2c3ccccc3c3c2ccc2c4ccccc4n(-c4cccc(-c5ccccc5)c4)c23)c1 ; [2H]c1ccc(-c2cccc(-n3c4c([2H])c([2H])c(-c5c([2H])c([2H])c6c(c5[2H])c5cc([2H])c([2H])c([2H])c5n6-c5ccc([2H])cc5)c([2H])c4c4c([2H])c([2H])c5c(c6c([2H])c([2H])c([2H])c([2H])c6n5-c5ccc([2H])cc5)c43)c2)cc1 ; [2H]c1c([2H])c([2H])c2c(c1[2H])c1c3c4c([2H])c([2H])c([2H])c([2H])c4n(-c4ccc(-c5ccccc5)cc4)c3c([2H])c([2H])c1n2-c1ccc(-c2ccccc2)cc1]

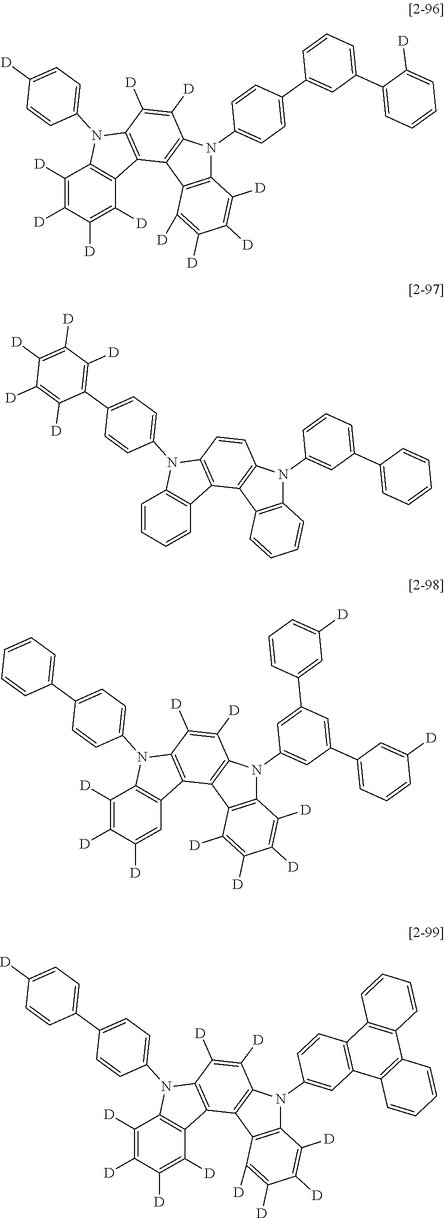

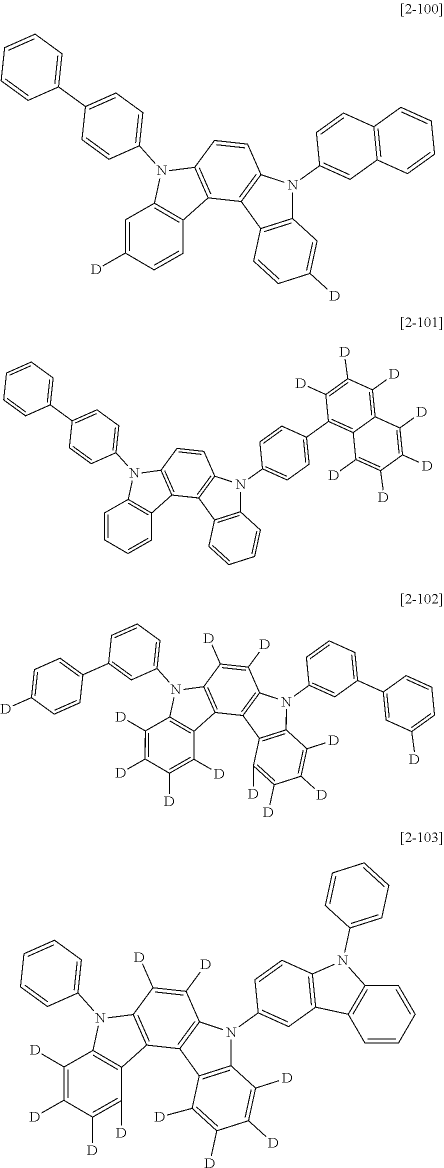 [SMILES: [2H]c1ccc2c3c4c5ccc([2H])cc5n(-c5ccc6ccccc6c5)c4ccc3n(-c3ccc(-c4ccccc4)cc3)c2c1 ; [2H]c1c([2H])c([2H])c2c(-c3ccc(-n4c5ccccc5c5c6c7ccccc7n(-c7ccc(-c8ccccc8)cc7)c6ccc54)cc3)c([2H])c([2H])c([2H])c2c1[2H] ; [2H]c1ccc(-c2cccc(-n3c4c([2H])c([2H])c([2H])c([2H])c4c4c5c6c([2H])c([2H])c([2H])c([2H])c6n(-c6cccc(-c7cccc([2H])c7)c6)c5c([2H])c([2H])c43)c2)cc1 ; [2H]c1c([2H])c([2H])c2c(c1[2H])c1c3c4c([2H])c([2H])c([2H])c([2H])c4n(-c4ccc5c(c4)c4ccccc4n5-c4ccccc4)c3c([2H])c([2H])c1n2-c1ccccc1]

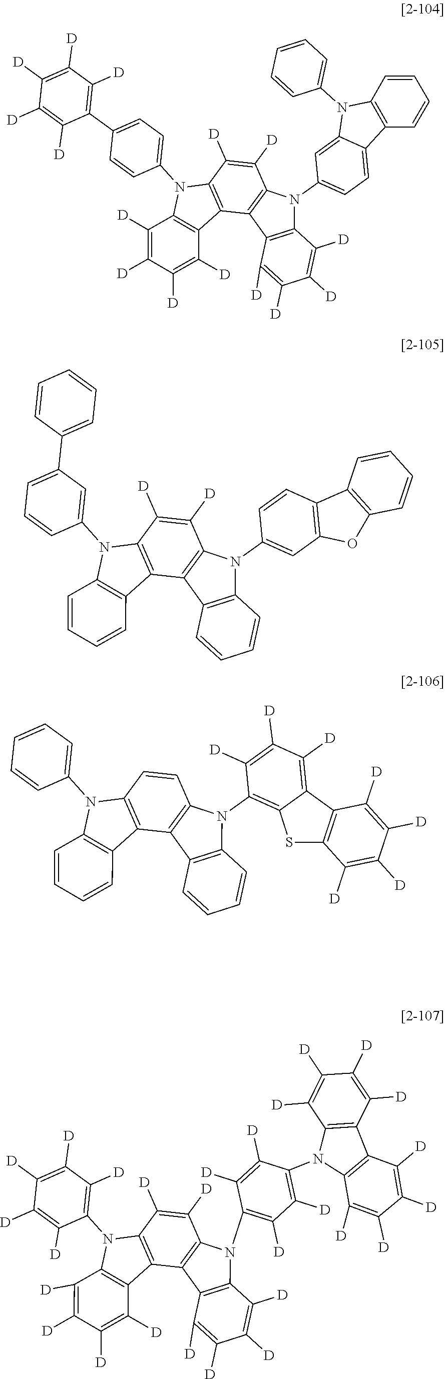

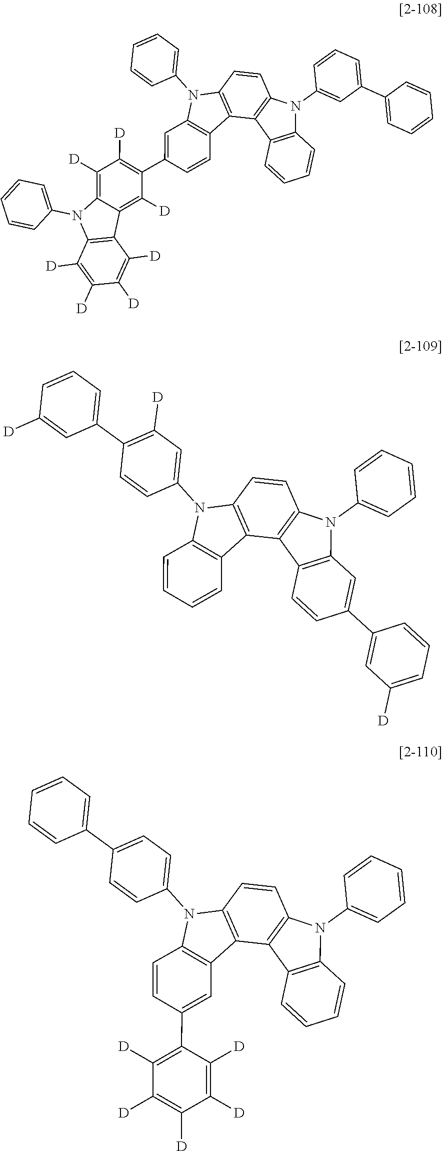 [SMILES: [2H]c1c([2H])c([2H])c2c(c1[2H])c1c([2H])c(-c3ccc4c5c6c7ccccc7n(-c7cccc(-c8ccccc8)c7)c6ccc5n(-c5ccccc5)c4c3)c([2H])c([2H])c1n2-c1ccccc1 ; [2H]c1cccc(-c2ccc3c4c5c6ccccc6n(-c6ccc(-c7cccc([2H])c7)c([2H])c6)c5ccc4n(-c4ccccc4)c3c2)c1 ; [2H]c1c([2H])c([2H])c(-c2ccc3c(c2)c2c4c5ccccc5n(-c5ccccc5)c4ccc2n3-c2ccc(-c3ccccc3)cc2)c([2H])c1[2H]]

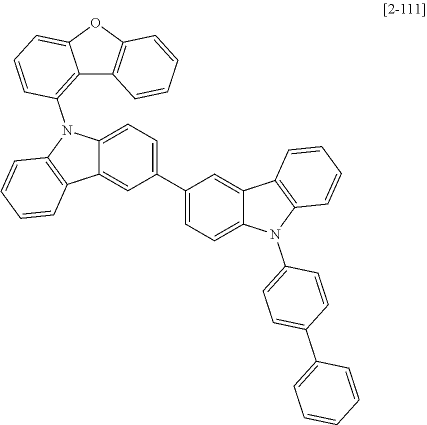 [SMILES: c1ccc(-c2ccc(-n3c4ccccc4c4cc(-c5ccc6c(c5)c5ccccc5n6-c5cccc6oc7ccccc7c56)ccc43)cc2)cc1]

The third compound having the buffer characteristics has a structure in which dibenzofuran (or dibenzothiophene) is substituted with triphenylene and is represented Chemical Formula IV.

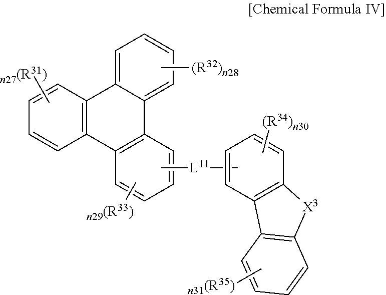

In Chemical Formula IV,
X³ is O or S
L¹¹ is a single bond, a substituted or unsubstituted C6 to C20 arylene group, a substituted or unsubstituted C2 to C20 heterocyclic group, or a combination thereof,
R³¹ to R³⁵ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof,
n27, n28, and n31 are each independently an integer of 1 to 4, and
n29 and n30 are each independently an integer of 1 to 3.

Chemical Formula IV may be represented by, for example, any of Chemical Formula IV-1 to Chemical Formula IV-4, depending on the specific substitution point of dibenzofuran (or dibenzothiophene) substituted with triphenylene.

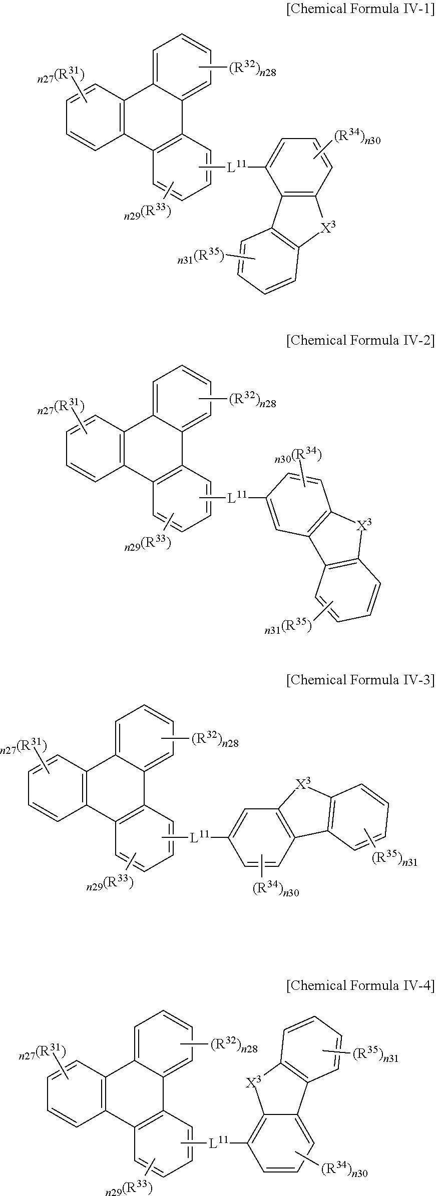

In Chemical Formula IV-1 to Chemical Formula IV-4, L¹¹, R³¹ to R³⁵ and n27 to n31 are the same as described above.

For example, Chemical Formula IV may be represented by Chemical Formula IV-1 or Chemical Formula IV-4.

Specifically, L¹¹ in Chemical Formula IV-1 and Chemical Formula IV-4 may be a substituted or unsubstituted phenylene group or a substituted or unsubstituted biphenylene group.

For example, L¹¹ in Chemical Formula IV-1 and Chemical Formula IV-4 may be selected from the linking groups listed in Group I.

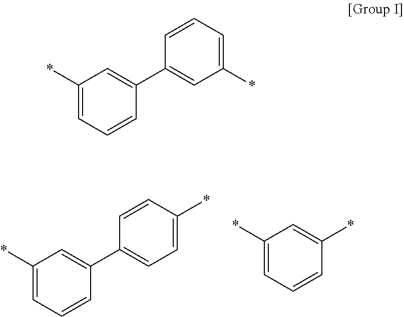

In Group I, * is a linking point, and
the linking groups listed in Group I may be further substituted with additional substituents.

The additional substituent may be deuterium, a cyano group, a C1 to C10 alkyl group, or a C6 to C12 aryl group.

Specifically, R³¹ to R³⁵ in Chemical Formula IV-1 and Chemical Formula IV-4 may be hydrogen, deuterium, or a substituted or unsubstituted phenyl group.

For example, Chemical Formula IV-1 may be represented by Chemical Formula IV-1a or Chemical Formula IV-1b.

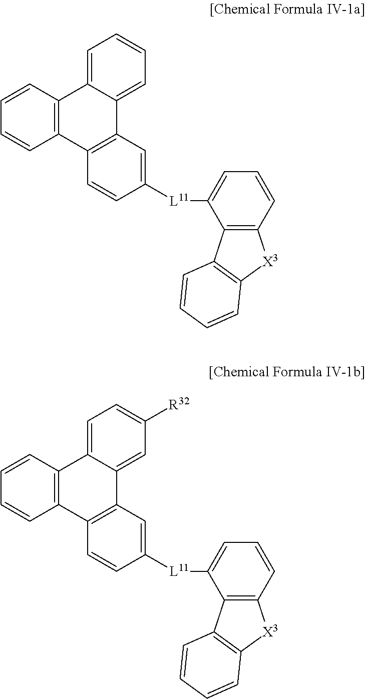

For example, Chemical Formula IV-4 may be represented by any one of Chemical Formula IV-4a to Chemical Formula IV-4d.

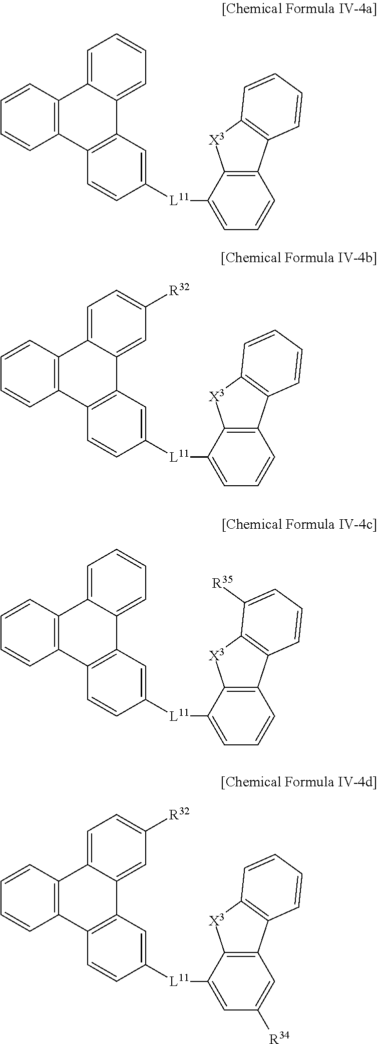

In Chemical Formula IV-4a to Chemical Formula IV-4d, L¹¹ and X³ are the same as described above, and R³², R³⁴, and R³⁵ are each independently a substituted or unsubstituted phenyl group.

For example, Chemical Formula IV may be represented by any one of Chemical Formula IV-1a, Chemical Formula IV-4a and Chemical Formula IV-4c.

The third compound may be, for example, one selected from the compounds listed in Group 3.

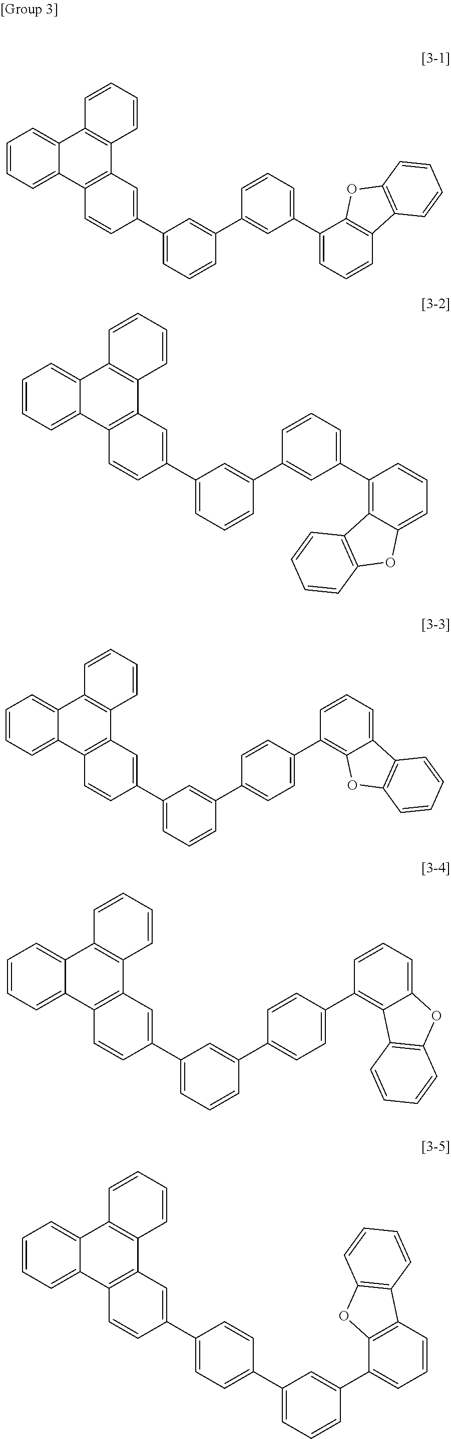 [SMILES: c1cc(-c2cccc(-c3cccc4c3oc3ccccc34)c2)cc(-c2ccc3c4ccccc4c4ccccc4c3c2)c1 ; c1cc(-c2cccc(-c3cccc4oc5ccccc5c34)c2)cc(-c2ccc3c4ccccc4c4ccccc4c3c2)c1 ; c1cc(-c2ccc(-c3cccc4c3oc3ccccc34)cc2)cc(-c2ccc3c4ccccc4c4ccccc4c3c2)c1 ; c1cc(-c2ccc(-c3cccc4oc5ccccc5c34)cc2)cc(-c2ccc3c4ccccc4c4ccccc4c3c2)c1 ; c1cc(-c2ccc(-c3ccc4c5ccccc5c5ccccc5c4c3)cc2)cc(-c2cccc3c2oc2ccccc23)c1]

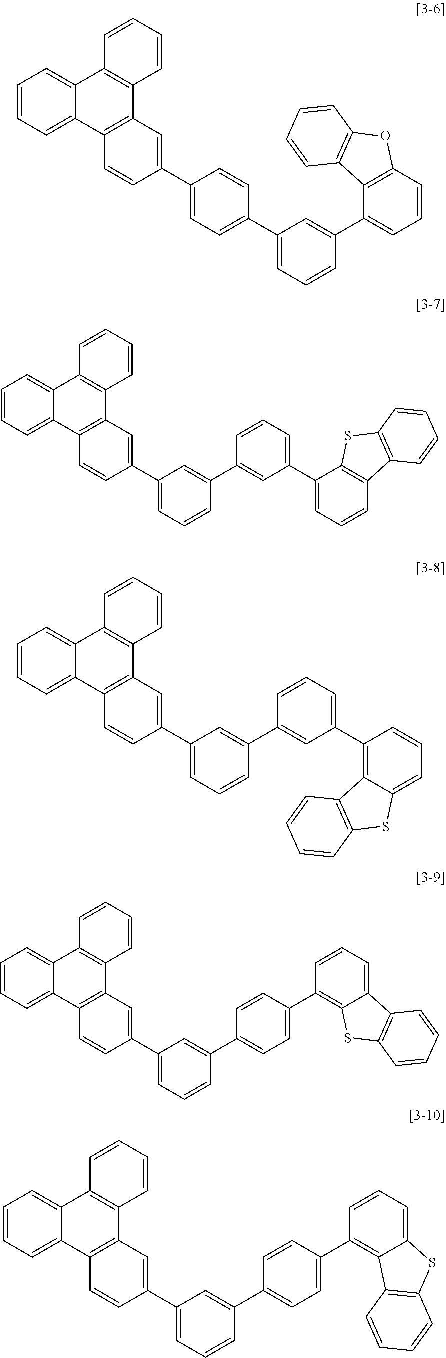 [SMILES: c1cc(-c2ccc(-c3ccc4c5ccccc5c5ccccc5c4c3)cc2)cc(-c2cccc3oc4ccccc4c23)c1 ; c1cc(-c2cccc(-c3cccc4c3sc3ccccc34)c2)cc(-c2ccc3c4ccccc4c4ccccc4c3c2)c1 ; c1cc(-c2cccc(-c3cccc4sc5ccccc5c34)c2)cc(-c2ccc3c4ccccc4c4ccccc4c3c2)c1 ; c1cc(-c2ccc(-c3cccc4c3sc3ccccc34)cc2)cc(-c2ccc3c4ccccc4c4ccccc4c3c2)c1 ; c1cc(-c2ccc(-c3cccc4sc5ccccc5c34)cc2)cc(-c2ccc3c4ccccc4c4ccccc4c3c2)c1]

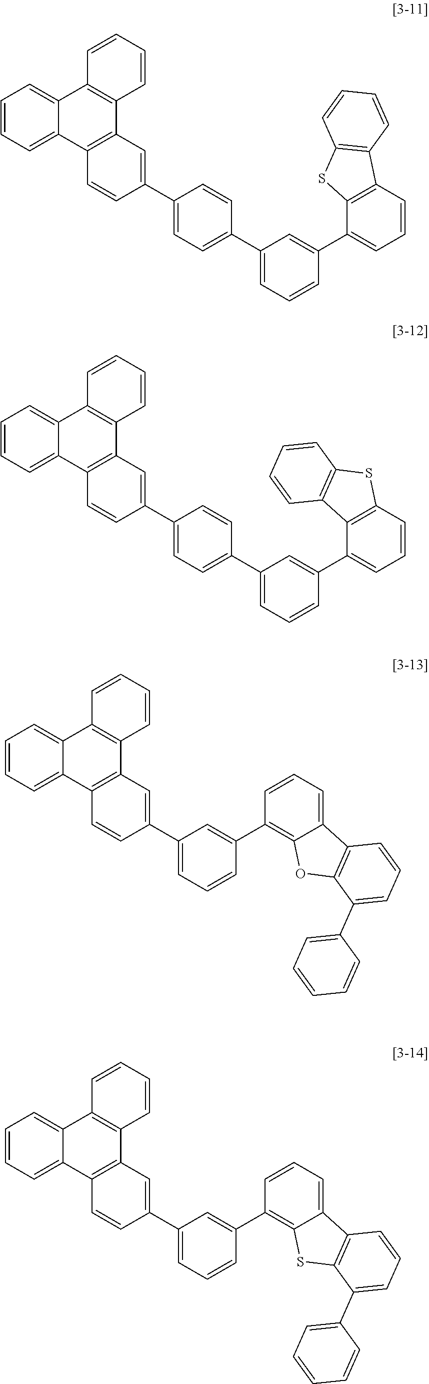 [SMILES: c1cc(-c2ccc(-c3ccc4c5ccccc5c5ccccc5c4c3)cc2)cc(-c2cccc3c2sc2ccccc23)c1 ; c1cc(-c2ccc(-c3ccc4c5ccccc5c5ccccc5c4c3)cc2)cc(-c2cccc3sc4ccccc4c23)c1 ; c1ccc(-c2cccc3c2oc2c(-c4cccc(-c5ccc6c7ccccc7c7ccccc7c6c5)c4)cccc23)cc1 ; c1ccc(-c2cccc3c2sc2c(-c4cccc(-c5ccc6c7ccccc7c7ccccc7c6c5)c4)cccc23)cc1]

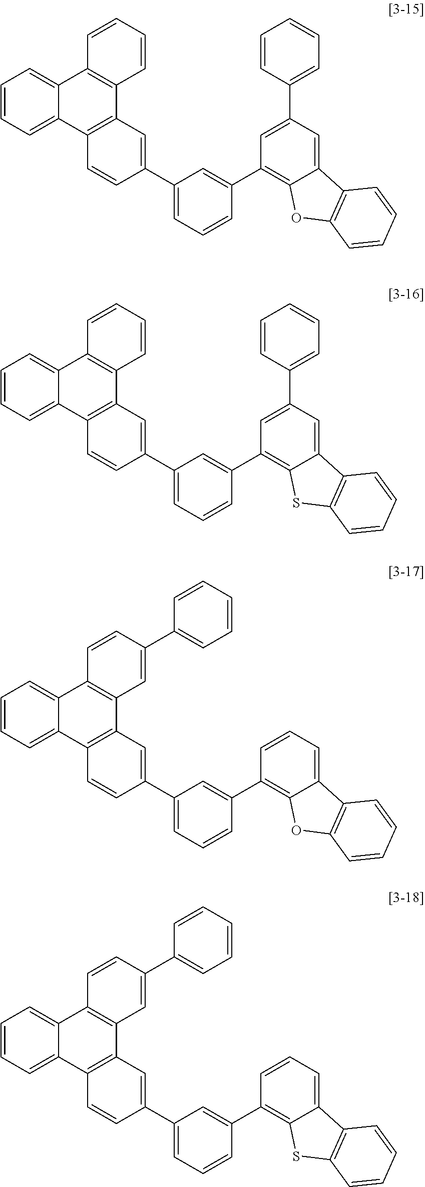 [SMILES: c1ccc(-c2cc(-c3cccc(-c4ccc5c6ccccc6c6ccccc6c5c4)c3)c3oc4ccccc4c3c2)cc1 ; c1ccc(-c2cc(-c3cccc(-c4ccc5c6ccccc6c6ccccc6c5c4)c3)c3sc4ccccc4c3c2)cc1 ; c1ccc(-c2ccc3c4ccccc4c4ccc(-c5cccc(-c6cccc7c6oc6ccccc67)c5)cc4c3c2)cc1 ; c1ccc(-c2ccc3c4ccccc4c4ccc(-c5cccc(-c6cccc7c6sc6ccccc67)c5)cc4c3c2)cc1]

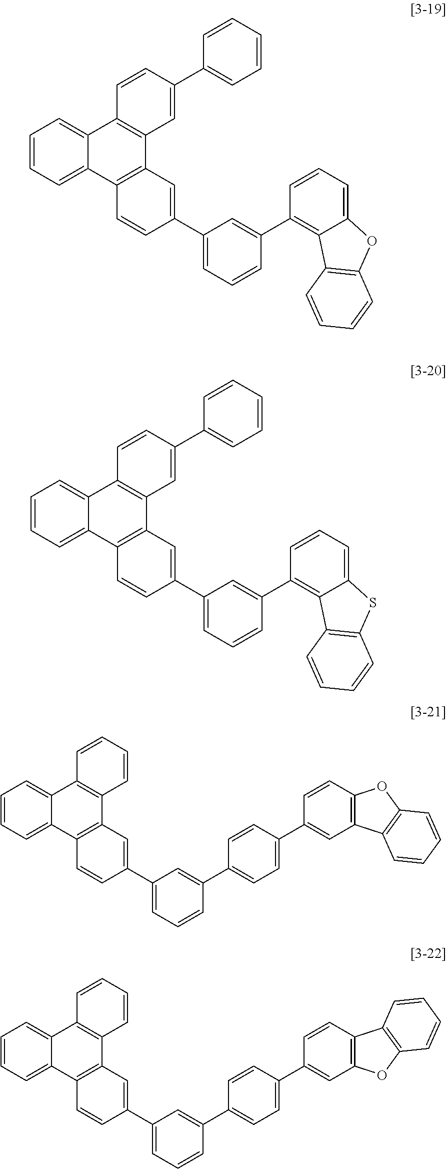 [SMILES: c1ccc(-c2ccc3c4ccccc4c4ccc(-c5cccc(-c6cccc7oc8ccccc8c67)c5)cc4c3c2)cc1 ; c1ccc(-c2ccc3c4ccccc4c4ccc(-c5cccc(-c6cccc7sc8ccccc8c67)c5)cc4c3c2)cc1 ; c1cc(-c2ccc(-c3ccc4oc5ccccc5c4c3)cc2)cc(-c2ccc3c4ccccc4c4ccccc4c3c2)c1 ; c1cc(-c2ccc(-c3ccc4c(c3)oc3ccccc34)cc2)cc(-c2ccc3c4ccccc4c4ccccc4c3c2)c1]

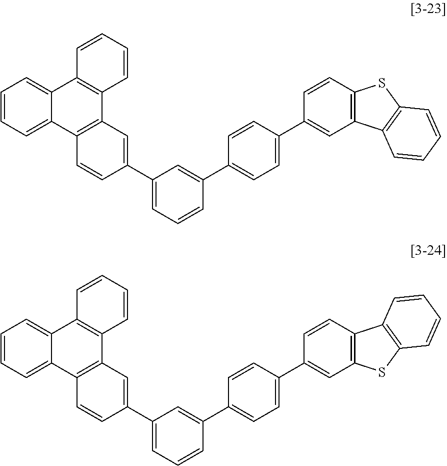 [SMILES: c1cc(-c2ccc(-c3ccc4sc5ccccc5c4c3)cc2)cc(-c2ccc3c4ccccc4c4ccccc4c3c2)c1 ; c1cc(-c2ccc(-c3ccc4c(c3)sc3ccccc34)cc2)cc(-c2ccc3c4ccccc4c4ccccc4c3c2)c1]

The first compound includes a 6-membered nitrogen-containing ring having high electron transport characteristics to stably and effectively transport electrons and thus lower a driving voltage, increase current efficiency, and realize long life-span characteristics of a device.

The second compound has a structure including carbazole having high HOMO energy to effectively inject and transport holes and thus contribute to improving device characteristics.

The third compound has a wide HOMO-LUMO bandgap and thus achieves an effect of preventing exciton quenching by controlling movement speeds of holes and electrons of the first and second compounds and also, preventing hole traps by relatively shifting a light emitting layer region and resultantly, contributes to improving life-span characteristics of the device.

The 3-host composition including the first compound, the second compound, and the third compound may be used to more finely adjust electron/hole characteristics to achieve an optimal balance in a device stack, compared with a 2-host composition, for example, a composition including the first compound and the second compound or a composition including the first compound and the third compound, and resultantly, to significantly improve device characteristics due to the proper charge balance.

The composition in which the first compound, the second compound, and the third compound are mixed may be included in a light emitting layer of an organic light emitting device to be described later, and may be included as, for example, a phosphorescent host.

In the composition for an organic optoelectronic device, the first compound may be included in an amount of about 20 wt % to about 50 wt % based on a total weight of the first compound, the second compound, and the third compound, the second compound may be included in an amount of about 40 wt % to about 60 wt % based on a total weight of the first compound, the second compound, and the third compound, and the third compound may be included in an amount of about 10 wt % to about 30 wt % based on a total weight of the first compound, the second compound, and the third compound.

Within the range, for example, the first compound for an organic optoelectronic device may be included in an amount of about 25 wt % to about 45 wt % based on a total weight of the first compound for an organic optoelectronic device, the second compound for an organic optoelectronic device, and the third compound for an organic optoelectronic device, the second compound for an organic optoelectronic device may be included in an amount of about 45 wt % to about 60 wt % based on a total weight of the first compound for an organic optoelectronic device, the second compound for an organic optoelectronic device, and the third compound for an organic optoelectronic device, and the third compound for an organic optoelectronic device may be included in an amount of about 10 wt % to about 25 wt % based on a total weight of the first compound for an organic optoelectronic device, the second compound for an organic optoelectronic device, and the third compound for an organic optoelectronic device.

In addition, as a specific example, the first compound may be included in an amount of about 30 wt % to 40 wt % based on a total weight of the first compound, the second compound, and the third compound, and the second compound may be included in an amount of about 45 wt % to 55 wt % based on a total weight of the first compound, the second compound, and the third compound, and the third compound may be included in an amount of about 10 wt % to 20 wt % based on a total weight of the first compound, the second compound, and the third compound.

As a more specific example, the composition for an organic optoelectronic device may include the first compound: the second compound: the third compound in a weight ratio of about 35:55:10 or about 32:48:20. Within the above range, the electron transport capability of the first compound, the hole transport capability of the second compound, and the buffering capability of the third compound are appropriately balanced to improve efficiency and life-span of the device.

The composition for an organic optoelectronic device may further include one or more compounds in addition to the aforementioned first compound, second compound, and third compound.

The composition for an organic optoelectronic device may further include a dopant. The dopant may be, for example, a phosphorescent dopant, for example, a red, green or blue phosphorescent dopant, and may be, for example, a green phosphorescent dopant.

A dopant is a material that causes light emission by being mixed in a small amount in a composition including the first compound, the second compound, and the third compound, and is generally a material such as a metal complex that emits light by multiple excitation in a triplet state or higher. The dopant may be, for example, an inorganic, organic, or organic-inorganic compound, and may include one or two or more types.

An example of the dopant may be a phosphorescent dopant, and examples of the phosphorescent dopant may include an organometallic compound including Ir, Pt, Os, Ti, Zr, Hf, Eu, Tb, Tm, Fe, Co, Ni, Ru, Rh, Pd, or a combination thereof. The phosphorescent dopant may be, for example, a compound represented by Chemical Formula Z, but is not limited thereto.

L¹²MX⁴ [Chemical Formula Z]

In Chemical Formula Z, M is a metal, and L¹² and X⁴ are the same or different, and are a ligand to form a complex compound with M.

The M may be for example Ir, Pt, Os, Ti, Zr, Hf, Eu, Tb, Tm, Fe, Co, Ni, Ru, Rh, Pd, or a combination thereof, and L¹² and X⁴ may be, for example a bidentate ligand.

Examples of ligands represented by L¹² and X⁴ may be selected from the Chemical Formulas listed in Group A, but is not limited thereto.

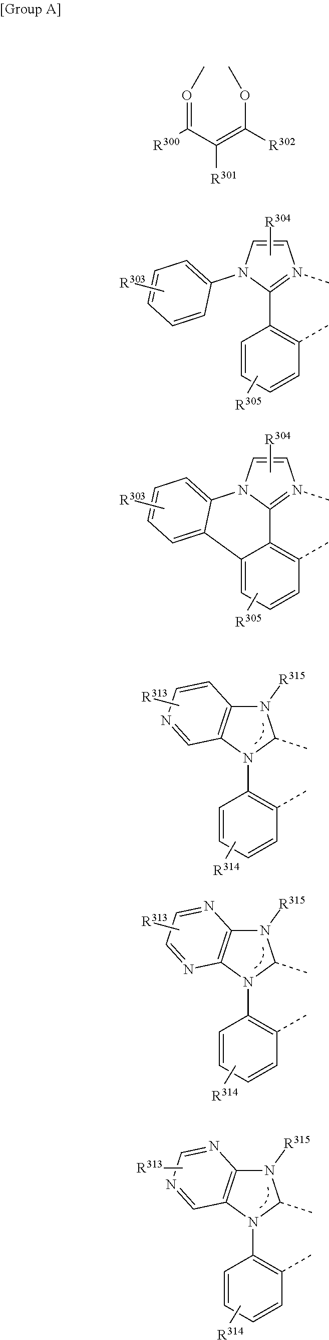

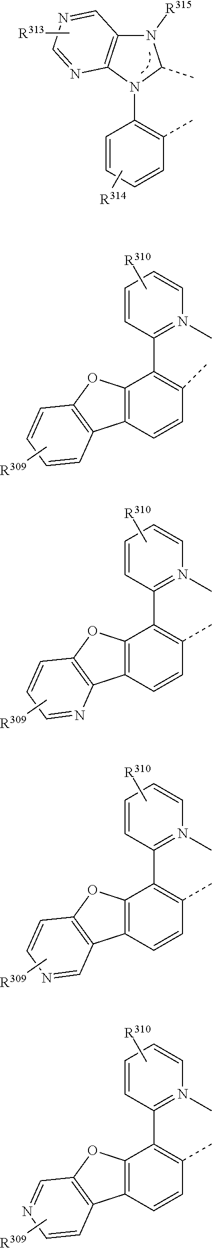

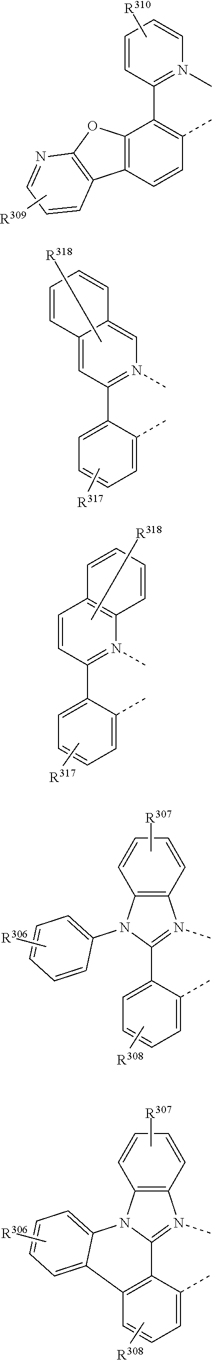

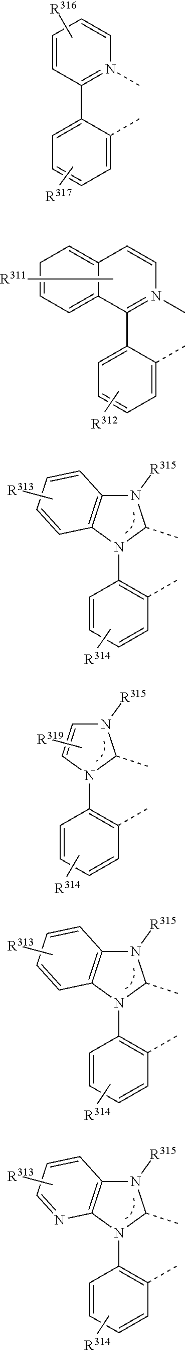

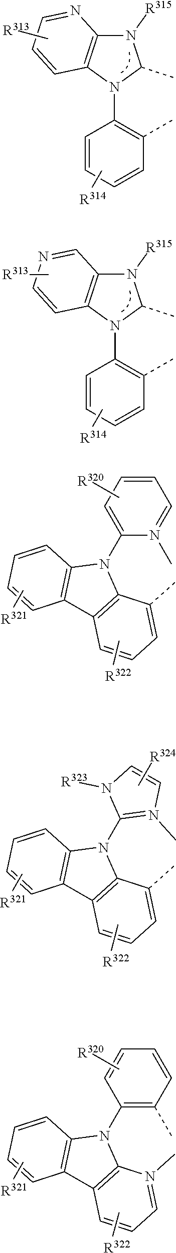

In Group A,
R³⁰⁰ to R³⁰² are each independently hydrogen, deuterium, a C1 to C30 alkyl group that is substituted or unsubstituted with a halogen, a C6 to C30 aryl group that is substituted or unsubstituted with a C1 to C30 alkyl, or a halogen, and
R³⁰³ to R³²⁴ are each independently hydrogen, deuterium, a halogen, a substituted or unsubstituted C1 to C30 alkyl group, a substituted or unsubstituted C1 to C30 alkoxy group, a substituted or unsubstituted C3 to C30 cycloalkyl group, a substituted or unsubstituted C1 to C30 cycloalkyl group, a substituted or unsubstituted C2 to C30 alkenyl group, a substituted or unsubstituted C6 to C30 aryl group, a substituted or unsubstituted C1 to C30 heteroaryl group, a substituted or unsubstituted C1 to C30 amino group, a substituted or unsubstituted C6 to C30 arylamino group, SF₅, a C1 to C30 trialkylsilyl group having a substituted or unsubstituted C1 to C30 alkyl group, a C1 to C30 dialkylarylsilyl group having a substituted or unsubstituted C1 to C30 alkyl group and a C6 to C30 aryl group, or a triarylsilyl group with a substituted or unsubstituted C6 to C30 aryl group.

For example, a dopant represented by Chemical Formula V may be included.

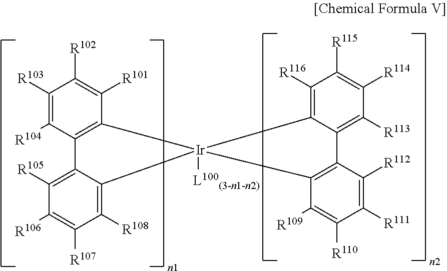

In Chemical Formula V,
R¹⁰¹ to R¹¹⁶ are each independently hydrogen, deuterium, a substituted or unsubstituted C1 to C10 alkyl group, a substituted or unsubstituted C6 to C20 aryl group, or —SiR¹³²R¹³³R¹³⁴,
R¹³² to R¹³⁴ are each independently a C1 to C6 alkyl group,
at least one of R¹⁰¹ to R¹¹⁶ is a functional group represented by Chemical Formula V-1,
L¹⁰⁰ is a bidentate ligand of a monovalent anion, and is a ligand that coordinates to iridium through a lone pair of carbons or heteroatoms, and
n1 and n2 are each independently any one of integers of 0 to 3, and n1+n2 is any one of integers of 1 to 3,

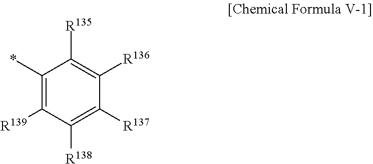

wherein, in Chemical Formula V-1
R¹³⁵ to R¹³⁹ are each independently hydrogen, deuterium, a substituted or unsubstituted C1 to C10 alkyl group, a substituted or unsubstituted C6 to C20 aryl group, or —SiR¹³²R¹³³R¹³⁴, and
* means a part connected to a carbon atom.

For example, the dopant represented by Chemical Formula Z-1 may be included.

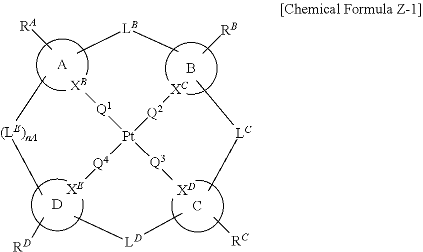

In Chemical Formula Z-1, rings A, B, C, and D are each independently a 5-membered or 6-membered carbocyclic or heterocyclic ring;
R^{A}, R^{B}, R^{C}, and R^{D} are each independently represent mono-, di-, tri-, or tetra-substituted, or unsubstituted;
L^{B}, L^{C}, and L^{D} are each independent selected from a direct bond, BR, NR, PR, O, S, Se, C═O, S═O, SO₂, CRR′, SiRR′, GeRR′, and a combination thereof,
when nA is 1, L^{E} is selected from a direct bond, BR, NR, PR, O, S, Se, C═O, S═O, SO₂, CRR′, SiRR′, GeRR′, and a combination thereof, when nA is 0, L^{E} does not exist; and
R^{A}, R^{B}, R^{C}, R^{D}, R, and R′ are each independently selected from hydrogen, deuterium, a halogen, an alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a carbonyl group, a carboxylic acid group, an ester group, a nitrile group, an isonitrile group, a sulfanyl group, a sulfinyl group, a sulfonyl group, a phosphino group, and a combination thereof, any adjacent R^{A}R^{B}, R^{C}, R^{D}, R, and R′ are optionally linked to form a ring; X^{B}, X^{C}, X^{D}, and X^{E} are each independently selected from carbon and nitrogen; and Q¹, Q², Q³, and Q⁴ each represent an oxygen or a direct bond.

The dopant according to an embodiment may be a platinum complex, and may be represented by Chemical Formula VI.

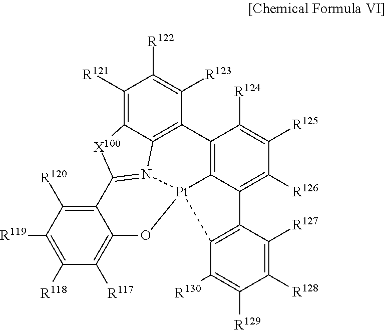

In Chemical Formula VI,
X¹⁰⁰ is selected from O, S and NR¹³¹,
R¹¹⁷ to R¹³¹ are each independently hydrogen, deuterium, a substituted or unsubstituted C1 to C10 alkyl group, a substituted or unsubstituted C6 to C20 aryl group, or —SiR¹³²R¹³³R¹³⁴,
R¹³² to R¹³⁴ are each independently a C1 to C6 alkyl group, and
at least one of R¹¹⁷ to R¹³¹ is —SiR¹³²R¹³³R¹³⁴ or tert-butyl group.

Hereinafter, an organic optoelectronic device to which the aforementioned composition for an organic optoelectronic device is applied will be described.

The organic photoelectronic device may be any device to convert electrical energy into photoenergy and vice versa without particular limitation, and may be, for example an organic photoelectric device, an organic light emitting diode, an organic solar cell, and an organic photoconductor drum.

Herein, an organic light emitting diode as one example of an organic optoelectronic device is described referring to drawings.

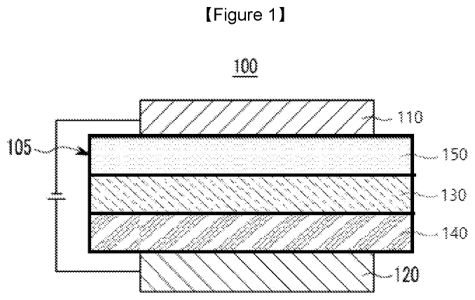

FIG. 1 is a cross-sectional view showing organic light emitting diodes according to embodiments.

Referring to FIG. 1, an organic light emitting diode 100 according to an embodiment includes an anode 120 and a cathode 110 facing each other and an organic layer 105 disposed between the anode 120 and cathode 110.

The anode 120 may be made of a conductor having a large work function to help hole injection, and may be for example a metal, a metal oxide and/or a conductive polymer. The anode 120 may be, for example a metal such as nickel, platinum, vanadium, chromium, copper, zinc, gold, and the like or an alloy thereof, a metal oxide such as zinc oxide, indium oxide, indium tin oxide (ITO), indium zinc oxide (IZO), and the like; a combination of a metal and an oxide such as ZnO and Al or SnO₂ and Sb; a conductive polymer such as poly(3-methylthiophene), poly(3,4-(ethylene-1,2-dioxy)thiophene) (PEDOT), polypyrrole, and polyaniline, but is not limited thereto.

The cathode 110 may be made of a conductor having a small work function to help electron injection, and may be for example a metal, a metal oxide, and/or a conductive polymer. The cathode 110 may be for example a metal such as magnesium, calcium, sodium, potassium, titanium, indium, yttrium, lithium, gadolinium, aluminum silver, tin, lead, cesium, barium, and the like, or an alloy thereof; a multi-layer structure material such as LiF/Al, LiO₂/Al, LiF/Ca, and BaF₂/Ca, but is not limited thereto.

The organic layer 105 may include the aforementioned composition for an organic optoelectronic device.

The organic layer 105 may include the light emitting layer 130, and the light emitting layer 130 may include the aforementioned composition for an organic optoelectronic device.

The composition for an organic optoelectronic device further including the dopant may be, for example, a red light emitting composition.

The light emitting layer 130 may include, for example, the aforementioned composition for an organic optoelectronic device as a phosphorescent host.

The organic layer may further include a charge transport region in addition to the light emitting layer.

The charge transport region may be, for example, the hole transport region 140.

The hole transport region 140 may further increase hole injection and/or hole mobility between the anode 120 and the light emitting layer 130 and block electrons.

Specifically, the hole transport region 140 may include a hole transport layer between the anode 120 and the light emitting layer 130, and a hole transport auxiliary layer between the light emitting layer 130 and the hole transport layer, and at least one of the compounds of Group B may be included in at least one of the hole transport layer and the hole transport auxiliary layer.

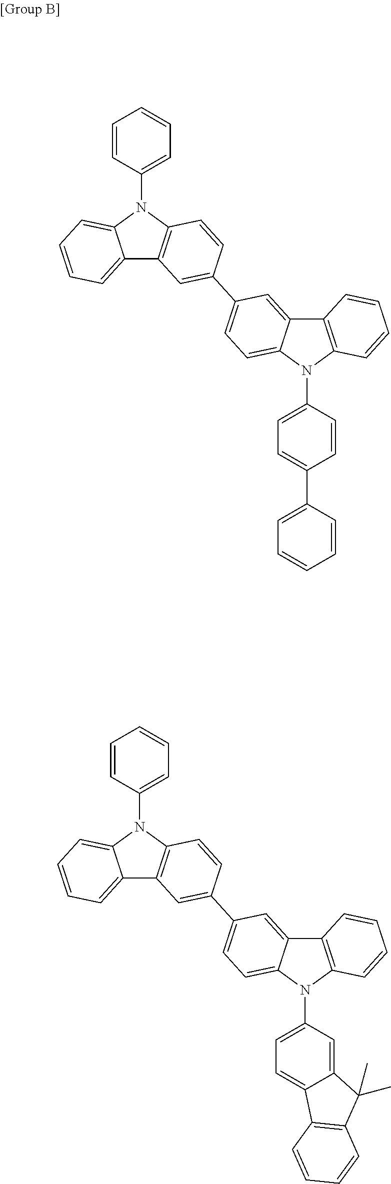 [SMILES: c1ccc(-c2ccc(-n3c4ccccc4c4cc(-c5ccc6c(c5)c5ccccc5n6-c5ccccc5)ccc43)cc2)cc1 ; CC1(C)c2ccccc2-c2ccc(-n3c4ccccc4c4cc(-c5ccc6c(c5)c5ccccc5n6-c5ccccc5)ccc43)cc21]

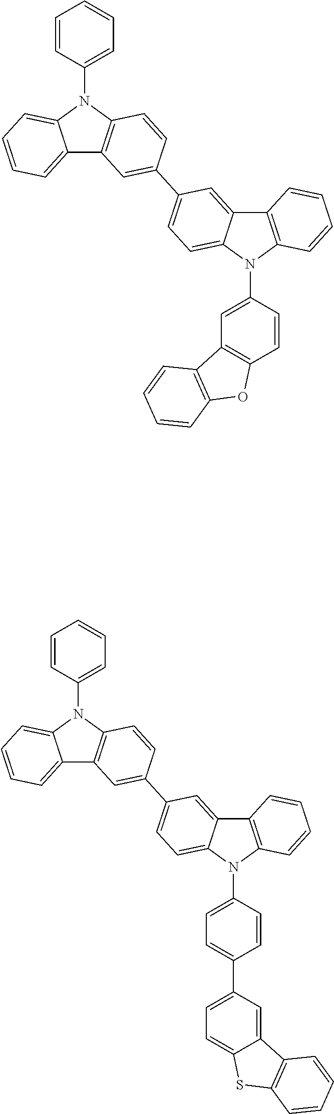 [SMILES: c1ccc(-n2c3ccccc3c3cc(-c4ccc5c(c4)c4ccccc4n5-c4ccc5oc6ccccc6c5c4)ccc32)cc1 ; c1ccc(-n2c3ccccc3c3cc(-c4ccc5c(c4)c4ccccc4n5-c4ccc(-c5ccc6sc7ccccc7c6c5)cc4)ccc32)cc1]

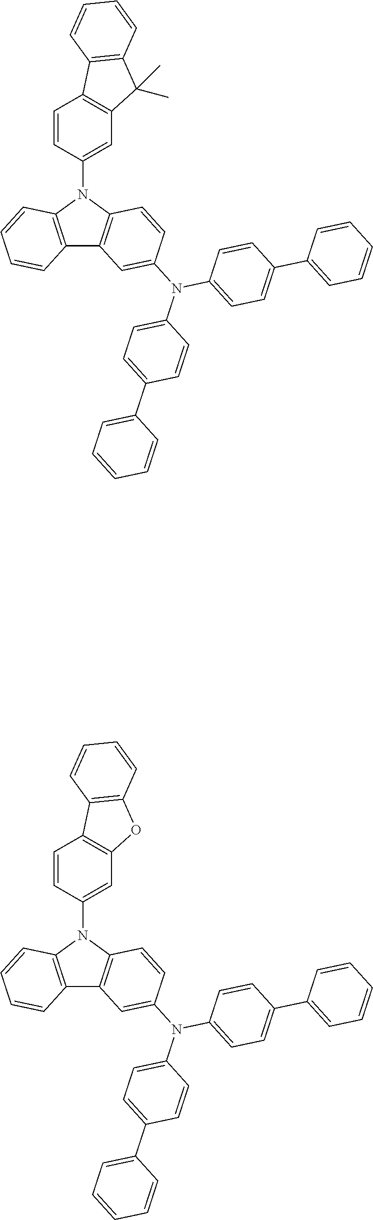 [SMILES: CC1(C)c2ccccc2-c2ccc(-n3c4ccccc4c4cc(N(c5ccc(-c6ccccc6)cc5)c5ccc(-c6ccccc6)cc5)ccc43)cc21 ; c1ccc(-c2ccc(N(c3ccc(-c4ccccc4)cc3)c3ccc4c(c3)c3ccccc3n4-c3ccc4c(c3)oc3ccccc34)cc2)cc1]

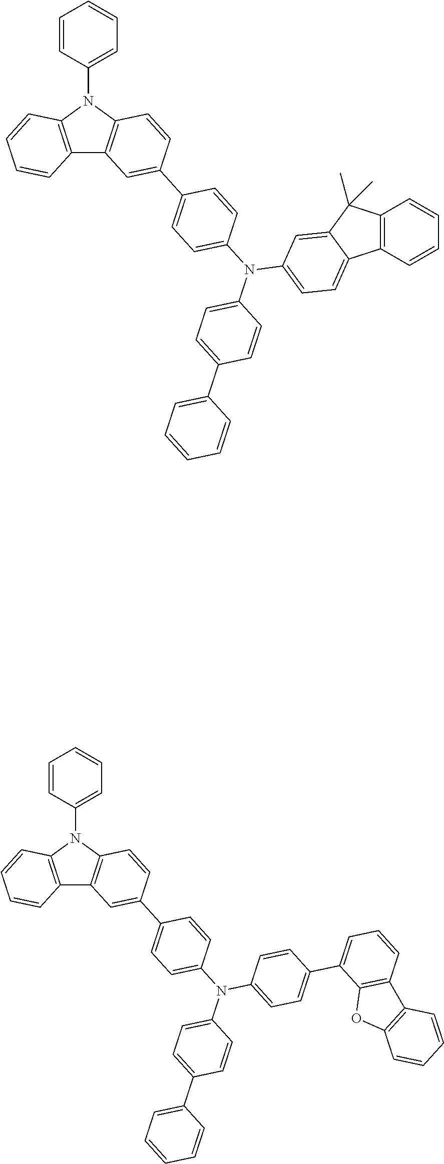 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4ccc5c(c4)c4ccccc4n5-c4ccccc4)cc3)c3ccc(-c4cccc5c4oc4ccccc45)cc3)cc2)cc1]

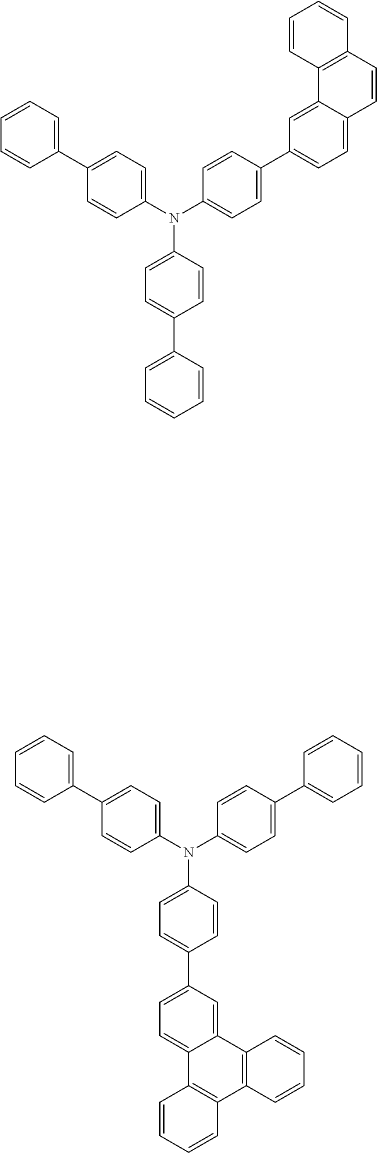 [SMILES: c1ccc(-c2ccc(N(c3ccc(-c4ccccc4)cc3)c3ccc(-c4ccc5ccc6ccccc6c5c4)cc3)cc2)cc1 ; c1ccc(-c2ccc(N(c3ccc(-c4ccccc4)cc3)c3ccc(-c4ccc5c6ccccc6c6ccccc6c5c4)cc3)cc2)cc1]

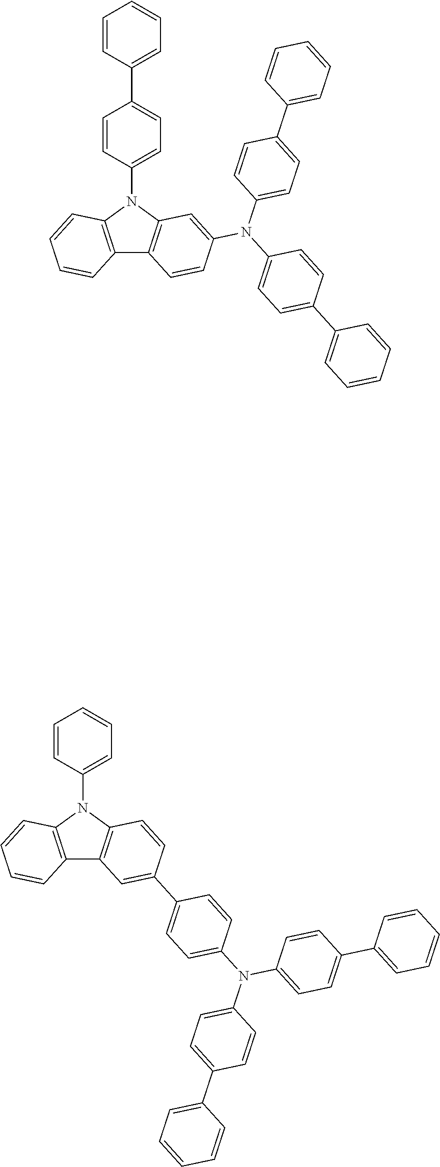 [SMILES: c1ccc(-c2ccc(N(c3ccc(-c4ccccc4)cc3)c3ccc4c5ccccc5n(-c5ccc(-c6ccccc6)cc5)c4c3)cc2)cc1 ; c1ccc(-c2ccc(N(c3ccc(-c4ccccc4)cc3)c3ccc(-c4ccc5c(c4)c4ccccc4n5-c4ccccc4)cc3)cc2)cc1]

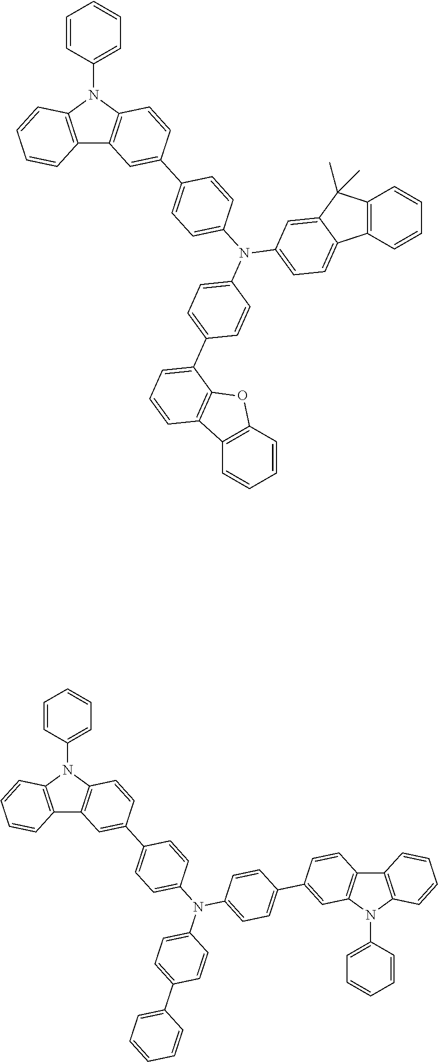 [SMILES: CC1(C)c2ccccc2-c2ccc(N(c3ccc(-c4ccc5c(c4)c4ccccc4n5-c4ccccc4)cc3)c3ccc(-c4cccc5c4oc4ccccc45)cc3)cc21 ; c1ccc(-c2ccc(N(c3ccc(-c4ccc5c(c4)c4ccccc4n5-c4ccccc4)cc3)c3ccc(-c4ccc5c6ccccc6n(-c6ccccc6)c5c4)cc3)cc2)cc1]

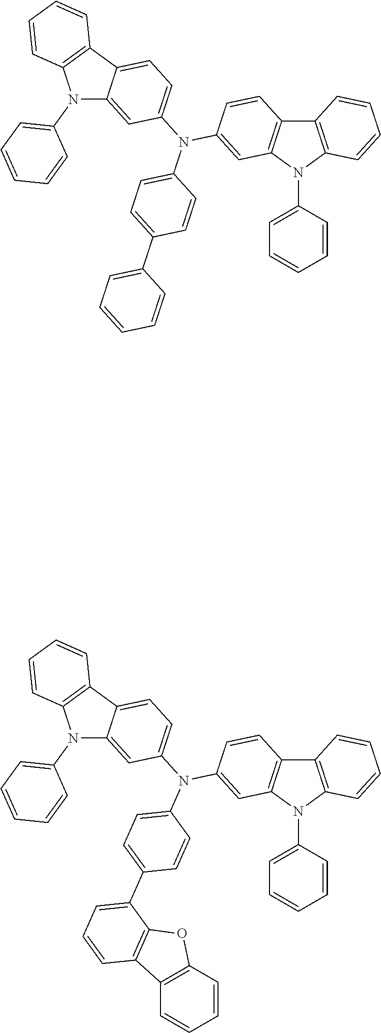 [SMILES: c1ccc(-c2ccc(N(c3ccc4c5ccccc5n(-c5ccccc5)c4c3)c3ccc4c5ccccc5n(-c5ccccc5)c4c3)cc2)cc1 ; c1ccc(-n2c3ccccc3c3ccc(N(c4ccc(-c5cccc6c5oc5ccccc56)cc4)c4ccc5c6ccccc6n(-c6ccccc6)c5c4)cc32)cc1]

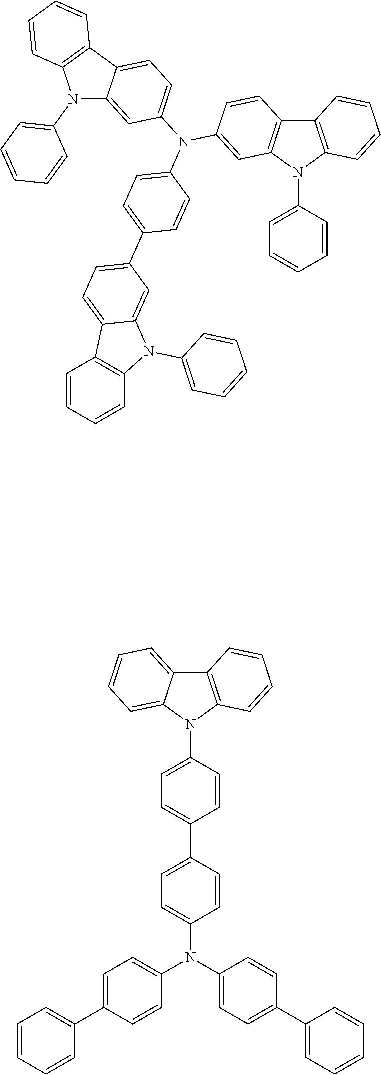 [SMILES: c1ccc(-n2c3ccccc3c3ccc(-c4ccc(N(c5ccc6c7ccccc7n(-c7ccccc7)c6c5)c5ccc6c7ccccc7n(-c7ccccc7)c6c5)cc4)cc32)cc1 ; c1ccc(-c2ccc(N(c3ccc(-c4ccccc4)cc3)c3ccc(-c4ccc(-n5c6ccccc6c6ccccc65)cc4)cc3)cc2)cc1]

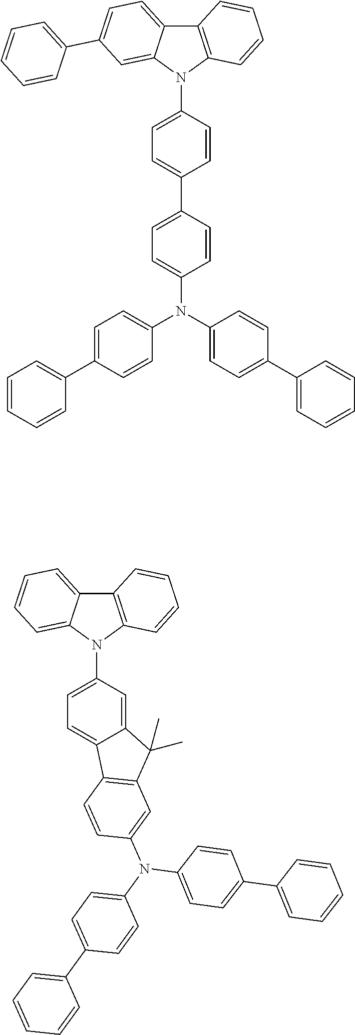 [SMILES: c1ccc(-c2ccc(N(c3ccc(-c4ccccc4)cc3)c3ccc(-c4ccc(-n5c6ccccc6c6ccc(-c7ccccc7)cc65)cc4)cc3)cc2)cc1 ; CC1(C)c2cc(N(c3ccc(-c4ccccc4)cc3)c3ccc(-c4ccccc4)cc3)ccc2-c2ccc(-n3c4ccccc4c4ccccc43)cc21]

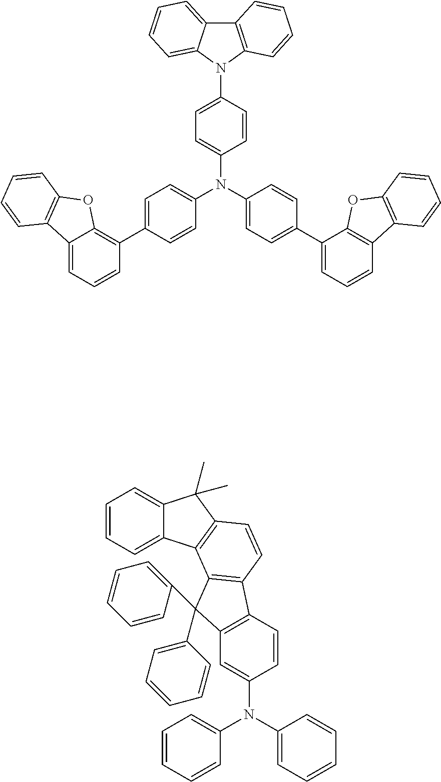 [SMILES: c1ccc2c(c1)oc1c(-c3ccc(N(c4ccc(-c5cccc6c5oc5ccccc56)cc4)c4ccc(-n5c6ccccc6c6ccccc65)cc4)cc3)cccc12 ; CC1(C)c2ccccc2-c2c1ccc1c2C(c2ccccc2)(c2ccccc2)c2cc(N(c3ccccc3)c3ccccc3)ccc2-1]

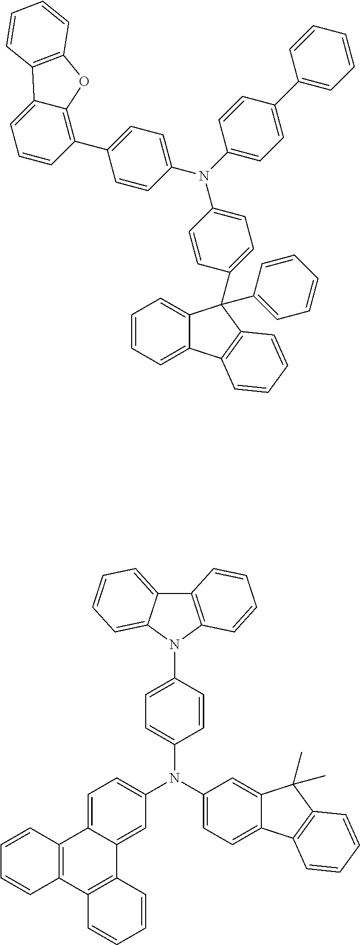 [SMILES: c1ccc(-c2ccc(N(c3ccc(-c4cccc5c4oc4ccccc45)cc3)c3ccc(C4(c5ccccc5)c5ccccc5-c5ccccc54)cc3)cc2)cc1 ; CC1(C)c2ccccc2-c2ccc(N(c3ccc(-n4c5ccccc5c5ccccc54)cc3)c3ccc4c5ccccc5c5ccccc5c4c3)cc21]

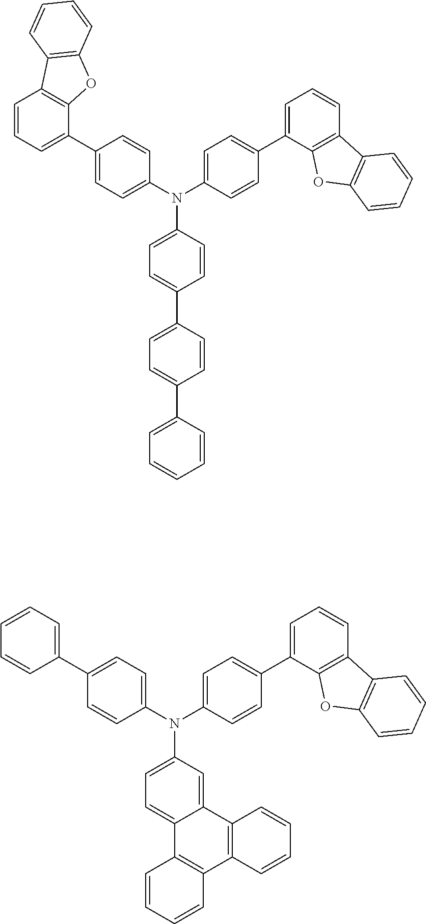 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccc(N(c3ccc(-c4cccc5c4oc4ccccc45)cc3)c3ccc4c5ccccc5c5ccccc5c4c3)cc2)cc1]

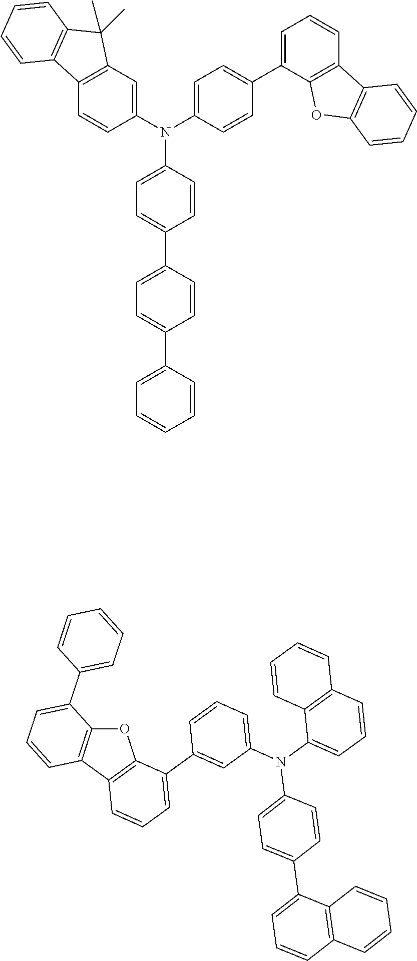 [SMILES: CC1(C)c2ccccc2-c2ccc(N(c3ccc(-c4ccc(-c5ccccc5)cc4)cc3)c3ccc(-c4cccc5c4oc4ccccc45)cc3)cc21 ; c1ccc(-c2cccc3c2oc2c(-c4cccc(N(c5ccc(-c6cccc7ccccc67)cc5)c5cccc6ccccc56)c4)cccc23)cc1]

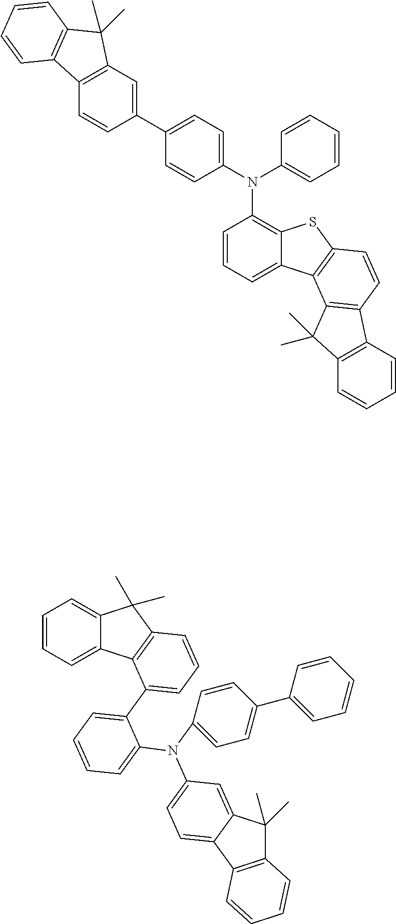 [SMILES: CC1(C)c2ccccc2-c2ccc(-c3ccc(N(c4ccccc4)c4cccc5c4sc4ccc6c(c45)C(C)(C)c4ccccc4-6)cc3)cc21 ; CC1(C)c2ccccc2-c2ccc(N(c3ccc(-c4ccccc4)cc3)c3ccccc3-c3cccc4c3-c3ccccc3C4(C)C)cc21]

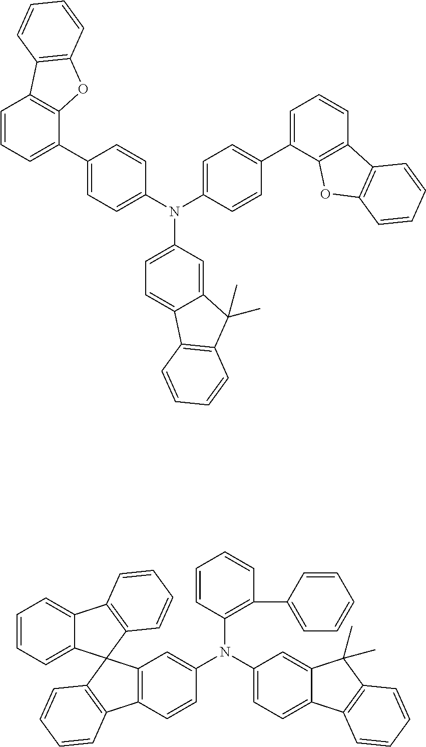 [SMILES: CC1(C)c2ccccc2-c2ccc(N(c3ccc(-c4cccc5c4oc4ccccc45)cc3)c3ccc(-c4cccc5c4oc4ccccc45)cc3)cc21 ; CC1(C)c2ccccc2-c2ccc(N(c3ccc4c(c3)C3(c5ccccc5-c5ccccc53)c3ccccc3-4)c3ccccc3-c3ccccc3)cc21]

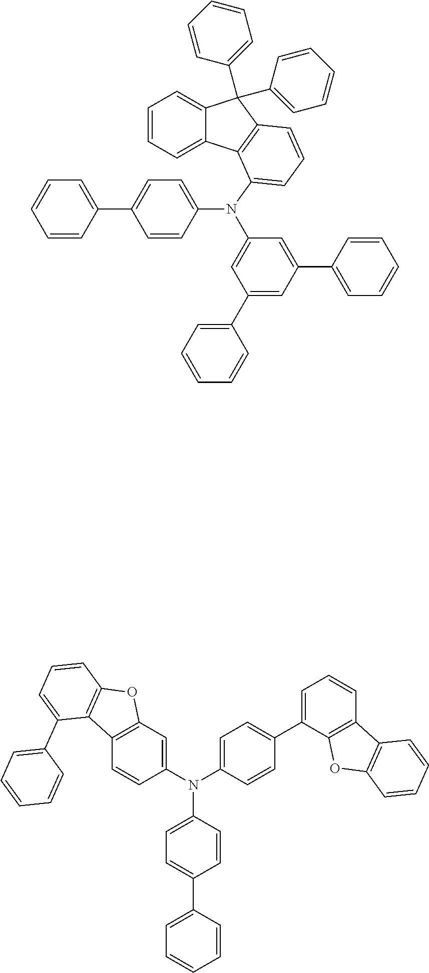 [SMILES: c1ccc(-c2ccc(N(c3cc(-c4ccccc4)cc(-c4ccccc4)c3)c3cccc4c3-c3ccccc3C4(c3ccccc3)c3ccccc3)cc2)cc1 ; c1ccc(-c2ccc(N(c3ccc(-c4cccc5c4oc4ccccc45)cc3)c3ccc4c(c3)oc3cccc(-c5ccccc5)c34)cc2)cc1]

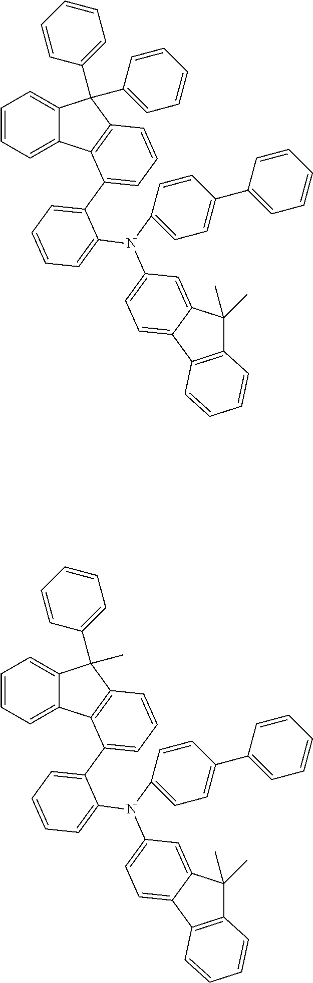 [SMILES: CC1(C)c2ccccc2-c2ccc(N(c3ccc(-c4ccccc4)cc3)c3ccccc3-c3cccc4c3-c3ccccc3C4(c3ccccc3)c3ccccc3)cc21 ; CC1(C)c2ccccc2-c2ccc(N(c3ccc(-c4ccccc4)cc3)c3ccccc3-c3cccc4c3-c3ccccc3C4(C)c3ccccc3)cc21]

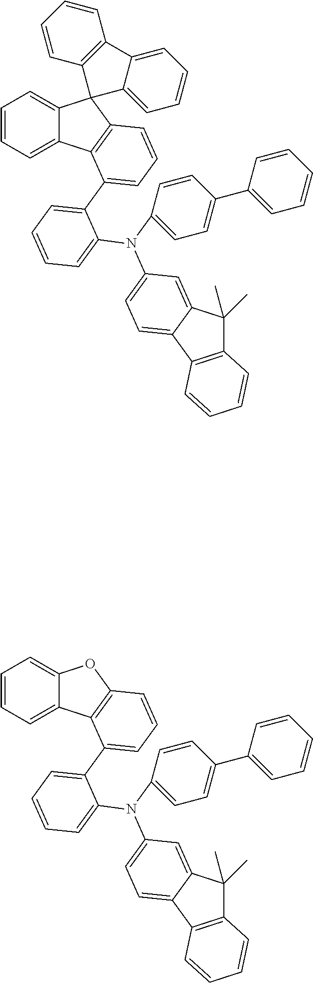 [SMILES: CC1(C)c2ccccc2-c2ccc(N(c3ccc(-c4ccccc4)cc3)c3ccccc3-c3cccc4c3-c3ccccc3C43c4ccccc4-c4ccccc43)cc21 ; CC1(C)c2ccccc2-c2ccc(N(c3ccc(-c4ccccc4)cc3)c3ccccc3-c3cccc4oc5ccccc5c34)cc21]

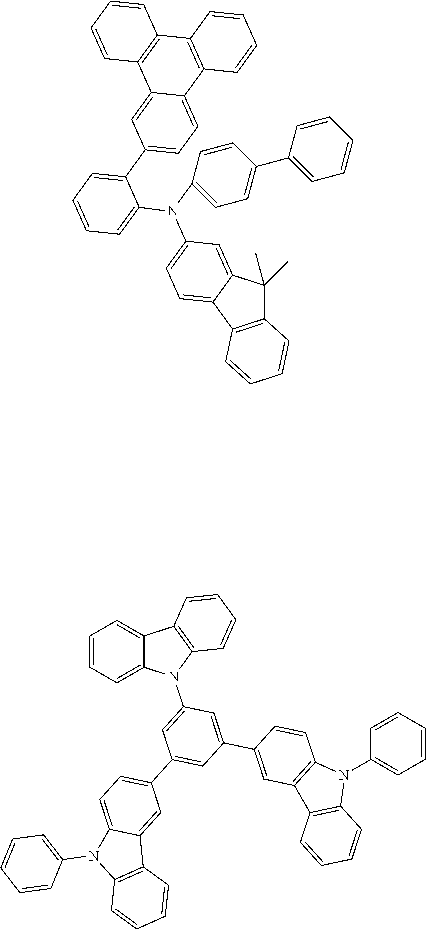 [SMILES: CC1(C)c2ccccc2-c2ccc(N(c3ccc(-c4ccccc4)cc3)c3ccccc3-c3ccc4c5ccccc5c5ccccc5c4c3)cc21 ; c1ccc(-n2c3ccccc3c3cc(-c4cc(-c5ccc6c(c5)c5ccccc5n6-c5ccccc5)cc(-n5c6ccccc6c6ccccc65)c4)ccc32)cc1]

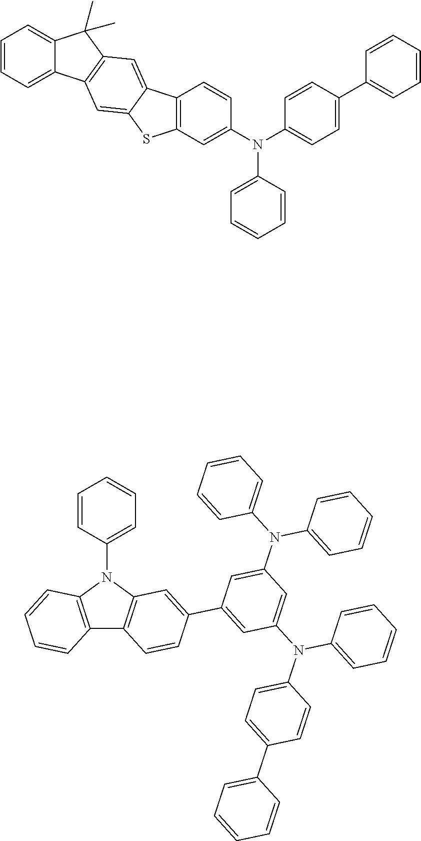 [SMILES: CC1(C)c2ccccc2-c2cc3sc4cc(N(c5ccccc5)c5ccc(-c6ccccc6)cc5)ccc4c3cc21 ; c1ccc(-c2ccc(N(c3ccccc3)c3cc(-c4ccc5c6ccccc6n(-c6ccccc6)c5c4)cc(N(c4ccccc4)c4ccccc4)c3)cc2)cc1]

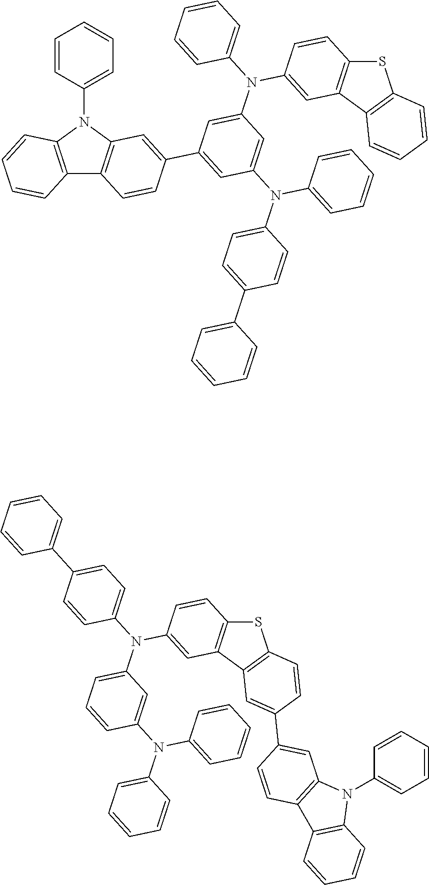 [SMILES: c1ccc(-c2ccc(N(c3ccccc3)c3cc(-c4ccc5c6ccccc6n(-c6ccccc6)c5c4)cc(N(c4ccccc4)c4ccc5sc6ccccc6c5c4)c3)cc2)cc1 ; c1ccc(-c2ccc(N(c3cccc(N(c4ccccc4)c4ccccc4)c3)c3ccc4sc5ccc(-c6ccc7c8ccccc8n(-c8ccccc8)c7c6)cc5c4c3)cc2)cc1]

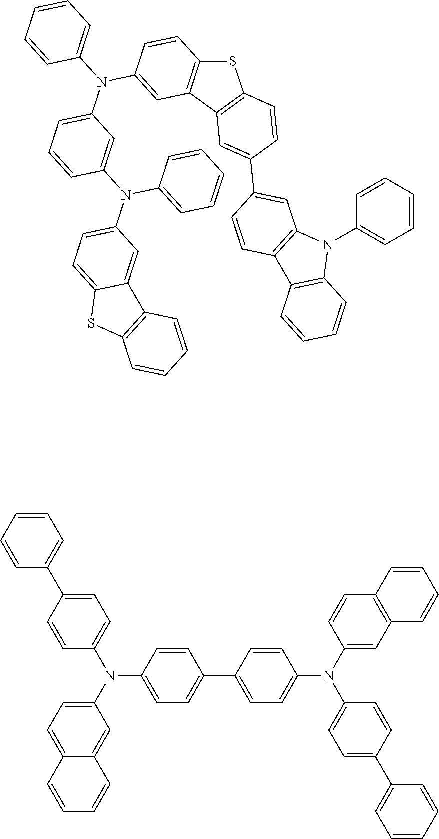 [SMILES: c1ccc(N(c2cccc(N(c3ccccc3)c3ccc4sc5ccc(-c6ccc7c8ccccc8n(-c8ccccc8)c7c6)cc5c4c3)c2)c2ccc3sc4ccccc4c3c2)cc1 ; c1ccc(-c2ccc(N(c3ccc(-c4ccc(N(c5ccc(-c6ccccc6)cc5)c5ccc6ccccc6c5)cc4)cc3)c3ccc4ccccc4c3)cc2)cc1]

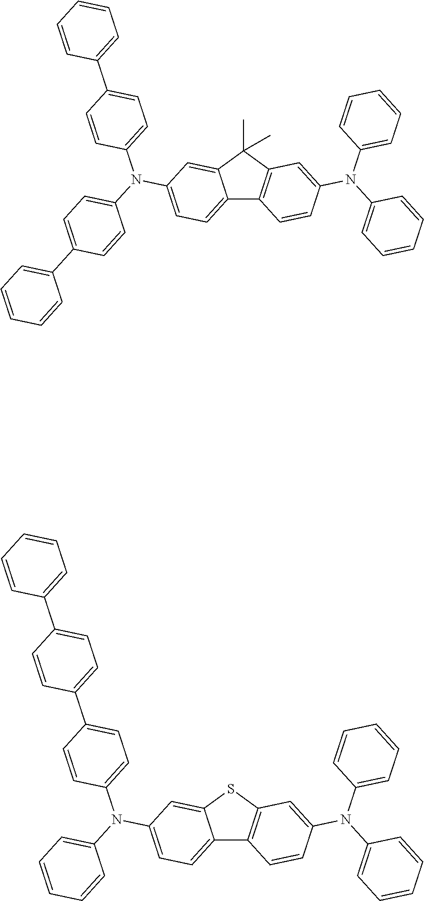 [SMILES: CC1(C)c2cc(N(c3ccccc3)c3ccccc3)ccc2-c2ccc(N(c3ccc(-c4ccccc4)cc3)c3ccc(-c4ccccc4)cc3)cc21 ; c1ccc(-c2ccc(-c3ccc(N(c4ccccc4)c4ccc5c(c4)sc4cc(N(c6ccccc6)c6ccccc6)ccc45)cc3)cc2)cc1]

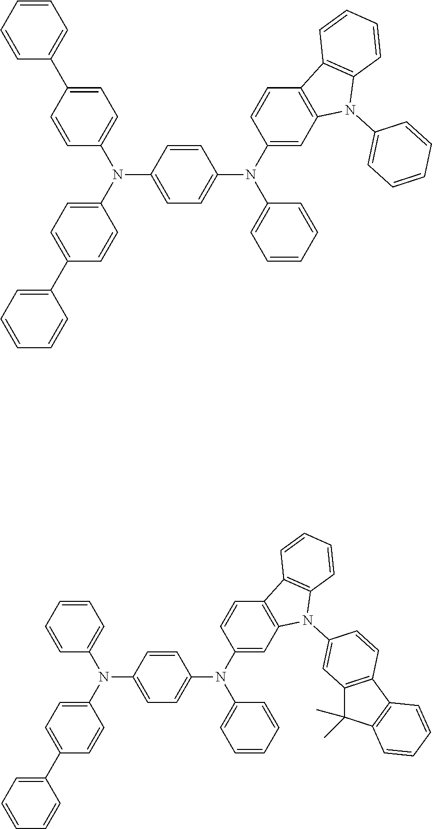 [SMILES: c1ccc(-c2ccc(N(c3ccc(-c4ccccc4)cc3)c3ccc(N(c4ccccc4)c4ccc5c6ccccc6n(-c6ccccc6)c5c4)cc3)cc2)cc1 ; CC1(C)c2ccccc2-c2ccc(-n3c4ccccc4c4ccc(N(c5ccccc5)c5ccc(N(c6ccccc6)c6ccc(-c7ccccc7)cc6)cc5)cc43)cc21]

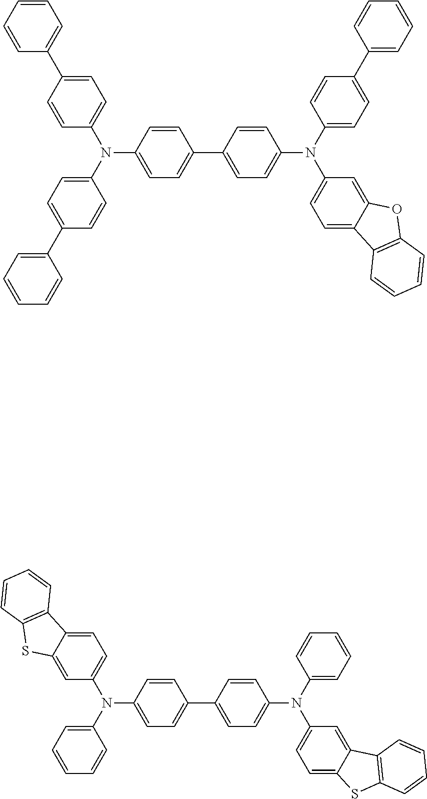 [SMILES: c1ccc(-c2ccc(N(c3ccc(-c4ccccc4)cc3)c3ccc(-c4ccc(N(c5ccc(-c6ccccc6)cc5)c5ccc6c(c5)oc5ccccc56)cc4)cc3)cc2)cc1 ; c1ccc(N(c2ccc(-c3ccc(N(c4ccccc4)c4ccc5sc6ccccc6c5c4)cc3)cc2)c2ccc3c(c2)sc2ccccc23)cc1]

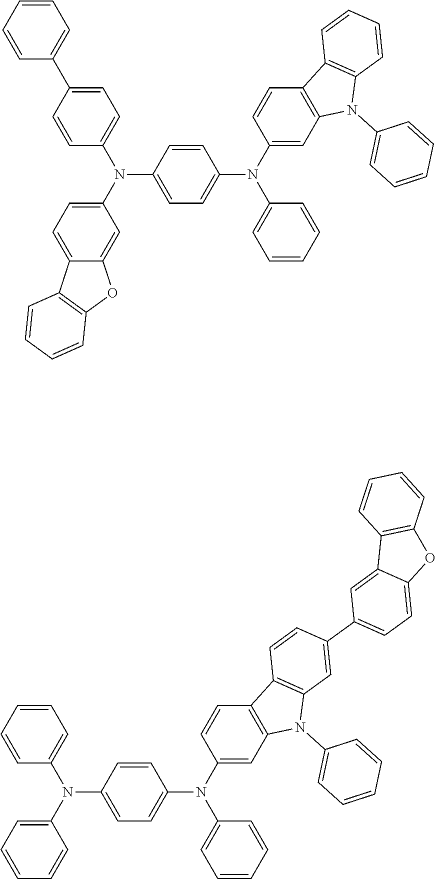 [SMILES: c1ccc(-c2ccc(N(c3ccc(N(c4ccccc4)c4ccc5c6ccccc6n(-c6ccccc6)c5c4)cc3)c3ccc4c(c3)oc3ccccc34)cc2)cc1 ; c1ccc(N(c2ccccc2)c2ccc(N(c3ccccc3)c3ccc4c5ccc(-c6ccc7oc8ccccc8c7c6)cc5n(-c5ccccc5)c4c3)cc2)cc1]

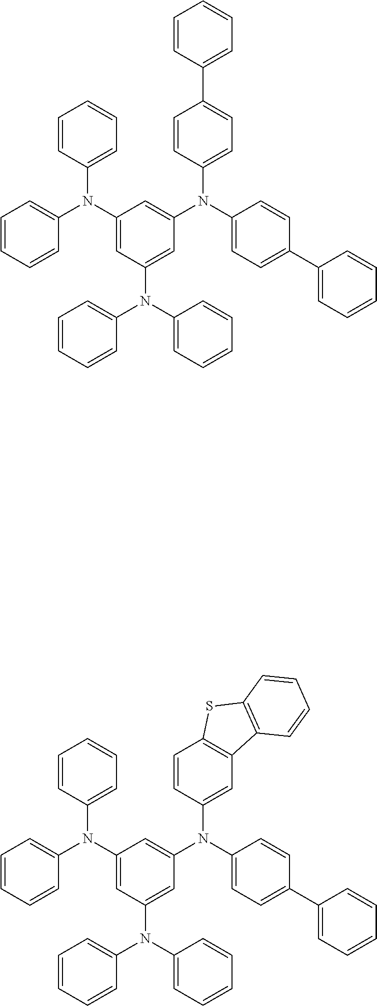 [SMILES: c1ccc(-c2ccc(N(c3ccc(-c4ccccc4)cc3)c3cc(N(c4ccccc4)c4ccccc4)cc(N(c4ccccc4)c4ccccc4)c3)cc2)cc1 ; c1ccc(-c2ccc(N(c3cc(N(c4ccccc4)c4ccccc4)cc(N(c4ccccc4)c4ccccc4)c3)c3ccc4sc5ccccc5c4c3)cc2)cc1]

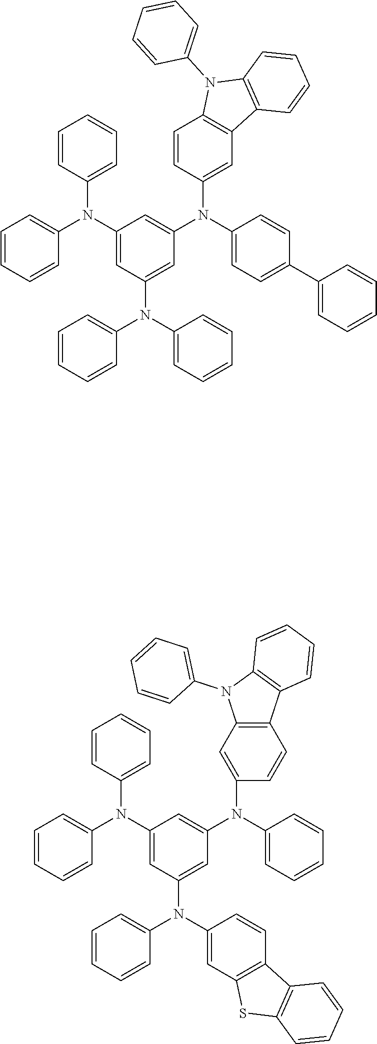 [SMILES: c1ccc(-c2ccc(N(c3cc(N(c4ccccc4)c4ccccc4)cc(N(c4ccccc4)c4ccccc4)c3)c3ccc4c(c3)c3ccccc3n4-c3ccccc3)cc2)cc1 ; c1ccc(N(c2ccccc2)c2cc(N(c3ccccc3)c3ccc4c(c3)sc3ccccc34)cc(N(c3ccccc3)c3ccc4c5ccccc5n(-c5ccccc5)c4c3)c2)cc1]

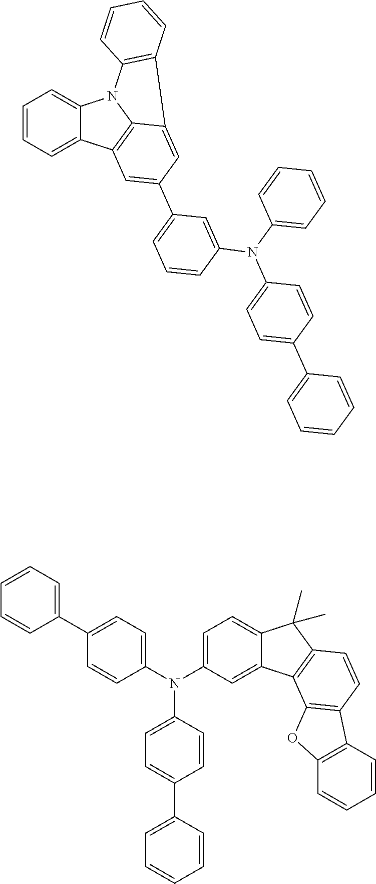 [SMILES: c1ccc(-c2ccc(N(c3ccccc3)c3cccc(-c4cc5c6ccccc6n6c7ccccc7c(c4)c56)c3)cc2)cc1 ; CC1(C)c2ccc(N(c3ccc(-c4ccccc4)cc3)c3ccc(-c4ccccc4)cc3)cc2-c2c1ccc1c2oc2ccccc21]

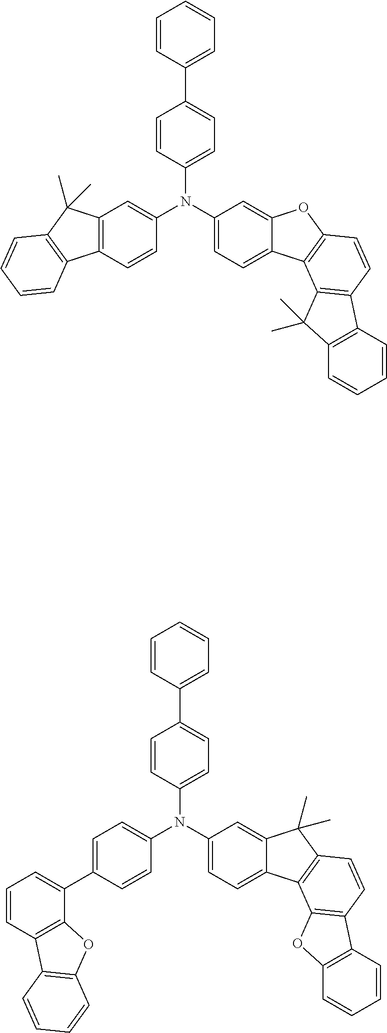 [SMILES: CC1(C)c2ccccc2-c2ccc(N(c3ccc(-c4ccccc4)cc3)c3ccc4c(c3)oc3ccc5c(c34)C(C)(C)c3ccccc3-5)cc21 ; CC1(C)c2cc(N(c3ccc(-c4ccccc4)cc3)c3ccc(-c4cccc5c4oc4ccccc45)cc3)ccc2-c2c1ccc1c2oc2ccccc21]

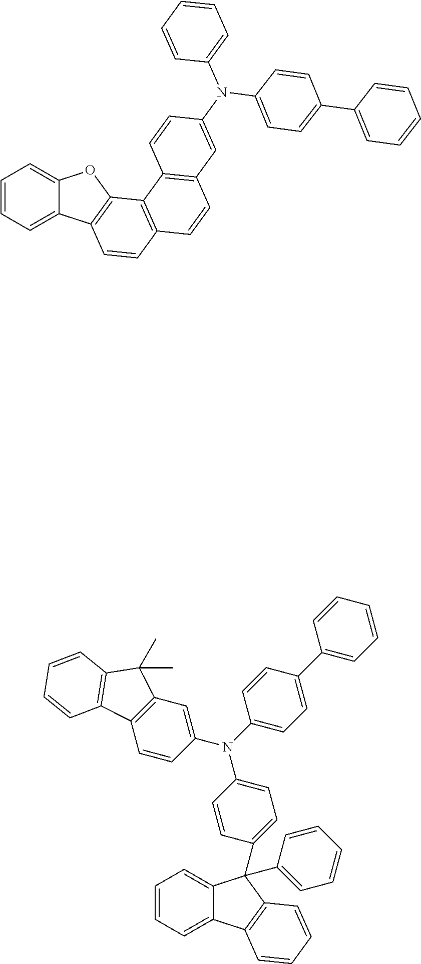 [SMILES: c1ccc(-c2ccc(N(c3ccccc3)c3ccc4c(ccc5ccc6c7ccccc7oc6c54)c3)cc2)cc1 ; CC1(C)c2ccccc2-c2ccc(N(c3ccc(-c4ccccc4)cc3)c3ccc(C4(c5ccccc5)c5ccccc5-c5ccccc54)cc3)cc21]

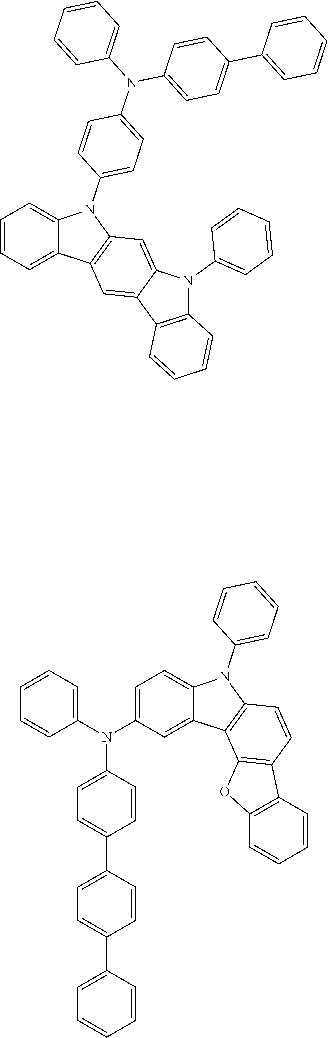 [SMILES: c1ccc(-c2ccc(N(c3ccccc3)c3ccc(-n4c5ccccc5c5cc6c7ccccc7n(-c7ccccc7)c6cc54)cc3)cc2)cc1 ; c1ccc(-c2ccc(-c3ccc(N(c4ccccc4)c4ccc5c(c4)c4c6oc7ccccc7c6ccc4n5-c4ccccc4)cc3)cc2)cc1]

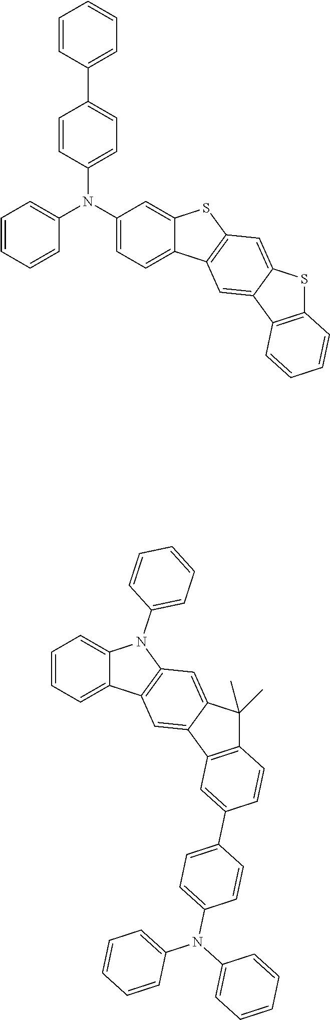 [SMILES: c1ccc(-c2ccc(N(c3ccccc3)c3ccc4c(c3)sc3cc5sc6ccccc6c5cc34)cc2)cc1 ; CC1(C)c2ccc(-c3ccc(N(c4ccccc4)c4ccccc4)cc3)cc2-c2cc3c4ccccc4n(-c4ccccc4)c3cc21]

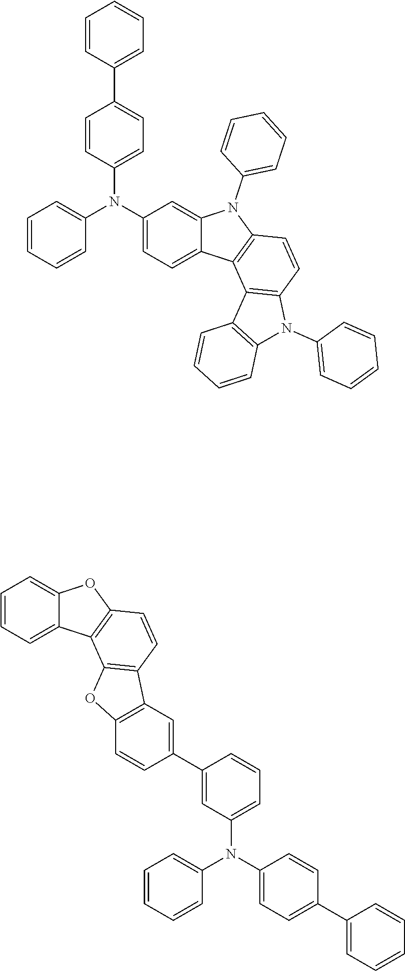 [SMILES: c1ccc(-c2ccc(N(c3ccccc3)c3ccc4c5c6c7ccccc7n(-c7ccccc7)c6ccc5n(-c5ccccc5)c4c3)cc2)cc1 ; c1ccc(-c2ccc(N(c3ccccc3)c3cccc(-c4ccc5oc6c(ccc7oc8ccccc8c76)c5c4)c3)cc2)cc1]

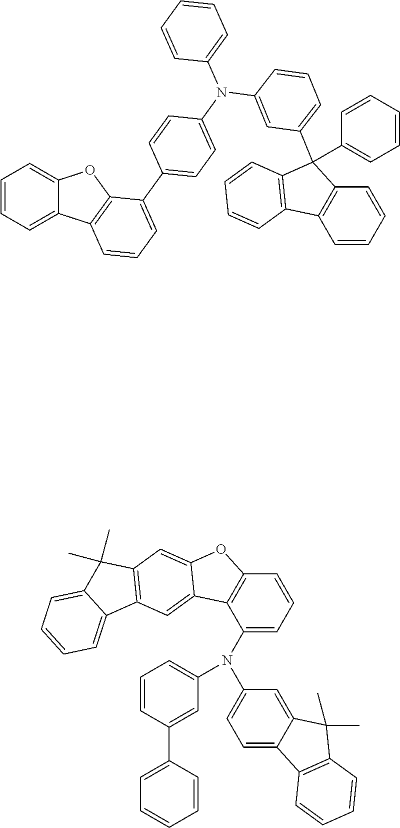 [SMILES: c1ccc(N(c2ccc(-c3cccc4c3oc3ccccc34)cc2)c2cccc(C3(c4ccccc4)c4ccccc4-c4ccccc43)c2)cc1 ; CC1(C)c2ccccc2-c2ccc(N(c3cccc(-c4ccccc4)c3)c3cccc4oc5cc6c(cc5c34)-c3ccccc3C6(C)C)cc21]

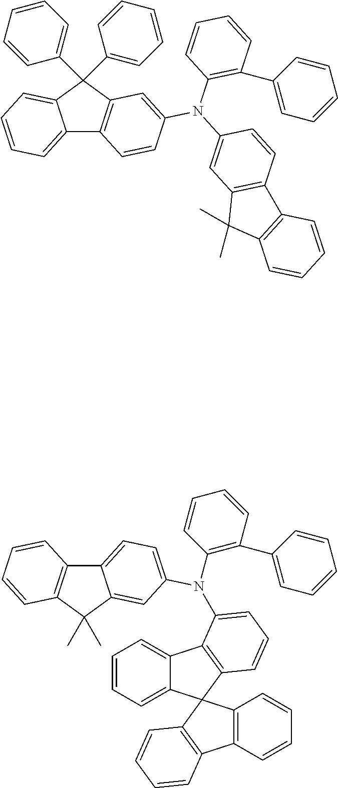 [SMILES: CC1(C)c2ccccc2-c2ccc(N(c3ccc4c(c3)C(c3ccccc3)(c3ccccc3)c3ccccc3-4)c3ccccc3-c3ccccc3)cc21 ; CC1(C)c2ccccc2-c2ccc(N(c3ccccc3-c3ccccc3)c3cccc4c3-c3ccccc3C43c4ccccc4-c4ccccc43)cc21]

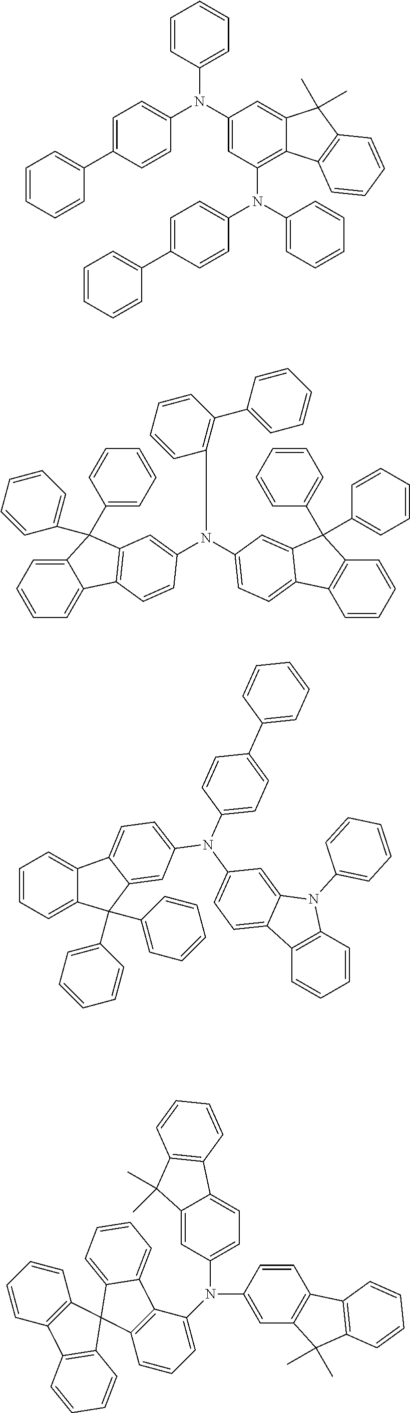 [SMILES: CC1(C)c2ccccc2-c2c(N(c3ccccc3)c3ccc(-c4ccccc4)cc3)cc(N(c3ccccc3)c3ccc(-c4ccccc4)cc3)cc21 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; c1ccc(-c2ccc(N(c3ccc4c(c3)C(c3ccccc3)(c3ccccc3)c3ccccc3-4)c3ccc4c5ccccc5n(-c5ccccc5)c4c3)cc2)cc1 ; CC1(C)c2ccccc2-c2ccc(N(c3ccc4c(c3)C(C)(C)c3ccccc3-4)c3cccc4c3-c3ccccc3C43c4ccccc4-c4ccccc43)cc21]

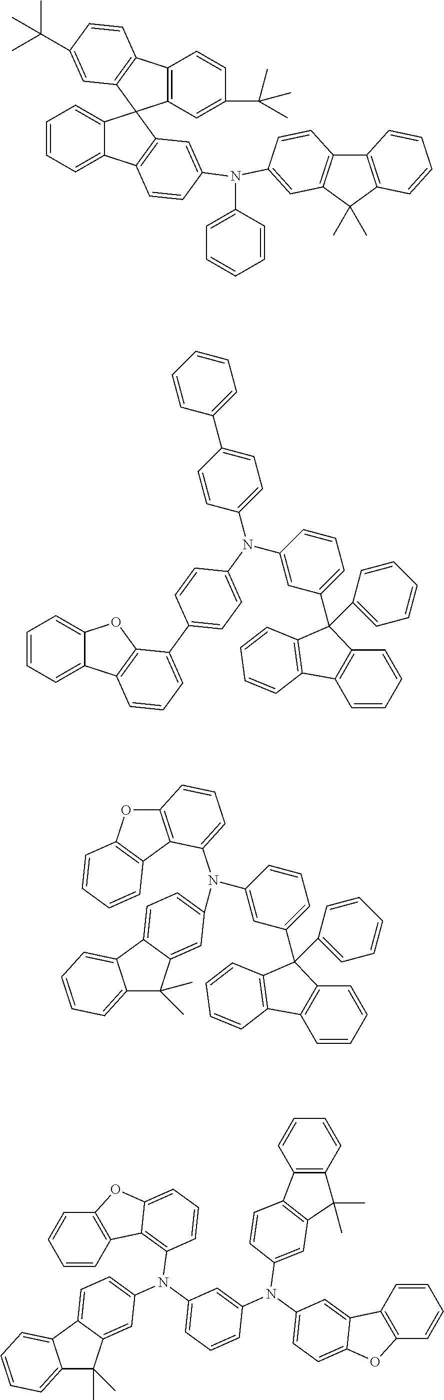 [SMILES: CC(C)(C)c1ccc2c(c1)C1(c3ccccc3-c3ccc(N(c4ccccc4)c4ccc5c(c4)C(C)(C)c4ccccc4-5)cc31)c1cc(C(C)(C)C)ccc1-2 ; c1ccc(-c2ccc(N(c3ccc(-c4cccc5c4oc4ccccc45)cc3)c3cccc(C4(c5ccccc5)c5ccccc5-c5ccccc54)c3)cc2)cc1 ; CC1(C)c2ccccc2-c2ccc(N(c3cccc(C4(c5ccccc5)c5ccccc5-c5ccccc54)c3)c3cccc4oc5ccccc5c34)cc21 ; CC1(C)c2ccccc2-c2ccc(N(c3cccc(N(c4ccc5c(c4)C(C)(C)c4ccccc4-5)c4cccc5oc6ccccc6c45)c3)c3ccc4oc5ccccc5c4c3)cc21]

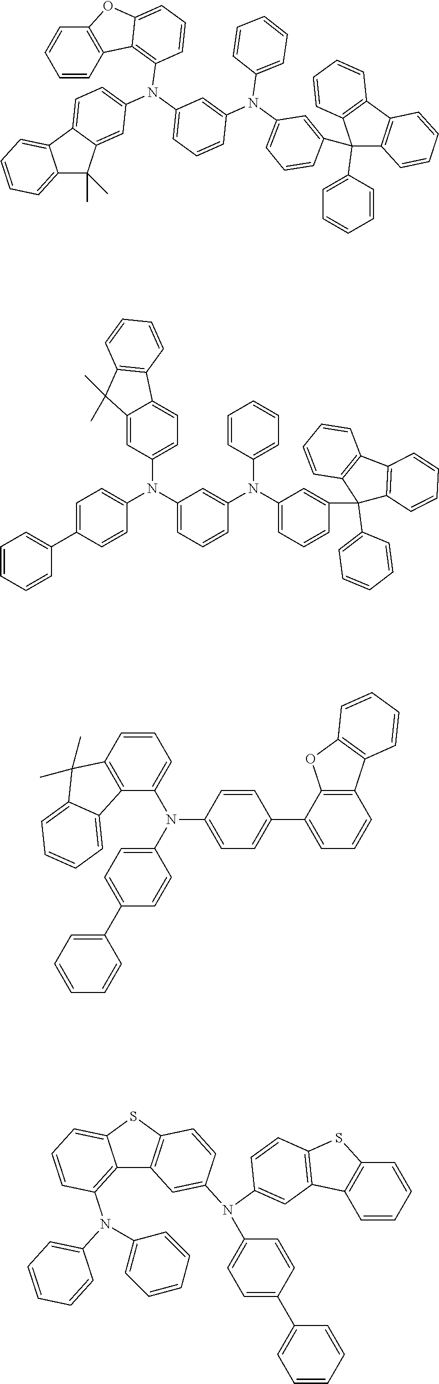 [SMILES: CC1(C)c2ccccc2-c2ccc(N(c3cccc(N(c4ccccc4)c4cccc(C5(c6ccccc6)c6ccccc6-c6ccccc65)c4)c3)c3cccc4oc5ccccc5c34)cc21 ; CC1(C)c2ccccc2-c2ccc(N(c3ccc(-c4ccccc4)cc3)c3cccc(N(c4ccccc4)c4cccc(C5(c6ccccc6)c6ccccc6-c6ccccc65)c4)c3)cc21 ; CC1(C)c2ccccc2-c2c(N(c3ccc(-c4ccccc4)cc3)c3ccc(-c4cccc5c4oc4ccccc45)cc3)cccc21 ; c1ccc(-c2ccc(N(c3ccc4sc5ccccc5c4c3)c3ccc4sc5cccc(N(c6ccccc6)c6ccccc6)c5c4c3)cc2)cc1]

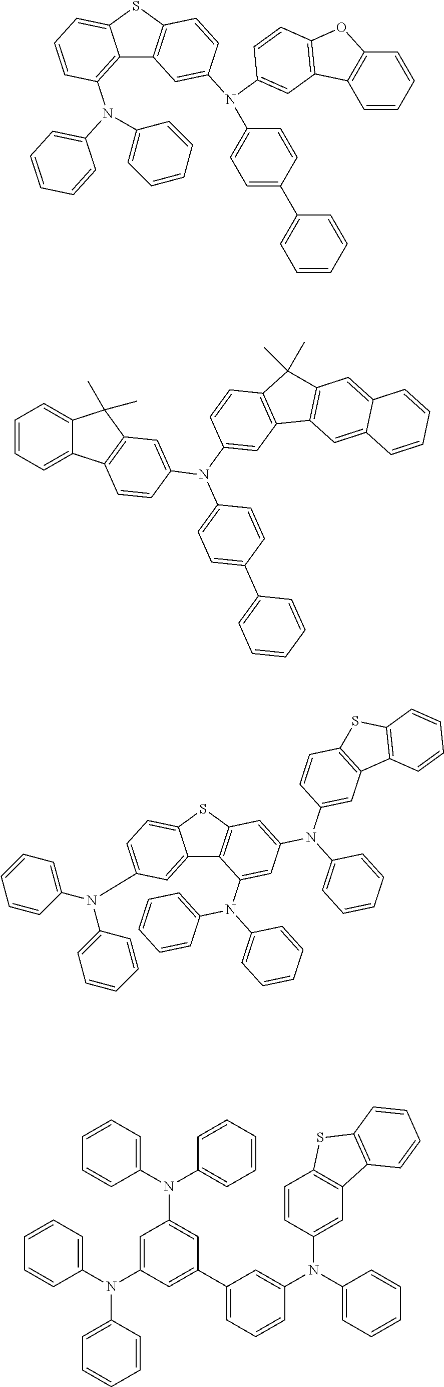 [SMILES: c1ccc(-c2ccc(N(c3ccc4oc5ccccc5c4c3)c3ccc4sc5cccc(N(c6ccccc6)c6ccccc6)c5c4c3)cc2)cc1 ; CC1(C)c2ccccc2-c2ccc(N(c3ccc(-c4ccccc4)cc3)c3ccc4c(c3)-c3cc5ccccc5cc3C4(C)C)cc21 ; c1ccc(N(c2cc(N(c3ccccc3)c3ccccc3)c3c(c2)sc2ccc(N(c4ccccc4)c4ccccc4)cc23)c2ccc3sc4ccccc4c3c2)cc1 ; c1ccc(N(c2ccccc2)c2cc(-c3cccc(N(c4ccccc4)c4ccc5sc6ccccc6c5c4)c3)cc(N(c3ccccc3)c3ccccc3)c2)cc1]

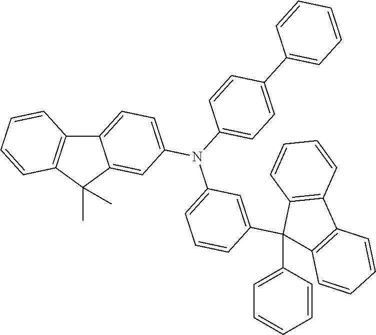 [SMILES: CC1(C)c2ccccc2-c2ccc(N(c3ccc(-c4ccccc4)cc3)c3cccc(C4(c5ccccc5)c5ccccc5-c5ccccc54)c3)cc21]

In the hole transport region, in addition to the compounds described above, known compounds disclosed in U.S. Pat. No. 5,061,569A, JP1993-009471A, WO1995-009147A1, JP1995-126615A, JP1998-095973A, etc. and compounds having a similar structure may also be used.

Also, the charge transport region may be, for example, the electron transport region 150.

The electron transport region 150 may further increase electron injection and/or electron mobility and block holes between the cathode 110 and the light emitting layer 130.

Specifically, the electron transport region 150 may include an electron transport layer between the cathode 110 and the light emitting layer 130, and an electron transport auxiliary layer between the light emitting layer 130 and the electron transport layer, and at least one of the compounds of Group C may be included in at least one of the electron transport layer and the electron transport auxiliary layer.

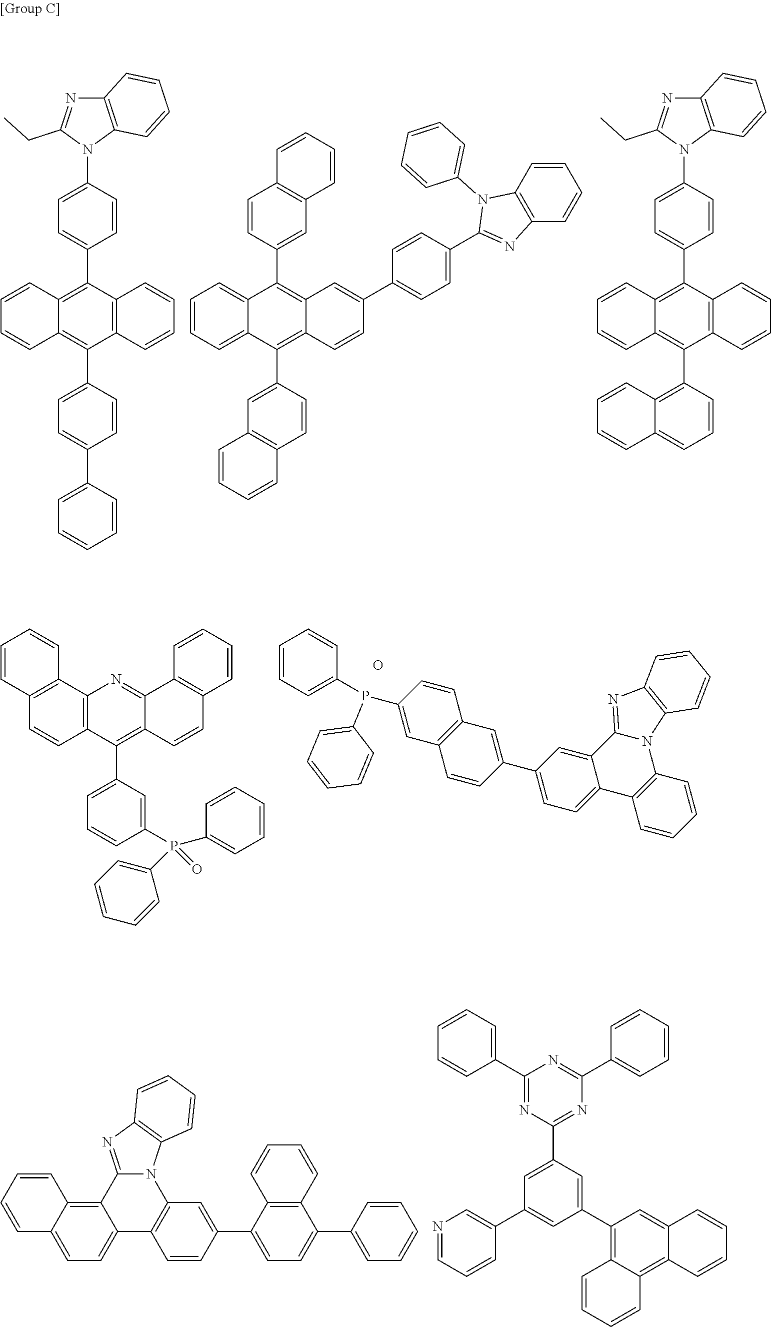

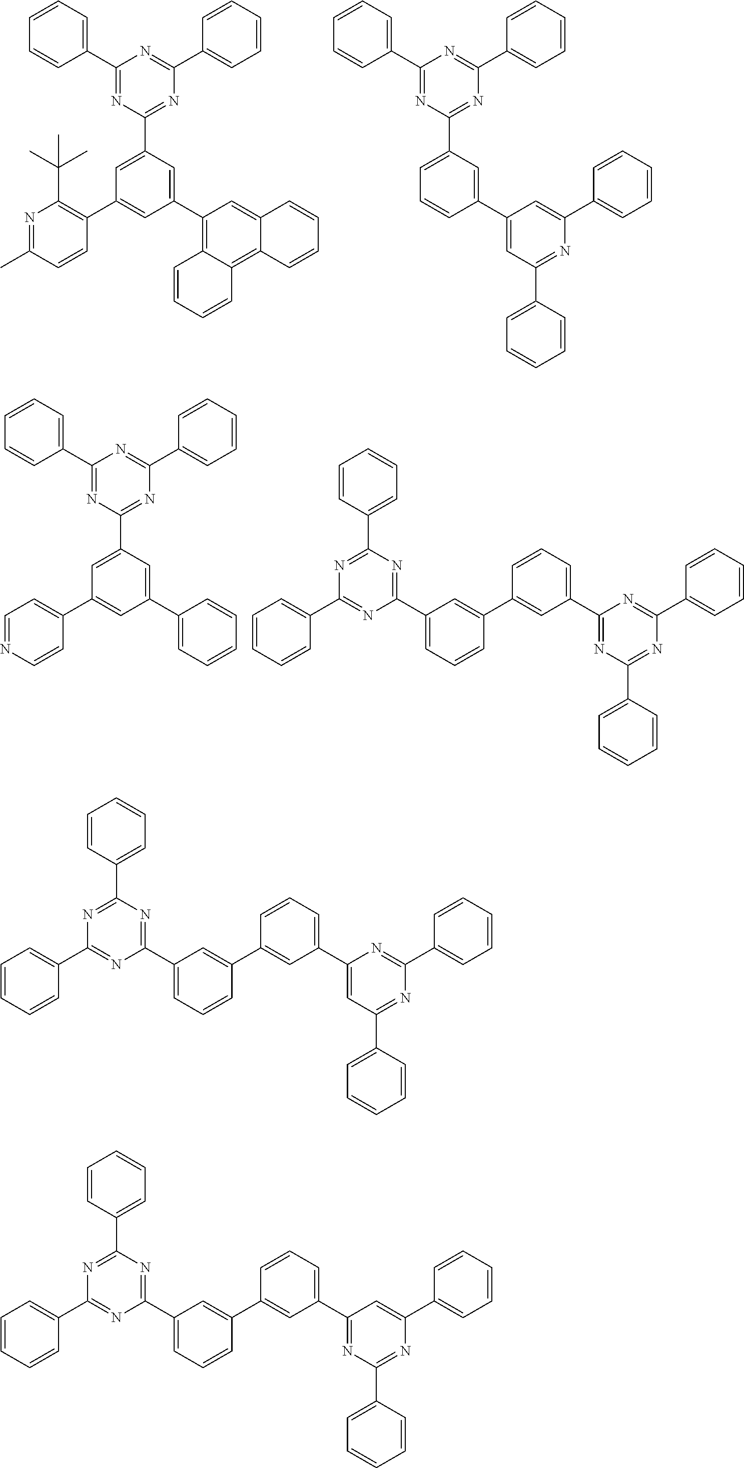

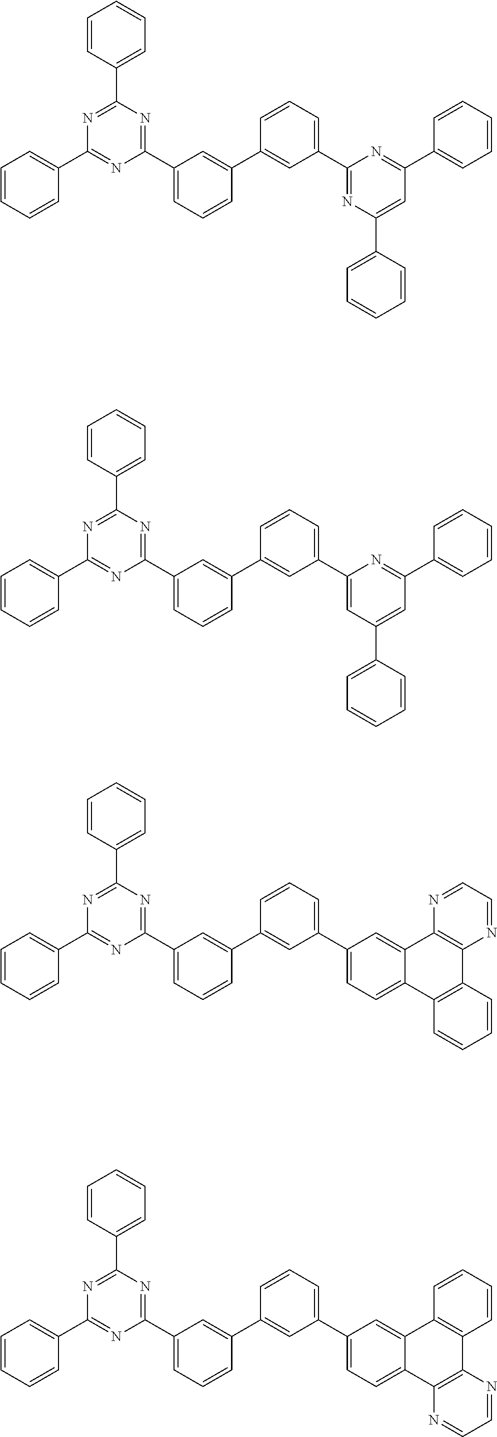 [SMILES: c1ccc(-c2cc(-c3ccccc3)nc(-c3cccc(-c4cccc(-c5nc(-c6ccccc6)nc(-c6ccccc6)n5)c4)c3)n2)cc1 ; c1ccc(-c2cc(-c3ccccc3)nc(-c3cccc(-c4cccc(-c5nc(-c6ccccc6)nc(-c6ccccc6)n5)c4)c3)c2)cc1 ; c1ccc(-c2nc(-c3ccccc3)nc(-c3cccc(-c4cccc(-c5ccc6c7ccccc7c7nccnc7c6c5)c4)c3)n2)cc1 ; c1ccc(-c2nc(-c3ccccc3)nc(-c3cccc(-c4cccc(-c5ccc6c(c5)c5ccccc5c5nccnc65)c4)c3)n2)cc1]

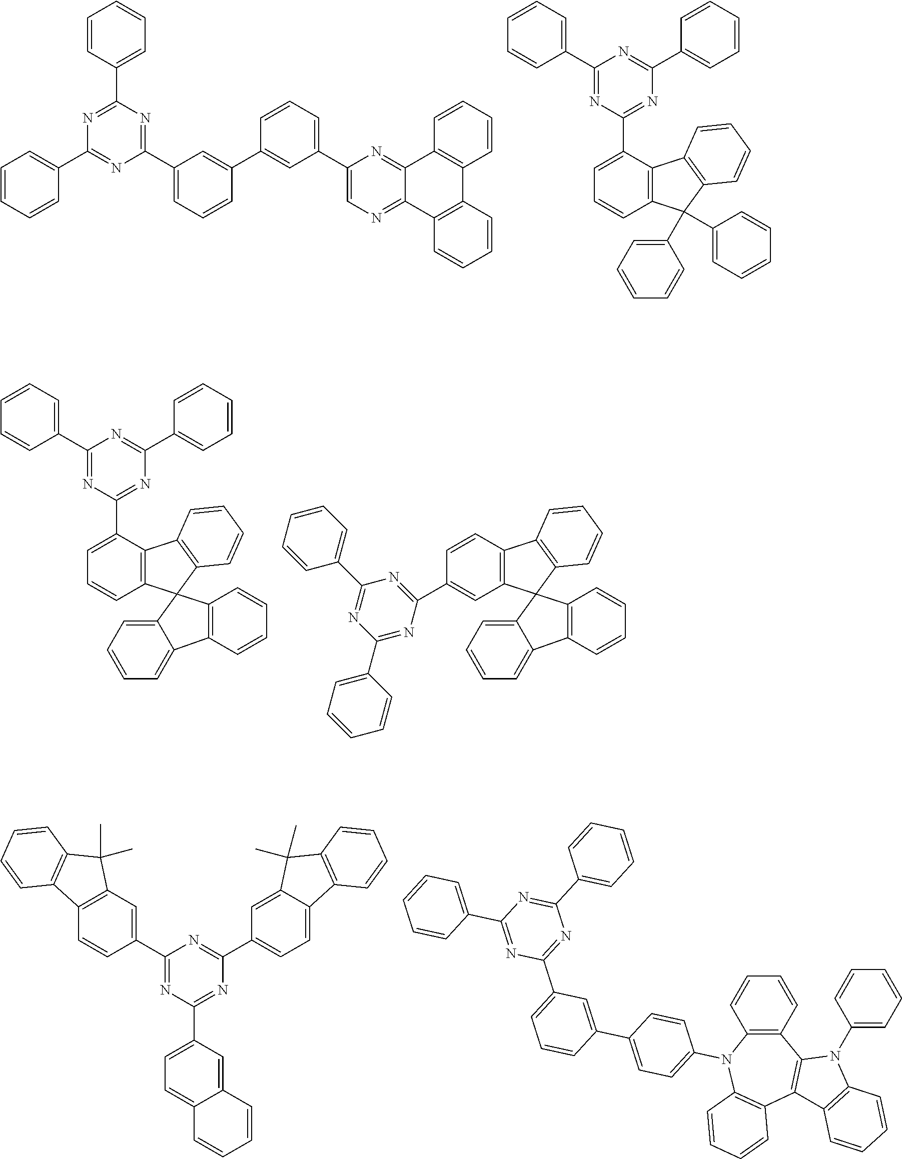

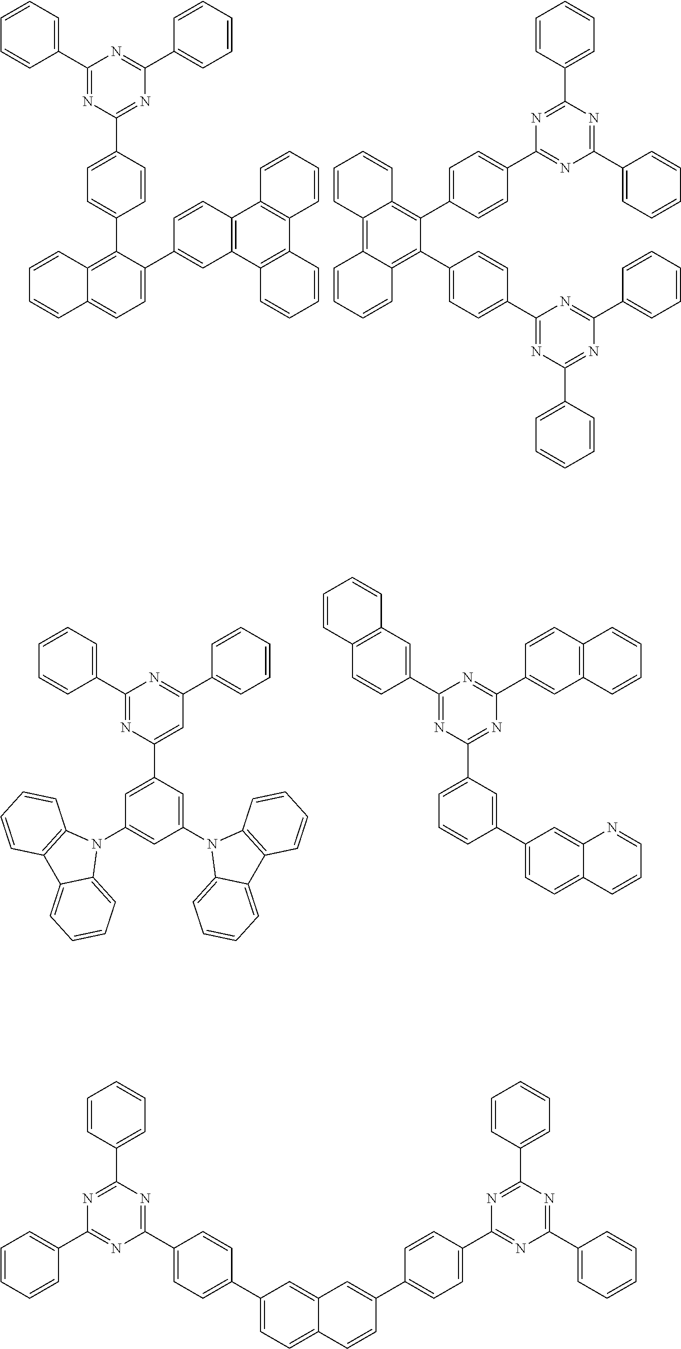

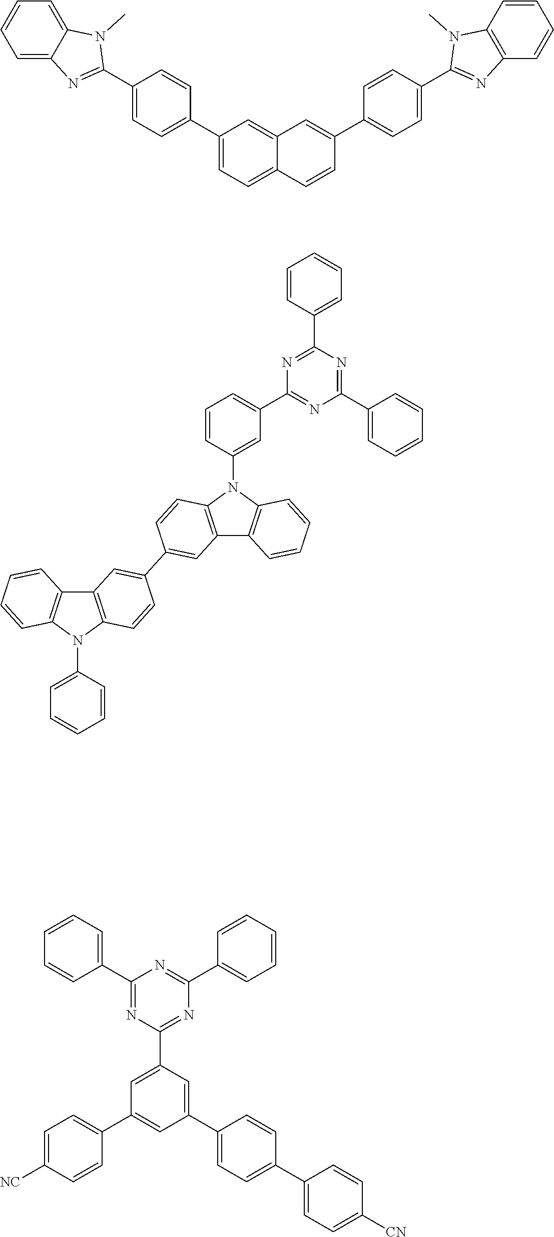 [SMILES: Cn1c(-c2ccc(-c3ccc4ccc(-c5ccc(-c6nc7ccccc7n6C)cc5)cc4c3)cc2)nc2ccccc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; N#Cc1ccc(-c2ccc(-c3cc(-c4ccc(C#N)cc4)cc(-c4nc(-c5ccccc5)nc(-c5ccccc5)n4)c3)cc2)cc1]

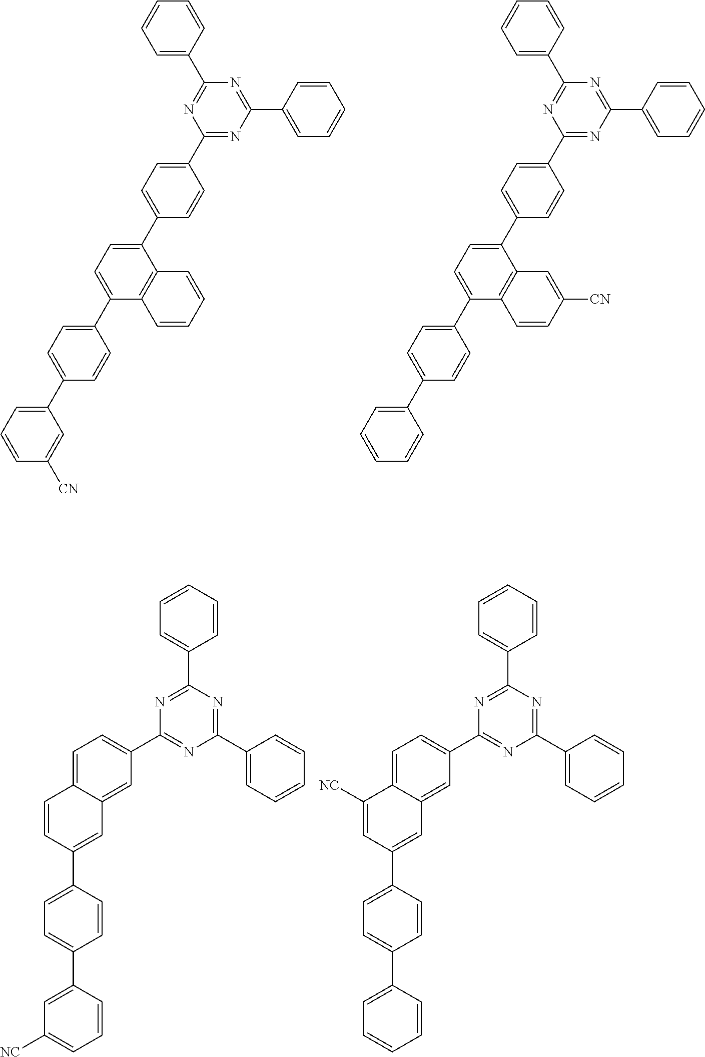

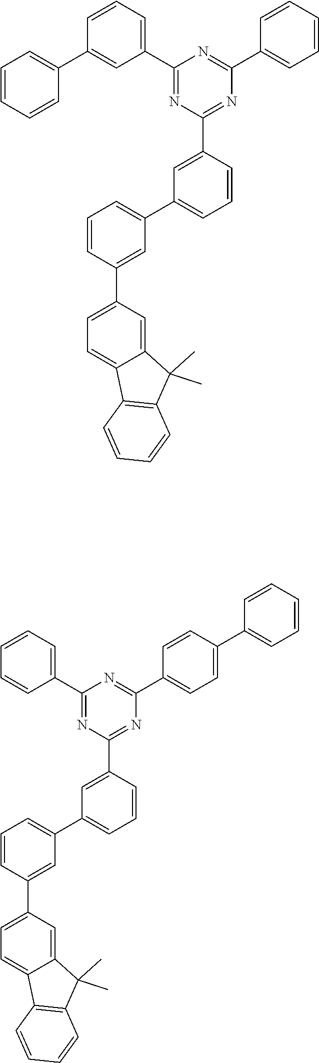 [SMILES: CC1(C)c2ccccc2-c2ccc(-c3cccc(-c4cccc(-c5nc(-c6ccccc6)nc(-c6cccc(-c7ccccc7)c6)n5)c4)c3)cc21 ; CC1(C)c2ccccc2-c2ccc(-c3cccc(-c4cccc(-c5nc(-c6ccccc6)nc(-c6ccc(-c7ccccc7)cc6)n5)c4)c3)cc21]

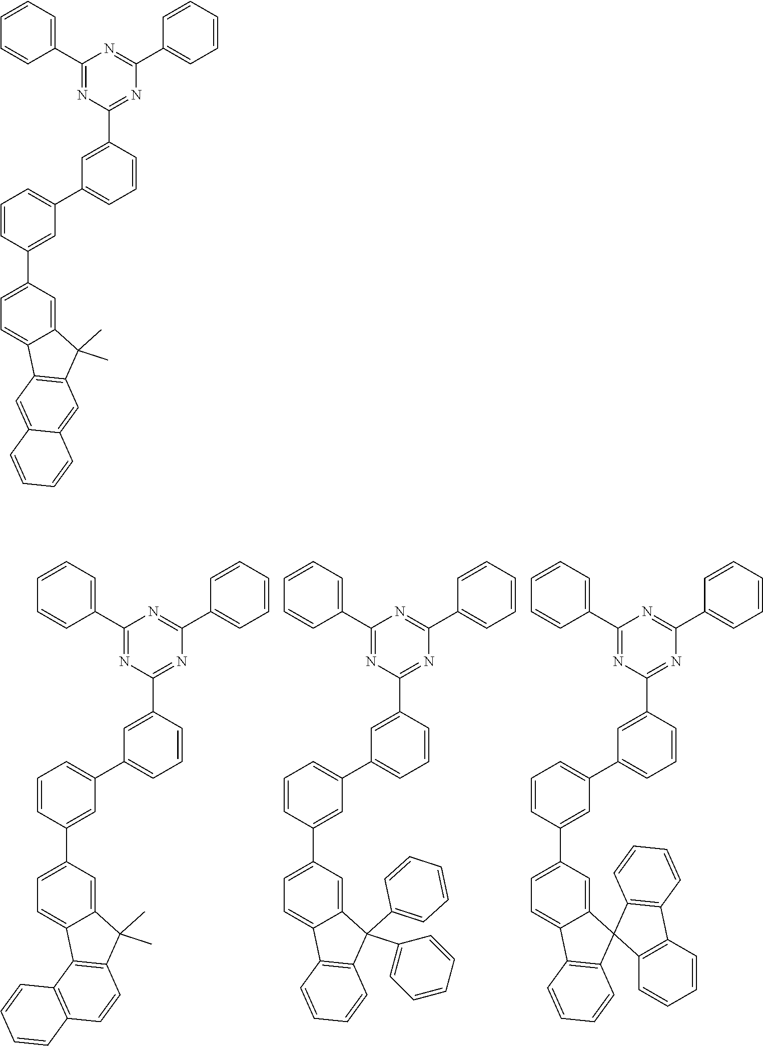

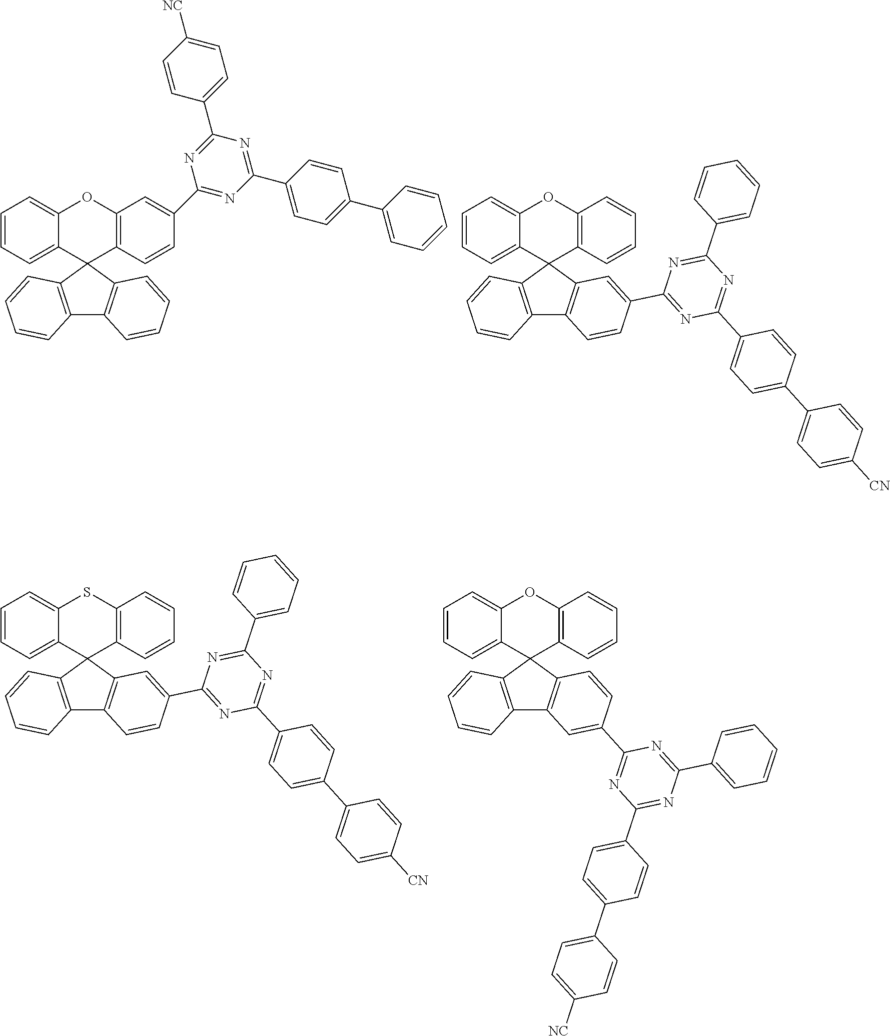

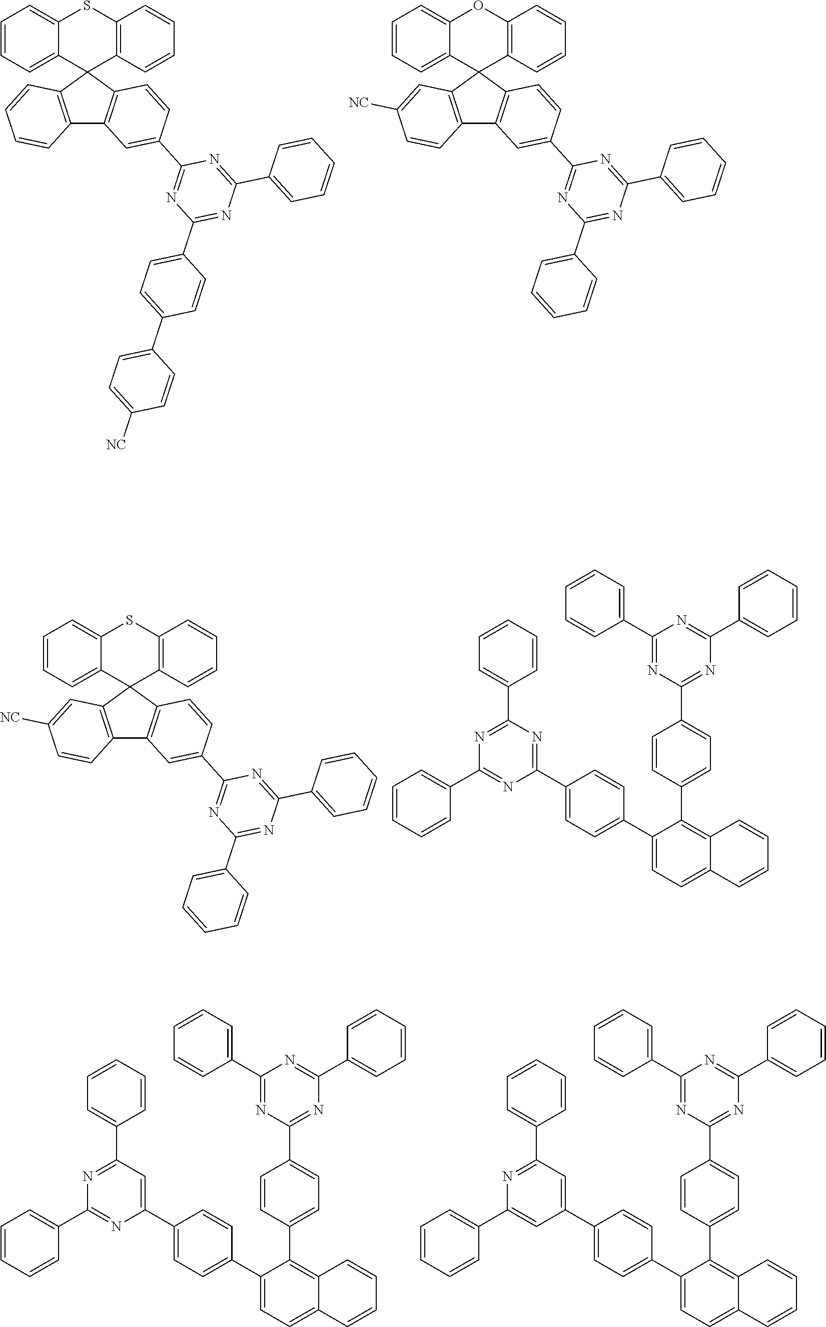

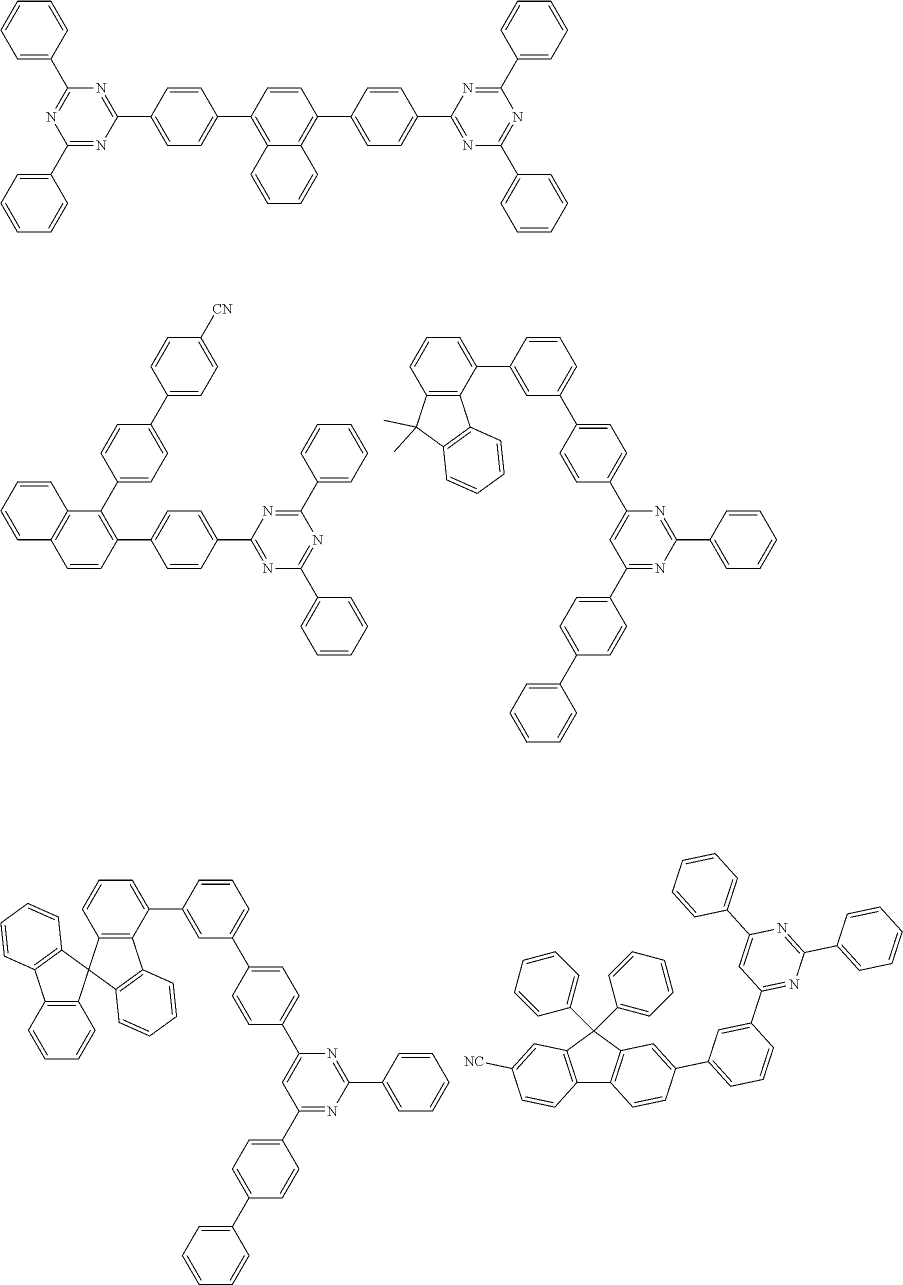

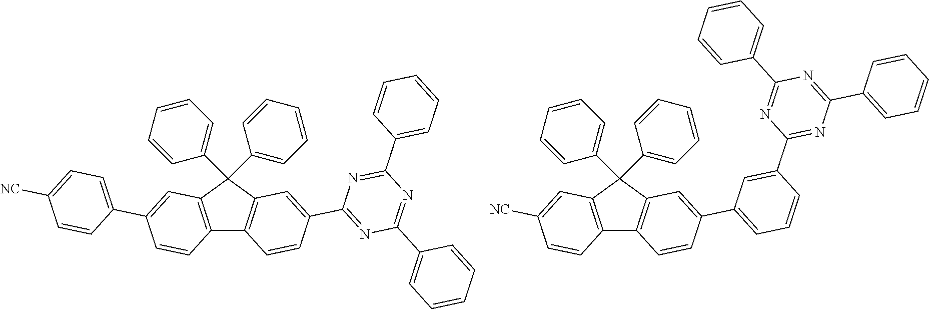 [SMILES: N#Cc1ccc(-c2ccc3c(c2)C(c2ccccc2)(c2ccccc2)c2cc(-c4nc(-c5ccccc5)nc(-c5ccccc5)n4)ccc2-3)cc1 ; N#Cc1ccc2c(c1)C(c1ccccc1)(c1ccccc1)c1cc(-c3cccc(-c4nc(-c5ccccc5)nc(-c5ccccc5)n4)c3)ccc1-2]

An embodiment of the present invention may provide an organic light emitting diode including the light emitting layer as the organic layer.

Another embodiment of the present invention may provide an organic light emitting diode including a hole transport region in addition to the light emitting layer as the organic layer.

Another embodiment of the present invention may provide an organic light emitting diode including an electron transport region in addition to the light emitting layer as the organic layer.

Another embodiment of the present invention may provide an organic light emitting diode including a hole transport region 140 and an electron transport region 150 in addition to the light emitting layer 130 as the organic layer 105, as shown in FIG. 1.

In another embodiment of the present invention, an organic light emitting diode may further include an electron injection layer (not shown), a hole injection layer (not shown), etc. in addition to the light emitting layer as the organic layer.

The organic light emitting diode 100 may be manufactured by forming an anode or a cathode on a substrate, and then forming an organic layer by a dry film method such as vacuum deposition, sputtering, plasma plating and ion plating, and forming a cathode or an anode thereon.

The organic light emitting diode may be applied to an organic light emitting display device.

Hereinafter, the embodiments are illustrated in more detail with reference to examples. However, these examples are exemplary, and the present scope is not limited thereto.

### DETAILED DESCRIPTION OF THE EMBODIMENTS

Hereinafter, starting materials and reactants used in examples and synthesis examples were purchased from Sigma-Aldrich Co. Ltd., TCI Inc., Tokyo chemical industry, or P&H tech as far as there is no particular comment or were synthesized by known methods.

### Preparation of Compound for Organic Optoelectronic Device

The compounds presented as a more specific example of the compound of the present invention were synthesized through the following steps.

### Synthesis Example 1: Synthesis of Compound 1-2

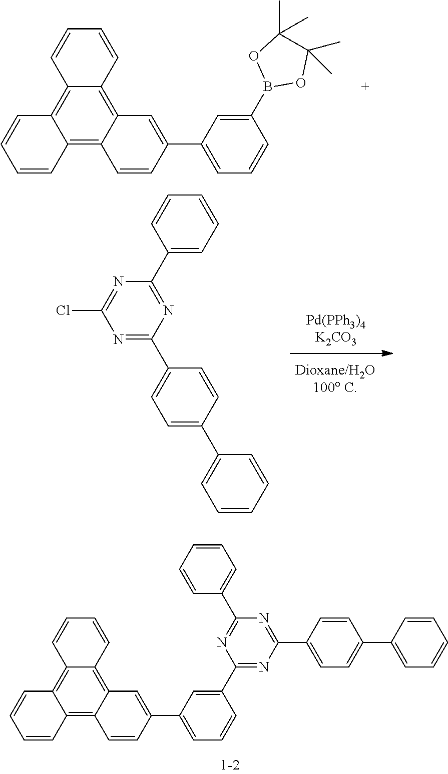

In a nitrogen environment, 4,4,5,5-tetramethyl-2-(3-(triphenylen-2-yl)phenyl)-1,3,2-dioxaborolane (20 g, 46.5 mmol) purchased from P&H Tech Co., Ltd. (http://www.phtech.co.kr/) was dissolved in 0.2 L of dioxane, and 2-(biphenyl-4-yl)-4-chloro-6-phenyl-1,3,5-triazine (16.0 g, 46.5 mmol) and tetrakis(triphenylphosphine)palladium (1.07 g, 0.93 mmol) purchased from Tokyo Chemical Industry Co., Ltd. (http://www.tcichemicals.com/) were added thereto and then, stirred. Subsequently, potassium carbonate (16.1 g, 116 mmol) saturated in water was added thereto and then, heated under reflux at 100° C. for 8 hours. When a reaction was completed, the reaction solution, after adding water thereto, was extracted with dichloromethane (DCM), treated with magnesium sulfate anhydrous to remove moisture, filtered, and concentrated under a reduced pressure. The obtained residue was separated and purified through flash column chromatography to obtain Compound 1-2 (27.0 g, 95%).

HRMS (70 eV, EI+): m/z calcd for C45H29N3: 611.2361, found: 611.

Elemental Analysis: C, 88%; H, 5%

### Synthesis Example 2: Synthesis of Compound 1-3

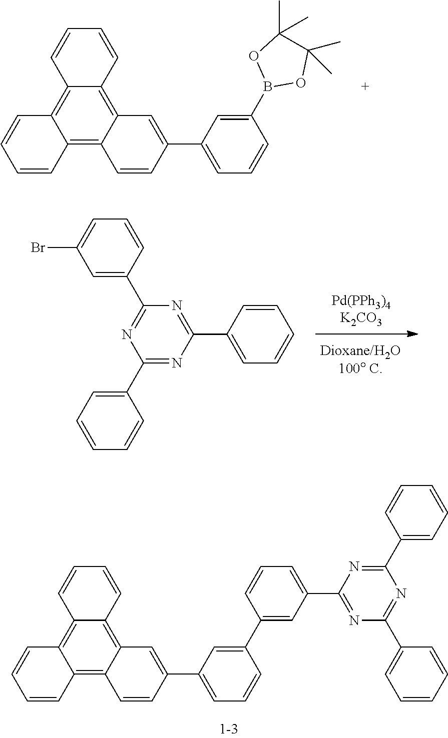

In a nitrogen environment, 4,4,5,5-tetramethyl-2-(3-(triphenylen-2-yl)phenyl)-1,3,2-dioxaborolane (20 g, 46.5 mmol) purchased from P&H Tech Co., Ltd. was dissolved in 0.2 L of dioxane, and 2-(3-bromophenyl)-4,6-diphenyl-1,3,5-triazine (18.1 g, 46.5 mmol) and tetrakis(triphenylphosphine)palladium (1.07 g, 0.93 mmol) purchased from Tokyo Chemical Industry (TCI) Co., Ltd. were added thereto and then, stirred. Subsequently, potassium carbonate (16.1 g, 116 mmol) saturated in water was added thereto and then, heated under reflux at 100° C. for 8 hours. When a reaction was completed, the reaction solution, after adding water thereto, was 1060 extracted with dichloromethane (DCM), treated with magnesium sulfate anhydrous to remove moisture, filtered, and concentrated under a reduced pressure. The obtained residue was separated and purified through flash column chromatography to obtain Compound 1-3 (27.9 g, 98%).

HRMS (70 eV, EI+): m/z calcd for C45H29N3: 611.2361, found: 611.

Elemental Analysis: C, 88%; H, 5%

### Synthesis Example 3: Synthesis of Compound 1-4

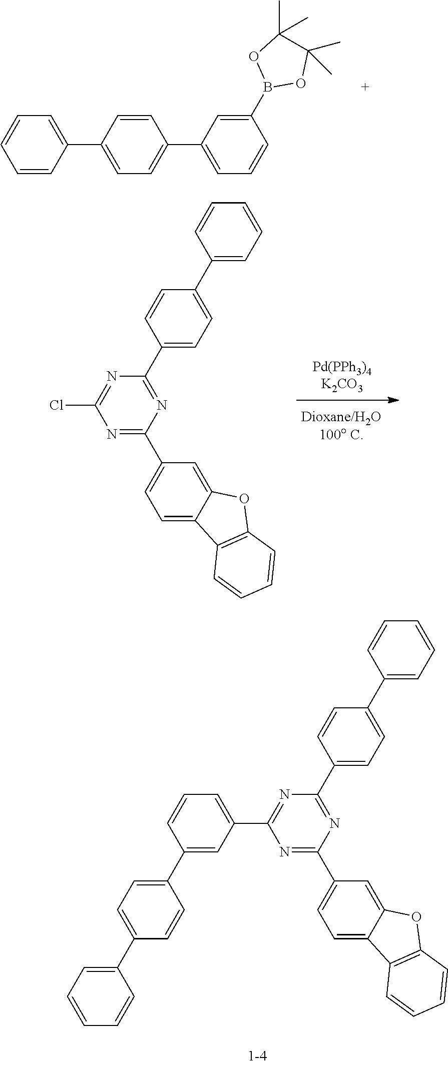

In a nitrogen environment, 2-([1,1′:4′,1″-Terphenyl]-3-yl)-4,4,5,5-tetramethyl-1,3,2-dioxaborolane (20 g, 56.1 mmol) purchased from TCI Co., Ltd. was dissolved in 0.2 L of dioxane, and 2-(biphenyl-4-yl)-4-chloro-6-(dibenzofuran-3-yl)-1,3,5-triazine (24.4 g, 56.1 mmol) and tetrakis(triphenylphosphine)palladium (1.30 g, 1.12 mmol) purchased from P&H Tech Co., Ltd. were added thereto and then, stirred. Subsequently, potassium carbonate (19.4 g, 140 mmol) saturated in water was added thereto and then, heated under reflux at 100° C. for 8 hours. When a reaction was completed, the reaction solution, after adding water thereto, was extracted with dichloromethane (DCM), treated with magnesium sulfate anhydrous to remove moisture, filtered, and concentrated under a reduced pressure. The obtained residue was separated and purified through flash column chromatography to obtain Compound 1-4 (31.3 g, 89%).

HRMS (70 eV, EI+): m/z calcd for C45H29N3O: 627.2311, found: 627.

Elemental Analysis: C, 86%; H, 5%

### Synthesis Example 4: Synthesis of Intermediate I-1

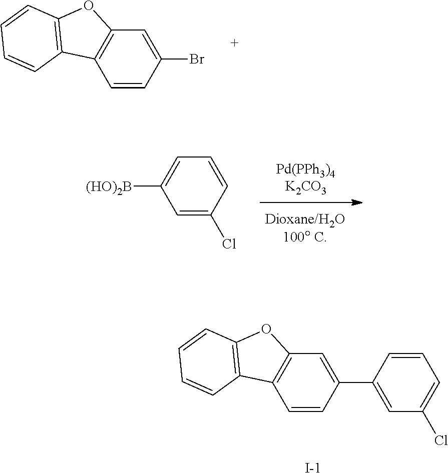 [SMILES: Brc1ccc2c(c1)oc1ccccc12 ; OB(O)c1cccc(Cl)c1 ; Clc1cccc(-c2ccc3c(c2)oc2ccccc23)c1 ; [I-]]

In a nitrogen environment, 3-bromodibenzofuran (50 g, 202 mmol) purchased from TCI Co., Ltd. was dissolved in 0.5 L of dioxane, and 3-chlorophenylboronic acid (38.0 g, 243 mmol) and tetrakis(triphenylphosphine)palladium (4.67 g, 4.04 mmol) purchased from TCI Co., Ltd. were added thereto and then, stirred. Subsequently, potassium carbonate (69.8 g, 505 mmol) saturated in water was added thereto and then, heated under reflux at 100° C. for 8 hours. When a reaction was completed, the reaction solution, after adding water thereto, was extracted with dichloromethane (DCM), treated with magnesium sulfate anhydrous to remove moisture, filtered, and concentrated under a reduced pressure. The obtained residue was separated and purified through flash column chromatography to obtain Intermediate I-1 (54.1 g, 96%).

HRMS (70 eV, EI+): m/z calcd for C18H11ClO: 278.0498, found: 278.

Elemental Analysis: C, 78%; H, 4%

### Synthesis Example 5: Synthesis of Intermediate I-2

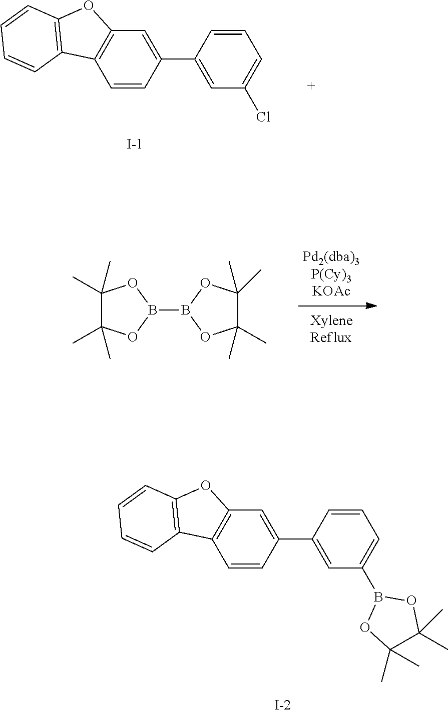

In a nitrogen environment, Intermediate I-1 (50 g, 179 mmol) was dissolved in 0.5 L of xylene, and bis(pinacolato)diboron (54.7 g, 215 mmol), tris(dibenzylideneacetone)dipalladium (0) (1.64 g, 1.79 mmol), tricyclohexylphosphine (2.01 g, 7.16 mmol), and potassium acetate (52.7 g, 537 mmol) were added thereto and then, heated under reflux for 8 hours. When a reaction was completed, the reaction solution, after adding water thereto, was extracted with dichloromethane (DCM), treated with magnesium sulfate anhydrous to remove moisture, filtered, and concentrated under a reduced pressure. The obtained residue was separated and purified through flash column chromatography to obtain Intermediate I-2 (53.0 g, 80%).

HRMS (70 eV, EI+): m/z calcd for C24H23BO3: 370.1740, found: 370.

Elemental Analysis: C, 78%; H, 6%

### Synthesis Example 6: Synthesis of Intermediate I-3

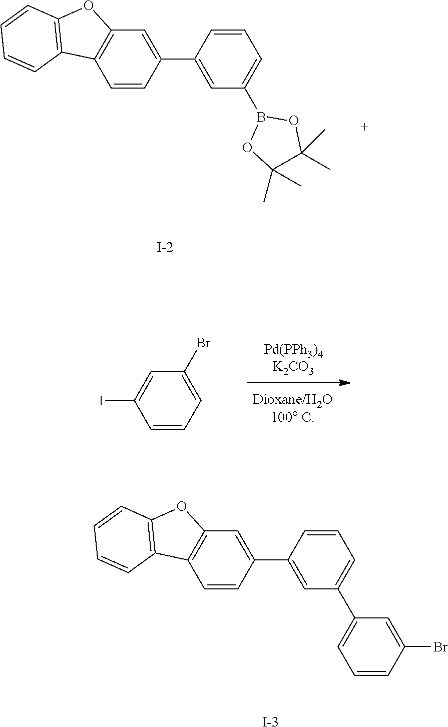

In a nitrogen environment, Intermediate I-2 (50 g, 135 mmol) was dissolved in 0.5 L of dioxane, and 1-bromo-3-iodobenzene (42.0 g, 149 mmol) and tetrakis(triphenylphosphine)palladium (3.12 g, 2.70 mmol) purchased from TCI Co., Ltd. were added thereto and then, stirred. Subsequently, potassium carbonate (46.6 g, 338 mmol) saturated in water was added thereto and then, heated under reflux at 100° C. for 8 hours. When a reaction was completed, the reaction solution, after adding water thereto, was extracted with dichloromethane (DCM), treated with magnesium sulfate anhydrous to remove moisture, filtered, and concentrated under a reduced pressure. The obtained residue was separated and purified through flash column chromatography to obtain Intermediate I-3 (48.5 g, 90%).

HRMS (70 eV, EI+): m/z calcd for C24H15BrO: 398.0306, found: 398.

Elemental Analysis: C, 72%; H, 4%

### Synthesis Example 7: Synthesis of Intermediate I-4

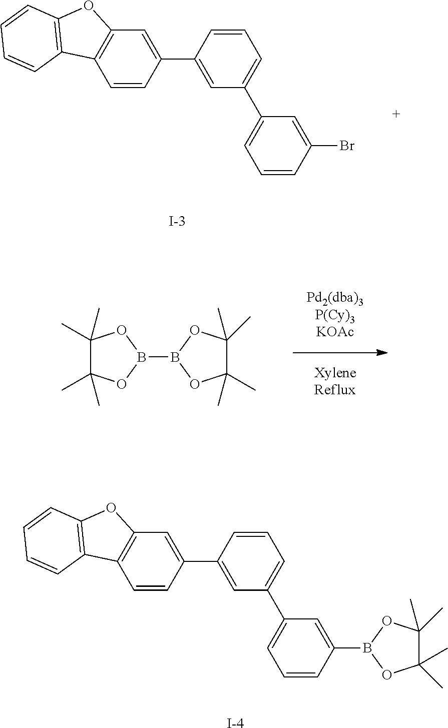

In a nitrogen environment, Intermediate I-3 (45 g, 113 mmol) was dissolved in 0.5 L of 1120 xylene, and bis(pinacolato)diboron (34.3 g, 135 mmol), tris(dibenzylideneacetone)dipalladium (0) (1.03 g, 1.13 mmol), tricyclohexylphosphine (1.27 g, 4.52 mmol), and potassium acetate (33.3 g, 339 mmol) were added thereto and then, heated under reflux for 8 hours. When a reaction was completed, the reaction solution, after adding water thereto, was extracted with dichloromethane (DCM), treated with magnesium sulfate anhydrous to remove moisture, filtered, and concentrated under a reduced pressure. The obtained residue was separated and purified through flash column chromatography to obtain Intermediate I-4 (44.4 g, 88%).

HRMS (70 eV, EI+): m/z calcd for C30H27BO3: 446.2053, found: 446.

Elemental Analysis: C, 81%; H, 6%

### Synthesis Example 8: Synthesis of Compound 1-5

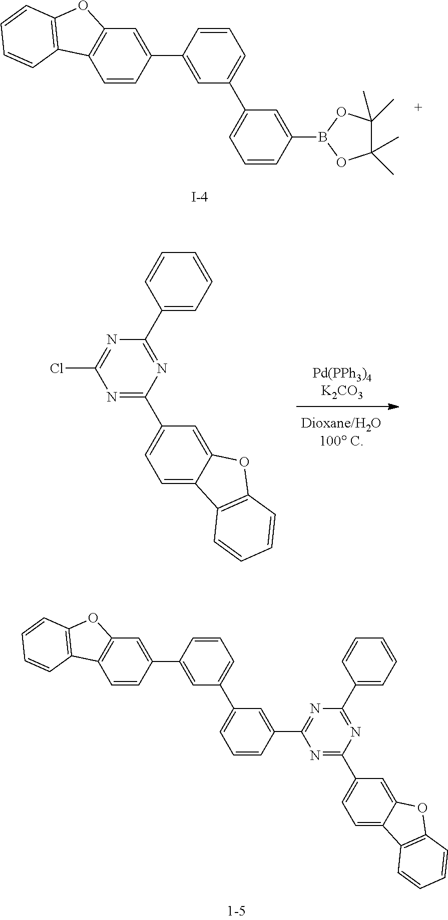

In a nitrogen environment, Intermediate I-4 (20 g, 44.8 mmol) was dissolved in 0.2 L of dioxane, and 2-chloro-4-(dibenzofuran-3-yl)-6-phenyl-1,3,5-triazine (16.0 g, 44.8 mmol) and tetrakis(triphenylphosphine)palladium (1.04 g, 0.90 mmol) purchased from P&H Tech Co., Ltd. were added thereto and then, stirred. Subsequently, potassium carbonate (15.5 g, 112 mmol) saturated in water was added thereto and then, heated under reflux at 100° C. for 8 hours. When a reaction was completed, the reaction solution, after adding water thereto, was extracted with dichloromethane (DCM), treated with magnesium sulfate anhydrous to remove moisture, filtered, and concentrated under a reduced pressure. The obtained residue was separated and purified through flash column chromatography to obtain Compound 1-5 (26.4 g, 92%).

HRMS (70 eV, EI+): m/z calcd for C45H27N3O2: 641.2103, found: 641.

Elemental Analysis: C, 84%; H, 4%

### Synthesis Example 9: Synthesis of Compound 1-8

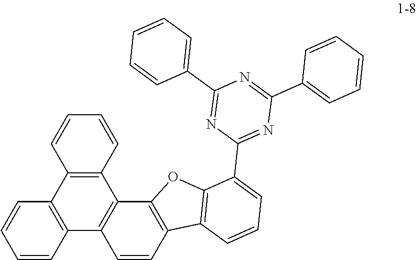 [SMILES: c1ccc(-c2nc(-c3ccccc3)nc(-c3cccc4c3oc3c4ccc4c5ccccc5c5ccccc5c43)n2)cc1]

Compounds 1-8 were synthesized by referring to the synthesis method of patent 1145 KR1970000.

HRMS (70 eV, EI+): m/z calcd for C39H23N3O: 549.1841, found: 549.

Elemental Analysis: C, 85%; H, 4%

### Synthesis Example 10: Synthesis of Compound 1-10

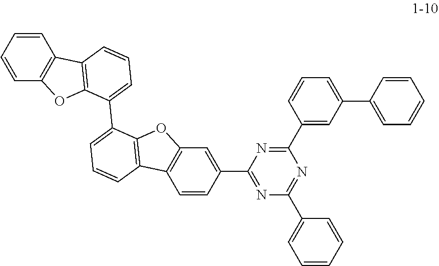 [SMILES: c1ccc(-c2cccc(-c3nc(-c4ccccc4)nc(-c4ccc5c(c4)oc4c(-c6cccc7c6oc6ccccc67)cccc45)n3)c2)cc1]

Compounds 1-10 were synthesized by referring to the synthesis method of patent KR1788094.

HRMS (70 eV, EI+): m/z calcd for C45H27N3O2: 641.2103, found: 641.

Elemental Analysis: C, 84%; H, 4%

### Synthesis Example 11: Synthesis of Compound 1-146

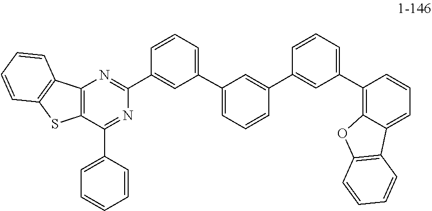 [SMILES: c1ccc(-c2nc(-c3cccc(-c4cccc(-c5cccc(-c6cccc7c6oc6ccccc67)c5)c4)c3)nc3c2sc2ccccc23)cc1]

Compound 1-146 was synthesized by referring to the synthesis method of patent KR1986260.

HRMS (70 eV, EI+): m/z calcd for C46H28N2OS: 656.1922, found: 656.

Elemental Analysis: C, 84%; H, 4%

### Synthesis Example 12: Synthesis of Compound 1-168

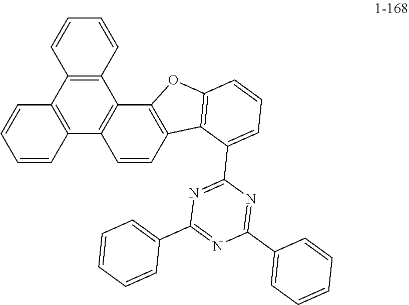 [SMILES: c1ccc(-c2nc(-c3ccccc3)nc(-c3cccc4oc5c(ccc6c7ccccc7c7ccccc7c65)c34)n2)cc1]

Compound 1-168 was synthesized by referring to the synthesis method of patent KR1970000.

HRMS (70 eV, EI+): m/z calcd for C39H23N3O: 549.1841, found: 549.

Elemental Analysis: C, 85%; H, 4%

### Synthesis Example 13: Synthesis of Compound 2-1

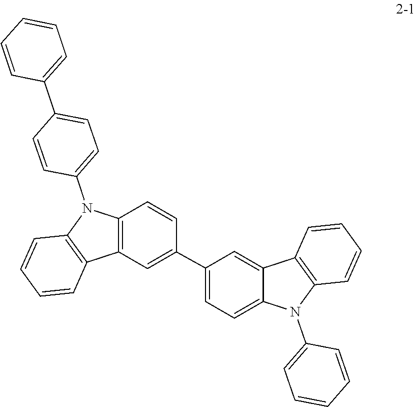 [SMILES: c1ccc(-c2ccc(-n3c4ccccc4c4cc(-c5ccc6c(c5)c5ccccc5n6-c5ccccc5)ccc43)cc2)cc1]

Compound 2-1 was synthesized by referring to the synthesis method of patent EP3034581.

HRMS (70 eV, EI+): m/z calcd for C42H28N2: 560.2252, found: 560.

Elemental Analysis: C, 90%; H, 5%

### Synthesis Example 14: Synthesis of Compound 2-3

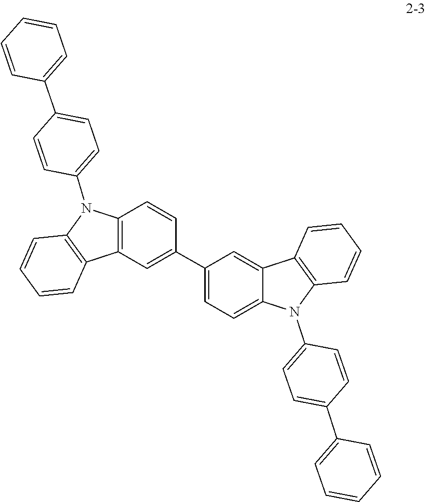 [SMILES: c1ccc(-c2ccc(-n3c4ccccc4c4cc(-c5ccc6c(c5)c5ccccc5n6-c5ccc(-c6ccccc6)cc5)ccc43)cc2)cc1]

Compound 2-3 was synthesized by referring to the synthesis method of patent KR2019-0000597.

HRMS (70 eV, EI+): m/z calcd for C48H32N2: 636.2565, found: 636.

Elemental Analysis: C, 91%; H, 5%

### Synthesis Example 15: Synthesis of Compound 2-69

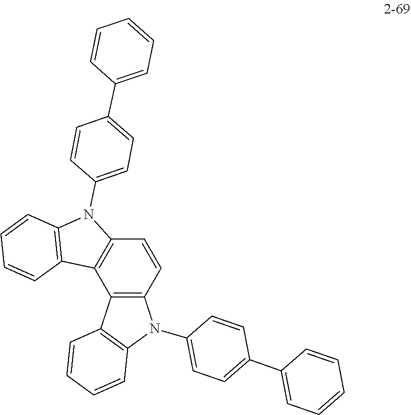 [SMILES: c1ccc(-c2ccc(-n3c4ccccc4c4c5c6ccccc6n(-c6ccc(-c7ccccc7)cc6)c5ccc43)cc2)cc1]

Compound 2-69 was synthesized by referring to the synthesis method of patent KR2031300.

HRMS (70 eV, EI+): m/z calcd for C42H28N2: 560.2252, found: 560.

Elemental Analysis: C, 90%; H, 5%

### Synthesis Example 16: Synthesis of Intermediate I-6

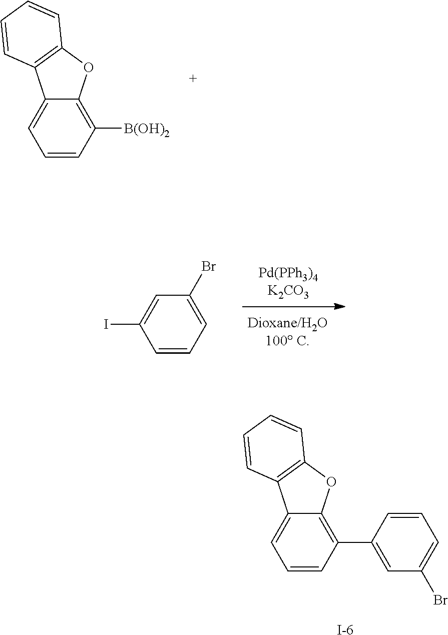

In a nitrogen environment, dibenzofuran-4-ylboronic acid (50 g, 236 mmol) purchased from TCI Co., Ltd. was dissolved in 0.5 L of dioxane, and 1-bromo-3-iodobenzene (73.4 g, 259 mmol) and tetrakis(triphenylphosphine)palladium (5.45 g, 4.72 mmol) purchased from TCI Co., Ltd. were added thereto and then, stirred. Subsequently, potassium carbonate (81.5 g, 590 mmol) saturated in water was added thereto and then, heated under reflux at 100° C. for 8 hours. When a reaction was completed, the reaction solution, after adding water thereto, was extracted with dichloromethane (DCM), treated with magnesium sulfate anhydrous to remove moisture, filtered, and concentrated under a reduced pressure. The obtained residue was separated and purified through flash column chromatography to obtain Intermediate I-6 (70.9 g, 93%).

HRMS (70 eV, EI+): m/z calcd for C18H11BrO: 321.9993, found: 321.

Elemental Analysis: C, 67%; H, 3%

### Synthesis Example 17: Synthesis of Compound 3-1

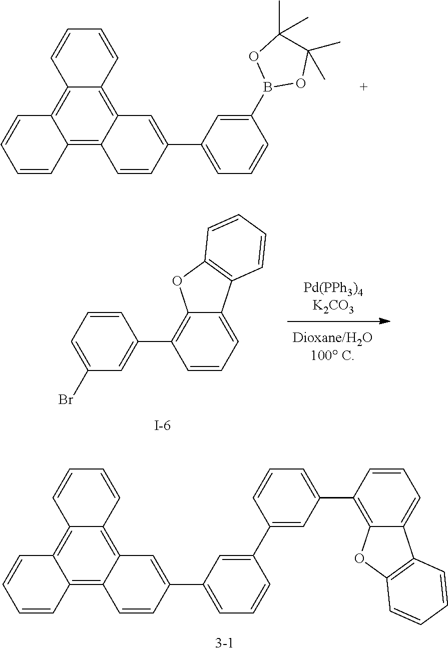

In a nitrogen environment, 4,4,5,5-tetramethyl-2-(3-(triphenylen-2-yl)phenyl)-1,3,2-dioxaborolane (20 g, 46.5 mmol) purchased from P&H Tech Co., Ltd. was dissolved in 0.2 L of dioxane, and Intermediate I-6 (15.0 g, 46.5 mmol) and tetrakis(triphenylphosphine)palladium (1.0 7 g, 0.93 mmol) were added thereto and then, stirred. Subsequently, potassium carbonate (16.1 g, 116 mmol) saturated in water was added thereto and then, heated under reflux at 100° C. for 8 hours. When a reaction was completed, the reaction solution, after adding water thereto, was extracted with dichloromethane (DCM), treated with magnesium sulfate anhydrous to remove moisture, filtered, and concentrated under a reduced pressure. The obtained residue was separated and purified through flash column chromatography to obtain Compound 3-1 (22.9 g, 90%).

HRMS (70 eV, EI+): m/z calcd for C46H20O: 546.1984, found: 546.

Elemental Analysis: C, 92%; H, 5%

### Synthesis Example 18: Synthesis of Intermediate I-7

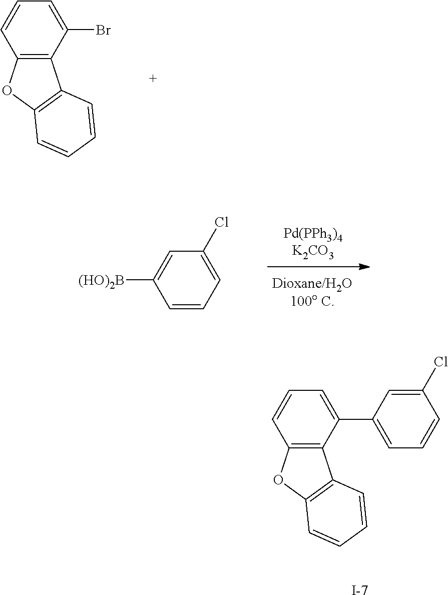

In a nitrogen environment, 1-bromodibenzofuran (50 g, 202 mmol) purchased from TCI Co., Ltd. was dissolved in 0.5 L of dioxane, and 3-chlorophenylboronic acid (37.2 g, 243 mmol) and tetrakis(triphenylphosphine)palladium (4.67 g, 4.04 mmol) purchased from TCI Co., Ltd. were added thereto and then, stirred. Subsequently, potassium carbonate (69.8 g, 505 mmol) saturated in water was added thereto and then, heated under reflux at 100° C. for 8 hours. When a reaction was completed, the reaction solution, after adding water thereto, was extracted with dichloromethane (DCM), treated with magnesium sulfate anhydrous to remove moisture, filtered, and concentrated under a reduced pressure. The obtained residue was separated and purified through flash column chromatography to obtain Intermediate I-7 (51.2 g, 91%).

HRMS (70 eV, EI+): m/z calcd for C18H11ClO: 278.0498, found: 278.

Elemental Analysis: C, 78%; H, 4%

### Synthesis Example 19: Synthesis of Intermediate I-8

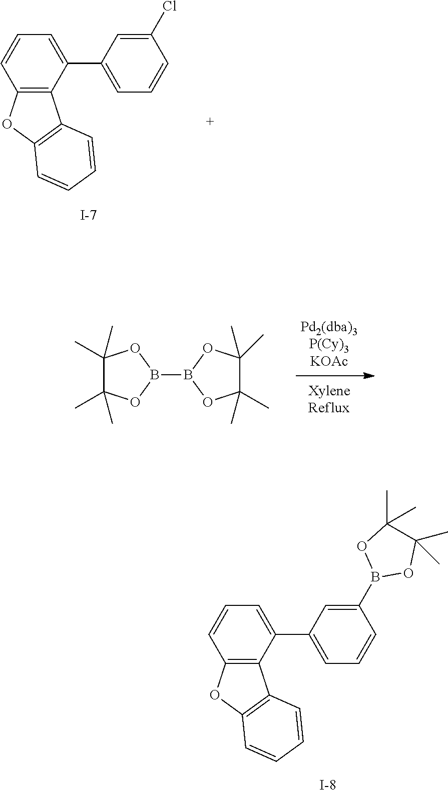

In a nitrogen environment, Intermediate I-7 (50 g, 179 mmol) was dissolved in 0.5 L of xylene, and bis(pinacolato)diboron (54.7 g, 215 mmol), tris(dibenzylideneacetone)dipalladium (0) (1.64 g, 1.79 mmol), tricyclohexylphosphine (2.01 g, 7.16 mmol), and potassium acetate (52.7 g, 537 mmol) were added thereto and then, heated under reflux for 8 hours. When a reaction was completed, the reaction solution, after adding water thereto, was extracted with dichloromethane (DCM), treated with magnesium sulfate anhydrous to remove moisture, filtered, and concentrated under a reduced pressure. The obtained residue was separated and purified through flash column chromatography to obtain Intermediate I-8 (49.7 g, 75%).

HRMS (70 eV, EI+): m/z calcd for C24H23BO3: 370.1740, found: 370.

Elemental Analysis: C, 78%; H, 6%

### Synthesis Example 20: Synthesis of Compound 3-2

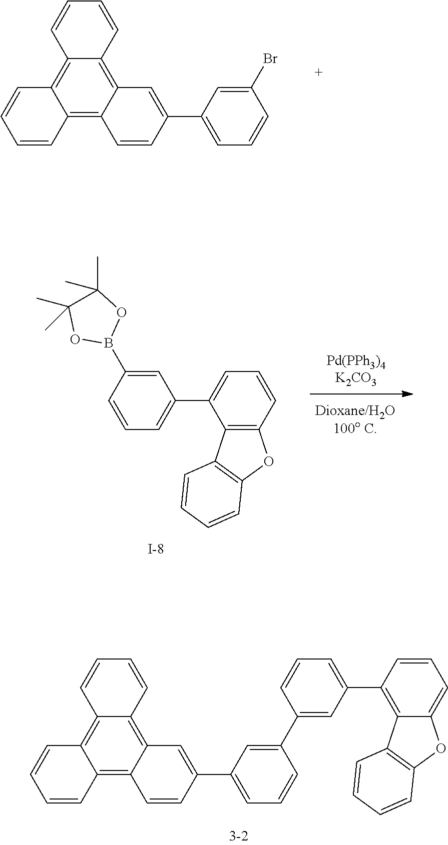

In a nitrogen environment, 2-(3-bromophenyl)triphenylene (20 g, 52.2 mmol) purchased from P&H Tech Co., Ltd. was dissolved in 0.2 L of dioxane, and Intermediate I-8 (21.3 g, 57.4 mmol) and tetrakis(triphenylphosphine)palladium (1.21 g, 1.04 mmol) were added thereto and then, stirred. Subsequently, potassium carbonate (18.1 g, 131 mmol) saturated in water was added thereto and then, heated under reflux at 100° C. for 8 hours. When a reaction was completed, the reaction solution, after adding water thereto, was extracted with dichloromethane (DCM), treated with magnesium sulfate anhydrous to remove moisture, filtered, and concentrated under a reduced pressure. The obtained residue was separated and purified through flash column chromatography to obtain Compound 3-2 (27.1 g, 95%).

HRMS (70 eV, EI+): m/z calcd for C46H20O: 546.1984, found: 546.

Elemental Analysis: C, 92%; H, 5%

### Example 1

A glass substrate coated with ITO (indium tin oxide) was washed with distilled water ultrasonic wave. After washing with the distilled water, the glass substrate was washed with a solvent such as isopropyl alcohol, acetone, methanol, and the like ultrasonically and dried and then, moved to a plasma cleaner, cleaned by using oxygen plasma for 10 minutes, and moved to a vacuum depositor. This prepared ITO transparent electrode was used as an anode, Compound A doped with 3% NDP-9 (Novaled GmbH) was vacuum-deposited on the ITO substrate to form a 100 Å-thick hole injection layer, and Compound A is deposited on the hole injection layer to a thickness of 1350 Å to form a hole transport layer. Compound B was deposited on the hole transport layer to a thickness of 350 Å to form a hole transport auxiliary layer. On the hole transport auxiliary layer, a 400 Å-thick light emitting layer was formed by vacuum deposition using a composition obtained by simultaneously mixing Compound 1-2 synthesized in Synthesis Example 1, Compound 2-1 synthesized in Synthesis Example 13, and Compound 3-1 synthesized in Synthesis Example 17 as a host and doping 10 wt % of PhGD. Herein, Compound 1-2, Compound 2-1, and Compound 3-1 were used in a weight ratio of 35:55:10. Subsequently, Compound C was deposited to form a 50 Å-thick electron transport auxiliary layer on the light emitting layer, and Compound D and Liq were simultaneously vacuum-deposited in a weight ratio of 1:1 to form a 300 Å-thick electron transport layer. On the electron transport layer, Liq and Al were sequentially vacuum-deposited to be 15 Å-thick and 1200 Å-thick, manufacturing an organic light emitting diode.

ITO/Compound A (3% NDP-9 doping, 100 Å)/Compound A (1350 Å)/Compound B (350 Å)/EML[{Host (Compound 1-2: Compound 2-1: Compound 3-1:=35:55:10) 90 wt %}+{dopant (PhGD) 10 wt %}] (400 Å)/Compound C (50 Å)/Compound D:LiQ (300 Å)/Liq (15 Å)/Al (1200 Å).

Compound A: N-(biphenyl-4-yl)-9,9-dimethyl-N-(4-(9-phenyl-9H-carbazol-3-yl)phenyl)-9H-fluoren-2-amine

Compound B: N,N-bis(9,9-dimethyl-9H-fluoren-4-yl)-9,9-spirobi(fluorene)-2-amine

Compound C: 2-[3′-(9,9-Dimethyl-9H-fluoren-2-yl)[1,1′-biphenyl]-3-yl]-4,6-diphenyl-1,3,5-triazine

Compound D: 2-[4-[4-(4′-Cyano-1,1′-biphenyl-4-yl)-1-naphthyl]phenyl]-4,6-diphenyl-1,3,5-triazine

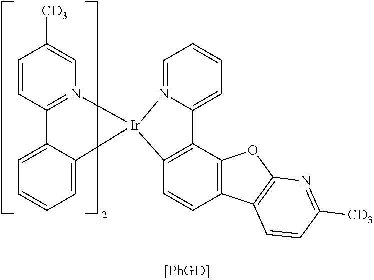

### Examples 2 to 12 and Comparative Examples 1 to 10

Organic light emitting diodes were manufactured in the same manner as in Example 1, except for changing the composition described in Tables 1 to 10.

### Evaluation

Driving voltage, luminous efficiency, and life-span characteristics of the organic light emitting diodes according to Examples 1 to 12 and Comparative Examples 1 to 10 were evaluated.

Specific measurement methods are as follows, and the results are shown in Table 1 to Table 10.

(1) Measurement of Current Density Change Depending on Voltage Change

The obtained organic light emitting diodes were measured regarding a current value flowing in the unit device, while increasing the voltage from 0 V to 10 V using a current-voltage meter (Keithley 2400), and the measured current value was divided by area to provide the results.

(2) Measurement of Luminance Change Depending on Voltage Change

Luminance was measured by using a luminance meter (Minolta Cs-1000A), while the voltage of the organic light emitting diodes was increased from 0 V to 10 V.

(3) Measurement of Luminous Efficiency

Luminous efficiency (cd/A) at the same current density (10 mA/cm²) were calculated by using the luminance and current density from (1) and (2) above, and voltages (V).

(4) Measurement of Life-Span

The results were obtained by measuring a time when current efficiency (cd/A) was 1300 decreased down to 97%, while luminance (cd/m²) was maintained to be 24000 cd/m².

(5) Measurement of Roll Off (RO)

Using the luminance and current density measured from (1) and (2) above, and voltage, the roll off value was calculated by dividing the luminous efficiency (max cd/A) at the highest luminance by the luminous efficiency (cd/A) when the luminance (cd/m²) was 9000 cd/m² [=(Luminous efficiency at Max luminance)/(Luminous efficiency at 9000 cd/m²)].

(6) Measurement Driving Voltage

A driving voltage of each diode was measured using a current-voltage meter (Keithley 2400) at 15 mA/cm² to obtain the results.

Regarding the luminous efficiency, life-span measurement, roll off (RO) and driving voltage of Examples 1 to 12 and Comparative Examples 1 to 10,
relative values based on Comparative Example 1 were calculated and shown in Table 1.
Relative values based on Comparative Example 2 were calculated and shown in Table 2.
Relative values based on Comparative Example 3 were calculated and shown in Table 3.
Relative values based on Comparative Example 4 were calculated and shown in Table 4.
Relative values based on Comparative Example 5 were calculated and shown in Table 5.
Relative values based on Comparative Example 6 were calculated and shown in Table 6.
Relative values based on Comparative Example 7 were calculated and shown in Table 7.
Relative values based on Comparative Example 8 were calculated and shown in Table 8.
Relative values based on Comparative Example 9 were calculated and shown in Table 9.
Relative values based on Comparative Example 10 were calculated and shown in Table 10.

TABLE 1

| | Composition: | | | | |
|---|---|---|---|---|---|
| | first compound/second | | Light | T97 | |
| | compound/third | Driving | emitting | life- | |
| | compound | voltage | efficiency | span | RO |
| Nos. | (weight ratio) | (%) | (%) | (%) | (%) |
| Example 1 | 1-2/2-1/3-1 (35:55:10) | 100% | 102% | 105% | 89% |
| Example 2 | 1-2/2-1/3-1 (27:53:20) | 100% | 105% | 100% | 84% |
| Example 3 | 1-2/2-1/3-2 (35:55:10) | 99% | 103% | 100% | 87% |
| Comparative | 1-2/2-1 (30:70) | 100% | 100% | 100% | 100% |
| Example 1 | | | | | |

TABLE 2

| | Composition: | | | | |
|---|---|---|---|---|---|
| | first compound/second | | Light | T97 | |
| | compound/third | Driving | emitting | life- | |
| | compound | voltage | efficiency | span | RO |
| Nos. | (weight ratio) | (%) | (%) | (%) | (%) |
| Example 4 | 1-2/2-3/3-1 (35:55:10) | 98% | 102% | 103% | 85% |
| Comparative | 1-2/2-3 (30:70) | 100% | 100% | 100% | 100% |
| Example 2 | | | | | |

TABLE 3

| | Composition: | | | | |
|---|---|---|---|---|---|
| | first compound/second | | Light | T97 | |
| | compound/third | Driving | emitting | life- | |
| | compound | voltage | efficiency | span | RO |
| Nos. | (weight ratio) | (%) | (%) | (%) | (%) |
| Example 5 | 1-2/2-69/3-1 (35:55:10) | 100% | 102% | 111% | 87% |
| Comparative | 1-2/2-69 (30:70) | 100% | 100% | 100% | 100% |
| Example 3 | | | | | |

TABLE 4

| | Composition: | | | | |
|---|---|---|---|---|---|
| | first compound/second | | Light | T97 | |
| | compound/third | Driving | emitting | life- | |
| | compound | voltage | efficiency | span | RO |
| Nos. | (weight ratio) | (%) | (%) | (%) | (%) |
| Example 6 | 1-3/2-1/3-1 (35:55:10) | 100% | 101% | 104% | 90% |
| Comparative | 1-3/2-1 (30:70) | 100% | 100% | 100% | 100% |
| Example 4 | | | | | |

TABLE 5

| | Composition: | | | | |
|---|---|---|---|---|---|
| | first compound/second | | Light | T97 | |
| | compound/third | Driving | emitting | life- | |
| | compound | voltage | efficiency | span | RO |
| Nos. | (weight ratio) | (%) | (%) | (%) | (%) |
| Example 7 | 1-4/2-1/3-1 (35:55:10) | 100% | 113% | 106% | 85% |
| Comparative | 1-4/2-1 (30:70) | 100% | 100% | 100% | 100% |
| Example 5 | | | | | |

TABLE 6

| | Composition: | | | | |
|---|---|---|---|---|---|
| | first compound/second | | Light | T97 | |
| | compound/third | Driving | emitting | life- | |
| | compound | voltage | efficiency | span | RO |
| Nos. | (weight ratio) | (%) | (%) | (%) | (%) |
| Example 8 | 1-5/2-1/3-1 (35:55:10) | 99% | 107% | 105% | 79% |
| Comparative | 1-5/2-1 (30:70) | 100% | 100% | 100% | 100% |
| Example 6 | | | | | |

TABLE 7

| | Composition: | | | | |
|---|---|---|---|---|---|
| | first compound/second | | Light | T97 | |
| | compound/third | Driving | emitting | life- | |
| | compound | voltage | efficiency | span | RO |
| Nos. | (weight ratio) | (%) | (%) | (%) | (%) |
| Example 9 | 1-8/2-1/3-1 (35:55:10) | 99% | 102% | 103% | 86% |
| Comparative | 1-8/2-1 (30:70) | 100% | 100% | 100% | 100% |
| Example 7 | | | | | |

TABLE 8

| | Composition: | | | | |
|---|---|---|---|---|---|
| | first compound/second | | Light | T97 | |
| | compound/third | Driving | emitting | life- | |
| | compound | voltage | efficiency | span | |
| Nos. | (weight ratio) | (%) | (%) | (%) | RO |
| Example 10 | 1-10/2-1/3-1 (35:55:10) | 100% | 102% | 110% | 80% |
| Comparative | 1-10/2-1 (30:70) | 100% | 100% | 100% | 100% |
| Example 8 | | | | | |

TABLE 9

| | Composition: | | | | |
|---|---|---|---|---|---|
| | first compound/second | | Light | T97 | |
| | compound/third | Driving | emitting | life- | |
| | compound | voltage | efficiency | span | RO |
| Nos. | (weight ratio) | (%) | (%) | (%) | (%) |
| Example 11 | 1-146/2-1/3-1 (35:55:10) | 100% | 104% | 114% | 72% |
| Comparative | 1-146/2-1 (30:70) | 100% | 100% | 100% | 100% |
| Example 9 | | | | | |

TABLE 10

| | Composition: | | | | |
|---|---|---|---|---|---|
| | first compound/second | | Light | T97 | |
| | compound/third | Driving | emitting | life- | |
| | compound | voltage | efficiency | span | RO |
| Nos. | (weight ratio) | (%) | (%) | (%) | (%) |
| Example 12 | 1-168/2-1/3-1 (35:55:10) | 99% | 102% | 106% | 84% |
| Comparative | 1-168/2-1 (30:70) | 100% | 100% | 100% | 100% |
| Example 10 | | | | | |

Referring to Tables 1 to 10, organic light emitting diodes according to Examples 1 to 12 are significantly improved in driving voltage, luminous efficiency, life-span characteristics and roll off characteristics compared to organic light emitting diodes according to Comparative Examples 1 to 10.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

1. A composition for an organic optoelectronic device, comprising
a first compound;
a second compound; and
a third compound,
wherein:
the first compound is represented by Chemical Formula I or Chemical Formula II,
the second compound is represented by Chemical Formula III, and
the third compound is represented by Chemical Formula IV: 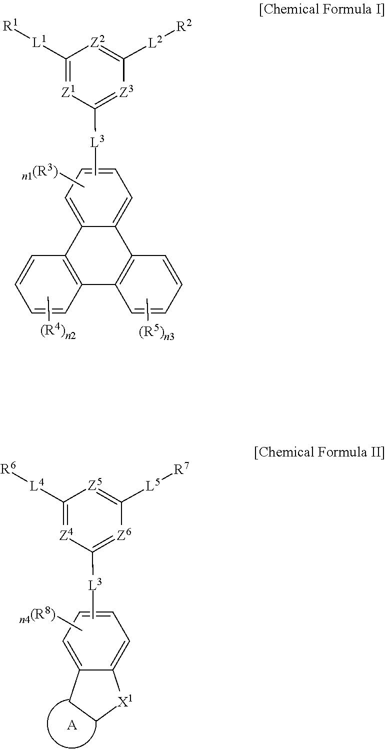
wherein, in Chemical Formula I and Chemical Formula II,
Z¹ to Z⁶ are N or C-L^{a}-R^{a},
at least two of Z¹ to Z³ are N,
at least two of Z⁴ to Z⁶ are N,
X¹ is O or S,
L^{a} and L¹ to L⁶ are each independently a single bond, a substituted or unsubstituted C6 to C20 arylene group, a substituted or unsubstituted C2 to C20 heterocyclic group, or a combination thereof,
R¹, R², R⁶, and R⁷ are each independently a substituted or unsubstituted C6 to C30 aryl group, a substituted or unsubstituted C2 to C30 heterocyclic group, or a combination thereof,
R^{a}, R³ to R⁵, and R⁸ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted thioaryl group, a substituted or unsubstituted silyl group, a substituted or unsubstituted amine group, a halogen, a cyano group, or a combination thereof,
R^{a}s of Chemical Formula I are each independently present or linked to R¹ or R² to form a substituted or unsubstituted hetero aromatic polycyclic ring,
R³ to R⁵ of Chemical Formula I are each independently present or adjacent groups are linked to each other to form a substituted or unsubstituted hetero aromatic polycyclic ring,
R^{a}s of Chemical Formula II are each independently present or linked to R⁶ or R⁷ to form a substituted or unsubstituted hetero aromatic polycyclic ring,
n1 and n4 are each independently one of integers of 1 to 3,
n2 and n3 are each independently one of integers of 1 to 4, and
ring A is represented by any one of the following Chemical II-1 to II-14, 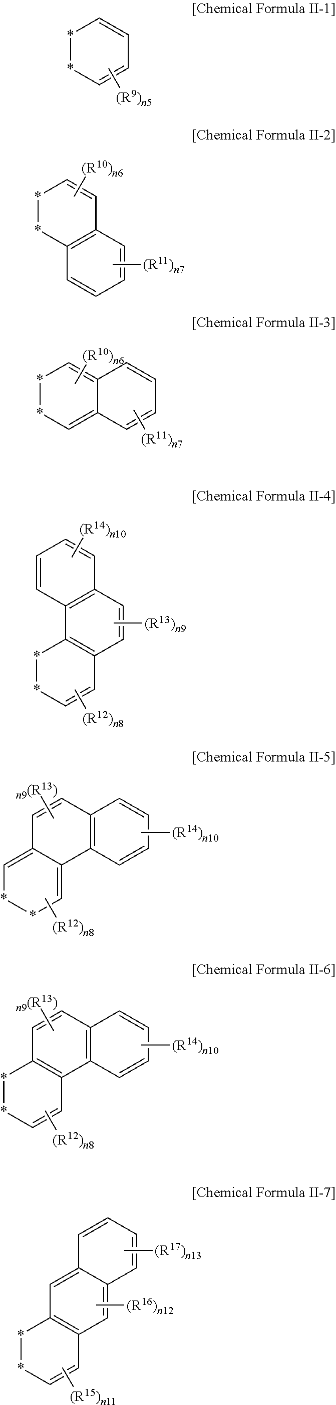 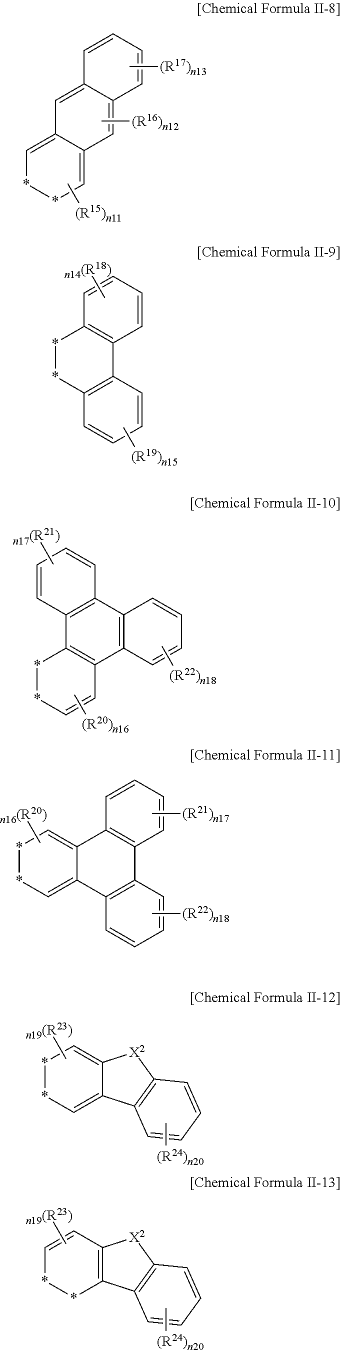 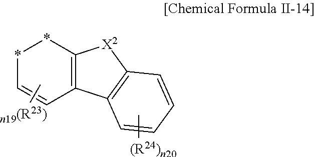
wherein, in Chemical Formula II-1 to Chemical Formula II-14,
X² is O or S,
R⁹ to R²⁴ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof,
n5, n7, n10, n13 to n15, n17, n18, and n20 are each independently one of integers of 1 to 4,
n6, n8, n9, n11, n12, n16, and n19 are each independently 1 or 2, and
* is a linking point; 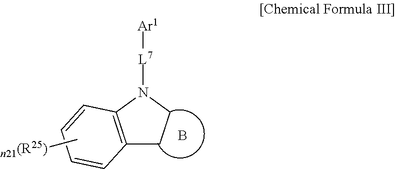
wherein, in Chemical Formula III,
L⁷ is a single bond, a substituted or unsubstituted C6 to C20 arylene group, a substituted or unsubstituted C2 to C20 heterocyclic group, or a combination thereof,
Ar¹ is a substituted or unsubstituted C6 to C30 aryl group, a substituted or unsubstituted dibenzofuranyl group, a substituted or unsubstituted dibenzothiophenyl group, or a combination thereof,
R²⁵ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof,
n21 is an integer from 1 to 4, and
ring B is represented by any one of Chemical Formulas III-1 to Chemical Formula III-4: 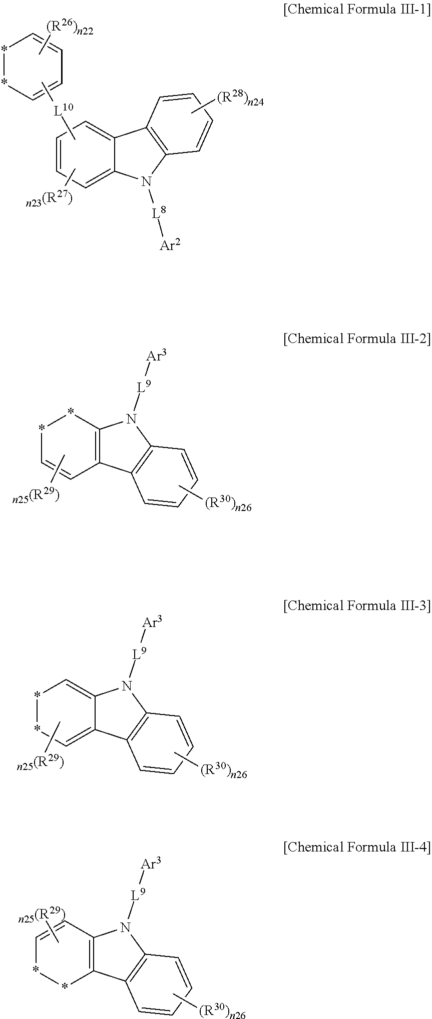
wherein, in Chemical Formula III-1 to Chemical Formula III-4,
L⁸ and L⁹ are each independently a single bond, a substituted or unsubstituted C6 to C20 arylene group, a substituted or unsubstituted C2 to C20 heterocyclic group, or a combination thereof,
L¹⁰ is a single bond or a substituted or unsubstituted C6 to C20 arylene group,
Ar² and Ar³ are a substituted or unsubstituted C6 to C30 aryl group, a substituted or unsubstituted dibenzofuranyl group, a substituted or unsubstituted dibenzothiophenyl group, or a combination thereof,
R²⁶ to R³⁰ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof,
n22 and n23 are each independently one of integers of 1 to 3,
n25 is 1 or 2,
n24 and n26 are each independently one of integers of 1 to 4, and
* is a linking point; 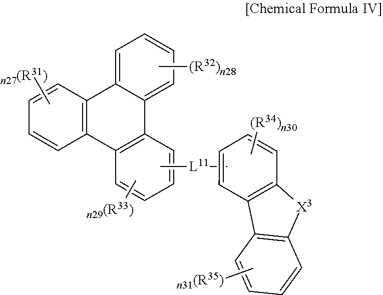
wherein, in Chemical Formula IV,
X³ is O or S,
L¹¹ is a single bond, a substituted or unsubstituted C6 to C20 arylene group, a substituted or unsubstituted C2 to C20 heterocyclic group, or a combination thereof,
R³¹ to R³⁵ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof,
n27, n28, and n31 are each independently an integer of 1 to 4, and
n29 and n30 are each independently an integer of 1 to 3.

2. The composition for the organic optoelectronic device of claim 1, wherein:
the first compound is represented by any one of Chemical Formula I-A, Chemical Formula II-A, Chemical Formula II-E, Chemical Formula II-O, and Chemical Formula II-U: 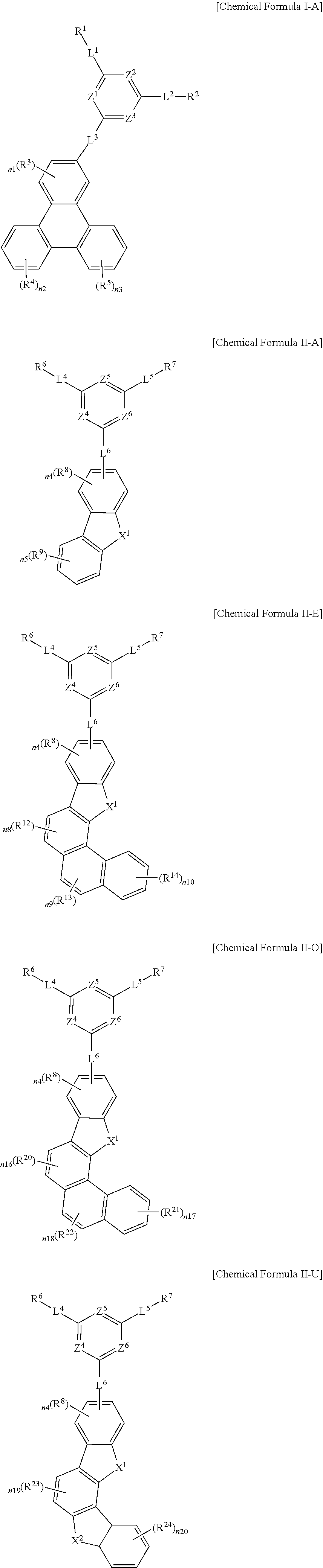
in Chemical Formula I-A, Chemical Formula II-A, Chemical Formula II-E, Chemical Formula II-O, and Chemical Formula II-U, Z¹ to Z⁶, L¹ to L⁶, R¹ to R⁹, R¹² to R¹⁴, R²⁰ to R²⁴, X¹, X², n1 to n5, n8 to n10, and n16 to n20 are defined the same as those of Chemical Formula I and Chemical Formula II.

3. The composition for the organic optoelectronic device of claim 1, wherein:
the second compound represented by Chemical Formula III-A or Chemical Formula III-F: 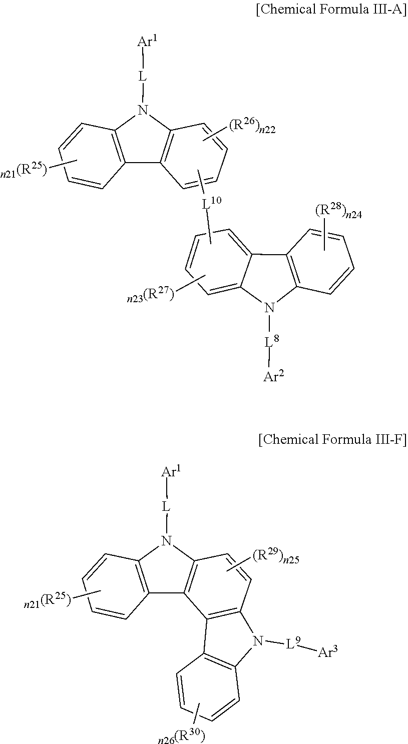
in Chemical Formula III-A and Chemical Formula III-F, L⁷ to L¹⁰, Ar¹ to Ar³, R²⁵ to R³⁰ and n21 to n26 are defined the same as those of Chemical Formula III.

4. The composition for the organic optoelectronic device of claim 3, wherein:
the second compound represented by Chemical Formula III-A,
Chemical Formula III-A is represented by any one of Chemical Formula III-A-1 to Chemical Formula III-A-3: 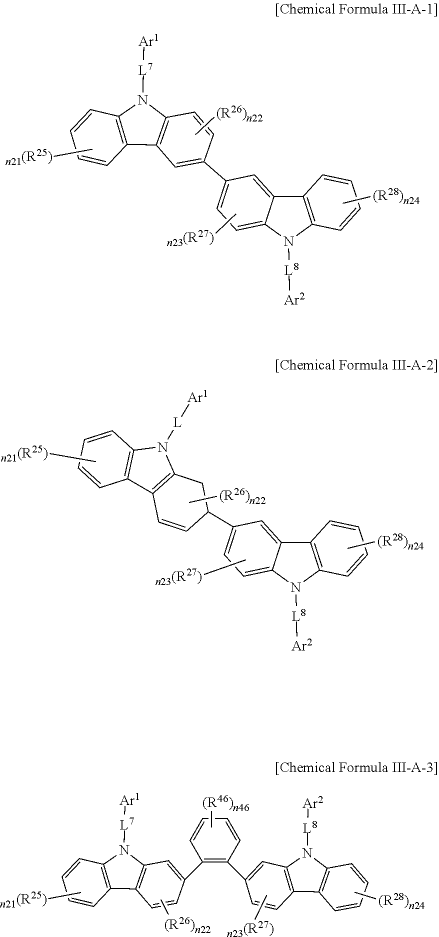
in Chemical Formula III-A-1 to Chemical Formula III-A-3, L⁷, L⁸, Ar¹, Ar², R²⁵ to R²⁸ and n21 to n24 are defined the same as those of Chemical Formula III,
R⁴⁶s are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and
n46 is an integer of 1 to 4.

5. The composition for the organic optoelectronic device of claim 1, wherein:
the second compound is represented by any one of the following Chemical Formula III-A-1, Chemical Formula III-A-2 and Chemical Formula III-F: 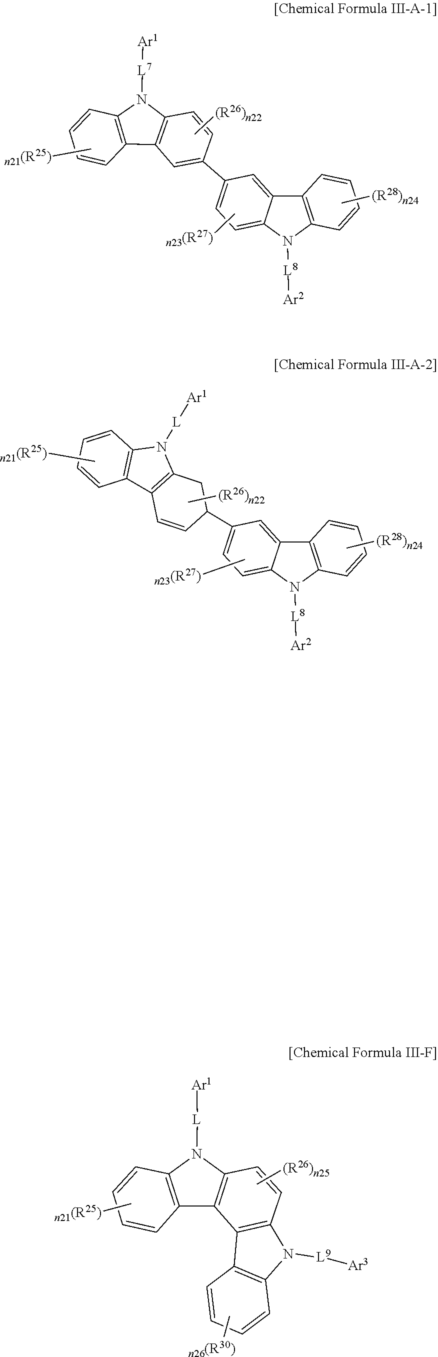
in Chemical Formula III-A-1, Chemical Formula III-A-2 and Chemical Formula III-F,
R²⁵ to R²⁸ are each hydrogen,
n21 to n24 are each 4,
L⁷ to L⁹ are each independently a single bond or a substituted or unsubstituted phenylene group, and
Ar¹ to Ar³ are each independently a substituted or unsubstituted phenyl group, or a substituted or unsubstituted biphenyl group.

6. The composition for the organic optoelectronic device of claim 1, wherein:
the third compound is represented by any one of Chemical Formula IV-1 to Chemical Formula IV-4: 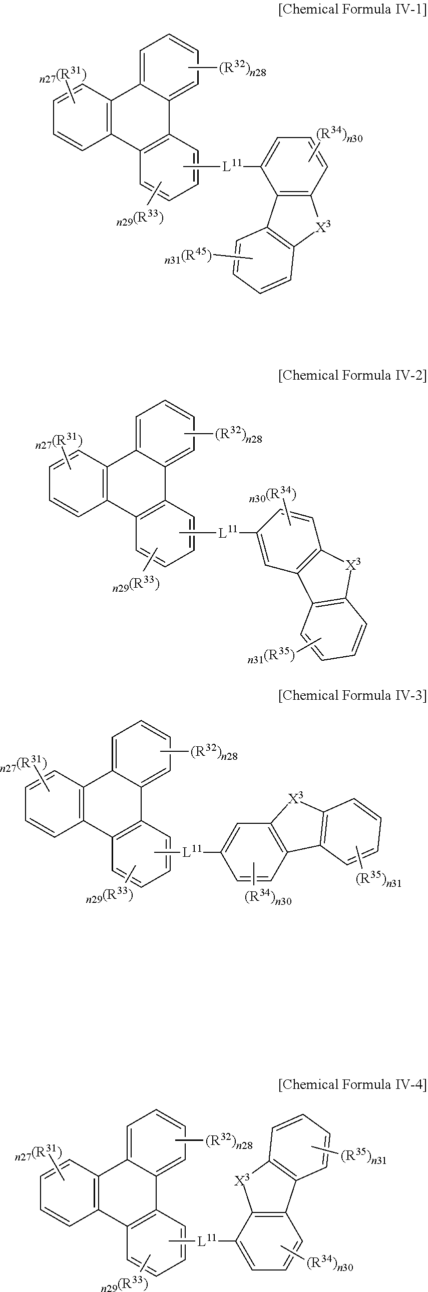
in Chemical Formula IV-1 to Chemical Formula IV-4, L¹¹, R³¹ to R³⁵ and n27 to n31 are defined the same as those of Chemical Formula IV.

7. The composition for the organic optoelectronic device of claim 6, wherein the third compound is represented by Chemical Formula IV-1 or Chemical Formula IV-4.

8. An organic photoelectronic device, comprising:
an anode and a cathode facing each other,
at least one organic layer between the anode and the cathode,
the at least one organic layer includes the composition for the organic optoelectronic device of claim 1.

9. The composition for the organic optoelectronic device of claim 8, wherein:
the organic layer includes a light emitting layer, and
the light emitting layer includes the composition for an organic optoelectronic device.

10. The composition for the organic optoelectronic device of claim 9, wherein the first compound, the second compound, and the third compound are each a phosphorescent host of the light emitting layer.

11. The composition for the organic optoelectronic device of claim 10, wherein:
the first compound is included in an amount of about 20 wt % to about 50 wt %, based on a total weight of the first compound, the second compound, and the third compound,
the second compound is included in an amount of about 40 wt % to about 60 wt %, based on the total weight of the first compound, the second compound, and the third compound, and
the third compound is included in an amount of about 10 wt % to about 30 wt %, based on the total weight of the first compound, the second compound, and the third compound.

12. The composition for the organic optoelectronic device of claim 9, wherein the composition for an organic optoelectronic device further includes a dopant.

13. The composition for the organic optoelectronic device of claim 12, wherein the composition for an organic optoelectronic device is a green light emitting composition.

14. A display device comprising the organic photoelectronic device of claim 8.
